(19) United States
(12) Patent Application Publication
(10) Pub. No.: US 2020/0366180 A1
(43) Pub. Date: Nov. 19, 2020

(54) MAGNETOHYDRODYNAMIC ELECTRIC POWER GENERATOR

(71) Applicant: Brilliant Light Power, Inc., Cranbury, NJ (US)

(72) Inventor: Randell L. Mills, Cranbury, NJ (US)

(73) Assignee: Brilliant Light Power, Inc., Cranbury, NJ (US)

(21) Appl. No.: 16/767,773

(22) PCT Filed: Dec. 5, 2018
(86) PCT No.: PCT/IB2018/059646

§ 371 Date: May 28, 2020

Related U.S. Application Data
(60) Provisional application No. 62/594,936, filed on Dec. 5, 2017.
(60) Provisional application No. 62/612,304, filed on Dec. 29, 2017.
(60) Provisional application No. 62/618,444, filed on Jan. 17, 2018.
(60) Provisional application No. 62/630,755, filed on Feb. 14, 2018.
(60) Provisional application No. 62/644,392, filed on Mar. 17, 2018.
(60) Provisional application No. 62/652,283, filed on Apr. 3, 2018.
(60) Provisional application No. 62/688,990, filed on Jun. 22, 2018.
(60) Provisional application No. 62/698,025, filed on Jul. 14, 2018.
(60) Provisional application No. 62/714,732, filed on Aug. 5, 2018.
(60) Provisional application No. 62/728,716, filed on Sep. 7, 2018.
(60) Provisional application No. 62/738,966, filed on Sep. 28, 2018.
(60) Provisional application No. 62/748,955, filed on Oct. 22, 2018.
(60) Provisional application No. 62/769,483, filed on Nov. 19, 2018.

(51) Int. Cl. H02K 44/08; H02K 47/02; H01L 31/0735; C01B 3/02; H02S 10/30

(52) U.S. Cl. CPC H02K 44/085; H02K 47/02; C01B 2203/0833; C01B 3/02; H02S 10/30; H01L 31/0735

(57) ABSTRACT

A power generator that provides at least one of electrical and thermal power comprising (i) at least one reaction cell for the catalysis of atomic hydrogen to form hydrinos identifiable by unique analytical and spectroscopic signatures, (ii) a reaction mixture comprising at least two components chosen from: a source of H2O catalyst or H2O catalyst; a source of atomic hydrogen or atomic hydrogen; reactants to form the source of H2O catalyst or H2O catalyst and a source of atomic hydrogen or atomic hydrogen; and a molten metal to cause the reaction mixture to be highly conductive, (iii) a molten metal injection system comprising at least one pump such as an electromagnetic pump that provides a molten metal stream and at least one reservoir that receives the molten metal stream, (iv) an ignition system comprising an electrical power source that provides low-voltage, high-current electrical energy to the at least one steam of molten metal to ignite a plasma to initiate rapid kinetics of the hydrino reaction and an energy gain due to forming hydrinos, (v) a source of H2 and O2 supplied to the plasma, (vi) a molten metal recovery system, and (vii) a power converter capable of (a) converting the high-power light output from a blackbody radiator of the cell into electricity using concentrator thermophotovoltaic cells or (b) converting the energetic plasma into electricity using a magnetohydrodynamic converter.

### CROSS-REFERENCES OF RELATED APPLICATIONS

This application claims the benefit of U.S. Provisional Application Nos. 62/594,936, filed Dec. 5, 2017, 62/612,304, filed Dec. 29, 2017, 62/618,444, filed Jan. 17, 2018, 62/630,755, filed Feb. 14, 2018, 62/644,392, filed Mar. 17, 2018, 62/652,283, filed Apr. 3, 2018, 62/688; 990, filed Jun. 22, 2018, 62/698,025, filed Jul. 14, 2018, 62/714,732, filed Aug. 5, 2018, 62/728,716, filed Sep. 7, 2018; 62/738,966, filed Sep. 28, 2018, 62/748,955, filed Oct. 22, 2018, and 62/769,483, filed Nov. 19, 2018, all of which are incorporated herein by reference.

The present disclosure relates to the field of power generation and, in particular; to systems, devices, and methods for the generation of power. More specifically, embodiments of the present disclosure are directed to power generation devices and systems, as well as related methods, which produce optical power; plasma, and thermal power and produces electrical power via a magnetohydrodynamic power converter, an optical to electric power converter, plasma to electric power converter, photon to electric power converter, or a thermal to electric power converter. In addition, embodiments of the present disclosure describe systems, devices; and methods that use the ignition of a water or water-based fuel source to generate optical power, mechanical power, electrical power, and/or thermal power using photovoltaic power converters. These and other related embodiments are described in detail in the present disclosure.

Power generation can take many forms, harnessing the power from plasma. Successful commercialization of plasma may depend on power generation systems capable of efficiently forming plasma and then capturing the power of the plasma produced.

Plasma may be formed during ignition of certain fuels. These fuels can include water or water-based fuel source. During ignition, a plasma cloud of electron-stripped atoms is formed, and high optical power may be released. The high optical power of the plasma can be harnessed by an electric converter of the present disclosure. The ions and excited state atoms can recombine and undergo electronic relaxation to emit optical power. The optical power can be converted to electricity with photovoltaics.

Certain embodiments of the present disclosure are directed to a power generation system comprising: a plurality of electrodes such as solid or molten metal electrodes configured to deliver power to a fuel to ignite the fuel and produce a plasma; a source of electrical power configured to deliver electrical energy to the plurality of electrodes; and at least one magnetohydrodynarnic power converter positioned to receive high temperature and pressure plasma or at least one photovoltaic (“PV”) power converter positioned to receive at least a plurality of plasma photons.

In an embodiment, a SunCell® power system that power system that generates at least one of electrical energy and thermal energy comprises at least one vessel capable of a maintaining a pressure of below, at, or above atmospheric and reactants comprising: (i) at least one source of catalyst or a catalyst comprising nascent H₂O; (ii) at least one source of H₂O or H₂O; (iii) at least one source of atomic hydrogen or atomic hydrogen; and (iv) a molten metal. The system further comprises a molten metal injector system comprising at least one reservoir that contains some of the molten metal and a molten metal pump with an injector tube that provides a molten metal stream and at least one non-injector reservoir that receives the molten metal stream; at least one ignition system comprising a source of electrical power to supply electrical power to the at least one steam of molten metal to ignite a plasma; at least one reactant supply system to replenish reactants that are consumed in a reaction of the reactants to generate at least one of the electrical energy and thermal energy; at least one power converter or output system of at least one of the light and thermal output to electrical power and/or thermal power. The power system may further comprise at least one of a heater to melt a metal to comprise the molten metal and a molten metal recovery system wherein the molten metal recovery system may comprise at least one molten metal overflow channel from the non-injection reservoir to the injector system reservoir that further creates breaks in the molten metal overflow stream to interrupt any current path through the overflowing molten metal. The molten metal recovery system may comprises the non-injector reservoir having its inlet to receive molten metal from the injector tube of the injector system at an elevation above the injector tube and further comprising a drip edge to break-up the overflow stream. The non-injector reservoir inlet may lie in a plane, and the plane may be aligned perpendicular to the initial direction of the molten metal stream from the injection tube. The non-injector reservoir and the injector tube of the injector system may both be aligned along an axis at an angle greater than zero from a horizontal axis that is transverse to the Earth's gravitational axis such as an angle in the range of about 25° to 90° from the horizontal. The injector reservoir may comprise an electrode in contact with the molten metal therein, and the non-injector reservoir may comprise an electrode that makes contact with the molten metal provided by the injector system. The ignition system may comprises a source of electrical power to supply opposite voltages to the injector and non-injector reservoir electrodes that supplies current and power flow through the stream of molten metal to cause the reaction of the reactants to form a plasma inside of the vessel. The source of electrical power may deliver a high-current electrical energy sufficient to cause the reactants to react to form plasma. The source of electrical power may comprise at least one supercapacitor. Each electromagnetic pump may comprises one of (i) a DC or AC conduction type comprising a DC or AC current source supplied to the molten metal through electrodes and a source of constant or in-phase alternating vector-crossed magnetic field, or (ii) an induction type comprising a source of alternating magnetic field through a shorted loop of molten metal that induces an alternating current in the metal and a source of in-phase alternating vector-crossed magnetic field. The current from the molten metal ignition system power may be in the range of 10 A to 50,000 A. The circuit of the molten metal ignition system may be closed by the molten metal stream to cause ignition to further cause an ignition frequency in the range of 0 Hz to 10,000 Hz. The molten metal may comprise at least one of (i) silver, silver-copper alloy, and copper, (ii) a metal has a melting point below 700° C., and (iii) at least one of bismuth, lead, tin; indium; cadmium, preferably gallium, antimony, or alloys such as Rose's metal, Cerrosafe, Wood's metal, Field's metal, Cerrolow 136, Cerrolow 117, Bi—Pb—Sn—Cd—In—Tl, and Galinstan. The power system may further comprise a vacuum pump and at least one heat exchanger. At least one reservoir may comprise boron nitride. The reactants may comprise a vessel gas comprising at least one of hydrogen, oxygen, and water wherein the vessel gas may further comprise an inert gas. The power system may further comprise a reactants supply and an inert gas supply wherein the supplies maintain the vessel gas at a pressure in the range of 0.01 Torr to 200 atm. At least one power converter or output system of the reaction power output may comprise at least one of the group of a thermophotovoltaic converter, a photovoltaic converter, a photoelectronic converter, a magnetohydrodynamic converter, a plasmadynamic converter, a thermionic converter, a thermoelectric converter, a Sterling engine, a supercritical CO₂ cycle converter, a Brayton cycle converter, an external-combustor type Brayton cycle engine or converter, a Rankine cycle engine or converter, an organic Rankine cycle converter, an internal-combustion type engine, and a heat engine, a heater, and a boiler. The vessel may comprise a light transparent photovoltaic (PV) window to transmit light from the inside of the vessel to a photovoltaic converter and at least one of a vessel geometry and at least one baffle to cause a pressure gradient to at least partially prevent the molten metal from coating the PV window wherein the vessel geometry may comprise a decreasing cross sectional area towards the PV window. The PV converter may comprise concentrator photovoltaic cells that comprise at least one compound chosen from crystalline silicon, germanium, gallium arsenide (GaAs), gallium antimonide (GaSb), indium gallium arsenide (InGaAs), indium gallium arsenide antimonide (InGaAsSb), indium phosphide arsenide antimonide (InPAsSb), InGaP/InGaAs/Ge; InAlGaP/AlGaAs/GaInNAsSb/Ge; GaInP/GaAsP/SiGe; GaInP/GaAsP/Si; GaInP/GaAsP/Ge; GaInP/GaAsP/Si/SiGe; GaInP/GaAs/InGaAs; GaInP/GaAs/GaInNAs; GaInP/GaAs/InGaAs/InGaAs; GaInP/Ga(In)As/InGaAs; GaInP—GaAs-wafer-InGaAs; GaInP/Ga(In)As—Ge; GaInP—GaInAs—Ge; a Group III nitride; GaN; AlN; GaAlN, and InGaN. The magnetohydrodynamic power converter may comprise a nozzle connected to the reaction vessel, a magnetohydrodynamic channel, electrodes, magnets, a metal collection system, a metal recirculation system, a heat exchanger, and optionally a gas recirculation system. In an embodiment, at least one component of the power system comprises at least one of a ceramic such as at least one of a metal oxide, alumina, zirconia, magnesia, hafnia, silicon carbide, zirconium carbide, zirconium diboride, silicon nitride, and a glass ceramic such as Li₂O×Al₂O₃×nSiO₂ system (LAS system), the MgO×Al₂O₃×nSiO₂ system (MAS system), the ZnO×Al₂O₃×nSiO₂ system (ZAS system) and a metal such as at least one of a stainless steel and a refractory metal. In an embodiment, the molten metal of the power system comprises silver and the magnetohydrodynamic converter further comprises a source of oxygen to form silver particles nanoparticles and accelerate the nanoparticles through magnetohydrodynamic nozzle to impart a kinetic energy inventory of the power produced in the vessel. The reactants supply system may additionally supply and control the source of oxygen to form the silver nanoparticles. In an embodiment of the magnetohydrodynamic power converter, at least a portion of the kinetic energy inventory of the silver nanoparticles is converted to electrical energy in the magnetohydrodynamic channel, the nanoparticles coalesce as molten metal in the metal collection system, the molten metal at least partially absorbs the oxygen, the metal comprising absorbed oxygen is returned to the injector reservoir by the metal recirculation system, and the oxygen is released by the plasma in the vessel wherein plasma is maintained in the magnetohydrodynamic channel and metal collection system to enhance the absorption of the oxygen by the molten metal. The electromagnetic pump may comprise a two-stage pump comprising a first stage that comprises a pump of the metal recirculation system, and a second stage that comprises the pump of the metal injector system. In an embodiment, the hydrogen product formed by reaction of the atomic hydrogen and catalyst in the power system may comprise at least one of the following: a hydrogen product with a Raman peak at about 1900 to 2000 cm⁻¹; a hydrogen product with a plurality of Raman peaks spaced at an integer multiple of about 0.23 to 0.25 eV; a hydrogen product with an infrared peak at about 1900 to 2000 cm⁻¹; a hydrogen product with a plurality of infrared peaks spaced at an integer multiple of about 0.23 to 0.25 eV; a hydrogen product with at a plurality of UV fluorescence emission spectral peaks in the range of about 200 to 300 nm having a spacing at an integer multiple of about 0.23 to 0.3 eV; a hydrogen product with a plurality of electron-beam emission spectral peaks in the range of about 200 to 300 nm having a spacing at an integer multiple of about 0.2 to 0.3 eV; a hydrogen product with a plurality of Raman spectral peaks in the range of about 5000 to 20,000 cm⁻¹ having a spacing at an integer multiple of about 1000±200 cm; a hydrogen product with a X-ray photoelectron spectroscopy peak at an energy in the range of about 490 to 525 eV; a hydrogen product that causes an upfield MAS NMR matrix shift; a hydrogen product that has an upfield MAS NMR or liquid NMR shift of greater than about −5 ppm relative to TMS; a hydrogen product comprising macro-aggregates or polymers Hₙ (n is an integer greater than 3); a hydrogen product comprising macro-aggregates or polymers Hₙ (n is an integer greater than 3) having a time of flight secondary ion mass spectroscopy (ToF-SIMS) peak of about 16.12 to 16.13; a hydrogen product comprising a metal hydride wherein the metal comprises at least one of Zn, Fe, Mo, Cr, Cu, and W; a hydrogen product comprising at least one of H₁₆ and H₂₄; a hydrogen product comprising an inorganic compound MₓX_{y} and H₂ wherein M is a cation and X in an anion having at least one of electrospray ionization time of flight secondary ion mass spectroscopy (ESI-ToF) and time of flight secondary ion mass spectroscopy (ToF-SIMS) peaks of M(MₓX_{y}H₂)n wherein n is an integer; a hydrogen product comprising at least one of K₂CO₃H₂ and KOHH₂ having at least one of electrospray ionization time of flight secondary ion mass spectroscopy (ESI-ToF) and time of flight secondary ion mass spectroscopy (ToF-SIMS) peaks of K(K₂H₂CO₃)ₙ⁺ and K(KOHH₂)ₙ⁺, respectively; a magnetic hydrogen product comprising a metal hydride wherein the metal comprises at least one of Zn, Fe, Mo, Cr, Cu, W, and a diamagnetic metal; a hydrogen product comprising a metal hydride wherein the metal comprises at least one of Zn, Fe, Mo, Cr, Cu, W, and a diamagnetic metal that demonstrates magnetism by magnetic susceptometry; a hydrogen product comprising a metal that is not active in electron paramagnetic resonance (EPR) spectroscopy wherein the EPR spectrum comprises at least one of very high g factors, very low g factors, extraordinary line width, and proton splitting; a hydrogen product comprising a hydrogen molecular dimer wherein the EPR spectrum shows at least one peak at about 2800-3100 G and ΔH of about 10 G to 500 G; a hydrogen product comprising a gas having a negative gas chromatography peak with hydrogen carrier; a hydrogen product having a quadrupole moment/e of about

$$\frac{1.70127 {a}_{0}^{2}}{{p}^{2}} \pm 10 \%$$

wherein p is an integer; a protonic hydrogen product comprising a molecular dimer having an end over end rotational energy for the integer J to J+1 transition in the range of about (J+1) 44.30 cm⁻¹±20 cm⁻¹ wherein the corresponding rotational energy of the molecular dimer comprising deuterium is % that of the dimer comprising protons; a hydrogen product comprising molecular dimers having at least one parameter from the group of (i) a separation distance of hydrogen molecules of about 1.028 Å±10%, (ii) a vibrational energy between hydrogen molecules of about 23 cm⁻¹±10%, and (iii) a van der Waals energy between hydrogen molecules of about 0.0011 eV±10%; a hydrogen product comprising a solid having at least one parameter from the group of (i) a separation distance of hydrogen molecules of about 1.028 Å±10%, (ii) a vibrational energy between hydrogen molecules of about 23 cm⁻¹±10%, and (iii) a van der Waals energy between hydrogen molecules of about 0.019 eV±10%; a hydrogen product having at least one of (i) FTIR and Raman spectral signatures of (a) (J+1) 44.30 cm⁻¹±20 cm⁻¹, (b) (J+1) 22.15 cm⁻¹±±10 cm⁻¹ and (c) 23 cm⁻¹±10%; (ii) an X-ray or neutron diffraction pattern showing a hydrogen molecule separation of about 1.028 Å±10%, and (c) a calorimetric determination of the energy of vaporization of about 0.0011 eV±10% per molecular hydrogen; a solid hydrogen product having at least one of (i) FTIR and Raman spectral signatures of (a) (J+1) 44.30 cm⁻¹±20 cm⁻¹, (b) (J+1) 22.15 cm⁻¹±10 cm⁻¹ and (c) 23 cm⁻¹±10%; (ii) an X-ray or neutron diffraction pattern showing a hydrogen molecule separation of about 1.028 Å±10%, and (iii) a calorimetric determination of the energy of vaporization of about 0.019 eV±10% per molecular hydrogen. In an embodiment, the hydrogen product formed by reaction of the atomic hydrogen and catalyst in the power system may comprise at least one of H(¼) and H₂(¼) wherein the hydrogen product has at least one of the following: the hydrogen product has a Fourier transform infrared spectrum (FTIR) comprising at least one of the H₂(¼) rotational energy at about 1940 cm⁻¹±10% and libation bands in the finger print region wherein other high energy features are absent; the hydrogen product has a proton magic-angle spinning nuclear magnetic resonance spectrum (¹H MAS NMR) comprising an upfield matrix peak; the hydrogen product has a thermal gravimetric analysis (TGA) result showing the decomposition of at least one of a metal hydride and a hydrogen polymer in the temperature region of about 100° C. to 1000° C.; the hydrogen product has an e-beam excitation emission spectrum comprising the H₂(¼) ro-vibrational band in the 260 nm region comprising a plurality of peaks spaced at about 0.23 eV to 0.3 eV from each other; the hydrogen product has an e-beam excitation emission spectrum comprising the H₂(¼) ro-vibrational band in the 260 nm region comprising a plurality of peaks spaced at about 0.23 eV to 0.3 eV from each other wherein the peaks decrease in intensity at cryo-temperatures in the range of about 0 K to 150 K; the hydrogen product has a photoluminescence Raman spectrum comprising the second order of the H₂(¼) ro-vibrational band in the 260 nm region comprising a plurality of peaks spaced at about 0.23 eV to 0.3 eV from each other; the hydrogen product has a photoluminescence Raman spectrum comprising the second order of the H₂(¼) ro-vibrational band comprising a plurality of peaks in the range of about 5000 to 20,000 cm⁻¹ having a spacing at an integer multiple of about 1000±200 cm, the hydrogen product has a Raman spectrum comprising the H₂(¼) rotational peak at about 1940 cm⁻¹±10%; the hydrogen product has an X-ray photoelectron spectrum (XPS) comprising the total energy of H₂(¼) at about 490-500 eV; the hydrogen product comprises macro-aggregates or polymers H(¼)ₙ. (n is an integer greater than 3); the hydrogen product comprises macro-aggregates or polymers H(¼)ₙ (n is an integer greater than 3) having a time of flight secondary ion mass spectroscopy (ToF-SIMS) peak of about 16.12 to 16.13; the hydrogen product comprises a metal hydride wherein the metal comprises at least one of Zn, Fe, Mo, Cr, Cu, and W and the hydrogen comprises H(¼); the hydrogen product comprises at least one of H(¼)₁ and H(¼)₂₄; the hydrogen product comprises an inorganic compound MₓX_{y} and H(¼)₂ wherein M is a cation and X is an anion and at least one of the electrospray ionization time of flight secondary ion mass spectrum (ESI-ToF) and the time of flight secondary ion mass spectrum (ToF-SIMS) comprises peaks of M(MₓX_{y}H(¼)₂)n wherein n is an integer; the hydrogen product comprises at least one of K₂CO₃H(¼)₂ and KOHH(¼)₂ and at least one of the electrospray ionization time of flight secondary ion mass spectrum (ESI-ToF) and the time of flight secondary ion mass spectrum (ToF-SIMS) comprises peaks of K(K₂H₂CO₃)ₙ⁺ and K(KOHH₂)ₙ⁺, respectively; the hydrogen product is magnetic and comprises a metal hydride wherein the metal comprises at least one of Zn, Fe, Mo, Cr, Cu, W, and a diamagnetic metal, and the hydrogen is H(¼); the hydrogen product comprises a metal hydride wherein the metal comprises at least one of Zn, Fe, Mo, Cr, Cu, W, and a diamagnetic metal and H is H(¼) wherein the product demonstrates magnetism by magnetic susceptometry; the hydrogen product comprises a metal that is not active in electron paramagnetic resonance (EPR) spectroscopy wherein the EPR spectrum shows at least one peak at about 2800-3100 G and ΔH of about 10 to 500 G; the hydrogen product comprises a [H₂(¼)]₂ wherein the EPR spectrum shows at least one peak at about 2800-3100 G and ΔH of about 10 G to 500 G; the hydrogen product comprises or releases H₂(¼) gas having a negative gas chromatography peak with hydrogen carrier; the hydrogen product comprises H₂(¼) having a quadrupole moment/e of about

$$\frac{1.70127 {a}_{0}^{2}}{{4}^{2}} \pm 10 ;$$

the hydrogen product comprises [H₂(¼)]₂ or [D₂(¼)]₂ having an end over end rotational energy for the integer J to J+1 transition in the range of about (J+1) 44.30 cm⁻¹±20 cm⁻¹ and about (J+1) 22.15 cm⁻¹±±10 cm⁻¹, respectively; the hydrogen product comprising [H₂(¼)]₂ having at least one parameter from the group of (i) a separation distance of H₂(¼) molecules of about 1.028 Å±10%, (ii) a vibrational energy between H₂(¼) molecules of about 23 cm⁻¹±10%, and (iii) a van der Waals energy between H₂(¼) molecules of about 0.0011 eV±10%, and the hydrogen product comprising a solid of H₂(¼) molecules having at least one parameter from the group of (i) a separation distance of H₂(¼) molecules of about 1.028 Å±10%, (ii) a vibrational energy between H₂(¼) molecules of about 23 cm⁻¹ 10%, and (iii) a van der Waals energy between H₂(¼) molecules of about 0.019 eV±10%; the [H₂(¼)]₂ product having at least one of (i) FTIR and Raman spectral signatures of (a) about (J+1) 44.30 cm⁻¹±20 cm⁻¹, (b) about (J+1) 22.15 cm⁻¹±10 cm⁻¹ and (c) about 23 cm⁻¹±10%; (ii) an X-ray or neutron diffraction pattern showing a H₂(¼) molecule separation of about 1.028 Å±10%, and (iii) a calorimetric determination of the energy of vaporization of about 0.0011 eV±10% per H₂(¼), and the solid H₂(¼) product having at least one of (i) FTIR and Raman spectral signatures of (a) about (J+1) 44.30 cm⁻¹±20 cm⁻¹, (b) about (J+1) 22.15 cm⁻¹±10 cm⁻¹ and (c) about 23 cm⁻¹ 10%; (ii) an X-ray or neutron diffraction pattern showing a hydrogen molecule separation of 1.028 Å±10%, and (iii) a calorimetric determination of the energy of vaporization of about 0.019 eV±10% per H₂(¼). The hydrogen product formed by reaction of the atomic hydrogen and catalyst in the power system may comprise at least one of a hydrino species selected from the group of H(1/p), H₂(1/p), and H⁻(1/p) alone or complexed with at least one of (i) an element other than hydrogen, (ii) an ordinary hydrogen species comprising at least one of H⁺, ordinary H₂, ordinary H⁻, and ordinary H₃⁺, an organic molecular species, and (iv) an inorganic species. The hydrogen product formed by reaction of the atomic hydrogen and catalyst may comprise an oxyanion compound. The hydrogen product formed by reaction of the atomic hydrogen and catalyst may comprise at least one compound having the formula selected from the group of: MH, MH₂, or M₂H₂, wherein M is an alkali cation and H is a hydrino species; MHₙ wherein n is 1 or 2, M is an alkaline earth cation and H is hydrino species; MHX wherein M is an alkali cation, X is one of a neutral atom such as halogen atom, a molecule, or a singly negatively charged anion such as halogen anion, and H is a hydrino species; MHX wherein M is an alkaline earth cation, X is a singly negatively charged anion, and H is H is a hydrino species; MHX wherein M is an alkaline earth cation, X is a double negatively charged anion, and H is a hydrino species; M₂HX wherein M is an alkali cation, X is a singly negatively charged anion, and H is a hydrino species; MHₙ wherein n is an integer, M is an alkaline cation and the hydrogen content Hₙ of the compound comprises at least one hydrino species; M₂Hₙ wherein n is an integer, M is an alkaline earth cation and the hydrogen content Hₙ of the compound comprises at least one hydrino species; M₂XHₙ wherein n is an integer, M is an alkaline earth cation, X is a singly negatively charged anion, and the hydrogen content Hₙ of the compound comprises at least one hydrino species; M₂X₂Hₙ wherein n is 1 or 2, M is an alkaline earth cation, X is a singly negatively charged anion, and the hydrogen content Hₙ of the compound comprises at least one hydrino species; M₂X₃H wherein M is an alkaline earth cation, X is a singly negatively charged anion, and H is a hydrino species; M₂XHₙ wherein n is 1 or 2, M is an alkaline earth cation, X is a double negatively charged anion, and the hydrogen content Hₙ of the compound comprises at least one hydrino species; M₂XX′H wherein M is an alkaline earth cation, X is a singly negatively charged anion, X′ is a double negatively charged anion, and H is hydrino species; MM′Hₙ wherein n is an integer from 1 to 3, M is an alkaline earth cation, M′ is an alkali metal cation and the hydrogen content Hₙ of the compound comprises at least one hydrino species; MM′XHₙ wherein n is 1 or 2, M is an alkaline earth cation, M′ is an alkali metal cation, X is a singly negatively charged anion and the hydrogen content Hₙ of the compound comprises at least one hydrino species; MM′XH wherein M is an alkaline earth cation, M′ is an alkali metal cation, X is a double negatively charged anion and H is a hydrino species; MM′XX′H wherein M is an alkaline earth cation, M′ is an alkali metal cation, X and X′ are singly negatively charged anion and H is a hydrino species; MXX′Hₙ wherein n is an integer from 1 to 5, M is an alkali or alkaline earth cation, X is a singly or double negatively charged anion, X′ is a metal or metalloid, a transition element, an inner transition element, or a rare earth element, and the hydrogen content Hₙ of the compound comprises at least one hydrino species; MHₙ wherein n is an integer, M is a cation such as a transition element, an inner transition element, or a rare earth element, and the hydrogen content Hₙ of the compound comprises at least one hydrino species; MXHₙ wherein n is an integer, M is an cation such as an alkali cation, alkaline earth cation, X is another cation such as a transition element, inner transition element, or a rare earth element cation, and the hydrogen content Hₙ of the compound comprises at least one hydrino species; (MHₘMCO₃)ₙ wherein M is an alkali cation or other +1 cation, m and n are each an integer, and the hydrogen content Hₘ of the compound comprises at least one hydrino species; (MHₘMNO₃)ₙ⁺nX⁻ wherein M is an alkali cation or other +1 cation, m and n are each an integer, X is a singly negatively charged anion, and the hydrogen content Hₘ of the compound comprises at least one hydrino species; (MHMNO₃)ₙ wherein M is an alkali cation or other +1 cation, n is an integer and the hydrogen content H of the compound comprises at least one hydrino species; (MHMOH)ₙ wherein M is an alkali cation or other +1 cation, n is an integer, and the hydrogen content H of the compound comprises at least one hydrino species; (MHₘM′X)ₙ wherein m and n are each an integer, M and M′ are each an alkali or alkaline earth cation, X is a singly or double negatively charged anion, and the hydrogen content Hₘ of the compound comprises at least one hydrino species, and (MHₘM′X′)ₙ⁺nX⁻ wherein m and n are each an integer, M and M′ are each an alkali or alkaline earth cation, X and X′ are a singly or double negatively charged anion, and the hydrogen content Hₘ of the compound comprises at least one hydrino species. The anion of hydrogen compound product formed by reaction of the atomic hydrogen and catalyst may comprise at least one or more singly negatively charged anions, halide ion, hydroxide ion, hydrogen carbonate ion, nitrate ion, double negatively charged anions, are carbonate ion, oxide, and sulfate ion. The hydrogen product formed by reaction of the atomic hydrogen and catalyst may comprise at least one hydrino species embedded in a crystalline lattice. In an exemplary embodiment, the compound comprises least one of H(1/p), H₂(1/p), and H⁻(1/p) embedded in a salt lattice wherein the salt lattice comprises at least one of an alkali salt, an alkali halide, an alkali hydroxide, alkaline earth salt, an alkaline earth halide, and an alkaline earth hydroxide.

In one embodiment, an electrode system comprises: a first electrode and a second electrode; a stream of molten metal (e.g., molten silver, molten gallium, etc.) in electrical contact with said first and second electrodes; a circulation system comprising a pump to draw said molten metal from a reservoir and convey it through a conduit (e.g., a tube) to produce said stream of molten metal exiting said conduit, and a source of electrical power configured to provide an electrical potential difference between said first and second electrodes wherein said stream of molten metal is in simultaneous contact with said first and second electrodes to create an electrical current between said electrodes. In one embodiment, the electrical power of the electrode system is sufficient to create an arc current. In one embodiment, an electrical circuit comprises: a heating means for producing molten metal; a pumping means for conveying said molten metal from a reservoir through a conduit to produce a stream of said molten metal exiting said conduit; and a first electrode and a second electrode in electrical communication with a power supply means for creating an electrical potential difference across said first and second electrode wherein said stream of molten metal is in simultaneous contact with said first and second electrodes to create an electrical circuit between said first and second electrodes. In one embodiment of an electrical circuit comprising a first and second electrode, the improvement comprises passing a stream of molten metal across said electrodes to permit a current to flow there between.

In an embodiment, a SunCell® power system that generates at least one of electrical energy and thermal energy comprises at least one vessel capable of a maintaining a pressure of below, at, or above atmospheric and reactants comprising: (i) at least one source of catalyst or a catalyst comprising nascent H₂O, (ii) at least one source of H₂O or H₂O, (iii) at least one source of atomic hydrogen or atomic hydrogen, and (iv) a molten metal; a molten metal injection system comprising at least two molten metal reservoirs each comprising a pump and an injector tube; at least one reactant supply system to replenish reactants that are consumed in a reaction of the reactants to generate at least one of the electrical energy and thermal energy; at least one ignition system comprising a source of electrical power to supply opposite voltages to the at least two molten metal reservoirs each comprising an electromagnetic pump, and at least one power converter or output system of at least one of the light and thermal output to electrical power and/or thermal power.

The molten metal injection system may comprise at least two molten metal reservoirs each comprising an electromagnetic pump to inject streams of the molten metal that intersect inside of the vessel wherein each reservoir may comprise a molten metal level controller comprising an inlet riser tube. The ignition system may comprise a source of electrical power to supply opposite voltages to the at least two molten metal reservoirs each comprising an electromagnetic pump that supplies current and power flow through the intersecting streams of molten metal to cause the reaction of the reactants comprising ignition to form a plasma inside of the vessel. The ignition system may comprise: (i) the source of electrical power to supply opposite voltages to the at least two molten metal reservoirs each comprising an electromagnetic pump and (ii) at least two intersecting streams of molten metal ejected from the at least two molten metal reservoirs each comprising an electromagnetic pump wherein the source of electrical power is capable of delivering a short burst of high-current electrical energy sufficient to cause the reactants to react to form plasma. The source of electrical power to deliver a short burst of high-current electrical energy sufficient to cause the reactants to react to form plasma may comprise at least one supercapacitor. Each electromagnetic pump may comprise one of a (i) DC or AC conduction type comprising a DC or AC current source supplied to the molten metal through electrodes and a source of constant or in-phase alternating vector-crossed magnetic field, or (ii) an induction type comprising a source of alternating magnetic field through a shorted loop of molten metal that induces an alternating current in the metal and a source of in-phase alternating vector-crossed magnetic field. At least one union of the pump and corresponding reservoir or another union between parts comprising the vessel, injection system, and converter may comprise at least one of a wet seal, a flange and gasket seal, an adhesive seal, and a slip nut seal wherein the gasket may comprise carbon. The DC or AC current of the molten metal ignition system may be in the range of 10 A to 50,000 A. The source of electrical power to deliver a short burst of high-current electrical energy may comprise at least one of the following:

a voltage selected to cause a high AC, DC, or an AC-DC mixture of current that is in the range of at least one of 100 A to 1,000,000 A, 1 kA to 100,000 A, 10 kA to 50 kA;

a DC or peak AC current density in the range of at least one of 100 A/cm² to 1,000,000 A/cm², 1000 A/cm² to 100,000 A/cm², and 2000 A/cm² to 50,000 A/cm²;

the voltage is determined by the conductivity of the solid fuel or wherein the voltage is given by the desired current times the resistance of the solid fuel sample;

the DC or peak AC voltage is in the range of at least one of 0.1 V to 500 kV, 0.1 V to 100 kV, and 1 V to 50 kV, and

the AC frequency is in range of at least one of 0.1 Hz to 10 GHz, 1 Hz to 1 MHz, 10 Hz to 100 kHz, and 100 Hz to 10 kHz.

The circuit of the molten metal ignition system may be closed by the intersection of the molten metal streams to cause ignition to further cause an ignition frequency in the range of 0 Hz to 10,000 Hz. The induction-type electromagnetic pump may comprise ceramic channels that form the shorted loop of molten metal. The power system may further comprise a heater such as an inductively coupled heater to form the molten metal from the corresponding solid metal wherein the molten metal may comprise at least one of silver, silver-copper alloy, and copper. The power system may further comprise a vacuum pump and at least one chiller. The power system may comprise a system to recover the products of the reactants such as at least one of the vessel comprising walls capable of providing flow to the melt under gravity, an electrode electromagnetic pump, and the reservoir in communication with the vessel and further comprising a cooling system to maintain the reservoir at a lower temperature than another portion of the vessel to cause metal vapor of the molten metal to condense in the reservoir wherein the pressure in the vessel may be maintained by the condensation. The recovery system comprising an electrode electromagnetic pump may comprise at least one magnet providing a magnetic field and a vector-crossed ignition current component. The power system may comprise at least one power converter or output system of the reaction power output such as at least one of the group of a thermophotovoltaic converter, a photovoltaic converter, a photoelectronic converter, a magnetohydrodynamic converter, a plasmadynamic converter, a thermionic converter, a thermoelectric converter, a Sterling engine, a Brayton cycle engine, a Rankine cycle engine, and a heat engine, a heater, and a boiler. The boiler may comprise a radiant boiler. A portion of the reaction vessel may comprise a blackbody radiator that may be maintained at a temperature in the range of 1000 K to 3700 K. The reservoirs of the power system may comprise boron nitride, the portion of the vessel that comprises the blackbody radiator may comprise carbon, and the electromagnetic pump parts in contact with the molten metal may comprise an oxidation resistant metal or ceramic. The hydrino reactants may comprise at least one of methane, carbon monoxide, carbon dioxide, hydrogen, oxygen, and water. The reactants supply may maintain each of the methane, carbon monoxide, carbon dioxide, hydrogen, oxygen, and water at a pressure in the range of 0.01 Torr to 1 Torr. The light emitted by the blackbody radiator of the power system that is directed to the thermophotovoltaic converter or a photovoltaic converter may be predominantly blackbody radiation comprising visible and near infrared light, and the photovoltaic cells may be concentrator cells that comprise at least one compound chosen from crystalline silicon, germanium, gallium arsenide (GaAs), gallium antimonide (GaSb), indium gallium arsenide (InGaAs), indium gallium arsenide antimonide (InGaAsSb), indium phosphide arsenide antimonide (InPAsSb), InGaP/InGaAs/Ge; InAGaP/AlGaAs/GaInNAsSb/Ge; GaInP/GaAsP/SiGe; GaInP/GaAsP/Si; GaInP/GaAsP/Ge; GaInP/GaAsP/Si/SiGe; GaInP/GaAs/InGaAs; GaInP/GaAs/GaInNAs; GaInP/GaAs/InGaAs/InGaAs; GaInP/Ga(In)As/InGaAs; GaInP—GaAs-wafer-InGaAs; GaInP—Ga(In)As—Ge; and GaInP—GaInAs—Ge. The light that is emitted by the reaction plasma and that is directed to the thermophotovoltaic converter or a photovoltaic converter may be predominantly ultraviolet light, and the photovoltaic cells may be concentrator cells that comprise at least one compound chosen from a Group III nitride, GaN, AlN, GaAlN, and InGaN. The thermophotovoltaic converter may convert low temperature blackbody radiation (BBR) such as BBR from a radiator such as 5b4 in the temperature range of about 1500 K to 2500 K. The corresponding PV cell may comprise bismuth.

In an embodiment, the PV converter may further comprise a UV window to the PV cells. The PV window may replace at least a portion of the blackbody radiator. The window may be substantially transparent to UV. The window may be resistant to wetting with the molten metal. The window may operate at a temperature that is at least one of above the melting point of the molten metal and above the boiling point of the molten metal. Exemplary windows are sapphire, quartz, MgF₂, and fused silica. The window may be cooled and may comprise a means for cleaning during operation or during maintenance. The SunCell® may further comprise a source of at least one of electric and magnetic fields to confine the plasma in a region that avoids contact with at least one of the window and the PV cells. The source may comprise an electrostatic precipitation system. The source may comprise a magnetic confinement system. The plasma may be confined by gravity wherein at least one of the window and PV cells are at a suitable height about the position of plasma generation.

Alternatively, the magnetohydrodynamic power converter may comprise a nozzle connected to the reaction vessel, a magnetohydrodynamic channel, electrodes, magnets, a metal collection system, a metal recirculation system, a heat exchanger, and optionally a gas recirculation system wherein the reactants may comprise at least one of H₂O vapor, oxygen gas, and hydrogen gas. The reactants supply may maintain each of the O₂, the H₂, and a reaction product H₂O at a pressure in the range of 0.01 Torr to 1 Torr. The reactants supply system to replenish the reactants that are consumed in a reaction of the reactants to generate at least one of the electrical energy and thermal energy may comprise at least one of O₂ and H₂ gas supplies, a gas housing, a selective gas permeable membrane in the wall of at least one of the reaction vessel, the magnetohydrodynamic channel, the metal collection system, and the metal recirculation system, O₂, H₂, and H₂O partial pressure sensors, flow controllers, at least one valve, and a computer to maintain at least one of the O₂ and H₂ pressures. In an embodiment, at least one component of the power system may comprise ceramic wherein the ceramic may comprise at least one of a metal oxide, alumina, zirconia, magnesia, hafnia, silicon carbide, zirconium carbide, zirconium diboride, silicon nitride, and a glass ceramic such as Li₂O×Al₂O₃×nSiO₂ system (LAS system), the MgO×Al₂O₃×nSiO₂ system (MAS system), the ZnO×Al₂O₃×nSiO₂ system (ZAS system). The molten metal may comprise silver, and the magnetohydrodynamic converter may further comprise a source of oxygen to form an aerosol of silver particles supplied to at least one of the reservoirs, reaction vessel, magnetohydrodynamic nozzle, and magnetohydrodynamic channel wherein the reactants supply system may additionally supply and control the source of oxygen to form the silver aerosol. The molten metal may comprise silver. The magnetohydrodynamic converter may further comprise a cell gas comprising ambient gas in contact with the silver in at least one of the reservoirs and the vessel. The power system may further comprise a means to maintain a flow of cell gas in contact with the molten silver to form silver aerosol wherein the cell gas flow may comprise at least one of forced gas flow and convection gas flow. The cell gas may comprise at least one of a noble gas, oxygen, water vapor, H₂, and O₂. The means to maintain the cell gas flow may comprise at least one of a gas pump or compressor such as a magnetohydrodynamic gas pump or compressor, the magnetohydrodynamic converter, and a turbulent flow caused by at least one of the molten metal injection system and the plasma.

The inductive type electromagnetic pump of the power system may comprise a two-stage pump comprising a first stage that comprises a pump of the metal recirculation system, and the second stage comprises the pump of the metal injection system to inject the stream of the molten metal that intersects with the other inside of the vessel. The source of electrical power of the ignition system may comprise an induction ignition system that may comprise a source of alternating magnetic field through a shorted loop of molten metal that generates an alternating current in the metal that comprises the ignition current. The source of alternating magnetic field may comprise a primary transformer winding comprising a transformer electromagnet and a transformer magnetic yoke, and the silver may at least partially serve as a secondary transformer winding such as a single turn shorted winding that encloses the primary transformer winding and comprises as an induction current loop. The reservoirs may comprise a molten metal cross connecting channel that connects the two reservoirs such that the current loop encloses the transformer yoke wherein the induction current loop comprises the current generated in molten silver contained in the reservoirs, the cross connecting channel, the silver in the injector tubes and injector tubes, and the injected streams of molten silver that intersect to complete the induction current loop. In the case of ceramic injector tubes, the tubes may be submerged such that the loop comprises the molten silver contained in the reservoirs, the cross connecting channel, and the injected streams of molten silver that intersect to complete the induction current loop.

In an embodiment, the emitter generates at least one of electrical energy and thermal energy wherein the emitter comprises at least one vessel capable of a maintaining a pressure of below, at, or above atmospheric; reactants, the reactants comprising: a) at least one source of catalyst or a catalyst comprising nascent H2O; b) at least one source of H2O or H2O; c) at least one source of atomic hydrogen or atomic hydrogen that may permeate through the wall of the vessel; d) a molten metal such as silver, copper, or silver-copper alloy; and e) an oxide such as at least one of CO₂, B₂O₃, LiVO₃, and a stable oxide that does not react with H₂; at least one molten metal injection system comprising a molten metal reservoir and an electromagnetic pump; at least one reactant ignition system comprising a source of electrical power to cause the reactants to form at least one of light-emitting plasma and thermal-emitting plasma wherein the source of electrical power receives electrical power from the power converter; a system to recover the molten metal and oxide; at least one power converter or output system of at least one of the light and thermal output to electrical power and/or thermal power; wherein the molten metal ignition system comprises at least one of ignition system comprising i) an electrode from the group of: a) at least one set of refractory metal or carbon electrodes to confine the molten metal; b) a refractory metal or carbon electrode and a molten metal stream delivered by an electromagnetic pump from an electrically isolated molten metal reservoir, and c) at least two molten metal streams delivered by at least two electromagnetic pumps from a plurality of electrically isolated molten metal reservoirs; and ii) a source of electrical power to deliver high-current electrical energy sufficient to cause the reactants to react to form plasma wherein the molten metal AC, DC or AC-DC-mixtures ignition system current is in the range of 50 A to 50,000 A; wherein the molten metal injection system comprises an electromagnetic pump comprising at least one magnet providing a magnetic field and current source to provide a vector-crossed current component; wherein the molten metal reservoir comprises an inductively coupled heater; the emitter further comprising a system to recover the molten metal and oxide such as at least one of the vessel comprising walls capable of providing flow to the melt under gravity and the reservoir in communication with the vessel and further comprising a cooling system to maintain the reservoir at a lower temperature than then the vessel to cause metal to collect in the reservoir; wherein the vessel capable of a maintaining a pressure of below, at, or above atmospheric comprises an inner reaction cell comprising a high temperature blackbody radiator, and an outer chamber capable of maintaining a pressure of below, at, or above atmospheric; wherein the blackbody radiator is maintained at a temperature in the range of 1000 K to 3700 K; wherein the inner reaction cell comprising a blackbody radiator comprises a refractory material such as carbon or W; wherein the blackbody radiation emitted from the exterior of the cell is incident on the light-to-electricity power converter; wherein the at least one power converter of the reaction power output comprises at least one of a thermophotovoltaic converter and a photovoltaic converter; wherein the light emitted by the cell is predominantly blackbody radiation comprising visible and near infrared light, and the photovoltaic cells are concentrator cells that comprise at least one compound chosen from crystalline silicon, germanium, gallium arsenide (GaAs), gallium antimonide (GaSb), indium gallium arsenide (InGaAs), indium gallium arsenide antimonide (InGaAsSb), and indium phosphide arsenide antimonide (InPAsSb), Group III/V semiconductors, InGaP/InGaAs/Ge; InAlGaP/AlGaAs/GaInNAsSb/Ge; GaInP/GaAsP/SiGe; GaInP/GaAsP/Si; GaInP/GaAsP/Ge; GaInP/GaAsP/Si/SiGe; GaInP/GaAs/InGaAs; GaInP/GaAs/GaInNAs; GaInP/GaAs/InGaAs/InGaAs; GaInP/Ga(In)As/InGaAs; GaInP—GaAs-wafer-InGaAs; GaInP—Ga(In)As—Ge; and GaInP—GaInAs—Ge, and the power system further comprises a vacuum pump and at least one heat rejection system and the blackbody radiator further comprises a blackbody temperature sensor and controller. Optionally, the emitter may comprise at least one additional reactant injection system, wherein the additional reactants comprise: a) at least one source of catalyst or a catalyst comprising nascent H₂O; b) at least one source of H₂O or H₂O, and c) at least one source of atomic hydrogen or atomic hydrogen. The additional reactant injection system may further comprise at least one of a computer, H₂O and H₂ pressure sensors, and flow controllers comprising at least one or more of the group of a mass flow controller, a pump, a syringe pump, and a high precision electronically controllable valve; the valve comprising at least one of a needle valve, proportional electronic valve, and stepper motor valve wherein the valve is controlled by the pressure sensor and the computer to maintain at least one of the H₂O and H₂ pressure at a desired value; wherein the additional reactants injection system maintains the H₂O vapor pressure in the range of 0.1 Torr to 1 Torr.

### BRIEF DESCRIPTION OF THE DRAWINGS

The accompanying drawings, which are incorporated in and constitute a part of this specification, illustrate several embodiments of the disclosure and together with the description, serve to explain the principles of the disclosure. In the drawings:

FIG. 2I161 is a schematic drawing of magnetohydrodynamic (MHD) converter components of a cathode, anode, insulator, and bus bar feed-through flange in accordance with an embodiment of the present disclosure.

FIGS. 2I162-2I166 are schematic drawings of a SunCell® power generator comprising dual EM pump injectors as liquid electrodes showing tilted reservoirs and a magnetohydrodynamic (MHD) converter comprising a pair of MHD return EM pumps in accordance with an embodiment of the present disclosure.

FIGS. 2I167-2I173 are schematic drawings of a SunCell® power generator comprising dual EM pump injectors as liquid electrodes showing tilted reservoirs and a magnetohydrodynamic (MHD) converter comprising a pair of MHD return EM pumps and a pair of MHD return gas pumps or compressors in accordance with an embodiment of the present disclosure.

FIGS. 2I174-2I176 are schematic drawings of SunCell® power generator comprising dual EM pump injectors as liquid electrodes showing tilted reservoirs, a ceramic EM pump tube assembly, and a magnetohydrodynamic (MHD) converter comprising a pair of MHD return EM pumps in accordance with an embodiment of the present disclosure.

FIG. 2I177 is a schematic drawing of a magnetohydrodynamic (MHD) SunCell® power generator comprising dual EM pump injectors as liquid electrodes showing tilted reservoirs, a ceramic EM pump tube assembly, and a straight MHD channel in accordance with an embodiment of the present disclosure.

FIG. 2I178 is a schematic drawing of a magnetohydrodynamic (MHD) SunCell® power generator comprising dual EM pump injectors as liquid electrodes showing tilted reservoirs, and a straight MHD channel in accordance with an embodiment of the present disclosure.

FIGS. 2I179-2I183 are schematic drawings of a magnetohydrodynamic (MHD) SunCell® power generator comprising dual EM pump injectors as liquid electrodes showing tilted reservoirs, a spherical reaction cell chamber, a straight MHD channel, and gas addition housing in accordance with an embodiment of the present disclosure.

FIG. 2I184 is schematic drawings of magnetohydrodynamic (MHD) SunCell® power generators comprising dual EM pump injectors as liquid electrodes showing tilted reservoirs, a spherical reaction cell chamber, a straight magnetohydrodynamic (MHD) channel, gas addition housing, and single-stage induction EM pumps for injection and either single-stage induction or DC conduction MHD return EM pumps in accordance with an embodiment of the present disclosure.

FIG. 2I185 is a schematic drawing of a single-stage induction injection EM pump in accordance with an embodiment of the present disclosure.

FIG. 2I186 is a schematic drawing of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return, and an induction ignition system in accordance with an embodiment of the present disclosure.

FIG. 2I187 is a schematic drawing of the reservoir baseplate assembly and connecting components of the inlet riser tube, injector tube and nozzle, and flanges in accordance with an embodiment of the present disclosure.

FIG. 2I188 is a schematic drawing of a two-stage induction EM pump wherein the first stage serves as the MHD return EM pump and the second stage serves as the injection EM pump in accordance with an embodiment of the present disclosure.

FIG. 2I189 is a schematic drawing of an induction ignition system in accordance with an embodiment of the present disclosure.

FIGS. 2I190-2I191 are schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having a forced air cooling system, and an induction ignition system in accordance with an embodiment of the present disclosure.

FIG. 2I192 is a schematic drawing of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having a forced liquid cooling system, an induction ignition system, and inductively coupled heating antennas on the EM pump tubes, reservoirs, reaction cell chamber, and MHD return conduit in accordance with an embodiment of the present disclosure.

FIGS. 2I193-2I198 are schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having an air cooling system, and an induction ignition system in accordance with an embodiment of the present disclosure.

FIG. 2I199 is a schematic drawing of a single-stage induction injection EM pump in accordance with an embodiment of the present disclosure.

FIG. 2I200 is a schematic drawing of a two-stage induction EM pump wherein the first stage serves as the MHD return EM pump and the second stage serves as the injection EM pump in accordance with an embodiment of the present disclosure.

FIG. 2I201 is a schematic drawing of a two-stage induction EM pump wherein the first stage serves as the MHD return EM pump and the second stage serves as the injection EM pump wherein the Lorentz pumping force is more optimized in accordance with an embodiment of the present disclosure.

FIGS. 2I202-2I203 are schematic drawings of a magnetohydrodynamic (MHD) SunCell® power generator comprising dual EM pump injectors as liquid electrodes showing tilted reservoirs, a spherical reaction cell chamber, a straight magnetohydrodynamic (MHD) channel, gas addition housing, two-stage induction EM pumps for both injection and MHD return each having a forced air cooling system, and an induction ignition system in accordance with an embodiment of the present disclosure.

FIG. 2I04 are schematic drawings showing an exemplary helical-shaped flame heater of the SunCell® and a flame heater comprising a series of annular rings in accordance with an embodiment of the present disclosure.

FIG. 2I205 is a schematic drawing showing an electrolyzer in accordance with an embodiment of the present disclosure.

FIG. 2I206 is a schematic drawing showing a housing for containing H₂+O₂ with a dilution gas to be recombined in desired surfaces of SunCell® to serve as a chemical heater in accordance with an embodiment of the present disclosure.

FIG. 2I207 shows schematic drawings of SunCell® thermal power generators, one comprising a half-spherical-shell-shaped radiant thermal absorber heat exchanger having walls with embedded coolant tubes to receive the thermal power from reaction cell comprising a blackbody radiator and transfer the heat to the coolant and another comprising a circumferential cylindrical heat exchanger and boiler in accordance with an embodiment of the present disclosure.

FIGS. 2I208-2I2012 are schematic drawings of SunCell® thermal power generator comprising a half-spherical-shell-shaped radiant thermal absorber heat exchanger having walls with embedded coolant tubes to receive the thermal power from reaction cell comprising a blackbody radiator and transfer the heat to the coolant in accordance with an embodiment of the present disclosure.

FIGS. 2I213-2I214 are schematic drawings showing details of the SunCell® thermal power generator heat exchanger comprising a half-spherical-shell-shaped radiant thermal absorber heat exchanger having walls with embedded coolant tubes to receive the thermal power from reaction cell comprising a blackbody radiator and transfer the heat to the coolant in accordance with an embodiment of the present disclosure.

FIG. 2I215 is a schematic drawing showing details of the SunCell® thermal power generator comprising a single EM pump injector in an injector reservoir and an extended non-injector reservoir as liquid electrodes in accordance with an embodiment of the present disclosure.

FIGS. 2I216-2I217 are schematic drawings showing details of SunCell® thermal power generators each comprising a single EM pump injector in an injector reservoir and an extended non-injector reservoir as liquid electrodes in accordance with an embodiment of the present disclosure.

FIG. 2I218 is a schematic drawing showing details of the SunCell® thermal power generator comprising a half-spherical-shell-shaped radiant thermal absorber heat exchanger, a single EM pump injector in an injector reservoir, and an extended non-injector reservoir as liquid electrodes in accordance with an embodiment of the present disclosure.

FIG. 2I219 are schematic drawings showing details of the SunCell® thermal power generator comprising a single EM pump injector in an injector reservoir and an inverted pedestal as liquid electrodes in accordance with an embodiment of the present disclosure.

FIGS. 2I220-2I221 are schematic drawings showing details of the SunCell® thermal power generator comprising a single EM pump injector in an injector reservoir and a partially inverted pedestal as liquid electrodes and a tapered reaction cell chamber to suppress metallization of a PV window in accordance with an embodiment of the present disclosure.

FIGS. 2I222-2I223 are schematic drawings of a magnetohydrodynamic (MHD) SunCell® power generator comprising two recuperators and two paired gas compressors wherein each recuperator removes heat from the MID gas flow before the corresponding compressor and returns the heat to the compressed gas output of the compressor in accordance with an embodiment of the present disclosure.

FIGS. 2I224-2I226 are schematic drawings of a supercritical CO₂ SunCell® electrical power generator comprising a SunCell® with a heat exchanger (shown separately in excerpt), high temperature and low temperature recuperators, a precooler, a recompression compressor, a main compressor, CO₂ working medium lines, a turbine that turns a generator shaft, and an electrical generator in accordance with an embodiment of the present disclosure.

FIGS. 2I227-2I228 are schematic drawings of a closed Rankine SunCell® electrical power generator comprising a SunCell® (shown separately in excerpt), a boiler, a turbine that turns a generator shaft, an electrical generator, a condenser, a coolant pump, and coolant lines in accordance with an embodiment of the present disclosure.

FIGS. 2I229-2I231 are schematic drawings of an external-combustor-type, open Brayton SunCell® electrical power generator comprising a turbine compressor to draw in air, a SunCell® with heat exchanger to extract heat from the SunCell® and transfer it to the air, a heat exchanger coolant tank and pump, a power turbine that turns a gear box and compressor shaft, a gear box, an electrical generator, and an air exhaust duct in accordance with an embodiment of the present disclosure.

FIG. 2I232 is a cross sectional schematic drawing of an external-combustor-type, open Brayton SunCell® electrical power generator showing the airflow pattern using arrows in accordance with an embodiment of the present disclosure.

FIG. 2I233 is a schematic drawing of components of an external-combustor-type, open Brayton SunCell® electrical power generator showing details of the turbine compressor to draw in air, the heat exchanger to extract heat from the SunCell® and transfer it to the air, a power turbine, and an air exhaust duct in accordance with an embodiment of the present disclosure.

FIGS. 2I234-2I235 are schematic drawings of an open Rankine SunCell® electrical power generator comprising a SunCell®, a boiler, a turbine that turns a generator shaft, an electrical generator, a cooling tower, and coolant recirculation and support systems in accordance with an embodiment of the present disclosure.

FIGS. 2I236-2I237 are schematic drawings of a Sterling engine SunCell® electrical power generator comprising a SunCell®, a heat exchanger, and a Sterling engine that drives an electrical generator shaft in accordance with an embodiment of the present disclosure.

FIG. 3 is a schematic drawing of the silver-oxygen phase diagram from Smithells Metals Reference Book-8^{th} Edition, 11-20 in accordance with an embodiment of the present disclosure.

FIGS. 4A-C are electron paramagnetic resonance spectroscopy (EPR) spectra of hydrino reaction products comprising lower-energy hydrogen species such as molecular hydrino dimer in different matrices in accordance with an embodiment of the present disclosure. (A) The product formed by the detonation of Sn wire in an atmosphere comprising water vapor in air. (B) The product formed by the ball milling NaOH and KCl having waters of hydration. (C) The product formed by the detonation of Zn wire in an atmosphere comprising water vapor in air wherein the effect of cryogenic temperature was determined on the EPR spectrum at 298K(red trace) and 77K(blue trace).

FIG. 5 is a schematic drawing of a hydrino reaction cell chamber comprising a means to detonate a wire to serve as at least one of a source of reactants and a means to propagate the hydrino reaction to form macro-aggregates or polymers comprising lower-energy hydrogen species such as molecular hydrino in accordance with an embodiment of the present disclosure.

FIG. 6 is Fourier transform infrared (FTIR) spectrum of the reaction product comprising lower-energy hydrogen species such as molecular hydrino formed by the detonation of Zn wire in an atmosphere comprising water vapor in air in accordance with an embodiment of the present disclosure.

FIGS. 7A-B is the ¹H MAS NMR spectrum relative to external TMS of an initial KOH—KCl (1:1) getter that shows the known down-field shifted matrix peak at +4.41 ppm and the ¹H MAS NMR spectrum relative to external TMS of the KOH—KCl (1:1) getter from a scale-up 5 W stack of 10 CIHT cells comprising [Mo/LiOH—LiBr—MgO/NiO] that output 1029 Wh at 137% gain that shows upfield shifted matrix peaks at −4.06 and −4.41 ppm in accordance with an embodiment of the present disclosure.

FIG. 8 is a vibrating sample magnetometer recording of the reaction product comprising lower-energy hydrogen species such as molecular hydrino formed by the detonation of Mo wire in an atmosphere comprising water vapor in air in accordance with an embodiment of the present disclosure.

FIG. 9 is the absolute spectrum in the 5 nm to 450 nm region of the ignition of a 80 mg shot of silver comprising absorbed H₂ and H₂O from gas treatment of silver melt before dripping into a water reservoir showing an average NIST calibrated optical power of 1.3 MW, essentially all in the ultraviolet and extreme ultraviolet spectral region in accordance with an embodiment of the present disclosure.

FIG. 10 is the spectrum (100 nm to 500 nm region with a cutoff at 180 nm due to the sapphire spectrometer window) of the ignition of a molten silver pumped into W electrodes in atmospheric argon with an ambient H₂O vapor pressure of about 1 Torr showing UV line emission that transitioned to 5000K blackbody radiation when the atmosphere became optically thick to the UV radiation with the vaporization of the silver in accordance with an embodiment of the present disclosure.

FIG. 11 is the high resolution visible spectrum of the 800 Torr argon-hydrogen plasma maintained by the hydrino reaction in a Pyrex SunCell® showing a Stark broadening of 1.3 nm corresponding to an electron density of 3.5×10²³/m³ and a 10% ionization fraction requiring about 8.6 GW/m³ to maintain in accordance with an embodiment of the present disclosure.

FIG. 12 is the ultraviolet emission spectrum from electron beam excitation of argon gas comprising some water that is assigned to the H₂(¼) ro-vibrational P branch in accordance with an embodiment of the present disclosure.

FIG. 13 is the ultraviolet emission spectrum from electron beam excitation of KCl that was impregnated with hydrino reaction product gas showing the H₂(¼) ro-vibrational P branch in the crystalline lattice in accordance with an embodiment of the present disclosure.

FIG. 14 is the ultraviolet emission spectrum from electron beam excitation of KCl that was impregnated with hydrino showing the H₂(¼) ro-vibrational P branch in the crystalline lattice that changed intensity with temperature confirming the H₂(¼) ro-vibration assignment in accordance with an embodiment of the present disclosure.

FIG. 15 is the Raman-mode second-order photoluminescence spectrum of the KOH—KCl (1:1 wt %) getter exposed to the product gases of the ignition of solid fuel samples of 100 mg Cu with 30 mg deionized water sealed in the DSC pan using a Horiba Jobin Yvon LabRam ARAMIS 325 nm laser with a 1200 grating over a range of 8000-19,000 cm⁻¹ Raman shift.

FIG. 16 is the Raman spectrum obtained using a Thermo Scientific DXR SmartRaman spectrometer and a 780 nm laser on a In metal foil exposed to the product gas from a series of solid fuel ignitions under argon, each comprising 100 mg of Cu mixed with 30 mg of deionized water showing an inverse Raman effect peak at 1982 cm⁻¹ that matches the free rotor energy of H₂(¼) (0.2414 eV).

FIGS. 17A-B are the Raman spectra obtained using the Thermo Scientific DXR SmartRaman spectrometer and the 780 nm laser on copper electrodes pre and post ignition of a 80 mg silver shot comprising 1 mole % H₂O, wherein the detonation was achieved by applying a 12 V 35,000 A current with a spot welder, and the spectra showed an inverse Raman effect peak at about 1940 cm⁻¹ that matches the free rotor energy of H₂(¼) (0.2414 eV) in accordance with an embodiment of the present disclosure.

FIGS. 18A-B are the XPS spectra recorded on the indium metal foil exposed to gases from sequential argon-atmosphere ignitions of the solid fuel 100 mg Cu+30 mg deionized water sealed in the DSC pan in accordance with an embodiment of the present disclosure. (A) A survey spectrum showing only the elements In, C, O, and trace K peaks were present. (B) High-resolution spectrum showing a peak at 498.5 eV assigned to H₂(¼) wherein other possibilities were eliminated based on the absence of any other corresponding primary element peaks in the survey scan.

FIGS. 19A-B are the XPS spectra of the Fe hydrino polymeric compound having a peak at 496 eV assigned to H₂(¼) wherein other possibilities such Na, Sn, and Zn were eliminated since only Fe, O, and C peaks are present and other peaks of the candidates are absent in accordance with an embodiment of the present disclosure. (A) Survey scan. (B) High resolution scan in the region of the 496 eV peak of H₂(¼).

FIGS. 20A-B are the XPS spectra of the Mo hydrino polymeric compound having a peak at 496 eV assigned to H₂(¼) wherein other possibilities such Na, Sn, and Zn were eliminated since only Mo, O, and C peaks are present and other peaks of the candidates are absent. Mo 3s which is less intense than Mo3p was at 506 eV with additional samples that also showed the H₂(¼) 496 eV peak in accordance with an embodiment of the present disclosure. (A) Survey scan. (B) High resolution scan in the region of the 496 eV peak of H₂(¼).

FIGS. 21A-B are the XPS spectra on copper electrodes post ignition of a 80 mg silver shot comprising 1 mole % H₂O, wherein the detonation was achieved by applying a 12 V 35,000 A current with a spot welder in accordance with an embodiment of the present disclosure. The peak at 496 eV was assigned to H₂(¼) wherein other possibilities such Na, Sn, and Zn were eliminated since the corresponding peaks of these candidates are absent. Raman post detonation spectra (FIGS. 17A-B) showed an inverse Raman effect peak at about 1940 cm⁻¹ that matches the free rotor energy of H₂(¼) (0.2414 eV).

FIG. 22 is a gas chromatograph of hydrino gas in argon recorded with an Agilent column and hydrogen carrier gas showing a negative peak at 74 minutes that eliminates any other assignment other than hydrino in accordance with an embodiment of the present disclosure.

Disclosed herein are catalyst systems to release energy from atomic hydrogen to form lower energy states wherein the electron shell is at a closer position relative to the nucleus. The released power is harnessed for power generation and additionally new hydrogen species and compounds are desired products. These energy states are predicted by classical physical laws and require a catalyst to accept energy from the hydrogen in order to undergo the corresponding energy-releasing transition.

Classical physics gives closed-form solutions of the hydrogen atom, the hydride ion, the hydrogen molecular ion, and the hydrogen molecule and predicts corresponding species having fractional principal quantum numbers. Atomic hydrogen may undergo a catalytic reaction with certain species, including itself, that can accept energy in integer multiples of the potential energy of atomic hydrogen, m·27.2 eV, wherein m is an integer. The predicted reaction involves a resonant, nonradiative energy transfer from otherwise stable atomic hydrogen to the catalyst capable of accepting the energy. The product is H(1/p), fractional Rydberg states of atomic hydrogen called “hydrino atoms,” wherein n=½, ⅓, ¼, . . . , 1/p (p≤137 is an integer) replaces the well-known parameter n=integer in the Rydberg equation for hydrogen excited states. Each hydrino state also comprises an electron, a proton, and a photon, but the field contribution from the photon increases the binding energy rather than decreasing it corresponding to energy desorption rather than absorption. Since the potential energy of atomic hydrogen is 27.2 eV, m H atoms serve as a catalyst of m·27.2 eV for another (m+1)th H atom [R. Mills, The Grand Unified Theory of Classical Physics; September 2016 Edition, posted at https://brilliantlightpower.com/book-download-and-streaming/(“Mills GUTCP”)]. For example, a H atom can act as a catalyst for another H by accepting 27.2 eV from it via through-space energy transfer such as by magnetic or induced electric dipole-dipole coupling to form an intermediate that decays with the emission of continuum bands with short wavelength cutoffs and energies of

$${m}^{2} \cdot 13.6 eV ( \frac{91.2}{{m}^{2}} nm ) .$$

In addition to atomic H, a molecule that accepts m·27.2 eV from atomic H with a decrease in the magnitude of the potential energy of the molecule by the same energy may also serve as a catalyst. The potential energy of H₂O is 81.6 eV. Then, by the same mechanism, the nascent H₂O molecule (not hydrogen bonded in solid, liquid, or gaseous state) formed by a thermodynamically favorable reduction of a metal oxide is predicted to serve as a catalyst to form H(¼) with an energy release of 204 eV, comprising an 81.6 eV transfer to HOH and a release of continuum radiation with a cutoff at 10.1 nm (122.4 eV).

In the H-atom catalyst reaction involving a transition to the

$$H [ \frac{{a}_{H}}{p = m + i} ]$$

state, m H atoms serve as a catalyst of n·27.2 eV for another (m+1)th H atom. Then, the reaction between m+1 hydrogen atoms whereby m atoms resonantly and nonradiatively accept m·27.2 eV from the (m+1)th hydrogen atom such that mH serves as the catalyst is given by

$$\begin{matrix}m \cdot 27.2 eV + m H + H \to m {H}_{fast}^{+} + {me}^{-} + H * [ \frac{{a}_{H}}{m + 1} ] + m \cdot 27.2 eV & ( 1 ) \\ H * [ \frac{{a}_{H}}{m + 1} ] \to H [ \frac{{a}_{H}}{m + 1} ] + [ {( m + 1 )}^{2} - {1}^{2} ] \cdot 13.6 eV - m \cdot 27.2 eV & ( 2 ) \\ m {H}_{fast}^{+} + {me}^{-} \to m H + m \cdot 27.2 eV & ( 3 ) \\ And , the overall reaction is & \\ H \to H [ \frac{{a}_{H}}{p = m + 1} ] + [ {( m + 1 )}^{2} - {1}^{2} ] \cdot 13.6 eV & ( 4 )\end{matrix}$$

The catalysis reaction (m=3) regarding the potential energy of nascent H₂O [R. Mills, The Grand Unified Theory of Classical Physics; September 2016 Edition, posted at https://brilliantlightpower.com/book-download-and-streaming/] is

$$\begin{matrix}81.6 eV + {H}_{2} O + H [ {a}_{H} ] \to 2 {H}_{fast}^{+} + {O}^{-} + {e}^{-} + H * [ \frac{{a}_{H}}{4} ] + 81.6 eV & ( 5 ) \\ H * [ \frac{{a}_{H}}{4} ] \to H [ \frac{{a}_{H}}{4} ] + 122.4 eV & ( 6 ) \\ 2 {H}_{fast}^{+} + {O}^{-} + {e}^{-} \to {H}_{2} O + 81.6 eV & ( 7 )\end{matrix}$$

And, the overall reaction is

$$H [ {a}_{H} ] \to H [ \frac{{a}_{H}}{4} ] + 81.6 eV + 122.4 eV \qquad ( 8 )$$

After the energy transfer to the catalyst (Eqs. (1) and (5)), an intermediate

$$H * [ \frac{{a}_{H}}{m + 1} ]$$

is formed having the radius of the H atom and a central field of m+1 times the central field of a proton. The radius is predicted to decrease as the electron undergoes radial acceleration to a stable state having a radius of 1/(m+1) the radius of the uncatalyzed hydrogen atom, with the release of m²·13.6 eV of energy. The extreme-ultraviolet continuum radiation band due to the

$$H * [ \frac{{a}_{H}}{m + 1} ]$$

intermediate (e.g. Eq. (2) and Eq. (6)) is predicted to have a short wavelength cutoff and energy

$${E}_{( H \to H [ \frac{{a}_{H}}{p = m + 1} ] )}$$

given by

$${E}_{( H \to H [ \frac{{a}_{H}}{p = m + 1} ] )} = {m}^{2} \cdot 13.6 eV ; {λ}_{( H \to H [ \frac{{a}_{H}}{p = m + 1} ] )} = \frac{91.2}{{m}^{2}} nm \qquad ( 9 )$$

and extending to longer wavelengths than the corresponding cutoff. Here the extreme-ultraviolet continuum radiation band due to the decay of the H*[a_{H}/4] intermediate is predicted to have a short wavelength cutoff at E=m²0.13.6=9·13.6=122.4 eV (10.1 nm) [where p=m+1=4 and m=3 in Eq. (9)] and extending to longer wavelengths. The continuum radiation band at 10.1 nm and going to longer wavelengths for the theoretically predicted transition of H to lower-energy, so called “hydrino” state H(¼), was observed only arising from pulsed pinch gas discharges comprising some hydrogen. Another observation predicted by Eqs. (1) and (5) is the formation of fast, excited state H atoms from recombination of fast H⁺. The fast atoms give rise to broadened Balmer α emission. Greater than 50 eV Balmer α line broadening that reveals a population of extraordinarily high-kinetic-energy hydrogen atoms in certain mixed hydrogen plasmas is a well-established phenomenon wherein the cause is due to the energy released in the formation of hydrinos. Fast H was previously observed in continuum-emitting hydrogen pinch plasmas.

Additional catalyst and reactions to form hydrino are possible. Specific species (e.g. He⁺, Ar⁺, Sr⁺, K, Li, HCl, and NaH, OH, SH, SeH, nascent H₂O, nH (n=integer)) identifiable on the basis of their known electron energy levels are required to be present with atomic hydrogen to catalyze the process. The reaction involves a nonradiative energy transfer followed by q·13.6 eV continuum emission or q·13.6 eV transfer to H to form extraordinarily hot, excited-state H and a hydrogen atom that is lower in energy than unreacted atomic hydrogen that corresponds to a fractional principal quantum number. That is, in the formula for the principal energy levels of the hydrogen atom:

$$\begin{matrix}{E}_{n} = - \frac{{e}^{2}}{{n}^{2} 8 {πɛ}_{o} {a}_{H}} = - \frac{13.598 eV}{{n}^{2}} . & ( 10 ) \\ n = 1 , 2 , 3 , … & ( 11 )\end{matrix}$$

where a_{H} is the Bohr radius for the hydrogen atom (52.947 pm), e is the magnitude of the charge of the electron, and εₒ is the vacuum permittivity, fractional quantum numbers:

$$n = 1 , \frac{1}{2} , \frac{1}{3} , \frac{1}{4} , … , \frac{1}{p} ; where p \leq 137 is an integer \qquad ( 12 )$$

replace the well known parameter n=integer in the Rydberg equation for hydrogen excited states and represent lower-energy-state hydrogen atoms called “hydrinos.” The n=1 state of hydrogen and the

$$n = \frac{1}{integer}$$

states of hydrogen are nonradiative, but a transition between two nonradiative states, say n=1 to n=1/2, is possible via a nonradiative energy transfer. Hydrogen is a special case of the stable states given by Eqs. (10) and (12) wherein the corresponding radius of the hydrogen or hydrino atom is given by

$$r = \frac{{a}_{H}}{p} , \qquad ( 13 )$$

where p=1, 2, 3, . . . . In order to conserve energy, energy must be transferred from the hydrogen atom to the catalyst in units of an integer of the potential energy of the hydrogen atom in the normal n=1 state, and the radius transitions to a

$$\frac{{a}_{H}}{m + p} .$$

Hydrinos are formed by reacting an ordinary hydrogen atom with a suitable catalyst having a net enthalpy of reaction of

m·27.2 eV (14)

where m is an integer. It is believed that the rate of catalysis is increased as the net enthalpy of reaction is more closely matched to m·27.2 eV. It has been found that catalysts having a net enthalpy of reaction within ±10%, preferably ±5%, of m·27.2 eV are suitable for most applications.

The catalyst reactions involve two steps of energy release: a nonradiative energy transfer to the catalyst followed by additional energy release as the radius decreases to the corresponding stable final state. Thus the general reaction is given by

$$\begin{matrix}m \cdot 27.2 eV + {Cat}^{q +} + H [ \frac{{a}_{H}}{p} ] \to {Cat}^{( q + r ) +} + {re}^{-} + H * [ \frac{{a}_{H}}{( m + p )} ] + m \cdot 27.2 eV & ( 15 ) \\ H * [ \frac{{a}_{H}}{( m + p )} ] \to H [ \frac{{a}_{H}}{( m + p )} ] + [ {( p + m )}^{2} - {p}^{2} ] \cdot 13.6 eV - m \cdot 27.2 eV & ( 16 ) \\ {Cat}^{( q + r ) +} + {re}^{-} \to {Cat}^{q +} + m \cdot 27.2 eV and & ( 17 )\end{matrix}$$

the overall reaction is

$$H [ \frac{{a}_{H}}{p} ] \to H [ \frac{{a}_{H}}{( m + p )} ] + [ {( p + m )}^{2} - {p}^{2} ] \cdot 13.6 eV \qquad ( 18 )$$

q, r, m, and p are integers.

$$H * [ \frac{{a}_{H}}{( m + p )} ]$$

has the radius of the hydrogen atom (corresponding to the 1 in the denominator) and a central field equivalent to (m+p) times that of a proton, and

$$H [ \frac{{a}_{H}}{( m + p )} ]$$

is the corresponding stable state with the radius of

$$\frac{1}{( m + p )}$$

that of H.

The catalyst product, H(1/p), may also react with an electron to form a hydrino hydride ion H⁺(1/p), or two H(1/p) may react to form the corresponding molecular hydrino H₂(1/p). Specifically, the catalyst product, H(1/p), may also react with an electron to form a novel hydride ion H⁺(1/p) with a binding energy E_{B}:

$${E}_{B} = \frac{{h}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {h}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) \qquad ( 19 )$$

where p=integer >1, s=1/2, h is Planck's constant bar, μₒ is the permeability of vacuum, mₑ is the mass of the electron, y, is the reduced electron mass given by

$${μ}_{e} = \frac{{m}_{e} {m}_{p}}{\frac{{m}_{e}}{\sqrt{\frac{3}{4}}} + {m}_{p}}$$

where mₚ is the mass of the proton, aₒ is the Bohr radius, and the ionic radius is

$${r}_{1} = \frac{{a}_{0}}{p} ( 1 + \sqrt{s ( s + 1 )} ) .$$

From Eq. (19), the calculated ionization energy of the hydride ion is 0.75418 eV, and the experimental value is 6082.99±0.15 cm⁻¹ (0.75418 eV). The binding energies of hydrino hydride ions may be measured by X-ray photoelectron spectroscopy (XPS).

Upfield-shifted NMR peaks are direct evidence of the existence of lower-energy state hydrogen with a reduced radius relative to ordinary hydride ion and having an increase in diamagnetic shielding of the proton. The shift is given by the sum of the contributions of the diamagnetism of the two electrons and the photon field of magnitude p (Mills GUTCP Eq. (7.87)):

$$\frac{Δ {B}_{T}}{B} = - {μ}_{0} \frac{{pe}^{2}}{12 {m}_{e} {a}_{0} ( 1 + \sqrt{s ( s + 1 )} )} ( 1 + p {α}^{2} ) = - ( p 29.9 + {p}^{2} 1.59 \times {10}^{- 3} ) ppm \qquad ( 20 )$$

where the first term applies to H⁻ with p=1 and p=integer >1 for H⁻(1/p) and α is the fine structure constant. The predicted hydrino hydride peaks are extraordinarily upfield shifted relative to ordinary hydride ion. In an embodiment, the peaks are upfield of TMS. The NMR shift relative to TMS may be greater than that known for at least one of ordinary H⁻, H, H₂, or H⁺ alone or comprising a compound. The shift may be greater than at least one of 0, −1, −2, −3, −4, −5, −6, −7, −8, −9, −10, −11, −12, −13, −14, −15, −16, −17, −18, −19, −20, −21, −22, −23, −24, −25, −26, −27, −28, −29, −30, −31, −32, −33, −34, −35, −36, −37, −38, −39, and −40 ppm. The range of the absolute shift relative to a bare proton, wherein the shift of TMS is about −31.5 relative to a bare proton, may be −(p29.9+p²2.74) ppm (Eq. (20)) within a range of about at least one of ±5 ppm, ±10 ppm, ±20 ppm, ±30 ppm, ±40 ppm, ±50 ppm, ±60 ppm, ±70 ppm, ±80 ppm, ±90 ppm, and 100 ppm. The range of the absolute shift relative to a bare proton may be −(p29.9+p²1.59×10⁻³) ppm (Eq. (20)) within a range of about at least one of about 0.1% to 99%, 1% to 50%, and 1% to 10%. In another embodiment, the presence of a hydrino species such as a hydrino atom, hydride ion, or molecule in a solid matrix such as a matrix of a hydroxide such as NaOH or KOH causes the matrix protons to shift upfield. The matrix protons such as those of NaOH or KOH may exchange. In an embodiment, the shift may cause the matrix peak to be in the range of about −0.1 ppm to −5 ppm relative to TMS. The NMR determination may comprise magic angle spinning ¹H nuclear magnetic resonance spectroscopy (MAS ¹H NMR).

H(1/p) may react with a proton and two H(1/p) may react to form H₂(1/p)⁺ and H₂(1/p), respectively. The hydrogen molecular ion and molecular charge and current density functions, bond distances, and energies were solved from the Laplacian in ellipsoidal coordinates with the constraint of nonradiation.

$$( η - ζ ) {R}_{ξ} \frac{\partial }{\partial ξ} ( {R}_{ξ} \frac{\partial φ}{\partial ξ} ) + ( ζ - ξ ) {R}_{η} \frac{\partial }{\partial η} ( {R}_{η} \frac{\partial φ}{\partial η} ) + ( ξ - η ) {R}_{ζ} \frac{\partial }{\partial ζ} ( {R}_{ζ} \frac{\partial φ}{\partial ζ} ) = 0 \qquad ( 21 )$$

The total energy E_{T} of the hydrogen molecular ion having a central field of +pe at each focus of the prolate spheroid molecular orbital is

$${E}_{T} = - {p}^{2} \{ \begin{matrix}\frac{{e}^{2}}{8 {πɛ}_{o} {a}_{H}} ( 4 ln 3 - 1 - 2 ln 3 ) [ 1 + p \sqrt{\frac{2 h \sqrt{\frac{2 {e}^{2}}{\frac{4 {{πɛ}_{o} ( 2 {a}_{H} )}^{3}}{{m}_{e}}}}}{{m}_{e} {c}^{2}}} ] \\ - \frac{1}{2} h \sqrt{\frac{\frac{{pe}^{2}}{4 {{πɛ}_{o} ( \frac{2 {a}_{H}}{p} )}^{3}} - \frac{{pe}^{2}}{8 {{πɛ}_{o} ( \frac{3 {a}_{H}}{p} )}^{3}}}{μ}}\end{matrix} \} = - {p}^{2} 16.13392 eV - {p}^{3} 0.118755 eV \qquad ( 22 )$$

where p is an integer, c is the speed of light in vacuum, and μ is the reduced nuclear mass. The total energy of the hydrogen molecule having a central field of +pe at each focus of the prolate spheroid molecular orbital is

$${E}_{T} = - {p}^{2} \{ \begin{matrix}\frac{{e}^{2}}{8 {πɛ}_{o} {a}_{H}} [ ( 2 \sqrt{2} - \sqrt{2} + \frac{\sqrt{2}}{2} ) ln \frac{\sqrt{2} + 1}{\sqrt{2} - 1} - \sqrt{2} ] \\ [ 1 + p \sqrt{\frac{2 h \sqrt{\frac{{e}^{2}}{\frac{4 {πɛ}_{o} {a}_{0}^{3}}{{m}_{e}}}}}{{m}_{e} {c}^{2}}} ] \\ - \frac{1}{2} h \sqrt{\frac{\frac{{pe}^{2}}{8 {{πɛ}_{o} ( \frac{{a}_{0}}{p} )}^{3}} - \frac{{pe}^{2}}{8 {{πɛ}_{o} ( \frac{( 1 + \frac{1}{\sqrt{2}} ) {a}_{0}}{p} )}^{3}}}{μ}}\end{matrix} \} = - {p}^{2} 31.351 eV - {p}^{3} 0.326469 eV \qquad ( 23 )$$

The bond dissociation energy, E_{D}, of the hydrogen molecule H₂(1/p) is the difference between the total energy of the corresponding hydrogen atoms and E_{T}.

$$\begin{matrix}{E}_{D} = E ( 2 H ( 1 / p ) ) - {E}_{T} & ( 24 ) \\ where & \\ E ( 2 H ( 1 / p ) ) = - {p}^{2} 27.20 eV \\ {E}_{D} is given by Eqs . ( 23 \text{-} 25 ) \text{:} & ( 25 ) \\ \begin{matrix}{E}_{D} = - {p}^{2} 27.20 eV - {E}_{T} \\ = - {p}^{2} 27.20 eV - ( - {p}^{2} 31.351 eV - {p}^{3} 0.326469 eV ) \\ = {p}^{2} 4.151 eV + {p}^{3} 0.326469 eV\end{matrix} & ( 26 )\end{matrix}$$

H₂(1/p) may be identified by X-ray photoelectron spectroscopy (XPS) wherein the ionization product in addition to the ionized electron may be at least one of the possibilities such as those comprising two protons and an electron, a hydrogen (H) atom, a hydrino atom, a molecular ion, hydrogen molecular ion, and H₂(1/p)⁺ wherein the energies may be shifted by the matrix.

The NMR of catalysis-product gas provides a definitive test of the theoretically predicted chemical shift of H₂(1/p). In general, the ¹H NMR resonance of H₂(1/p) is predicted to be upfield from that of H₂ due to the fractional radius in elliptic coordinates wherein the electrons are significantly closer to the nuclei. The predicted shift,

$$\frac{Δ {B}_{T}}{B} ,$$

for H₂(1/p) is given by the sum of the contributions of the diamagnetism of the two electrons and the photon field of magnitude p (Mills GUTCP Eqs. (11.415-11.416)):

$$\begin{matrix}\frac{Δ {B}_{T}}{B} = - {μ}_{0} ( 4 - \sqrt{2} ln \frac{\sqrt{2} + 1}{\sqrt{2} - 1} ) \frac{{pe}^{2}}{36 {a}_{0} {m}_{e}} ( 1 + p {α}^{2} ) & ( 27 ) \\ \frac{Δ {B}_{T}}{B} = - ( p 28.01 + {p}^{2} 1.49 \times {10}^{- 3} ) ppm & ( 28 )\end{matrix}$$

where the first term applies to H₂ with p=1 and p=integer >1 for H₂(1/p). The experimental absolute H₂ gas-phase resonance shift of −28.0 ppm is in excellent agreement with the predicted absolute gas-phase shift of −28.01 ppm (Eq. (28)). The predicted molecular hydrino peaks are extraordinarily upfield shifted relative to ordinary H₂. In an embodiment, the peaks are upfield of TMS. The NMR shift relative to TMS may be greater than that known for at least one of ordinary H⁺, H, H₂, or H⁺ alone or comprising a compound. The shift may be greater than at least one of 0, −1, −2, −3, −4, −5, −6, −7, −8, −9, −10, −11, −12, −13, −14, −15, −16, −17, −18, −19, −20, −21, −22, −23, −24, −25, −26, −27, −28, −29, −30, −31, −32, −33, −34, −35, −36, −37, −38, −39, and −40 ppm. The range of the absolute shift relative to a bare proton, wherein the shift of TMS is about −31.5 ppm relative to a bare proton, may be −(p28.01+p²2.56) ppm (Eq. (28)) within a range of about at least one of ±5 ppm, ±10 ppm, ±20 ppm, ±30 ppm, ±40 ppm, ±50 ppm, ±60 ppm, 70 ppm, ±80 ppm, 90 ppm, and ±100 ppm. The range of the absolute shift relative to a bare proton may be −(p28.01+p² 1.49×10⁻³) ppm (Eq. (28)) within a range of about at least one of about 0.1% to 99%, 1% to 50%, and 1% to 10%.

The vibrational energies, E_{vib}, for the υ=0 to υ=1 transition of hydrogen-type molecules H₂(1/p) are

E_{vib}=p²0.515902 eV (29)

where p is an integer.

The rotational energies, Eᵣₒₜ for the J to J+1 transition of hydrogen-type molecules H₂ (1/p) are

$${E}_{rot} = {E}_{J + 1} - {E}_{J} = \frac{{ℏ}^{2}}{I} [ J + 1 ] = {p}^{2} ( J + 1 ) 0.01509 eV \qquad ( 30 )$$

where p is an integer and I is the moment of inertia. Ro-vibrational emission of H₂ (¼) was observed on e-beam excited molecules in gases and trapped in solid matrix.

The p² dependence of the rotational energies results from an inverse p dependence of the internuclear distance and the corresponding impact on the moment of inertia I. The predicted internuclear distance 2c′ for H₂(1/p) is

$$2 {c}^{′} = \frac{{a}_{o} \sqrt{2}}{p} \qquad ( 31 )$$

At least one of the rotational and vibration energies of H₂(1/p) may be measured by at least one of electron-beam excitation emission spectroscopy, Raman spectroscopy, and Fourier transform infrared (FTIR) spectroscopy. H₂(1/p) may be trapped in a matrix for measurement such as in at least one of MOH, MX, and M₂CO₃ (M=alkali; X=halide) matrix.

In an embodiment, the molecular hydrino product is observed as an inverse Raman effect (IRE) peak at about 1950 cm⁻¹. The peak is enhanced by using a conductive material comprising roughness features or particle size comparable to that of the Raman laser wavelength that supports a Surface Enhanced Raman Scattering (SERS) to show the IRE peak.

I. Catalysts

In the present disclosure the terms such as hydrino reaction, H catalysis, H catalysis reaction, catalysis when referring to hydrogen, the reaction of hydrogen to form hydrinos, and hydrino formation reaction all refer to the reaction such as that of Eqs. (15-18)) of a catalyst defined by Eq. (14) with atomic H to form states of hydrogen having energy levels given by Eqs. (10) and (12). The corresponding terms such as hydrino reactants, hydrino reaction mixture, catalyst mixture, reactants for hydrino formation, reactants that produce or form lower-energy state hydrogen or hydrinos are also used interchangeably when referring to the reaction mixture that performs the catalysis of H to H states or hydrino states having energy levels given by Eqs. (10) and (12).

The catalytic lower-energy hydrogen transitions of the present disclosure require a catalyst that may be in the form of an endothermic chemical reaction of an integer m of the potential energy of uncatalyzed atomic hydrogen, 27.2 eV, that accepts the energy from atomic H to cause the transition. The endothermic catalyst reaction may be the ionization of one or more electrons from a species such as an atom or ion (e.g. m=3 for Li→L²⁺) and may further comprise the concerted reaction of a bond cleavage with ionization of one or more electrons from one or more of the partners of the initial bond (e.g. m=2 for NaH→Na²⁺+H). He⁺ fulfills the catalyst criterion—a chemical or physical process with an enthalpy change equal to an integer multiple of 27.2 eV since it ionizes at 54.417 eV, which is 2.27.2 eV. An integer number of hydrogen atoms may also serve as the catalyst of an integer multiple of 27.2 eV enthalpy. catalyst is capable of acceptin energy from atomic hydrogen in integer units of one of about 27.2 eV±0.5 eV and

$$\frac{27.2}{2} eV \pm 0.5 eV .$$

In an embodiment, the catalyst comprises an atom or ion M wherein the ionization of t electrons from the atom or ion M each to a continuum energy level is such that the sum of ionization energies of the t electrons is approximately one of m·27.2 eV and

$$m \cdot \frac{27.2}{2} eV$$

where m is an integer.

In an embodiment, the catalyst comprises a diatomic molecule MH wherein the breakage of the M-H bond plus the ionization of t electrons from the atom M each to a continuum energy level is such that the sum of the bond energy and ionization energies of the t electrons is approximately one of m·27.2 eV

$$m \cdot \frac{27.2}{2} eV$$

where m is an integer.

In an embodiment, the catalyst comprises atoms, ions, and/or molecules chosen from molecules of AlH, AsH, BaH, BiH, CdH, ClH, CoH, GeH, InH, NaH, NbH, OH, RhH, RuH, SH, Sb, SeH, SiH, SnH, SrH, TH, C₂, N₂, O₂, CO₂, NO₂, and NO₃ and atoms or ions of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, 2K⁺, He⁺, Ti²⁻, Na⁺, Rb⁺, Sr⁺, Fe³⁺, Mo²⁺, In³⁺, He⁺, Ar⁺, Xe⁺, Ar²⁺ and H⁺, and Ne⁺ and H⁺.

In other embodiments, MH⁻ type hydrogen catalysts to produce hydrinos provided by the transfer of an electron to an acceptor A, the breakage of the M-H bond plus the ionization of t electrons from the atom M each to a continuum energy level such that the sum of the electron transfer energy comprising the difference of electron affinity (EA) of MH and A, M-H bond energy, and ionization energies of the t electrons from M is approximately m·27.2 eV where m is an integer. MH⁻ type hydrogen catalysts capable of providing a net enthalpy of reaction of approximately m·27.2 eV are OH⁻, SiH⁻, CoH⁻, NiH⁻, and SeH⁻

In other embodiments, MH⁺ type hydrogen catalysts to produce hydrinos are provided by the transfer of an electron from an donor A which may be negatively charged, the breakage of the M-H bond, and the ionization of t electrons from the atom M each to a continuum energy level such that the sum of the electron transfer energy comprising the difference of ionization energies of MH and A, bond M-H energy, and ionization energies of the t electrons from M is approximately m·27.2 eV where m is an integer.

In an embodiment, at least one of a molecule or positively or negatively charged molecular ion serves as a catalyst that accepts about m27.2 eV from atomic H with a decrease in the magnitude of the potential energy of the molecule or positively or negatively charged molecular ion by about m27.2 eV. Exemplary catalysts are H₂O, OH, amide group NH₂, and H₂S.

O₂ may serve as a catalyst or a source of a catalyst. The bond energy of the oxygen molecule is 5.165 eV, and the first, second, and third ionization energies of an oxygen atom are 13.61806 eV, 35.11730 eV, and 54.9355 eV, respectively. The reactions O₂→O+O²⁺, O₂→O+O³⁺, and 2O→2O⁺ provide a net enthalpy of about 2, 4, and 1 times Eₕ, respectively, and comprise catalyst reactions to form hydrino by accepting these energies from H to cause the formation of hydrinos.

II. Hydrinos

A hydrogen atom having a binding energy given by

$${E}_{B} = \frac{13.6 eV}{{( 1 \text{/} p )}^{2}}$$

where p is an integer greater than 1, preferably from 2 to 137, is the product of the H catalysis reaction of the present disclosure. The binding energy of an atom, ion, or molecule, also known as the ionization energy, is the energy required to remove one electron from the atom, ion or molecule. A hydrogen atom having the binding energy given in Eqs. (10) and (12) is hereafter referred to as a “hydrino atom” or “hydrino.” The designation for a hydrino of radius

$$\frac{{a}_{H}}{p} ,$$

where a_{H} is the radius of an ordinary hydrogen atom and p is an integer, is

$$H [ \frac{{a}_{H}}{p} ] .$$

A hydrogen atom with a radius a_{H} is hereinafter referred to as “ordinary hydrogen atom” or “normal hydrogen atom.” Ordinary atomic hydrogen is characterized by its binding energy of 13.6 eV.

According to the present disclosure, a hydrino hydride ion (H) having a binding energy according to Eq. (19) that is greater than the binding of ordinary hydride ion (about 0.75 eV) for p=2 up to 23, and less for p=24 (H⁻) is provided. For p=2 to p=24 of Eq. (19), the hydride ion binding energies are respectively 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV. Exemplary compositions comprising the novel hydride ion are also provided herein.

Exemplary compounds are also provided comprising one or more hydrino hydride ions and one or more other elements. Such a compound is referred to as a “hydrino hydride compound.”

Ordinary hydrogen species are characterized by the following binding energies (a) hydride ion, 0.754 eV (“ordinary hydride ion”); (b) hydrogen atom (“ordinary hydrogen atom”), 13.6 eV; (c) diatomic hydrogen molecule, 15.3 eV (“ordinary hydrogen molecule”); (d) hydrogen molecular ion, 16.3 eV (“ordinary hydrogen molecular ion”); and (e) H₃⁺, 22.6 eV (“ordinary trihydrogen molecular ion”). Herein, with reference to forms of hydrogen, “normal” and “ordinary” are synonymous.

According to a further embodiment of the present disclosure, a compound is provided comprising at least one increased binding energy hydrogen species such as (a) a hydrogen atom having a binding energy of about

$$\frac{13.6 eV}{{( \frac{1}{p} )}^{2}} ,$$

such as within a range of about 0.9 to 1.1 times

$$\frac{13.6 eV}{{( \frac{1}{p} )}^{2}}$$

where p is an integer from 2 to 137; (b) a hydride ion (H⁻) having a binding energy of about

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) ,$$

such as within a range of about 0.9 to 1.1 times

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$

where p is an integer from 2 to 24; (c) H₄⁺(1/p); (d) a trihydrino molecular ion, H₃⁺(1/p), having a binding energy of about

$$\frac{22.6}{{( \frac{1}{p} )}^{2}} eV$$

such as within a range of about 0.9 to 1.1 times

$$\frac{22.6}{{( \frac{1}{p} )}^{2}} eV$$

where p is an integer from 2 to 137; (e) a dihydrino having a binding energy of about

$$\frac{15.3}{{( \frac{1}{p} )}^{2}} eV$$

such as within a range of about 0.9 to 1.1 times

$$\frac{15.3}{{( \frac{1}{p} )}^{2}} eV$$

where p is an integer from 2 to 137; (f) a dihydrino molecular ion with a binding energy of about

$$\frac{16.3}{{( \frac{1}{p} )}^{2}} eV$$

such as within a range of about 0.9 to 1.1 time

$$\frac{16.3}{{( \frac{1}{p} )}^{2}} eV$$

where p is an integer, preferably an integer from 2 to 137.

According to a further embodiment of the present disclosure, a compound is provided comprising at least one increased binding energy hydrogen species such as (a) a dihydrino molecular ion having a total energy of about

$$\begin{matrix}{E}_{T} = - {p}^{2} \{ \begin{matrix}\frac{{e}^{2}}{8 {πɛ}_{o} {a}_{H}} ( 4 ln 3 - 1 - 2 ln 3 ) [ 1 + p \sqrt{\frac{2 ℏ \sqrt{\frac{\frac{2 {e}^{2}}{4 {{πɛ}_{o} ( 2 {a}_{H} )}^{2}}}{{m}_{e}}}}{{m}_{e} {c}^{2}}} ] \\ - \frac{1}{2} ℏ \sqrt{\frac{\frac{{pe}^{2}}{4 {{πɛ}_{o} ( \frac{2 {a}_{H}}{p} )}^{3}} - \frac{{pe}^{2}}{8 {{πɛ}_{o} ( \frac{3 {a}_{H}}{p} )}^{3}}}{μ}} \end{matrix} \} \\ = - {p}^{2} 16.13392 eV - {p}^{3} 0.118755 eV\end{matrix}$$

such as within a range of about 0.9 to 1.1 times

$$\begin{matrix}{E}_{T} = - {p}^{2} \{ \begin{matrix}\frac{{e}^{2}}{8 {πɛ}_{o} {a}_{H}} ( 4 ln 3 - 1 - 2 ln 3 ) [ 1 + p \sqrt{\frac{2 ℏ \sqrt{\frac{\frac{2 {e}^{2}}{4 {{πɛ}_{o} ( 2 {a}_{H} )}^{2}}}{{m}_{e}}}}{{m}_{e} {c}^{2}}} ] \\ - \frac{1}{2} ℏ \sqrt{\frac{\frac{{pe}^{2}}{4 {{πɛ}_{o} ( \frac{2 {a}_{H}}{p} )}^{3}} - \frac{{pe}^{2}}{8 {{πɛ}_{o} ( \frac{3 {a}_{H}}{p} )}^{3}}}{μ}} \end{matrix} \} \\ = - {p}^{2} 16.13392 eV - {p}^{3} 0.118755 eV\end{matrix}$$

where p is an integer, h is Planck's constant bar, mₑ is the mass of the electron, c is the speed of light in vacuum, and μ is the reduced nuclear mass, and (b) a dihydrino molecule having a total energy of about

$$\begin{matrix}{E}_{T} = - {p}^{2} \{ \begin{matrix}\frac{{e}^{2}}{8 {πɛ}_{o} {a}_{0}} [ ( 2 \sqrt{2} - \sqrt{2} + \frac{\sqrt{2}}{2} ) ln \frac{\sqrt{2} + 1}{\sqrt{2} - 1} - \sqrt{2} ] [ 1 + p \sqrt{\frac{2 ℏ \sqrt{\frac{{e}^{2}}{\frac{4 {πɛ}_{o} {a}_{0}^{3}}{{m}_{e}}}}}{{m}_{e} {c}^{2}}} ] \\ - \frac{1}{2} ℏ \sqrt{\frac{\frac{{pe}^{2}}{8 {{πɛ}_{o} ( \frac{{a}_{0}}{p} )}^{3}} - \frac{{pe}^{2}}{8 {{πɛ}_{o} ( \frac{( 1 + \frac{1}{\sqrt{2}} ) {a}_{0}}{p} )}^{3}}}{μ}} \end{matrix} \} \\ = - {p}^{2} 31.351 eV - {p}^{3} 0.326469 eV\end{matrix}$$

such as within a range of about 0.9 to 1.1 times

$$\begin{matrix}{E}_{T} = - {p}^{2} \{ \begin{matrix}\frac{{e}^{2}}{8 {πɛ}_{o} {a}_{0}} [ ( 2 \sqrt{2} - \sqrt{2} + \frac{\sqrt{2}}{2} ) ln \frac{\sqrt{2} + 1}{\sqrt{2} - 1} - \sqrt{2} ] [ 1 + p \sqrt{\frac{2 ℏ \sqrt{\frac{{e}^{2}}{\frac{4 {πɛ}_{o} {a}_{0}^{3}}{{m}_{e}}}}}{{m}_{e} {c}^{2}}} ] \\ - \frac{1}{2} ℏ \sqrt{\frac{\frac{{pe}^{2}}{8 {{πɛ}_{o} ( \frac{{a}_{0}}{p} )}^{3}} - \frac{{pe}^{2}}{8 {{πɛ}_{o} ( \frac{( 1 + \frac{1}{\sqrt{2}} ) {a}_{0}}{p} )}^{3}}}{μ}} \end{matrix} \} \\ = - {p}^{2} 31.351 eV - {p}^{3} 0.326469 eV\end{matrix}$$

where p is an integer and aₒ is the Bohr radius.

According to one embodiment of the present disclosure wherein the compound comprises a negatively charged increased binding energy hydrogen species, the compound further comprises one or more cations, such as a proton, ordinary H₂⁺, or ordinary H₃⁺.

A method is provided herein for preparing compounds comprising at least one hydrino hydride ion. Such compounds are hereinafter referred to as “hydrino hydride compounds.” The method comprises reacting atomic hydrogen with a catalyst having a net enthalpy of reaction of about

$$\frac{m}{2} \cdot 27 eV ,$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 137. A further product of the catalysis is energy. The increased binding energy hydrogen atom can be reacted with an electron source, to produce an increased binding energy hydride ion. The increased binding energy hydride ion can be reacted with one or more cations to produce a compound comprising at least one increased binding energy hydride ion.

In an embodiment, at least one of very high power and energy may be achieved by the hydrogen undergoing transitions to hydrinos of high p values in Eq. (18) in a process herein referred to as disproportionation as given in Mills GUTCP Chp. 5 which is incorporated by reference. Hydrogen atoms H(1/p) p=1, 2, 3, . . . 137 can undergo further transitions to lower-energy states given by Eqs. (10) and (12) wherein the transition of one atom is catalyzed by a second that resonantly and nonradiatively accepts m·27.2 eV with a concomitant opposite change in its potential energy. The overall general equation for the transition of H(1/p) to H(1/(p+m)) induced by a resonance transfer of m·27.2 eV to H(1/p′) given by Eq. (32) is represented by

H(1/p′)+H(1/p)→H+H(1/(p+m))+[2 pm+m²−p′²+1]·13.6 eV (32)

The EUV light from the hydrino process may dissociate the dihydrino molecules and the resulting hydrino atoms may serve as catalysts to transition to lower energy states. An exemplary reaction comprises the catalysis H to H( 1/17) by H(¼) wherein H(¼) may be a reaction product of the catalysis of another H by HOH. Disproportionation reactions of hydrinos are predicted to given rise to features in the X-ray region. As shown by Eqs. (5-8) the reaction product of HOH catalyst is

$$H [ \frac{{a}_{H}}{4} ] .$$

Consider a likely transition reaction in hydrogen clouds containing H₂O gas wherein the first hydrogen-type atom H

$$H [ \frac{{a}_{H}}{p} ]$$

is an H atom and the second acceptor hydrogen-type atom

$$H [ \frac{{a}_{H}}{{p}^{′}} ]$$

serving as a catalyst is

$$H [ \frac{{a}_{H}}{4} ] .$$

Since the potential energy of

$$H [ \frac{{a}_{H}}{4} ] is {4}^{2} \cdot 27.2 eV = 16 \cdot 27.2 eV = 435.2 eV ,$$

the transition reaction is represented by

$$\begin{matrix}16 \cdot 27.2 eV + H [ \frac{{a}_{H}}{4} ] + H [ \frac{{a}_{H}}{1} ] \to {H}_{fast}^{+} + {e}^{-} + H * [ \frac{{a}_{H}}{17} ] + 16 \cdot 27.2 eV & ( 33 ) \\ H * [ \frac{{a}_{H}}{17} ] \to H [ \frac{{a}_{H}}{17} ] + 3481.6 eV & ( 34 ) \\ {H}_{fast}^{+} + {e}^{-} \to H [ \frac{{a}_{H}}{1} ] + 231.2 eV & ( 35 )\end{matrix}$$

And, the overall reaction is

$$H [ \frac{{a}_{H}}{4} ] + H [ \frac{{a}_{H}}{1} ] \to H [ \frac{{a}_{H}}{1} ] + H [ \frac{{a}_{H}}{17} ] + 3712.8 eV \qquad ( 36 )$$

The extreme-ultraviolet continuum radiation band due to the

$$H * [ \frac{{a}_{H}}{p + m} ]$$

intermediate (e.g. Eq. (16) and Eq. (34)) is predicted to have a short wavelength cutoff and energy

$${E}_{( H \to H [ \frac{{a}_{H}}{p + m} ] )}$$

given by

$${E}_{( H \to H [ \frac{{a}_{H}}{p + m} ] )} = [ {( p + m )}^{2} - {p}^{2} ] \cdot 13.6 eV - m \cdot 27.2 eV \\ {λ}_{( H \to H [ \frac{{a}_{H}}{p + m} ] )} = \frac{91.2}{[ {( p + m )}^{2} - {p}^{2} ] \cdot 13.6 eV - m \cdot 27.2 eV} nm \qquad ( 37 )$$

and extending to longer wavelengths than the corresponding cutoff. Here the extreme-ultraviolet continuum radiation band due to the decay of the

$$H * [ \frac{{a}_{H}}{17} ]$$

intermediate is predicted to have a short wavelength cutoff at E=3481.6 eV; 0.35625 nm and extending to longer wavelengths. A broad X-ray peak with a 3.48 keV cutoff was observed in the Perseus Cluster by NASA's Chandra X-ray Observatory and by the XMM-Newton [E. Bulbul, M. Markevitch, A. Foster, R. K. Smith, M. Loewenstein, S. W. Randall, “Detection of an unidentified emission line in the stacked X-Ray spectrum of galaxy clusters,” The Astrophysical Journal, Volume 789, Number 1, (2014); A. Boyarsky, O. Ruchayskiy, D. Iakubovskyi, J. Franse, “An unidentified line in X-ray spectra of the Andromeda galaxy and Perseus galaxy cluster,” (2014), arXiv:1402.4119 [astro-ph.CO]] that has no match to any known atomic transition. Th 3.48 keV feature assigned to dark matter of unknown identity by BulBul et al. matches the

$$H [ \frac{{a}_{H}}{4} ] + H [ \frac{{a}_{H}}{1} ] \to H [ \frac{{a}_{H}}{17} ]$$

transition and further confirms hydrinos as the identity of dark matter.

The novel hydrogen compositions of matter can comprise:

(a) at least one neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions (standard temperature and pressure, STP), or is negative; and

(b) at least one other element. The compounds of the present disclosure are hereinafter referred to as “increased binding energy hydrogen compounds.”

By “other element” in this context is meant an element other than an increased binding energy hydrogen species. Thus, the other element can be an ordinary hydrogen species, or any element other than hydrogen. In one group of compounds, the other element and the increased binding energy hydrogen species are neutral. In another group of compounds, the other element and increased binding energy hydrogen species are charged such that the other element provides the balancing charge to form a neutral compound. The former group of compounds is characterized by molecular and coordinate bonding; the latter group is characterized by ionic bonding.

Also provided are novel compounds and molecular ions comprising

(a) at least one neutral, positive, or negative hydrogen species (hereinafter “increased binding energy hydrogen species”) having a total energy

(i) greater than the total energy of the corresponding ordinary hydrogen species, or

(ii) greater than the total energy of any hydrogen species for which the corresponding ordinary hydrogen species is unstable or is not observed because the ordinary hydrogen species' total energy is less than thermal energies at ambient conditions, or is negative; and

(b) at least one other element.

The total energy of the hydrogen species is the sum of the energies to remove all of the electrons from the hydrogen species. The hydrogen species according to the present disclosure has a total energy greater than the total energy of the corresponding ordinary hydrogen species. The hydrogen species having an increased total energy according to the present disclosure is also referred to as an “increased binding energy hydrogen species” even though some embodiments of the hydrogen species having an increased total energy may have a first electron binding energy less that the first electron binding energy of the corresponding ordinary hydrogen species. For example, the hydride ion of Eq. (19) for p=24 has a first binding energy that is less than the first binding energy of ordinary hydride ion, while the total energy of the hydride ion of Eq. (19) for p=24 is much greater than the total energy of the corresponding ordinary hydride ion.

Also provided herein are novel compounds and molecular ions comprising

(a) a plurality of neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions or is negative; and

(b) optionally one other element. The compounds of the present disclosure are hereinafter referred to as “increased binding energy hydrogen compounds.”

The increased binding energy hydrogen species can be formed by reacting one or more hydrino atoms with one or more of an electron, hydrino atom, a compound containing at least one of said increased binding energy hydrogen species, and at least one other atom, molecule, or ion other than an increased binding energy hydrogen species.

Also provided are novel compounds and molecular ions comprising

(a) a plurality of neutral, positive, or negative hydrogen species (hereinafter “increased binding energy hydrogen species”) having a total energy

(i) greater than the total energy of ordinary molecular hydrogen, or

(ii) greater than the total energy of any hydrogen species for which the corresponding ordinary hydrogen species is unstable or is not observed because the ordinary hydrogen species' total energy is less than thermal energies at ambient conditions or is negative; and

(b) optionally one other element. The compounds of the present disclosure are hereinafter referred to as “increased binding energy hydrogen compounds.”

In an embodiment, a compound is provided comprising at least one increased binding energy hydrogen species chosen from (a) hydride ion having a binding energy according to Eq. (19) that is greater than the binding of ordinary hydride ion (about 0.8 eV) for p=2 up to 23, and less for p=24 (“increased binding energy hydride ion” or “hydrino hydride ion”); (b) hydrogen atom having a binding energy greater than the binding energy of ordinary hydrogen atom (about 13.6 eV) (“increased binding energy hydrogen atom” or “hydrino”); (c) hydrogen molecule having a first binding energy greater than about 15.3 eV (“increased binding energy hydrogen molecule” or “dihydrino”); and (d) molecular hydrogen ion having a binding energy greater than about 16.3 eV (“increased binding energy molecular hydrogen ion” or “dihydrino molecular ion”). In the disclosure, increased binding energy hydrogen species and compounds is also referred to as lower-energy hydrogen species and compounds. Hydrinos comprise an increased binding energy hydrogen species or equivalently a lower-energy hydrogen species.

III. Chemical Reactor

The present disclosure is also directed to other reactors for producing increased binding energy hydrogen species and compounds of the present disclosure, such as dihydrino molecules and hydrino hydride compounds. Further products of the catalysis are power and optionally plasma and light depending on the cell type. Such a reactor is hereinafter referred to as a “hydrogen reactor” or “hydrogen cell.” The hydrogen reactor comprises a cell for making hydrinos. The cell for making hydrinos may take the form of a chemical reactor or gas fuel cell such as a gas discharge cell, a plasma torch cell, or microwave power cell, and an electrochemical cell. In an embodiment, the catalyst is HOH and the source of at least one of the HOH and H is ice. In an embodiment, the cell comprises an arc discharge cell and that comprises ice at least one electrode such that the discharge involves at least a portion of the ice.

In an embodiment, the arc discharge cell comprises a vessel, two electrodes, a high voltage power source such as one capable of a voltage in the range of about 100 V to 1 MV and a current in the range of about 1 A to 100 kA, and a source of water such as a reservoir and a means to form and supply H₂O droplets. The droplets may travel between the electrodes. In an embodiment, the droplets initiate the ignition of the arc plasma. In an embodiment, the water arc plasma comprises H and HOH that may react to form hydrinos. The ignition rate and the corresponding power rate may be controlled by controlling the size of the droplets and the rate at which they are supplied to the electrodes. The source of high voltage may comprise at least one high voltage capacitor that may be charged by a high voltage power source. In an embodiment, the arc discharge cell further comprises a means such as a power converter such as one of the present invention such as at least one of a PV converter and a heat engine to convert the power from the hydrino process such as light and heat to electricity.

Exemplary embodiments of the cell for making hydrinos may take the form of a liquid-fuel cell, a solid-fuel cell, a heterogeneous-fuel cell, a CIHT cell, and an SF-CIHT or SunCell® cell. Each of these cells comprises: (i) a source of atomic hydrogen; (ii) at least one catalyst chosen from a solid catalyst, a molten catalyst, a liquid catalyst, a gaseous catalyst, or mixtures thereof for making hydrinos; and (iii) a vessel for reacting hydrogen and the catalyst for making hydrinos. As used herein and as contemplated by the present disclosure, the term “hydrogen,” unless specified otherwise, includes not only proteum (¹H), but also deuterium (²H) and tritium (³H). Exemplary chemical reaction mixtures and reactors may comprise SF-CIHT, CIHT, or thermal cell embodiments of the present disclosure. Additional exemplary embodiments are given in this Chemical Reactor section. Examples of reaction mixtures having H₂O as catalyst formed during the reaction of the mixture are given in the present disclosure. Other catalysts may serve to form increased binding energy hydrogen species and compounds. The reactions and conditions may be adjusted from these exemplary cases in the parameters such as the reactants, reactant wt %'s, H₂ pressure, and reaction temperature. Suitable reactants, conditions, and parameter ranges are those of the present disclosure. Hydrinos and molecular hydrino are shown to be products of the reactors of the present disclosure by predicted continuum radiation bands of an integer times 13.6 eV, otherwise unexplainable extraordinarily high H kinetic energies measured by Doppler line broadening of H lines, inversion of H lines, formation of plasma without a breakdown fields, and anomalously plasma afterglow duration as reported in Mills Prior Publications. The data such as that regarding the CIHT cell and solid fuels has been validated independently, off site by other researchers. The formation of hydrinos by cells of the present disclosure was also confirmed by electrical energies that were continuously output over long-duration, that were multiples of the electrical input that in most cases exceed the input by a factor of greater than 10 with no alternative source. The predicted molecular hydrino H₂(¼) was identified as a product of CHT cells and solid fuels by MAS H NMR that showed a predicted upfield shifted matrix peak of about −4.4 ppm, ToF-SIMS and ESI-ToFMS that showed H₂(¼) complexed to a getter matrix as m/e=M+n2 peaks wherein M is the mass of a parent ion and n is an integer, electron-beam excitation emission spectroscopy and photoluminescence emission spectroscopy that showed the predicted rotational and vibration spectrum of H₂(¼) having 16 or quantum number p=4 squared times the energies of H₂, Raman and FTIR spectroscopy that showed the rotational energy of H₂(¼) of 1950 cm⁻¹, being 16 or quantum number p=4 squared times the rotational energy of H₂, XPS that showed the predicted total binding energy of H₂(¼) of 500 eV, and a ToF-SIMS peak with an arrival time before the m/e=1 peak that corresponded to H with a kinetic energy of about 204 eV that matched the predicted energy release for H to H(¼) with the energy transferred to a third body H as reported in Mills Prior Publications and in R. Mills X Yu, Y. Lu, G Chu, J. He, J. Lotoski, “Catalyst Induced Hydrino Transition (CIHT) Electrochemical Cell”, International Journal of Energy Research, (2013) and R. Mills, J. Lotoski, J. Kong, G Chu, J. He, J. Trevey, “High-Power-Density Catalyst Induced Hydrino Transition (CIHT) Electrochemical Cell” (2014) which are herein incorporated by reference in their entirety.

Using both a water flow calorimeter and a Setaram DSC 131 differential scanning calorimeter (DSC), the formation of hydrinos by cells of the present disclosure such as ones comprising a solid fuel to generate thermal power was confirmed by the observation of thermal energy from hydrino-forming solid fuels that exceed the maximum theoretical energy by a factor of 60 times. The MAS H NMR showed a predicted H₂(¼) upfield matrix shift of about −4.4 ppm. A Raman peak starting at 1950 cm⁻¹ matched the free space rotational energy of H₂(¼) (0.2414 eV). These results are reported in Mills Prior Publications and in R. Mills, J. Lotoski, W. Good, J. He, “Solid Fuels that Form HOH Catalyst”, (2014) which is herein incorporated by reference in its entirety.

IV. SunCell and Power Converter

In an embodiment, a power system that generates at least one of direct electrical energy and thermal energy comprises at least one vessel, reactants comprising: (a) at least one source of catalyst or a catalyst comprising nascent H₂O; (b) at least one source of atomic hydrogen or atomic hydrogen; and (c) at least one of a conductor and a conductive matrix, and at least one set of electrodes such as liquid electrodes, a source of electrical power to deliver a short burst of high-current electrical energy, and at least one direct converter such as at least one of a plasma to electricity converter such as PDC, magnetohydrodynamic converter, a photovoltaic converter, an optical rectenna such as the one reported by A. Sharma, V. Singh, T. L. Bougher, B. A. Cola, “A carbon nanotube optical rectenna”, Nature Nanotechnology, Vol. 10, (2015), pp. 1027-1032, doi:10.1038/nnano.2015.220 which is incorporated by reference in its entirety, and at least one thermal to electric power converter. In a further embodiment, the vessel is capable of a pressure of at least one of atmospheric, above atmospheric, and below atmospheric. In another embodiment, the at least one direct plasma to electricity converter can comprise at least one of the group of plasmadynamic power converter, \vec{E}×\vec{B} direct converter, magnetohydrodynamic power converter, magnetic mirror magnetohydrodynamic power converter, charge drift converter, Post or Venetian Blind power converter, gyrotron, photon bunching microwave power converter, and photoelectric converter. In a further embodiment, the at least one thermal to electricity converter can comprise at least one of the group of a heat engine, a steam engine, a steam turbine and generator, a gas turbine and generator, a Rankine-cycle engine, a Brayton-cycle engine, a Stirling engine, a thermionic power converter, and a thermoelectric power converter. Exemplary thermal to electric systems that may comprise closed coolant systems or open systems that reject heat to the ambient atmosphere are supercritical CO₂, organic Rankine, or external combustor gas turbine systems.

In addition to UV photovoltaic and thermal photovoltaic of the current disclosure, the SunCell® may comprise other electric conversion means known in the art such as thermionic, magnetohydrodynamic, turbine, microturbine, Rankine or Brayton cycle turbine, chemical, and electrochemical power conversion systems. The Rankine cycle turbine may comprise supercritical CO₂, an organic such as hydrofluorocarbon or fluorocarbon, or steam working fluid. In a Rankine or Brayton cycle turbine, the SunCell® may provide thermal power to at least one of the preheater, recuperator, boiler, and external combustor-type heat exchanger stage of a turbine system. In an embodiment, the Brayton cycle turbine comprises a SunCell® turbine heater integrated into the combustion section of the turbine. The SunCell® turbine heater may comprise ducts that receive airflow from at least one of the compressor and recuperator wherein the air is heated and the ducts direct the heated compressed flow to the inlet of the turbine to perform pressure-volume work. The SunCell® turbine heater may replace or supplement the combustion chamber of the gas turbine. The Rankine or Brayton cycle may be closed wherein the power converter further comprises at least one of a condenser and a cooler.

The converter may be one given in Mills Prior Publications and Mills Prior Applications. The hydrino reactants such as H sources and HOH sources and SunCell® systems may comprise those of the present disclosure or in prior US patent applications such as Hydrogen Catalyst Reactor, PCT/US08/61455, filed PCT Apr. 24, 2008; Heterogeneous Hydrogen Catalyst Reactor, PCT/US09/052072, filed PCT Jul. 29, 2009; Heterogeneous Hydrogen Catalyst Power System, PCT/US10/27828, PCT filed Mar. 18, 2010; Electrochemical Hydrogen Catalyst Power System, PCT/US11/28889, filed PCT Mar. 17, 2011; H₂O-Based Electrochemical Hydrogen-Catalyst Power System, PCT/US12/31369 filed Mar. 30, 2012; CIHT Power System, PCT/US13/041938 filed May 21, 2013; Power Generation Systems and Methods Regarding Same, PCT/IB2014/058177 filed PCT Jan. 10, 2014; Photovoltaic Power Generation Systems and Methods Regarding Same, PCT/US14/32584 filed PCT Apr. 1, 2014; Electrical Power Generation Systems and Methods Regarding Same, PCT/US2015/033165 filed PCT May 29, 2015; Ultraviolet Electrical Generation System Methods Regarding Same, PCT/US2015/065826 filed PCT Dec. 15, 2015; Thermophotovoltaic Electrical Power Generator, PCT/US16/12620 filed PCT Jan. 8, 2016; Thermophotovoltaic Electrical Power Generator Network, PCT/US2017/035025 filed PCT Dec. 7, 2017; Thermophotovoltaic Electrical Power Generator, PCT/US2017/013972 filed PCT Jan. 18, 2017; Extreme and Deep Ultraviolet Photovoltaic Cell, PCT/US2018/012635 filed PCT Jan. 5, 2018; Magnetohydrodynamic Electric Power Generator, PCT/US18/17765 filed PCT Feb. 12, 2018; and Magnetohydrodynamic Electric Power Generator, PCT/US2018/034842 filed PCT May 29, 2018 (“Mills Prior Applications”) herein incorporated by reference in their entirety.

In an embodiment, H₂O is ignited to form hydrinos with a high release of energy in the form of at least one of thermal, plasma, and electromagnetic (light) power. (“Ignition” in the present disclosure denotes a very high reaction rate of H to hydrinos that may be manifest as a burst, pulse or other form of high power release.) H₂O may comprise the fuel that may be ignited with the application a high current such as one in the range of about 10 A to 100,000 A. This may be achieved by the application of a high voltage such as about 5,000 to 100,000 V to first form highly conducive plasma such as an arc. Alternatively, a high current may be passed through a conductive matrix such as a molten metal such as silver further comprising the hydrino reactants such as H and HOH, or a compound or mixture comprising H₂O wherein the conductivity of the resulting fuel such as a solid fuel is high. (In the present disclosure a solid fuel is used to denote a reaction mixture that forms a catalyst such as HOH and H that further reacts to form hydrinos. The plasma voltage may be low such as in the range of about 1 V to 100V. However, the reaction mixture may comprise other physical states than solid. In embodiments, the reaction mixture may be at least one state of gaseous, liquid, molten matrix such as molten conductive matrix such a molten metal such as at least one of molten silver, silver-copper alloy, and copper, solid, slurry, sol gel, solution, mixture, gaseous suspension, pneumatic flow, and other states known to those skilled in the art.) In an embodiment, the solid fuel having a very low resistance comprises a reaction mixture comprising H₂O. The low resistance may be due to a conductor component of the reaction mixture. In embodiments, the resistance of the solid fuel is at least one of in the range of about 10⁻⁹ ohm to 100 ohms, 10⁻⁸ ohm to 10 ohms, 10⁻³ ohm to 1 ohm, 10⁻⁴ ohm to 10⁻¹ ohm, and 10⁻⁴ ohm to 10⁻² ohm. In another embodiment, the fuel having a high resistance comprises H₂O comprising a trace or minor mole percentage of an added compound or material. In the latter case, high current may be flowed through the fuel to achieve ignition by causing breakdown to form a highly conducting state such as an arc or arc plasma.

In an embodiment, the reactants can comprise a source of H₂O and a conductive matrix to form at least one of the source of catalyst, the catalyst, the source of atomic hydrogen, and the atomic hydrogen. In a further embodiment, the reactants comprising a source of H₂O can comprise at least one of bulk H₂O, a state other than bulk H₂O, a compound or compounds that undergo at least one of react to form H₂O and release bound H₂O. Additionally, the bound H₂O can comprise a compound that interacts with H₂O wherein the H₂O is in a state of at least one of absorbed H₂O, bound H₂O, physisorbed H₂O, and waters of hydration. In embodiments, the reactants can comprise a conductor and one or more compounds or materials that undergo at least one of release of bulk H₂O, absorbed H₂O, bound H₂O, physisorbed H₂O, and waters of hydration, and have H₂O as a reaction product. In other embodiments, the at least one of the source of nascent H₂O catalyst and the source of atomic hydrogen can comprise at least one of: (a) at least one source of H₂O; (b) at least one source of oxygen, and (c) at least one source of hydrogen.

In an embodiment, the hydrino reaction rate is dependent on the application or development of a high current. In an embodiment of a SunCell®, the reactants to form hydrinos are subject to a low voltage, high current, high power pulse that causes a very rapid reaction rate and energy release. In an exemplary embodiment, a 60 Hz voltage is less than 15 V peak, the current ranges from 100 A/cm² and 50,000 A/cm² peak, and the power ranges from 1000 W/cm² and 750,000 W/cm². Other frequencies, voltages, currents, and powers in ranges of about 1/100 times to 100 times these parameters are suitable. In an embodiment, the hydrino reaction rate is dependent on the application or development of a high current. In an embodiment, the voltage is selected to cause a high AC, DC, or an AC-DC mixture of current that is in the range of at least one of 100 A to 1,000,000 A, 1 kA to 100,000 A, 10 kA to 50 kA. The DC or peak AC current density may be in the range of at least one of 100 A/cm² to 1,000,000 A/cm², 1000 A/cm² to 100,000 A/cm², and 2000 A/cm² to 50,000 A/cm². The DC or peak AC voltage may be in at least one range chosen from about 0.1 V to 1000 V, 0.1 V to 100 V, 0.1 V to 15 V, and 1 V to 15 V. The AC frequency may be in the range of about 0.1 Hz to 10 GHz, 1 Hz to 1 MHz, 10 Hz to 100 kHz, and 100 Hz to 10 kHz. The pulse time may be in at least one range chosen from about 10⁻⁶ to 10 s, 10⁻⁵ s to 1 s, 10⁻⁴ s to 0.1 s, and 10⁻³ s to 0.01 s.

In an embodiment, the transfer of energy from atomic hydrogen catalyzed to a hydrino state results in the ionization of the catalyst. The electrons ionized from the catalyst may accumulate in the reaction mixture and vessel and result in space charge build up. The space charge may change the energy levels for subsequent energy transfer from the atomic hydrogen to the catalyst with a reduction in reaction rate. In an embodiment, the application of the high current removes the space charge to cause an increase in hydrino reaction rate. In another embodiment, the high current such as an arc current causes the reactant such as water that may serve as a source of H and HOH catalyst to be extremely elevated in temperature. The high temperature may give rise to the thermolysis of the water to at least one of H and HOH catalyst. In an embodiment, the reaction mixture of the SunCell® comprises a source of H and a source of catalyst such as at least one of nH (n is an integer) and HOH. The at least one of nH and HOH may be formed by the thermolysis or thermal decomposition of at least one physical phase of water such as at least one of solid, liquid, and gaseous water. The thermolysis may occur at high temperature such as a temperature in at least one range of about 500K to 10,000K, 1000K to 7000K, and 1000K to 5000K. In an exemplary embodiment, the reaction temperature is about 3500 to 4000K such that the mole fraction of atomic H is high as shown by J. Lede, F. Lapicque, and J Villermaux [J. Lédé, F. Lapicque, J. Villermaux, “Production of hydrogen by direct thermal decomposition of water”, International Journal of Hydrogen Energy, 1983, V8, 1983, pp. 675-679; H. H. G. Jellinek, H. Kachi, “The catalytic thermal decomposition of water and the production of hydrogen”, International Journal of Hydrogen Energy, 1984, V9, pp. 677-688; S. Z. Baykara, “Hydrogen production by direct solar thermal decomposition of water, possibilities for improvement of process efficiency”, International Journal of Hydrogen Energy, 2004, V9 pp. 1451-1458; S. Z. Baykara, “Experimental solar water thermolysis”, International Journal of Hydrogen Energy, 2004, V29, pp. 1459-1469 which are herein incorporated by reference]. The thermolysis may be assisted by a solid surface such as one of the cell components. The solid surface may be heated to an elevated temperature by the input power and by the plasma maintained by the hydrino reaction. The thermolysis gases such as those down stream of the ignition region may be cooled to prevent recombination or the back reaction of the products into the starting water. The reaction mixture may comprise a cooling agent such as at least one of a solid, liquid, or gaseous phase that is at a lower temperature than the temperature of the product gases. The cooling of the thermolysis reaction product gases may be achieved by contacting the products with the cooling agent. The cooling agent may comprise at least one of lower temperature steam, water, and ice.

In an embodiment, the SunCell® generator comprises a power system that generates at least one of electrical energy and thermal energy comprising:
at least one vessel;
reactants comprising:
   a) at least one source of catalyst or a catalyst comprising nascent H2O;
   b) at least one source of H2O or H2O;
   c) at least one source of atomic hydrogen or atomic hydrogen; and
   d) at least one of a conductor and a conductive matrix;
at least one reactants injection system;
at least one reactants ignition system to cause the reactants to form at least one of light-emitting plasma and thermal-emitting plasma;
a system to recover reaction products of the reactants;
at least one regeneration or resupply system to regenerate additional reactants from the reaction products or resupply additional reactants,
   wherein the additional reactants comprise:
      a) at least one source of catalyst or a catalyst comprising nascent H2O;
      b) at least one source of H2O or H2O;
      c) at least one source of atomic hydrogen or atomic hydrogen; and
      d) at least one of a conductor and a conductive matrix; and
   at least one power converter or output system of at least one of the light and thermal output to electrical power and/or thermal power such as at least one of the group of a photovoltaic converter, a photoelectronic converter, a plasmadynamic converter, a thermionic converter, a thermoelectric converter, a Sterling engine, a Brayton cycle engine, a Rankine cycle engine, and a heat engine, and a heater.

In an embodiment, the fuel or reactants may comprise at least one of a source of H, H₂, a source of catalyst, a source of H₂O, and H₂O. Suitable reactants may comprise a conductive metal matrix and a hydrate such as at least one of an alkali hydrate, an alkaline earth hydrate, and a transition metal hydrate. The hydrate may comprise at least one of MgCl₂.6H₂O, BaI₂.2H₂O, and ZnC₂.4H₂O. Alternatively, the reactants may comprise at least one of silver, copper, hydrogen, oxygen, and water.

At least one of the reaction cell chamber H₂O vapor pressure, H₂ pressure, and O₂ pressure may be in at least one range of about 0.01 Torr to 100 atm, 0.1 Torr to 10 atm, and 0.5 Torr to 1 atm. The EM pumping rate may be in at least one range of about 0.01 ml/s to 10,000 ml/s, 0.1 ml/s to 1000 ml/s, and 0.1 ml/s to 100 ml/s.

The ignition system may comprise:

a) at least one set of solid or liquid metal electrodes to at least one of confine the reactants or provide a conductive matrix or circuit; and

b) a source of electrical power to deliver a short burst of high-current electrical energy wherein the short burst of high-current electrical energy is sufficient to cause the reactants to react to form plasma. The source of electrical power may receive electrical power from the power converter. In an embodiment, the reactants ignition system comprises at least one set of electrodes that are separated to form an open circuit, wherein the open circuit is closed by the injection of the reactants to cause the high current to flow to achieve ignition. In another embodiment, the electrodes comprise liquid metal from a plurality of injectors such as electromagnetic (EM) pump injectors wherein the electrical circuit of the ignition system is closed by the intersection of at least two injected molten metal streams.

In an embodiment, the SunCell® may comprise liquid electrodes. The electrodes may comprise liquid metal. The liquid metal may comprise the molten metal of the fuel. The injection system may comprise at least two reservoirs 5c and at least two electromagnetic pumps that may be substantially electrically isolated from each other. The nozzles 5q of each of the plurality of injections system may be oriented to cause the plurality of molten metal streams to intersect. Each stream may have a connection to a terminal of a source of electricity 2 to provide voltage and current to the intersecting streams. The current may flow from one nozzle 5q through its molten metal stream to the other stream and nozzle 5 and back to the corresponding terminal of the source of electricity 2. The cell comprises a molten metal return system to facilitate the return of the injected molten metal to the plurality of reservoirs. The return system may comprise a gravity flow system. In another embodiment, the ignition current may comprise an induction current maintained by a changing magnetic field through the current loop comprising the intersecting molten metal streams. The source of electricity may comprise an AC power source that supplies a primary transformer winding that supplies the changing magnetic field through the current loop comprising the intersecting molten metal streams.

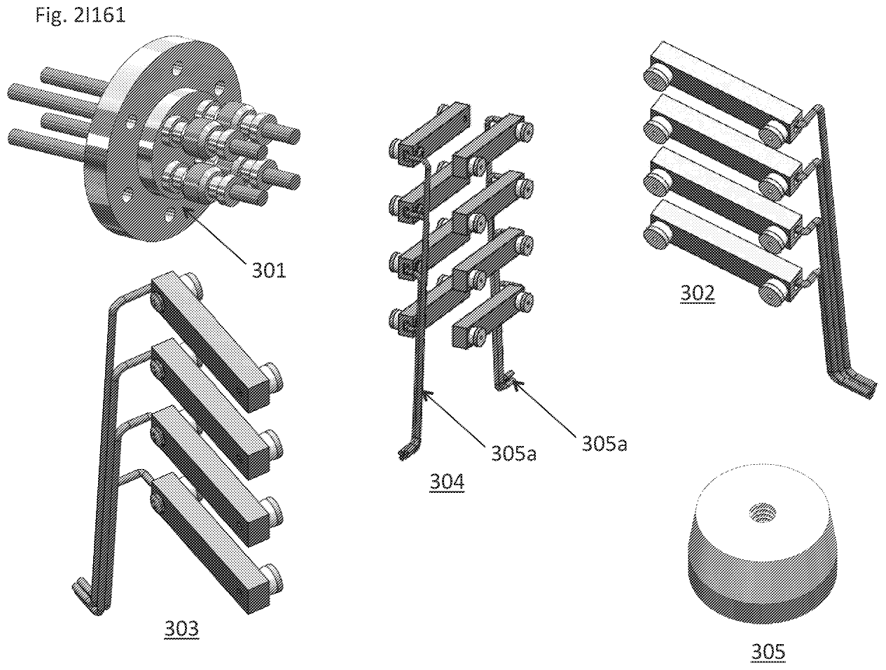

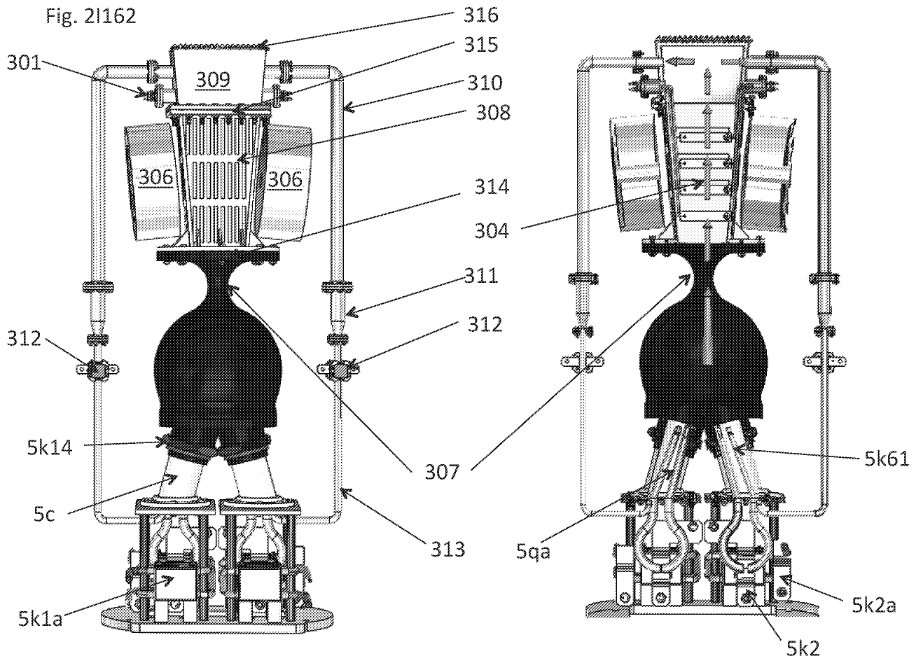

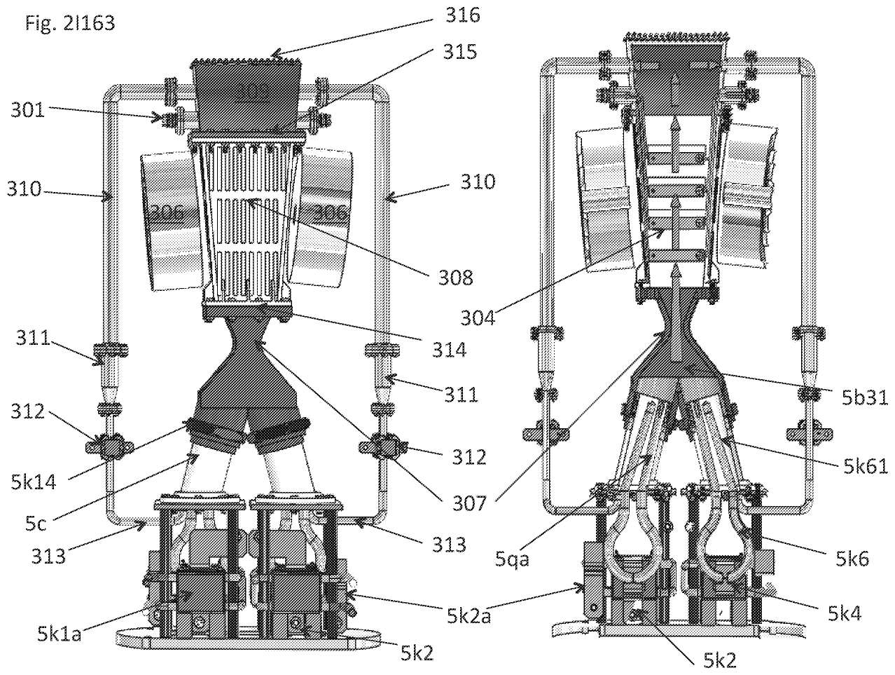

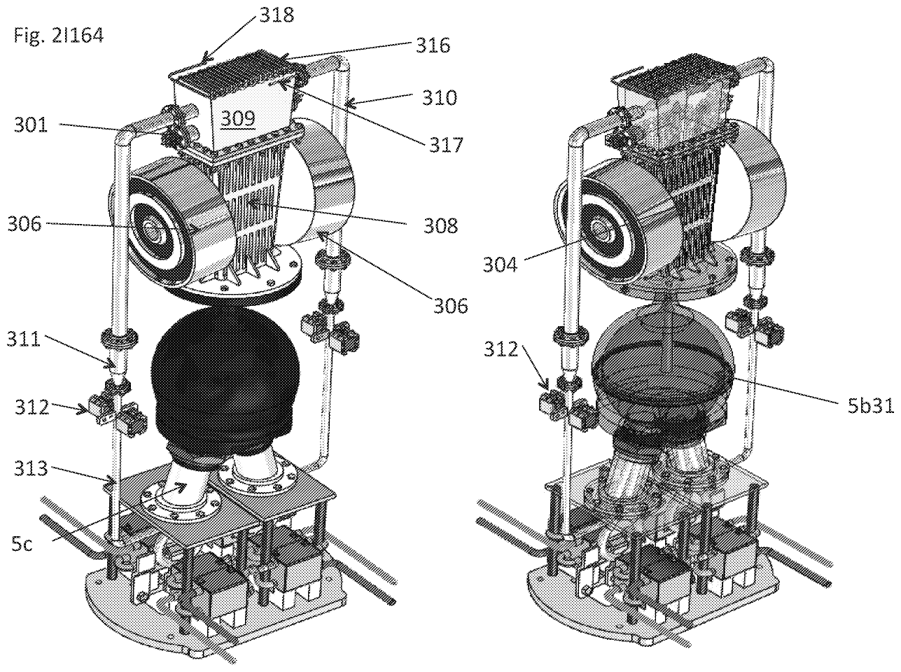

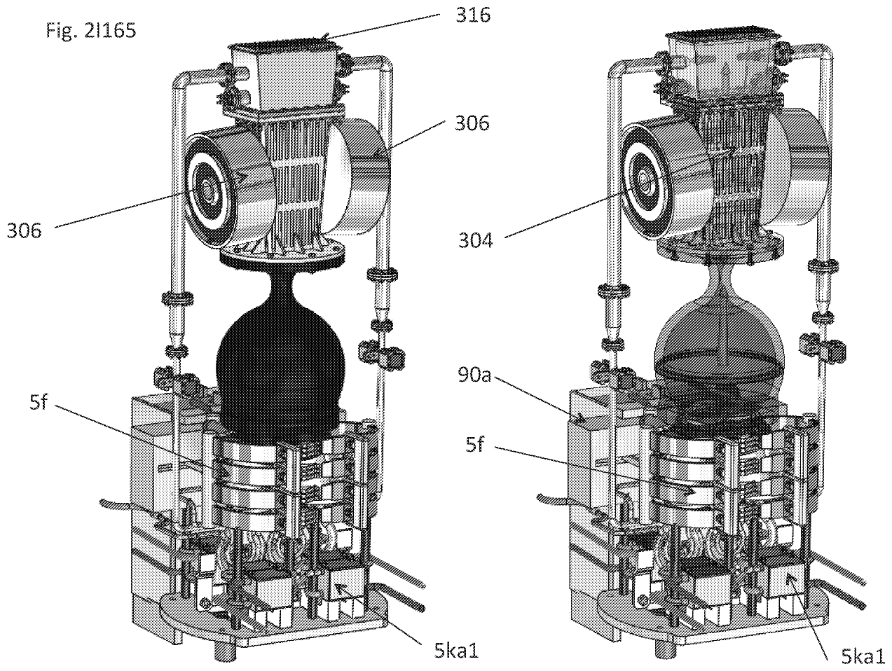

In an embodiment, the EM pump comprises an inlet riser 5qa (FIG. 2I168) comprising a hollow conduit such as a tube. The conduit may be connected to the EM pump tube 5k6 on the inlet side of the EM pump magnets 5k4. The tube comprises at least one inlet for the flow of silver. The inlet may comprise at least one of an opening at the top of the tube and at least one hole in the side of the tube. In an exemplary embodiment, the inlet riser may comprise an open-end conduit or tube having a height of the desired height of the reservoir molten metal level. A submerged inlet riser submerged in molten metal in its reservoir permits molten metal to flow into the EM pump until the molten metal level of the reservoir matches that of the lowest inlet of the inlet riser 5qa. The inlet riser may comprise a refractory material such as a refractory metal, carbon, or a ceramic such as magnesi, hafnia, zirconia, aluimin, or other refractory material of the disclosure. The lowest inlet of the inlet riser may have a higher height relative to the nozzle 5q to maintain the nozzle as always submerged during operation. Alternatively, the highest inlet of the inlet riser may have a lower height relative to the nozzle 5q to maintain the inlet riser as always submerged during operation. The submersion of either the nozzle 5q or inlet riser 5qa may reduce or eliminate the potential for the ignition current to electrically short to the nozzle or inlet riser. The submerged nozzle may be the positive electrode that may be submerged to protect it form the hydrino reaction plasma. The inlet riser may be non-conducting. The inlet riser may be coated with a coating such as a coating of the disclosure. The coating may be a non-conductor. The inlet riser that may comprise a refractory metal such as Mo that may be covered with a sheath or cladding. The sheath or cladding may comprise a non-conductor. In an embodiment, the EM pump may comprise at least one of a voltage and current sensor to measure the induction or conduction EM pump voltage and current. A processor may use the sensor data and control the voltage and current to control the pumping rates. In an embodiment, the SunCell® may be at least one of monitored and controlled by a wireless device such as a cell phone. The SunCell® may comprise an antenna to send and receive data and control signals.

In an embodiment, the ignition system comprises a switch to at least one of initiate the current and interrupt the current once ignition is achieved. The flow of current may be initiated by reactants that completes the gap between the electrodes. The switching may be performed electronically by means such as at least one of an insulated gate bipolar transistor (IGBT), a silicon controlled rectifier (SCR), and at least one metal oxide semiconductor field effect transistor (MOSFET). Alternatively, ignition may be switched mechanically. The current may be interrupted following ignition in order to optimize the output hydrino generated energy relative to the input ignition energy. The ignition system may comprise a switch to allow controllable amounts of energy to flow into the fuel to cause detonation and turn off the power during the phase wherein plasma is generated. In an embodiment, the source of electrical power to deliver a short burst of high-current electrical energy comprises at least one of the following:
a voltage selected to cause a high AC, DC, or an AC-DC mixture of current that is in the range of at least one of 100 A to 1,000,000 A, 1 kA to 100,000 A, 10 kA to 50 kA;
a DC or peak AC current density in the range of at least one of 1 A/cm² to 1,000,000 A/cm², 1000 A/cm² to 100,000 A/cm², and 2000 A/cm² to 50,000 A/cm²;

wherein the voltage is determined by the conductivity of the solid fuel wherein the voltage is given by the desired current times the resistance of the solid fuel sample;

the DC or peak AC voltage is in the range of at least one of 0.1 V to 500 kV, 0.1 V to 100 kV, and 1 V to 50 kV, and

the AC frequency is in range of at least one of 0.1 Hz to 10 GHz, 1 Hz to 1 MHz, 10 Hz to 100 kHz, and 100 Hz to 10 kHz.

The output power of the SunCell cell may comprise at least one of thermal and plasma power that may be converted to electricity by at least one of a thermophotovoltaic converter and a magnetohydrodynamic converter. Alternatively, the power may be collected by a heat exchanger to provide thermal power.

In an embodiment comprising dual molten metal injectors, the trajectory of the molten metal stream from one nozzle may be in a first plane and the plane of the trajectory of the molten metal stream from the second nozzle may be in a second plane that is rotated about at least one of the two Cartesian axes of the first plane. The streams may approach each other along oblique paths. In an embodiment, the trajectory of molten metal stream of the first nozzle is in the yz-plane, and the second nozzle may be displaced laterally from yz-plane and rotated towards that yz-plane such that the streams approach obliquely. In an exemplary embodiment, the trajectory of molten metal stream of the first nozzle is in the yz-plane, and the trajectory of molten metal stream of the second nozzle is in a plane defined by a rotation of the yz-plane about the z-axis such that second nozzle may be displaced laterally from yz-plane and rotated towards that yz-plane such that the streams approach obliquely. In an embodiment, the trajectories intersect at a first stream height and a second stream height that is each adjusted to cause the intersection. In an embodiment, the outlet tube of the second EM pump is off set from the outlet tube of the first EM pump tube, and the nozzle of second EM pump is rotated towards the nozzle of the first EM pump such that the molten streams approached each other obliquely, and stream intersection can be achieved by adjusting the relative heights of the streams. The stream heights may be controlled by a controller such as one that controls the EM pump current of at least one EM pump.

In an embodiment comprising two nozzles of two injectors initially aligned in the same yz-plane, the oblique relative trajectory of the injected molten metal streams to achieve intersection of the injected streams may be achieved by at least one operation of the rotation of at least one corresponding reservoir 5c slightly about the z-axis and the operation of slightly bending the nozzle that was translated out of the yz-plane by the rotation towards the yz-plane.

In another embodiment, the injection system may comprise a field source such as a source of at least one of a magnetic and an electric field to deflect at least one molten metal stream to achieve alignment of the injected streams. At least one of the injected molten metal streams may be deflected by a Lorentz force due the movement of corresponding conductor through an applied magnetic field and the force between at least one current such as the Hall and ignition current and the applied magnetic field. The deflection may be controlled by controlling at least one of the magnetic field strength, the molten metal flow rate, and the ignition current. The magnetic field may be provided by at least one of permanent magnets, electromagnets that may be cooled, and superconducting magnets. The magnetic field strength may be controlled by at least one of controlling the distance between the magnets and the molten stream and the magnetic field strength by controlling the current.

The ignition current or resistance may be measured to determine the optimal intersection. The optimal alignment may be achieved when the current is maximized at a set voltage or the resistance is lowest. A controller that may comprise at least one of a programmable logic controller and a computer may achieve the optimization.

The SunCell® generator comprises the components having the parameters such as those of the disclosure that are sensed and controlled. In embodiments the computer with sensors and control systems may sense and control, (i) the inlet and outlet temperatures and coolant pressure and flow rate of each chiller of each cooled system such as at least one of the power converter, EM pump magnets, and the inductively coupled heater, (ii) the ignition system voltage, current, power, frequency, and duty cycle, (iii) the EM pump injection flow rate (iv) the voltages, currents, and powers of the inductively coupled heater and the electromagnetic pump 5k, (v) the pressure in the cell, (vi) the wall temperature of cell components, (vii) the heater power in each section, (viii) current and magnetic flux of the electromagnetic pump, (ix) the silver melt temperature, flow rate, and pressure, (xi) the pressure, temperature, and flow rate of each permeated or injected gas such as H₂, O₂, and H₂O and mixtures formed by a regulator that may be delivered through a common gas injection manifold or housing, (xi) the intensity of incident light to the PV converter or plasma power to the MHD converter, (xii) the voltage, current, and power output of the converter, (xiii) the voltage, current, power, and other parameters of any power conditioning equipment, and (xiv) the SunCell® generator output voltage, current, and power to at least one of the parasitic loads and the external loads, (xv) the voltage, current, and power input to any parasitic load such as at least one of the inductively coupled heater, the electromagnetic pump, the chillers, and the sensors and controls, and (xvi) the voltage, current, and charge state of the starter circuit with energy storage. In an embodiment, the SunCell® may be at least one of monitored and controlled by a wireless device such as a cell phone. The SunCell® may comprise an antenna to send and receive data and control signals.

The system further comprises a startup power/energy source such as a battery such as a lithium ion battery. Alternatively, external power such as grid power may be provided for startup through a connection from an external power source to the generator. The connection may comprise the power output bus bar. The startup power energy source may at least one of supply power to the heater to maintain the molten metal conductive matrix, power the injection system, and power the ignition system.

The SunCell® may comprise a high-pressure water electrolyzer such as one comprising a proton exchange membrane (PEM) electrolyzer having water under high pressure to provide high-pressure hydrogen. Each of the H₂ and O₂ chambers may comprise a recombiner to eliminate contaminant O₂ and H₂, respectively. The PEM may serve as at least one of the separator and salt bridge of the anode and cathode compartments to allow for hydrogen to be produced at the cathode and oxygen at the anode as separate gases. The cathode may comprise a dichalcogenide hydrogen evolution catalyst such as one comprising at least one of niobium and tantalum that may further comprise sulfur. The cathode may comprise one known in the art such as Pt or Ni. The hydrogen may be produced at high pressure and may be supplied to the reaction cell chamber 5b31 directly or by permeation such as permeation through the blackbody radiator. The SunCell® may comprise a hydrogen gas line from the cathode compartment to the point of delivery of the hydrogen gas to the cell. The SunCell® may comprise an oxygen gas line from the anode compartment to the point of delivery of the oxygen gas to a storage vessel or a vent. In an embodiment, the SunCell® comprises sensors, a processor, and an electrolysis current controller. The sensors may sense at least one of (i) the hydrogen pressure in at least one chamber such as the electrolysis cathode compartment, the hydrogen lines, the outer chamber 5b3a1, and the reaction cell chamber 5b31, (ii) the power output of the SunCell®, and (iii) the electrolysis current. In an embodiment, the hydrogen supply into the cell is controlled by controlling the electrolysis current. The hydrogen supply may increase with increasing electrolysis current and vice versa. The hydrogen may be at least one of under high pressure and comprise a low inventory such that the hydrogen supply to the cell may be controlled with a quick temporal response by controlling the electrolysis current.

In another embodiment, the hydrogen may be produced by thermolysis using supplied water and the heat generated by the SunCell®. The thermolysis cycle may comprise one of the disclosure or one known in the art such as one that is based on a metal and its oxide such as at least one of SnO/Sn and ZnO/Zn. In an embodiment wherein the inductively coupled heater, EM pump, and ignition systems only consume power during startup, the hydrogen may be produced by thermolysis such that the parasitic electrical power requirement is very low. The SunCell® may comprise batteries such as lithium ion batteries to provide power to run systems such as the gas sensors and control systems such as those for the reaction plasma gases.

Magnetohydrodynamic (MHD) Converter

Charge separation based on the formation of a mass flow of ions or an electrically conductive medium in a crossed magnetic field is well known art as magnetohydrodynamic (MHD) power conversion. The positive and negative ions undergo Lorentzian direction in opposite directions and are received at corresponding MHD electrode to affect a voltage between them. The typical MHD method to form a mass flow of ions is to expand a high-pressure gas seeded with ions through a nozzle to create high-speed flow through the crossed magnetic field with a set of MHD electrodes crossed with respect to the deflecting field to receive the deflected ions. In an embodiment, the pressure is typically greater than atmospheric, and the directional mass flow may be achieved by hydrino reaction to form plasma and highly conductive, high-pressure-and-temperature molten metal vapor that is expanded to create high-velocity flow through a cross magnetic field section of the MHD converter. The flow may be through an MHD converter may be axial or radial. Further directional flow may be achieved with confining magnets such as those of Helmholtz coils or a magnetic bottle.

Specifically, the MHD electric power system shown in FIGS. 2I161-2I206 may comprise a hydrino reaction plasma source of the disclosure such as one comprising an EM pump 5ka, at least one reservoir 5c, at least two electrodes such as ones comprising dual molten metal injectors 5k61, a source of hydrino reactants such as a source of HOH catalyst and H, an ignition system comprising a source of electrical power 2 to apply voltage and current to the electrodes to form a plasma from the hydrino reactants, and a MHD electric power converter. The components of the MHD power system comprising a hydrino reaction plasma source and a MHD converter may be comprised of at least one of oxidation resistant materials such as oxidation resistant metals, metals comprising oxidation resistant coatings, and ceramics such that the system may be operated in air. In a dual molten metal injector embodiment, a high electric field is achieved by maintaining a pulsed injection comprising intermittent current. The plasma is pulsed by the silver streams disconnecting and reconnecting. The voltage may be that applied until the dual molten metal streams connect. The pulsing may comprise a high frequency by causing a corresponding high frequency of disconnect-reconnect of the metal steams. The connection-reconnection may occur spontaneously and may be controlled by controlling at least one of the hydrino reaction power by means such as those of the disclosure and the rate of molten metal injection by means of the disclosure such as by controlling the EM pump current. In an embodiment, the ignition system may comprise a source of voltage and current such as a DC power supply and a bank of capacitor to deliver pulsed ignition with the capacity for high current pulses. The magnetohydrodynamic power converter shown in FIGS. 2I161-2I206 may comprise a source of magnetic flux transverse to the z-axis, the direction of axial molten metal vapor and plasma flow through the MHD converter 300. The conductive flow may have a preferential velocity along the z-axis due to the expansion of the gas along the z-axis. Further directional flow may be achieved with confining magnets such as those of Helmholtz coils or a magnetic bottle. Thus, the metal electrons and ions propagate into the region of the transverse magnetic flux. The Lorentzian force on the propagating electrons and ions is given by

F=ev×B (38)

The force is transverse to the charge's velocity and the magnetic field and in opposite directions for positive and negative ions. Thus, a transverse current forms. The source of transverse magnetic field may comprise components that provide transverse magnetic fields of different strengths as a function of position along the z-axis in order to optimize the crossed deflection (Eq. (38)) of the flowing charges having parallel velocity dispersion.

The reservoir 5c molten metal may be in at least one state of liquid and gaseous. The reservoir 5c molten metal may defined as the MHD working medium and may be referred to as such or referred to as the molten metal wherein it is implicit that the molten metal may further be in at least one state of liquid and gaseous. A specific state such as molten metal, liquid metal, metal vapor, or gaseous metal may also be used wherein another physical state may be present as well. An exemplary molten metal is silver that may be in at least one of liquid and gaseous states. The MHD working medium may further comprise an additive comprising at least one of an added metal that may be in at least one of a liquid and a gaseous state at the operating temperature range, a compound such as one of the disclosure that may be in at least one of a liquid and a gaseous state at the operating temperature range, and a gas such as at least one of a noble gas such as helium or argon, water, H₂, and other plasma gas of the disclosure. The MHD working medium additive may be in any desired ratio with the MHD working medium. In an embodiment, the ratios of the medium and additive medium are selected to give the optional electrical conversion performance of the MHD converter. The working medium such as silver or silver-copper alloy may be run under supersaturated conditions.

In an embodiment, the MHD electrical generator 300 may comprise at least one of a Faraday, channel Hall, and disc Hall type. In a channel Hall MHD embodiment, the expansion or generator channel 308 may be oriented vertically along the z-axis wherein the molten metal plasma such as silver vapor and plasma flow through an accelerator section such as a restriction or nozzle throat 307 followed by an expansion section 308. The channel may comprise solenoidal magnets 306 such as superconducting or permanent magnets such as a Halbach array transverse to the flow direction along the x-axis. The magnets may be secured by MHD magnet mounting bracket 306a. The magnet may comprise a liquid cryogen or may comprise a cryo-refrigerator with or without a liquid cryogen. The cryo-refrigerator may comprise a dry dilution refrigerator. The magnets may comprise a return path for the magnetic field such as a yoke such as a C-shaped or rectangular back yoke. An exemplary permanent magnet material is SmCo, and an exemplary yoke material is magnetic CRS, cold rolled steel, or iron. The generator may comprise at least one set of electrodes such as segmented electrodes 304 along the y-axis, transverse to the magnetic field (B) to receive the transversely Lorentzian deflected ions that creates a voltage across the MHD electrodes 304. In another embodiment, at least one channel such as the generator channel 308 may comprise geometry other than one with planar walls such as a cylindrically walled channel. Magnetohydrodynamic generation is described by Walsh [E. M. Walsh, Energy Conversion Electromechanical, Direct, Nuclear, Ronald Press Company, NY, NY, (1967), pp. 221-248] the complete disclosure of which is incorporated herein by reference.

The MHD magnets 306 may comprise at least one of permanent and electromagnets.

The electromagnet(s) 306 may be at least one of uncooled, water cooled, and superconducting magnets with a corresponding cryogenic management. Exemplary magnets are solenoidal or saddle coils that may magnetize a MHD channel 308 and racetrack coils that may magnetize a disc channel. The superconducting magnet may comprise at least one of a cryo-refrigerator and a cryogen-dewar system. The superconducting magnet system 306 may comprise (i) superconducting coils that may comprise superconductor wire windings of NbTi or NbSn wherein the superconductor may be clad on a normal conductor such as copper wire to protect against transient local quenches of the superconductor state induced by means such as vibrations, or a high temperature superconductor (HTS) such as YBa₂Cu₃O₇, commonly referred to as YBCO-123 or simply YBCO, (ii) a liquid helium dewar providing liquid helium on both sides of the coils, (iii) liquid nitrogen dewars with liquid nitrogen on the inner and outer radii of the solenoidal magnet wherein both the liquid helium and liquid nitrogen dewars may comprise radiation baffles and radiation shields that may be comprise at least one of copper, stainless steel, and aluminum and high vacuum insulation at the walls, and (iv) an inlet for each magnet that may have attached a cyropump and compressor that may be powered by the power output of the SunCell® generator through its output power terminals.

In one embodiment, the magnetohydrodynamic power converter is a segmented Faraday generator. In another embodiment, the transverse current formed by the Lorentzian deflection of the ion flow undergoes further Lorentzian deflection in the direction parallel to the input flow of ions (z-axis) to produce a Hall voltage between at least a first MHD electrode and a second MHD electrode relatively displaced along the z-axis. Such a device is known in the art as a Hall generator embodiment of a magnetohydrodynamic power converter. A similar device with MHD electrodes angled with respect to the z-axis in the xy-plane comprises another embodiment of the present invention and is called a diagonal generator with a “window frame” construction. In each case, the voltage may drive a current through an electrical load. Embodiments of a segmented Faraday generator, Hall generator, and diagonal generator are given in Petrick [J. F. Louis, V. I. Kovbasyuk, Open-cycle Magnetohydrodynamic Electrical Power Generation, M Petrick, and B. Ya Shumyatsky, Editors, Argonne National Laboratory, Argonne, Ill., (1978), pp. 157-163] the complete disclosure of which is incorporated by reference.

In a further embodiment of the magnetohydrodynamic power converter, the flow of ions along the z-axis with v_{∥}>>v_{⊥} may then enter a compression section comprising an increasing axial magnetic field gradient wherein the component of electron motion parallel to the direction of the z-axis v_{∥} is at least partially converted into to perpendicular motion v_{⊥} due to the adiabatic invariant

$$\frac{{v}_{⊥}^{2}}{B} = constant .$$

An azimuthal current due to v_{⊥} is formed around the z-axis. The current is deflected radially in the plane of motion by the axial magnetic field to produce a Hall voltage between an inner ring and an outer ring MHD electrode of a disk generator magnetohydrodynamic power converter. The voltage may drive a current through an electrical load. The plasma power may also be converted to electricity using a \vec{E}×\vec{B} direct converter or other plasma to electricity devices of the disclosure or known in the art.

The MHD generator may comprise a condenser channel section 309 that receives the expansion flow and the generator further comprises return flow channels or conduits 310 wherein the MHD working medium such as silver vapor cools as it loses at least one of temperature, pressure, and energy in the condenser section and flows back to the reservoirs through the channels or conduits 310. The generator may comprise at least one return pump 312 and return pump tube 313 to pump the return flow to the reservoirs 5c and EM pump injectors 5ka. The return pump and pump tube may pump at least one of liquid, vapor, and gas. The return pump 312 and return pump tube 313 may comprise an electromagnetic (EM) pump and EM pump tube. The inlet to the EM pump may have a greater diameter than the outlet pump tube diameter to increase the pump outlet pressure. In an embodiment, the return pump may comprise the injector of the EM pump-injector electrode 5ka. In a dual molten metal injector embodiment, the generator comprises return reservoirs 311 each with a corresponding return pump such as a return EM pump 312. The return reservoir 311 may at least one of balance the return molten metal such as molten silver flow and condense or separate silver vapor mixed in with the liquid silver. The reservoir 311 may comprise a heat exchanger to condense the silver vapor. The reservoir 311 may comprise a first stage electromagnetic pump to preferentially pump liquid silver to separate liquid from gaseous silver. In an embodiment, the liquid metal may be selectively injected into the return EM pump 312 by centrifugal force. The return conduit or return reservoir may comprise a centrifuge section. The centrifuge reservoir may be tapered from inlet to outlet such that the centrifugal force is greater at the top than at the bottom to force the molten metal to the bottom and separate it from gas such as metal vapor and any working medium gas. Alternatively, the SunCell® may be mounted on a centrifuge table that rotates about the axis perpendicular to the flow direction of the return molten metal to produce centrifugal force to separate liquid and gaseous species.

In an embodiment, the condensed metal vapor flows into the two independent return reservoirs 311, and each return EM pumps 312, pumps the molten metal into the corresponding reservoir 5c. In an embodiment, at least one of the two return reservoirs 311 and EM pump reservoirs 5c comprises a level control system such as one of the disclosure such as an inlet riser 5qa. In an embodiment, the return molten metal may be sucked into a return reservoir 311 due at a higher or lower rate depending on the level in the return reservoir wherein the sucking rate is controlled by the corresponding level control system such as the inlet riser.

In an embodiment, the MHD converter 300 may further comprise at least one heater such as an inductively coupled heater. The heater may preheat the components that are in contact with the MHD working medium such as at least one of the reaction cell chamber 5b31, MHD nozzle section 307, MHD generator section 308, MHD condensation section 309, return conduits 310, return reservoirs 311, return EM pumps 312, and return EM pump tube 313. The heater may comprise at least one actuator to engage and retract the heater. The heater may comprise at least one of a plurality of coils and coil sections. The coils may comprise one known in the art. The coil sections may comprise at least one split coil such as one of the disclosure. In an embodiment, the MHD converter may comprise at least one cooling system such as heat exchanger 316. The MHD converter may comprise coolers for at least one cell and MHD component such as at least one of the group of chamber 5b31, MHD nozzle section 307, MHD magnets 306, MHD electrodes 304, MHD generator section 308, MHD condensation section 309, return conduits 310, return reservoirs 311, return EM pumps 312, and return EM pump tube 313. The cooler may remove heat lost from the MHD flow channel such as heat lost from at least one of the chamber 5b31, MHD nozzle section 307, MHD generator section 308, and MHD condensation section 309. The cooler may remove heat from the MHD working medium return system such as at least one of the return conduits 310, return reservoirs 311, return EM pumps 312, and return EM pump tube 313. The cooler may comprise a radiative heat exchanger that may reject the heat to ambient atmosphere.

In an embodiment, the cooler may comprise a recirculator or recuperator that transfers energy from the condensation section 309 to at least one of the reservoirs 5c, the reaction cell chamber 5b31, the nozzle 307, and the MHD channel 308. The transferred energy such as heat may comprise that from at least one of the remaining thermal energy, pressure energy, and heat of vaporization of the working medium such as one comprising at least one of a vaporized metal, a kinetic aerosol, and a gas such as a noble gas. Heat pipes are passive two-phase devices capable of transferring large heat fluxes such as up to 20 MW/m² over a distances of meters with a few tenths of degree temperature drop; thus, reducing dramatically the thermal stresses on material, using only a small quantity of working fluid. Sodium and lithium heat pipes can transfer large heat flues and remain nearly isothermal along the axial direction. The lithium heat pipe can transfer up to 200 MW/m². In an embodiment, a heat pipe such as molten metal one such as liquid alkali metal such as sodium or lithium encased in a refractory metal such as W may transfer the heat from the condenser 309 and recirculate it to the reaction cell chamber 5b31 or nozzle 307. In an embodiment, at least one heat pipe recovers the silver heat of vaporization and recirculates it such that the recovered heat power is part of the power input to the MHD channel 308.

In an embodiment, at least one of component of the SunCell® such as one comprising a MHD converter may comprise a heat pipe to at least one of transfer heat from one part of the SunCell® power generator to another and transfer heat from a heater such as an inductively coupled heater to a SunCell® component such as the EM pump tube 5k6, the reservoirs 5c, the reaction cell chamber 5b31, and the MHD molten metal return system such as the MHD return conduit 310, MHD return reservoir 311, MHD return EM pump 312, and MHD return EM tube. Alternatively, the SunCell® or at least one component may be heated within an oven such as one known in the art. In an embodiment, at least one SunCell® component may be heated for at least startup of operation.

The SunCell® heater 415 may be a resistive heater or an inductively coupled heater. An exemplary SunCell® heater 415 comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Additional FeCrAl alloys for suitable heating elements are at least one of Kanthal APM, Kanthal A F, Kanthal D, and Alkrothal. The heating element such as a resistive wire element may comprise a NiCr alloy that may operate in the 1100° C. to 1200° C. range such as at least one of Nikrothal 80, Nikrothal 70, Nikrothal 60, and Nikrothal 40. Alternatively, the heater 415 may comprise molybdenum disilicide (MoSi₂) such as at least one of Kanthal Super 1700, Kanthal Super 1800, Kanthal Super 1900, Kanthal Super RA, Kanthal Super ER, Kanthal Super HT, and Kanthal Super NC that is capable of operating in the 1500° C. to 1800° C. range in an oxidizing atmosphere. The heating element may comprise molybdenum disilicide (MoSi₂) alloyed with Alumina. The heating element may have an oxidation resistant coating such as an Alumina coating. The heating element of the resistive heater 415 may comprise SiC that may be capable of operating at a temperature of up to 1625° C.

The SunCell® heater 415 may comprise an internal heater that may be introduced through thermowells or indentations of the component wall that are open to the outside, but closed to the inside of the SunCell® component. The SunCell® heater 415 may comprise an internal resistive heater wherein power may be coupled to the internal heater by magnetic induction across the wall of the heated SunCell® component or by liquid electrodes that penetrate the wall of the heated SunCell® component.

The SunCell® heater may comprise insulation to increase at least one of its efficiency and effectiveness. The insulation may comprise a ceramic such as one known by those skilled in the art such as an insulation comprising alumina-silicate. The insulation may be at least one of removable or reversible. The insulation such as ceramic fiber insulation may comprise gas voids. The insulation may be reversible by applying a low heat transfer gas such as air, nitrogen, or SF₆ (33.8 mW/m K at 600K, 1 atm) during heating and then replacing it with a high heat transfer gas such as helium (252.4 mW/m K at 600K, 1 atm) following heat up. Alternatively, the insulation may be removed following startup to more effectively transfer heat to a desired receiver such as ambient surroundings or a heat exchanger. The insulation may be mechanically removed. The insulation may comprise a vacuum capable chamber and a pump, wherein the insulation is applied by pulling a vacuum, and the insulation is reversed by adding a heat transfer gas such as a noble gas such as helium. A vacuum chamber with a heat transfer gas such as helium that can be added or pumped off may serve as adjustable insulation. The SunCell® may comprise a gas circulation system to cause force convection heat transfer with its activation to switch from a thermally insulating to non-thermally insulating mode.

In another embodiment, the SunCell® may comprise a particle insulation and at least one insulation reservoir having at least one chamber about the component to be thermally insulated to house the insulation during warm-up of the SunCell®. Exemplary particulate insulation comprises at least one of sand and ceramic beads such as alumina or alumina-silicate beads such as Mullite beads. The beads may be removed following warm up. The beads may be removed by gravity flow wherein the housing may comprise a shoot for bead removal. The beads may also be removed mechanically with a bead transporter such as an auger, conveyor, or pneumatic pump. The particulate insulation may further comprise a fluidizer such as a liquid such as water to increase the flow when filling the insulation reservoir. The liquid may be removed before heating and added during insulation transport. The insulation-liquid mixture may comprise slurry. The SunCell® may comprise at least one additional reservoir to fill or empty the insulation from the insulation reservoir. The fill reservoir may comprise a means to maintain slurry such as an agitator.

In an embodiment, the SunCell® may further comprise a liquid insulation reservoir circumferential to the components to be insulated, liquid insulation, and a pump wherein the reversible insulation may comprise the liquid that may be drained or pumped away following startup. In an embodiment, the liquid insulation reservoir may have a low thermal resistance such that the heat transfer from the SunCell® to a load is facilitated once the liquid insulation is removed. The liquid insulation reservoir may comprise thin-walled quartz. An exemplary liquid insulation is gallium having a heat transfer coefficient of 29 W/m K, and an other is mercury having a heat transfer coefficient of 8.3 W/m K.

The liquid insulation may comprise at least one radiation shield wherein the liquid reflects radiation. The liquid insulation may comprise a low emissivity. The radiation shields may be refrigerated by a refrigeration means. The liquid insulation reservoir may comprise means to disperse the liquid insulation such as a stack of separators having intervening gallium layers such as thin liquid layers having a thickness in at least one range of 1 micron to 10 cm, 10 micron to 1 cm, and 100 micron to 1 mm. The layers may comprise thin films. The separators may comprise a material that is transparent to the radiation emitted by the at least one of the heater and the SunCell® such as visible radiation and blackbody radiation in the temperature range of about 100° C. to 3000° C. Exemplary separators comprise ceramic particles, beads, or plates such as sapphire or quartz beads that have surfaces that cause the reflection of the incident radiation back onto at least one of the heater and the SunCell® source of emission. For cylindrical components, the plates may comprise concentric tubes such as concentric sapphire tubes wherein the liquid insulation such as liquid gallium forms a film or layer between each tube. The dispersion may provide a plurality of reflecting surfaces to decrease radiative power losses from the heater during SunCell® startup. The separators may be optically transparent to the radiation that is desired to be reflected and not melt under operating conditions. The separators may comprise a ceramic, zirconia, ceria, alumina, sapphire, LiF, MgF₂, and CaF₂, other alkaline earth halides such as fluorides such as BaF₂, CdF₂, quartz, fused quartz, alkali-aluminosilicate glass such as Gorilla Glass, borosilicate glass, ceramic glass, and Infrasil (ThorLabs). In another embodiment, the liquid insulation reservoir may comprise a plurality of chambers comprising gas or vacuum separators that have a low thermal conductivity. Insulation such as at least one of superinsulation and floating shields may be interspersed between the radiation shields such as refrigerated radiation shields.

At least one of the liquid insulation reservoir wall material or a coating, liquid insulation, or a liquid insulation additive may be selected such that the liquid reservoir wall is not wetted by the liquid insulation when it is drained or pumped away. An agent such as Ga₂O₃ may be applied to the inner liquid reservoir wall to prevent the liquid insulation such as Galistan from wetting the wall of the liquid insulation reservoir such as one comprising quartz when the liquid insulation is removed by means such as by draining or pumping. In an embodiment, the liquid insulation such as gallium is hermetically sealed in the liquid insulation reservoir to prevent it from oxidizing. In an exemplary embodiment, the avoidance of the formation of Ga₂O₃ may prevent gallium from wetting the wall of a quartz liquid insulation reservoir. Different liquid reservoir coatings, liquid insulation additives, and liquid metals or alloys are selected by one skilled in the art to avoid liquid insulation wall wetting during liquid insulation removal. In an exemplary embodiment, the introduction of up to 47.9 at % Ag, 9.2 at % Ni, and 68 at % Cu into gallium avoids wetting the walls of a quartz liquid insulation reservoir when removing the liquid insulation.

In another embodiment, the liquid insulation may comprise a molten salt such as a molten eutectic mixture of salts such as a mixture of a plurality of at least two of alkali and alkaline earth halides, carbonates, hydroxides, oxides, sulfates, and nitrates. Exemplary mixture are LiF—BeF₂ (also known as FLiBe [67-33 mol %]), LiF—NaF—KF (also known as FLiNaK [46.5-11.5-42 mol %]), KCl-MgCl₂ (67-33 mol %), LiCl—NaCl—KCl, LiF—NaF—KF, and NaCl—KCl—ZnC₂. NaCl—KCl—ZnCl₂ with relative composition of 7.5-23.9-68.6 mol % has a melting point of 204° C. and an upper operating temperature in excess of 800° C. Li₂CO₃—Na₂CO₃—K₂CO₃ with relative composition of 32.1-33.4-34.5 mol % has a melting point of 400° C. and an upper operating temperature of 658° C. The liquid insulation reservoir may be capable of vacuum, atmospheric pressure, or pressure above atmospheric pressure. The liquid insulation reservoir may be selected to be resistant to corrosion with the molten salt insulation. In exemplary embodiments, the liquid insulation reservoir for molten carbonates and chlorides may comprise stainless steel (SS) such as 316 SS and alumina, respectively. The SunCell® may further comprise at least one of a liquid insulation cooling reservoir to permit the liquid to cool to a temperature suitable for pumping and a liquid insulation pump such as a centrifugal pump such as a submersible centrifugal pump such as a GVSO model from Rheinhuette Pumps, LLC (http://www.rh-pumps.com/pumps/gvso-submersible-chemical-pump-in-metallic-materials/). The pump may comprise a mechanical pump. The pump may comprise one used to pump molten salt coolant such as one known in the art such as known for coolant circulation in nuclear power plants. The liquid may flow into the cooling reservoir by gravity flow or by active pumping. The liquid may be pumped against gravity to a holding reservoir that may comprise at least one valve such as an outlet valve. In another embodiment, the cooling reservoir containing the insulation may be transported against gravity to become the holding reservoir. The holding reservoir may comprise a heater in the case that the liquid insulation must be melted before flowing into the liquid insulation reservoir. The liquid may be flowed into the liquid insulation reservoir by gravity flow or by active pumping. The liquid insulation reservoir may be pre-heated by a heater such as the SunCell® heater prior to receiving the liquid insulation. In another embodiment, the liquid may be agitated, stirred, or circulated following startup to control the heat transfer from the heated SunCell® component to a load wherein the liquid insulation remains in the liquid insulation reservoir.

The liquid insulation may comprise a pressurized liquid or supercritical liquid such as CO₂ or water.

In an embodiment, the reversible insulation may comprise a material that significantly increases its thermal conductivity with temperature over at least the range of about the melting of the molten metal such as silver to about the SunCell® operating temperature. The reversible insulation may comprise a solid compound that may be insulating during heat up and becomes thermally conductive at a temperature above the desired startup temperature. Quartz is an exemplary insulating material that has a significant increase in thermal conductivity over the temperature range of the melting point of silver to a desired operating temperature of a quartz SunCell® of about 1000° C. to 1600° C. The quartz insulation thickness may be adjusted to achieve the desired behavior of insulation during startup and heat transfer to a load during operation. Another exemplary embodiment comprises a highly porous semitransparent ceramic material.

In an embodiment, the reversible insulation may comprise a material that changes properties under power input such as electrical input or thermal input. The reversible insulation may comprise a solid compound that may be insulating as a solid and become thermally conductive at a temperature above the desired startup temperature. The reversible insulation may comprise a solid that is insulating wherein the solid melts above the desired startup temperature of the SunCell® to become significantly more thermally conductive. An exemplary pure element with the lowest thermal conductivity of any pure metal is manganese having a thermal conductivity of 7.7 W/mK and a melting point of 1246° C. The reversible insulation may comprise a solid such as a metal oxide that is thermally insulating wherein the solid may be converted to the corresponding metal that is thermally conductive following startup. The conversion may be achieved by electrolysis or other known method. In another embodiment, the reversible insulation may comprise an anisotropic material such as oriented graphite that has poor thermal conductivity in one direction and high thermal conductivity in another. In another embodiment, the anisotropic material may be oriented with an electric or magnetic field to control the desired thermal conductivity.

The heater insulation may comprise a material that is circumferential to the resistive heater and heats up slower than heat is transferred to the wall of the heated SunCell® component. The insulation may comprise at least one resistive heater insulating coating such as a ceramic such as at least one of SiO₂, alumina, Mullite, glass, fused quartz, vitreous silica, fused silica, slip cast quartz, and powdered quartz. The coating and its thickness relative to the wall thickness of the heated SunCell® component may be selected such that heat from the heater is transferred inside of the wall on a faster time scale than to the outer surface of the coating comprising the surface radial from the wall. After startup, the outer surface may heat to a temperature similar to that of the wall temperature. Heat may be transferred from the outer surface to a load. The load may comprise a space or process heating system or a thermal to electric converter. The heat transfer may be achieved by at least one of radiation, convection, and conduction. The transfer may be facilitated by a coolant or a heat exchanger. At least one of the surface area and emissivity of the outer surface of the coating may be selected to achieve the desired heat transfer rate to the load wherein the heat transfer rate may control the operating temperature of at least one of the wall and the coating. In an exemplary embodiment, the insulation comprises SiO₂ insulation circumferential to resistive heater elements such as resistive wire wrapping such as Kanthal wire wrapping.

In another embodiment, heat is loss from the heated SunCell® is predominantly by radiation. The insulation may comprise at least one of a vacuum chamber housing the SunCell® and radiation shields. The radiation shields may be removed following startup. The SunCell® may comprise a mechanism to at least one of rotate and translate the heat shields. The heat shields may further comprise a backing layer of insulation such as silica or alumina insulation. In an exemplary embodiment, the radiation shields may be turned to decrease the reflecting surface area. In another embodiment, the radiation shields may further comprise heating elements such as MoSi₂ heating elements.

The heater may comprise a plurality of heating elements wherein each element may be dedicated to a specific zone or component of the SunCell®. The resistive heater may comprise resistive heating zones.

The heater may comprise sections that separate circumferentially. The sections may comprise complementary pieces that surround the heated cell components during startup that may be removed following startup. The sections may comprise complementary shapes such as mirror images in the case of a cylindrically component. The sections may comprise clamshell heaters that separate. The heater may comprise a servo-mechanism such as a mechanical, pneumatic, hydraulic, piezoelectric, electromagnetic, or other servo-mechanism known in the art to retract the heater sections following startup. The heater sections may be retracted to prevent interference with a component that operates by inductive fields such as magnetic fields such as those of a transformer such as the EM pump or ignition transformers, respecitively.

The heater may comprise a heat transfer element or means that spreads the heat to avoid heat gradients in the heated component. The heat transfer element or means may comprise at least one of heat transfer paste such as one of the disclosure, a cladding such as a refractory oxidation resistant metal such as SS 625, or the cell may comprise a material that is more favorable for spreading heat such as Pyrex. The heater may comprise a continuous resistive wire wrapping such as a continuous Kanthal wire wrapping. In an embodiment, the wire has high resistance to eliminate IR losses in the bus bars and to simplify them. In another embodiment, the SunCell® may comprise a housing about a component or components to be heated. The housing may contain a heat transfer medium to serve as a heating bath with the housing. The heat transfer medium may be liquid at its desired temperature such as one in the temperature range of 1000° C. to 2000° C. An exemplary heat transfer medium is a metal with a high boiling point such as gallium, a molten salt such as LiBr, or sand wherein the melting point may be lowered by addition of an additive such as potash. The heating element may heat the bath that heats the component. An exemplary bath heating element comprises MoSi₂ or SiC.

In an embodiment, the surface of the component to be heated, such as one comprising quartz, is at least one of coated with a low-emissivity coating and polished to lower the emissivity and corresponding radiative power loss. The low-emissivity component is suitable for use in a vacuum chamber to achieve variable insulation.

The SunCell® may comprise permanent insulation and a system to remove heat internal to the SunCell®. The SunCell® may comprise a heat exchanger internal to the insulation wherein the coolant may be flowed to remove heat following heating by the heater during startup. The heater may be shut off and the coolant flow of the heat exchanger commenced following SunCell® startup. In an embodiment, the SunCell® may comprise a heat pipe to remove internal heat. In an embodiment, the SunCell® may comprise an external heat exchanger to remove internal heat. Molten silver may be pumped through the external heat exchanger to transfer heat externally to the SunCell®. The heat exchanger may serve as a space or process heater. The SunCell® may comprise at least one addition pump such as an EM pump to pump the molten metal such as silver through the external heat exchanger. Alternatively, the injection EM pumps may further serve to pump the molten metal through the external heat exchanger. In an embodiment, the SunCell® may comprise a heat exchanger internal to the insulation.

The resistive heater 415 may be powered by at least one of series and parallel wired circuits to selectively heat SunCell® different components. The resistive heating wire may comprise a twisted pair to prevent interference by systems that cause a time-varying field such as induction systems such as at least one induction EM pump, an induction ignition system, and electromagnets. The resistive heating wires may be oriented such that any linked time-varying magnetic flux is minimized. The wire orientation may be such that any closed loops are in a plane parallel with the magnetic flux. In an embodiment, coupling of the flux of at least one of the inductive EM pump winding 401 and the induction ignition transformer winding 411 with the resistive heater wire is reduced by increasing the resistive heater wire resistance. In an embodiment, the resistive heater comprises wire with higher resistivity. The heater wire may comprise a small diameter to increase the resistance. The resistance may be increased by operating the wire at elevated temperature.

In an embodiment, the inductive current such as that induced in the EM pump tube sections 405 and 406 may cause the silver in the EM pump section 405 to melt by resistive heating. The current may be induced by EM pump transformer winding 401. The EM pump tube section 405 may be pre-loaded with silver before startup. In an embodiment, the heat of the hydrino reaction may heat at one SunCell® component. In an exemplary embodiment, a heater such as an inductively coupled heater heats the EM pump tube 5k6, the reservoirs 5c, and at least the bottom portion of the reaction cell chamber 5b31. At least one other component may be heated by the heat release of the hydrino reaction such as at least one of the top of the reaction cell chamber 5b31, the MHD nozzle 307, MHD channel 308, MHD condensation section 309, and MHD molten metal return system such as the MHD return conduit 310, MHD return reservoir 311, MHD return EM pump 312, and MHD return EM tube. In an embodiment, the MHD molten metal return system such as the MHD return conduit 310, MHD return reservoir 311, MHD return EM pump 312, and MHD return EM tube may be heated with elevated temperature molten metal or metal vapor such as molten silver or vapor having a temperature in at least one range of about 1000° C. to 7000° C., 1100° C. to 6000° C., 1100° C. to 5000° C., 1100° C. to 4000° C., 1100° C. to 3000° C., 1100° C. to 2300° C., 1100° C. to 2000° C., 1100° C. to 1800° C., and 1100° C. to 1500° C. The elevated temperature molten metal or metal vapor may be caused to flow through the MHD component with bypass or disablement of the MHD conversion into electricity. The disablement may be achieved by removing the electric field or by electrically shorting the electrodes.

In an embodiment, at least one component of the cell and MHD converter may be insulated to prevent heat loss. At least one of the group of chamber 5b31, MHD nozzle section 307, MHD generator section 308, MHD condensation section 309, return conduits 310, return reservoirs 311, return EM pumps 312, and return EM pump tube 313 may be insulated. Heat lost from the insulation may be dissipated in the corresponding cooler or heat exchanger. In an embodiment, the working fluid such as silver may serve as a coolant. The EM pump injection rate may be increased to provide silver to absorb heat to cool at least one cell or MHD component such as the MHD nozzle 307. The vaporization of silver may cool the nozzle MHD 307. A recirculator or recuperator may comprise the working medium used for cooling. In an exemplary embodiment, silver is pumped over the component to be cooled and is injected into the reaction cell chamber and MHD converter to recover the heat while providing the cooling.

At least the high-pressure components such as the reservoirs 5c, reaction cell chamber 5b31, and high-pressure portions of the MHD converter 307 and 308 may be maintained in the pressure chamber 5b3a1 comprising housing 5b3a and 5b3b. The pressure chamber 5b3a1 may be maintained at a pressure to at least counter balance at least a portion of the high internal reaction chamber 5b31 and MHD nozzle 307 and MHD generator channel 308. The pressure balance may reduce the strain on the joints of the generator components such as those between the reservoirs 5c and the EM pump assembly 5kk. The high-pressure vessel 5b3a may selective house the high-pressure components such as at least one of the reaction cell chamber 5b31, the reservoirs 5c, and the MHD expansion channel 308. The other cell components may be housed in a lower-pressure vessel or housing.

A source of hydrino reactant such as at least one of H₂O, H₂, CO₂, and CO may be permeated through a permeable cell components such as at least one of the cell chamber 5b31, the reservoirs 5c, the MHD expansion channel 308, and the MHD condensation section 309. The hydrino reaction gases may be introduced into the molten metal stream in at least one location such as through the EM pump tube 5k6, the MHD expansion channel 308, the MHD condensation section 309, the MHD return conduit 310, the return reservoir 311, the MHD return pump 312, the MHD return EM pump tube 313. The gas injector such as a mass flow controller may be capable of injecting at high pressure on the high-pressure side of the MHD converter such as through at least one of the EM pump tube 5k6, the MHD return pump 312, and the MHD return EM pump tube 313. The gas injector may be capable of injection of the hydrino reactants at lower pressure on the low-pressure side of the MHD converter such as at least one location such as through the MHD condensation section 309, the MHD return conduit 310, and the return reservoir 311. In an embodiment at least one of water and water vapor may be injected through the EM pump tube 5k4 by a flow controller that may further comprise a pressure arrestor and a back-flow check valve to present the molten metal from flowing back into the water supplier such as the mass flow controller. Water may be injected through a selectively permeable membrane such as a ceramic or carbon membrane. In an embodiment, the converter may comprise a PV converter wherein the hydrino reactant injector is capable of supplying reactants by at least one of means such as by permeation or injection at the operating pressure of the site of delivery. In another embodiment, the SunCell® may further comprise a source of hydrogen gas and a source of oxygen gas wherein the two gases are combined to provide water vapor in the reaction cell chamber 5b31. The source of hydrogen and the source of oxygen may each comprise at least one of a corresponding tank, a line to flow the gas into reaction cell chamber 5b31 directly or indirectly, a flow regulator, a flow controller, a computer, a flow sensor, and at least one valve. In the latter case, the gas may be flowed into a chamber in gas continuity with the reaction cell chamber 5b31 such as at least one of the EM pump 5ka, the reservoir 5c, the nozzle 307, the MHD channel 308, and other MHD converter components such as any return lines 310a, conduits 313a, and pumps 312a. In an embodiment, at least one of the H₂ and O₂ may be injected into the injection section the EM pump tube 5k61. O₂ and H₂ may be injected through separate EM pump tubes of the dual EM pump injectors. Alternatively, a gas such as at least one of oxygen and hydrogen may be added to the cell interior through an injector in a region with lower silver vapor pressure such as the MHD channel 308 or MHD condensation section 309. At least one of hydrogen and oxygen may be injected through a selective membrane such as a ceramic membrane such as a nano-porous ceramic membrane. The oxygen may be supplied through an oxygen permeable membrane such as one of the disclosure such as BaCo_{0.7}Fe_{0.2}Nb_{0.1}O_{3-δ} (BCFN) oxygen permeable membrane that may be coated with Bi₂₆Mo₁₀O₆₉ to increase the oxygen permeation rate. The hydrogen may be supplied through a hydrogen permeable membrane such as a palladium-silver alloy membrane. The SunCell® may comprise an electrolyzer such as a high-pressure electrolyzer. The electrolyzer may comprise a proton exchange membrane where pure hydrogen may be supplied by the cathode compartment. Pure oxygen may be supplied by the anode compartment. In an embodiment, the EM pump parts are coated with a non-oxidizing coating or oxidation protective coating, and hydrogen and oxygen are injected separately under controlled conditions using two mass flow controllers wherein the flows may be controlled based on the cell concentrations sensed by corresponding gas sensors.

In an embodiment, hydrogen may be supplied to the reaction cell chamber 5b31 by permeation or diffusion across a permeable membrane. The membrane may comprise a ceramic such as polymers, silica, zeolite, alumina, zirconia, hafnia, carbon, or a metal such as Pd—Ag alloy, niobium, Ni, Ti, stainless steel or other hydrogen permeable material known in the art such as one reported by McLeod [L. S. McLeod, “Hydrogen permeation through microfabricated palladium-silver alloy membranes”, PhD thesis Georgia Institute of Technology, December, (2008), https://smartech.gatech.edu/bitstream/handle/1853/31672/mcleod_logan_s_200812_phd.pdf] which is incorporate by reference in its entirety. The H₂ permeation rate may be increased by at least one of increasing the pressure differential between the supply side of the H₂ permeable membrane such as a Pd or Pd—Ag membrane and the reaction cell chamber 5b31, increasing the area of the membrane, decreasing the thickness of the membrane, and elevating the temperature of the membrane. The membrane may comprise a grating or perforated backing to provide structural support to operate under at least one condition of higher pressure differential such as in the range of about 1 to 500 atm, larger area such as in the range of about 0.01 cm² to 10 m², decreased thickness such as in the range of 10 nm to 1 cm, and elevated temperature such as in the range of about 30° C. to 3000° C. The grating may comprise a metal that does not react with hydrogen. The grating may be resistant to hydrogen embrittlement. An exemplary embodiment, a Pd—Ag alloy membrane having a permeation coefficient of 5×10⁻¹¹ m m⁻² s⁻¹ Pa⁻¹, an area of 1×10⁻³ m², and a thickness of 1×10⁻⁴ m operates at a pressure differential of 1×10⁷ Pa and a temperature of 300° C. to provide a H₂ flow rate of about 0.01 moles/s.

The permeation rate may increased by maintaining a plasma on the outer surface of the permeable membrane. The SunCell® may comprise a semipermeable membrane that may comprise an electrode of a plasma cell such as a cathode of a plasma cell. The SunCell® such as one shown in FIGS. 2I216-2I219 may comprise an outer sealed plasma chamber comprising an outer wall surrounding a portion of the wall of cell 5b3 wherein a portion of the metal wall of the cell 5b3 comprises an electrode of the plasma cell. The sealed plasma chamber may comprise a chamber around the cell 5b3 such as housing 427 (FIG. 2I206) wherein the wall of cell 5b3 may comprise a plasma cell electrode and the housing 427 or an independent electrode in the chamber may comprise the counter electrode. The SunCell® may further comprise a plasma power source, and plasma control system, a gas source such as a hydrogen gas supply tank, a hydrogen supply monitor and regular, and a vacuum pump. In another embodiment, the hydrogen may be injected as a gas through a gas injector. In an embodiment, the hydrogen gas may be maintained at an elevated pressure such as in the range of 1 to 100 atm to decrease the required flow rate to maintain a desired power.

In an embodiment, at least one component of the SunCell® and MHD converter comprising an interior compartment such as the reservoirs 5c, the reaction cell chamber 5b31, the nozzle 307, the MHD channel 308, the MHD condensation section 309, and other MHD converter components such as any return lines 310a, conduits 313a, and pumps 312a are housed in a gas-sealed housing or chamber wherein the gases in the chamber equilibrate with the interior cell gas by diffusion across a membrane permeable to gases and impermeable to silver vapor. The gas selective membrane may comprise a semipermeable ceramic such as one of the disclosure. The cell gases may comprise at least one of hydrogen, oxygen, and a noble gas such as argon or helium. The outer housing may comprise a pressure sensor for each gas. The SunCell® may comprise a source and controller for each gas. The source of noble gas such as argon may comprise a tank. The source for at least one of hydrogen and oxygen may comprise an electrolyzer such as a high-pressure electrolyzer. The gas controller may comprise at least one of a flow controller, a gas regulator, and a computer. The gas pressure in the housing may be controlled to control the gas pressure of each gas in the interior of the cell such as in the reservoirs, reaction cell chamber, and MHD converter components. The pressure of each gas may be in the range of about 0.1 Torr to 20 atm. In an exemplary embodiment shown in FIGS. 2I179-2I206, the straight MHD channel 308 and MHD condensation section 309 comprises a gas housing 309b, a pressure gauge 309c, and gas supply and evacuation assembly 309e comprising a gas inlet line, a gas outlet line, and a flange wherein the gas permeable membrane 309d may be mounted in the wall of the MHD condensation section 309. The mount may comprise a sintered joint, a metalized ceramic joint, a brazed joint, or others of the disclosure. The gas housing 309b may further comprise an access port. The gas housing 309b may comprise a metal such as an oxidation resistant metal such as SS 625 or an oxidation resistant coating on a metal such as an iridium coating on a metal of suitable CTE such as molybdenum. Alternatively, the gas housing 309b may comprise ceramic such as a metal oxide ceramic such as zirconia, alumina, magnesia, hafnia, quartz, or another of the disclosure. Ceramic penetrations through a metal gas housing 309b such as those of the MHD return conduits 310 may be cooled. The penetration may comprise a carbon seal wherein the seal temperature is below the carbonization temperature of the metal and the carbo-reduction temperature of the ceramic. The seal may be removed for the hot molten metal to cool it. The seal may comprise cooling such as passive or forced air or water-cooling.

In exemplary embodiments, the inductively coupled heater antenna 5f may comprise one coil, three separate coils as shown in FIGS. 2I178-2I179, three continuous coils as shown in FIGS. 2I182-2I183, two separated coils, or two continuous coils as shown in FIGS. 2I180-2I181. An exemplary inductively coupled heater antenna 5f comprises an upper elliptical coil and a lower EM pump tube pancake coil that may comprise a spiral coil that may comprise concentric boxes with a continuous circumferential current direction (FIGS. 2I180-2I181). The reaction cell chamber 5b31 and MHD nozzle 307 may comprise planar, polygonal, rectangular, cylindrical, spherical, or other desired geometry as shown in FIGS. 2I162-2I206. The inductively coupled heater antenna 5f may comprise a continuous set of three turnings comprising two helices circumferential to each reservoirs 5c and a pancake coil parallel to the EM pump tubes as shown in FIGS. 2I182-2I183. The turns of the opposing helices about the reservoirs may be wound such that the currents are in the same direction to reinforce the magnetic fields of the two coils or opposite directions to cancel in the space between the helices. The inductively coupled heater antenna 5f may further serve to cool at least one component such as at least one of the EM pump 5kk, the reservoirs 5c, the walls of the reaction cell chamber 5b31, and the yoke of an induction ignition system. At least one cooled component may comprise a ceramic such as one of the disclosure such as silicon nitride, quartz, alumina, zirconia, magnesia, or hafnia.

The SunCell® may comprise one MHD working medium return conduit from the end of the MHD expansion channel to the reservoir 5c wherein the reservoir 5c may comprise a sealed top cover that isolates lower pressure in the reservoir from the higher reaction cell chamber 5b31 pressure. The EM pump injector section 5k61 and nozzle 5q may penetrate the cover to inject molten metal such as silver in the reaction cell chamber 5b31. The penetration may comprise a seal of the disclosure such as a compression seal, slip nut, gasket braze, or stuffing box seal. The reservoir may comprise an inlet riser tube 5qa to control the molten metal level in the reservoir 5c. The covered reservoir and EM pump assembly 5kk that receives return molten metal flow may comprise a first injector of a dual molten metal injector system. The second injector comprising a second reservoir and EM pump assembly may comprise an open reservoir that receives return flow indirectly from the first injector. The second injector may comprise the positive electrode. The second injector may be maintained submerged below the molten metal level in the reservoir. The corresponding inlet riser tube 5qa may control the submersion.

The SunCell® may comprise at least one gaseous metal return conduit 310 from the end of the MHD generator channel 308 to at least one reservoir 5c of a molten metal injector system. The SunCell® may comprise two return conduits 310 from the end of the MHD generator channel 308 to the two corresponding reservoirs 5c of a dual molten metal injector system. Each reservoir 5c may comprise a sealed top cover that isolates lower pressure in the reservoir 5c from the higher reaction cell chamber 5b31 pressure. The EM pump injector section 5ka and 5k61 and nozzle 5q may penetrate the reservoir top cover to inject molten metal such as silver in the reaction cell chamber 5b31. The penetration may comprise a seal of the disclosure such as a compression seal, slip nut, gasket, braze, or stuffing box seal. Each reservoir 5c may comprise an inlet riser tube 5qa to control the molten metal level in the reservoir 5c. The temperature of the reaction cell chamber 5b31 may be above the boiling point of the molten metal such that the liquid metal that is injected into reaction cell chamber is vaporized and is returned through return conduits 310.

The SunCell® may comprise at least one MHD working medium return conduit 310 from the end of the MHD condenser channel 309 to at least one reservoir 5c of a molten metal injector system. The SunCell® may comprise two MHD working medium return conduits 310 from the end of the MHD condenser channel 309 to the two corresponding reservoirs 5c of a dual molten metal injector system. Each reservoir 5c may comprise a sealed top cover that isolates lower pressure in the reservoir 5c from the higher reaction cell chamber 5b31 pressure. The EM pump injector section 5ka and 5k61 and nozzle 5q may penetrate the reservoir top cover to inject molten metal such as silver in the reaction cell chamber 5b31. The penetration may comprise a seal of the disclosure such as a compression seal, slip nut, gasket, braze, or stuffing box seal. Each reservoir 5c may comprise an inlet riser tube 5qa to control the molten metal level in the reservoir 5c. The temperature of the reaction cell chamber 5b31 may be above the boiling point of the molten metal such that the liquid metal that is injected into reaction cell chamber is vaporized, the vapor is accelerated through the MHD nozzle section 307, the kinetic energy of the vapor is converted to electricity in the generator channel 308, the vapor is condensed in the MHD condenser section 309, and the molten metal is returned through return conduits 310.

The SunCell® may comprise at least one MHD working medium return conduit 310, one return reservoir 311, and corresponding pump 312. The pump 312 may comprise an electromagnetic (EM) pump. The SunCell® may comprise dual molten metal conduits 310; return reservoirs 311, and corresponding EM pumps 312. A corresponding inlet riser tube 5qa may control the molten metal level in each return reservoir 311. The return EM pumps 312 may pump the MHD working medium from the end of the MHD condenser channel 309 to return reservoirs 311 and then to the corresponding injector reservoirs 5c. In another embodiment, molten metal return flow is through the return conduit 310 directly to the corresponding return EM pumps 312 and then to the corresponding injector reservoirs 5c. In an embodiment, the MHD working medium such as silver is pumped against a pressure gradient such as about 10 atm to complete a molten metal flow circuit comprising injection, ignition, expansion, and return flow. To achieve the high pressure, the EM pump may comprise a series of stages. The SunCell® may comprise a dual molten metal injector system comprising a pair of reservoirs 5c, each comprising an EM pump injector 5ka and 5k61 and an inlet riser tube 5qa to control the molten metal level in the corresponding reservoir 5c. The return flow may enter the base 5kk1 of the corresponding EM pump assembly 5kk.

In an embodiment, the velocity of the working medium in at least one position comprising the at position in an MHD component such as the entrance of the nozzle, the nozzle, exit of the nozzle, and a desired portion of the MHD channel may be sufficiently high such that condensation such as shock condensation does not occur even in the case that metal vapor saturation conditions are met. The condensation may not occur due to the short transit time compared to the condensation time. The condensation kinetics may be altered or selected by controlling the plasma pressure, plasma temperature, jet velocity, working medium composition, and magnetic field strength. The metal vapor such as silver vapor may condense on the condenser 309 that may have high surface area, and the collected liquid silver may be returned through the return conduit and EM pumping system. In an embodiment, a short transit time in the nozzle that avoids shock condensation is exploited to allow the production of favorable MHD conversion conditions in the MHD channel 307 that otherwise would result in shock condensation.

In an embodiment, the MHD expansion or generator channel also know as the MHD channel comprises a flared MHD channel to continuously derive power conversion with the heat gradient converted to a pressure gradient that drives kinetic energy flow. Heat from silver condensation may contribute to the pressure gradient or mass flow in the MHD channel. The heat of vaporization released by the condensing silver may serve the function of an afterburner in a jet engine to create higher velocity flow. In an exemplary embodiment, the silver heat of vaporization serves the function of combustion in a jet afterburner to increase or contribute to the velocity of the silver jet stream. In an embodiment, the heat of vaporization released by condensation of the silver vapor increases the pressure above the pressure in the absence of the condensation. The MHD channel may comprise geometry such as a flare or nozzle geometry to convert the pressure into directed flow or kinetic energy that is converted into electricity by the MHD converter. The magnetic field provided by the MHD magnets 306 may be adjusted to prevent plasma stall in the case that the silver vapor condenses with a corresponding change in conductivity. In an embodiment, the walls of the MHD channel 308 are maintained at an elevated temperature to prevent metal vapor condensation on the walls with the corresponding mass and kinetic energy loss. The high electrode temperature may also protect from plasma arcing that may occur in the opposite case of cooled electrodes having a less electrically conductive or more insulating boundary layer relative to hotter plasma.

The MHD channel 308 may be maintained at a desired elevated temperature by transferring heat from the reaction cell chamber 5b31 to the walls of the MHD channel. The MHD converter may comprise a heat exchanger to transfer the heat from the reaction cell chamber to the walls of the MHD channel. The heat exchanger may comprises a conductive or convective heat exchanger such as one comprising heat transfer blocks that conducts heat from the reaction cell chamber to the walls of the MHD channel. The heat exchanger may comprise a radiative heat exchanger wherein the outer wall of at least a portion of reaction cell chamber comprises a blackbody radiator to emit power and at least a portion of the wall of the MHD channel may comprise a blackbody radiator to absorb the blackbody radiation. The heat exchanger may comprise a coolant that may be pumped. The pump may comprise an EM pump wherein the coolant is a molten metal. In another embodiment, the hydrino reaction is further propagated and maintained in the MHD channel 308 to maintain the MHD channel wall temperature above the condensation temperature of the metal vapor flowing in the channel. The hydrino reaction may be maintained by supplying reactants such as H and HOH catalyst or sources thereof. The reaction may be selectively maintained at the electrodes due to their conductivity that supports and accelerates the hydrino reaction rate. The MHD converter may comprise at least one temperature sensor to record the MHD channel wall temperature and a controller to control at least one of the heat transfer means such as a heat exchanger and the hydrino reaction rate to maintain the desired MHD channel wall temperature. The hydrino reaction rate may be controlled by means of the disclosure such as means to control the flow of hydrino reactants to the MHD channel.

In another embodiment, at least one of the plasma, metal vapor, and condensed metal vapor is confined to the channel and prevented from collecting on the MHD walls by a channel confinement means such as one comprising a source of at least one of electric and magnetic fields. The confinement means may comprise a magnetic confinement means such as a magnetic bottle. The confinement means may comprise an inductively couple field such as an RF field. The MHD converter may comprise at least one of an RF power source, at least one antenna, electrostatic electrodes and power source, and at least one magnetostatic magnetic field source to achieve the confinement.

In an embodiment, the working medium comprises a vaporized metal in the MHD channel 308 wherein the pressure and temperature of working medium is increased by the heat released by condensation of the metal vapor along the MHD channel as it looses kinetic energy due to MHD conversion to electricity. The energy from the condensation of the silver may increase at least one of the pressure, temperature, velocity, and kinetic energy of the working medium in the MHD channel. The flow velocity may be increased by a channel geometry that exploits the Venturi effect or Bernoulli principle. In an embodiment, flowing liquid silver may serve as an aspirator medium for the vapor to cause it to flow in the MHD channel.

In an embodiment, at least one of the MHD channel 308 diameter and volume are reduced as a function of the distance along the flow axis or z-axis of the MHD channel from the nozzle 307 exit to the MHD channel 308 exit. The MHD channel 308 may comprise a channel that converges alone the z-axis. In another embodiment, the channel size along the z-axis remains the same or diverges less than that of a conventional seeded-gas MHD working medium converter. The channel volume may be reduced to maintain pressure and velocity along the z-axis as the silver condenses and releases heat to maintain energetic plasma. The heat of vaporization released from condensing silver vapor (254 kJ/mole) with plasma flow along the z-axis may increase the temperature and pressure of the working medium to cause increased flow of the non-condensed silver at any given position along the z-axis of the channel. The increase in flow velocity may be caused by the Venturi effect or Bernoulli principle. The magnetic flux may be varied permanently or dynamically along the flow axis (z-axis) of the MHD channel to extract MHD power as a function of z-axial position to maintain a desired pressure, temperature, velocity, power, and energy inventory along the channel wherein the channel size as a function of distance along the z-axis may be matched to z-axial magnetic flux variation to at least partially achieve the extraction of the energy of the heat of vaporization from the vaporized metal as electricity. The plasma gas flow may also serve as a carrier gas for the condensed silver vapor.

The condensed silver may comprise a mist or fog. The fog state may be favored due to the tendency of silver to form an aerosol at a temperature well below its boiling point at a given pressure. The working medium may comprise oxygen and silver wherein molten silver has a tendency to form an aerosol in the presence of oxygen at a temperature well below its boiling point at a given pressure wherein silver may absorb large amounts of oxygen. The working medium may comprise an aerosolizing gas such as nitrogen, oxygen, water vapor, or a noble gas such as argon in addition to metal vapor such as silver vapor to form an aerosol of condensed silver. In an embodiment, the pressure of the aerosolizing gas throughout the reaction cell chamber and MHD channel may be maintained at its steady state distribution under operating conditions. The MHD converter may further comprise a supply of the aerosolizing gas such as a tank of the aerosolizing gas, a pump, and at least one gauge to selectively measure the aerosolizing gas pressure at one or more locations. The aerosolizing gas inventory may be maintained at a desired level by addition or removal of aerosolizing gas using the pump and aerosolizing gas supply. In an exemplary embodiment, liquid silver forms a fog or aerosol at a temperature just above the melting point such that a constant ambient pressure aerosolizing gas such as argon in the MHD channel 308 causes the silver vapor to liquid transition to occur in the form of an aerosol that may be carried with the plasma flow and aggregated on the MHD condenser 309. In an embodiment, the velocity of the condensing vapor is conserved in the condensate. The velocity of the condensate may increase from the release of the heat of vaporization. The MHD channel may comprise a geometry that converts the heat of vaporization into condensate kinetic energy. In an embodiment, the channel may narrow to convert the heat of vaporization into condensate kinetic energy. In another embodiment, the heat of vaporization may increase the channel pressure, and the pressure may be converted to kinetic energy by a nozzle. In an embodiment, copper or silver-copper alloy may replace silver. In an embodiment, the molten metal that serves as the source of metal aerosol comprises at least one of silver, copper, and silver-copper alloy. The aerosol may form in the presence of a gas such as at least one of oxygen, water vapor, and a noble gas such as argon.

In an embodiment, the SunCell® comprises a means to maintain a flow of cell gas in contact with molten silver to form molten metal aerosol such as silver aerosol. The gas flow may comprise at least one of forced gas flow and convection gas flow. In an embodiment, at least one of the reaction cell chamber 5b31 and the reservoirs 5c may comprise at least one baffle to cause a circulation of the cell gas to increase the gas flow. The flow may be driven by at least one of convection and pressure gradients such as those caused by at least one of thermal gradients and pressure from the plasma reaction. The gas may comprise at least one of a noble gas, oxygen, water vapor, H₂, and O₂. The means to maintain the gas flow may comprise at least one of a gas pump or compressor such as MHD gas pump or compressor 312a, the MHD converter, and the turbulent flow caused by at least one of the EM pump molten metal injectors and the hydrino plasma reaction. At least one of the gas flow rate and composition of the gas may be controlled to control that aerosol production rate. In an embodiment wherein water vapor is recirculated, the SunCell® further comprises a recombiner to recombine any H₂O thermalized into H₂ and O₂ back into H₂O, a condenser to condense the water vapor to liquid water, and a liquid water pump to inject pressurized water into a line that supplies at least one interior cell component such as the reservoir 5c or reaction cell chamber 5b31 wherein the pressurized water may transition into steam in route to injection inside of the cell. The recombiner may be one known in the art such as one comprising at least one of Raney nickel, Pd, and Pt. The water vapor may be recirculated in a loop comprising high-pressure compartments such as between the reaction cell chamber 5b31 and the reservoirs 5c.

In an embodiment, at least one of the reservoirs 5c and the reaction cell chamber 5b31 comprises a source of gas having a temperature sufficiently low to at least one of condense silver vapor to silver aerosol and cool silver aerosol. The heat released by the energetic hydrino reaction may form the silver vapor. The vaporization may occur in the hydrino reaction plasma. The ambient gas in contact with the hydrino reaction comprises the cell gas. A portion of at least one of the cell gas and aerosol may be cooled by a heat exchanger and chiller in a region inside of at least one of the reservoirs and reaction cell chamber containing at least one of gas, aerosol, and plasma. At least one of the cell gas and aerosol may be sufficiently cooled to at least one of condense silver vapor to aerosol and cool aerosol. At least one of the vapor condensation rate and the temperature and pressure of the cool cell gas-aerosol-vapor mixture may be controlled by controlling at least one of heat transfer during cooling and the temperature and pressure of the cool cell gas and aerosol.

In an embodiment to avoid mass loss along the channel, the silver vapor is caused to from fog as the vapor is condenses. The molar fraction that loses its kinetic energy to electricity along the channel may be caused to form fog wherein the corresponding heat of vaporization imparts kinetic energy to the corresponding aerosol particles to maintain the constant initial velocity of the otherwise lost mass. The channel may be straight to converging to maintain the velocity with reduced particle number due to partial atomic aggregation into aerosol particles flowing with remaining gas atoms. In an embodiment, the MHD channel 308 walls may be maintained at a temperature such as greater than the melting point of silver to avoid condensed liquid condensation by supporting fog formation.

In an embodiment, the MHD channel components and surfaces that the silver plasma jet contacts may comprise materials that resist wetting by the silver liquid. At least one of the MHD channel walls 308 and MHD electrodes 304 may comprise surfaces that resist wetting.

The aerosol particles may be charged and collected. The collection may occur at the end of the MHD channel. The aerosol particles may be removed by electrostatic precipitation or electrospray precipitation. In an embodiment, the MHD converter may comprise an aerosol particle charging means such as at least one particle charging electrode, an electrical power supply such as a source of high voltage, and a charged particle collector such as at least one electrode that is electrically biased to collect the charged particles. The charged particles may be collected at the end of the MHD channel by an applied electric field.

In an embodiment, metal vapor droplets are carried out by the plasma flow. The droplets may form a thin film on the surface of at least one of the MHD electrodes and MHD channel walls. Excess condensed liquid may be mechanically ablated and carried with the plasma and mass flow. In an embodiment, a Faraday current passes through condensed metal vapor such as condensed silver vapor and a Hall current is produced that forces the condensed silver particles along the trajectory of the plasma jet from the MHD nozzle 307. The Hall current may cause condensed silver to flow out of the MHD channel to be returned to the reservoirs 5c. The current may preferentially flow though the condensed silver due to the higher conductivity than the metal vapor. In another embodiment, the transport may be assisted by at least one of a divergence and convergence of the MHD channel. In an embodiment, the MHD converter such as a disc generator may comprise electrodes that contact the plasma at the entrance and exit of the MHD channel such that the effect of molten metal shorting in the channel is ameliorated.

In an embodiment, the working medium comprises a metal such silver that may sublime at a temperature below its boiling point to prevent the metal from condensing on the walls of the MHD channel such that it flows to the recirculation system. In an embodiment, the pressure at the exit of the MHD channel is maintained at a low pressure such as one below atmospheric pressure. A vacuum may be maintained at the exit of the MHD channel such that the working medium metal vapor does not condense in the MHD channel 308. The vacuum may be maintained by a MHD gas pump or compressor 312a (FIGS. 2I67-2I73).

In an embodiment, the MHD channel may comprise a generator in the entrance section and a compressor in the exit section. The compressor may cause condensed vapor to be pumped out of the MHD channel. The MH converter may comprise a source of current and a current controller to controllably apply current to the working medium of the MHD channel in a perpendicular direction to the applied magnetic field to cause the condensed working medium vapor to flow from the channel wherein the channel conditions may be controlled to cause vapor condensation to achieve the release of the heat of vaporization of the vapor.

In another embodiment, the heat of vaporization of the metal vapor such as silver metal vapor may be recovered by condensing the vapor at a heat exchanger such as MHD condenser 309. The condensation may occur at a temperature that is higher than the boiling point of the metal such as silver. The heat may be transferred to a portion of the reservoir 5c by a means known in the art such as by convection, conduction, radiation, or by a coolant. The heat transfer system may comprise refractory heat transfer blocks such as Mo, W, or carbon bocks that transfer the heat by conduction. The heat may cause the silver in the reservoir to vaporize. The heat may be conserved in the heat of vaporization. The hydrino reaction may further increase the pressure and temperature of the vaporized metal. In an embodiment comprising a working medium additive such as a noble gas such as argon or helium, the MHD converter further comprises a gas pump or compressor 312a (FIGS. 2I67-2I73) to recirculate the gas from the low-pressure to the high-pressure part of the MHD converter. The gas pump or compressor 312a may comprise a drive motor 312b and blades or vanes 312c. The MHD converter may comprise a pump inlet that may comprise a gas passage 310a from the MHD condensation section 309 to the pump inlet and a pump outlet that may comprise a gas passage 313a from the pump or compressor 312a to the reaction cell chamber 5b31. The pump may pump gas from a low pressure such as about 1 to 2 atm to high pressure such as about 4 to 15 atm. The inlet conduit 310a from the MHD condensation section 309 to the pump 312a may comprise a filter such as a selective membrane or metal condenser at the inlet to separate the gas such as a noble gas from the metal vapor such as silver vapor. Baffles 309a in the MHD condenser section 309 may direct the molten metal such as that condensed in the MHD condensation section 309 into the MHD return conduit 310. At least one of the height of the baffles in the center and the molten metal return inlet to the MHD return conduit 310 may be at a position wherein the upward gas pressure exceeds the force of gravity on condensed or liquid molten metal particles to facilitate their flow into the MHD return conduit 310.

The SunCell® may comprise a metal vapor condenser such as a constant pressure condenser that may be located in the MHD condensation section 309 and may comprise a heat exchanger 316. The working medium may comprise metal vapor seeded carrier or working gas such as silver vapor seeded noble gas such as helium or argon. The condenser may condense the metal vapor so that liquid metal and noble gas may be separately pumped. The separation may be by at least one of method of the group of gravity sedimentation, centrifugal separation, cyclone separation, filtration, electrostatic precipitation, and other methods known to those skilled in the art. In an exemplary embodiment, the separated noble gas is removed from the top of the condenser, and the separated liquid metal is removed from the bottom of the condenser. The liquid and gas may be separated by at least one of baffles 309a, filters, a selectively permeable membrane, and a liquid barrier that is passable for the gas.

A compressor 312a may pump or cause the gas to recirculate to the reaction cell chamber 5b31. An EM pump 312 may pump the liquid silver to return it to the reservoir 5c to be re-injected into the reaction cell chamber 5b31. The compressor 312a and EM pump 312 re-pressurizes the working medium gas such as argon or helium and liquid metal such as liquid silver, respectively. The working medium gas may be returned to reaction cell chamber through a conduit 313a that may connect at least one of the EM pump tube 5k6, the reservoir 5c, the base 5kk1 of the EM pump assemble 5kk, and the reaction cell chamber 5b31. Alternatively, the gas may be returned to the reaction cell chamber 5b31 through a conduit 313a connected to a delivery tube 313b such as one that provides a direct passage into the reservoir 5c or the reaction cell chamber 5b31. The gas may serve to inject the molten metal into the reaction cell chamber. The molten metal may become entrained in the gas injection to replace or supplement the EM pump molten metal injectors. The injected molten metal and vapor such as the liquid and gaseous silver vapor flow rates may be controlled by controlling the gas flow rate, gas pressure, gas temperature, reservoir temperature, reaction cell temperature, nozzle inlet pressure, MHD nozzle flow rate, MHD nozzle outlet pressure, and hydrino reaction rate.

The return conduit tube 313b for at least one of the working medium gas and molten metal such as one that runs through the molten metal of the reservoir 5c may comprise a refractory material such as at least one of Mo, W, rhenium, rhenium coated Mo or W, a ceramic such as a metal oxide such as ZrO₂, HfO₂, MgO, Al₂O₃, and another of the disclosure. The conduit may comprise a refractory material tube that is threaded into a collar or seat in the EM pump tube assembly base 5kk1. The height of the return conduit tube 313b may be one desired to deliver the gas while allowing desired performances of other components such as metal injection and level control by the injection section of the EM pump tube 5k61 and the inlet riser tube 5qa, respectively. The height may be about the reservoir molten metal level.

In an embodiment shown in FIGS. 2I71-2I73, the gas pump or compressor 312a may pump a mixture of gaseous working medium species such as at least two of noble gas, molten metal seed, and molten metal vapor such as silver vapor. In an embodiment, the gas pump or compressor 312a may pump both gaseous and liquid working medium such as at least one of noble gas, metal vapor and liquid molten metal such as liquid silver. The liquid and gas may be returned to reaction cell chamber through a conduit 313a that may connect at least one of the EM pump tube 5k6, the reservoir 5c, the base 5kk1 of the EM pump assemble 5kk, and the reaction cell chamber 5b31. Alternatively, the gas may be returned to the reaction cell chamber 5b31 through a conduit 313a connected to a delivery tube 313b such as one that provides a direct passage into the reservoir 5c or the reaction cell chamber 5b31.

In an embodiment, the gas and liquid may flow through the EM pump tube 5k6. The gas may serve to inject the molten metal into the reaction cell chamber. The molten metal may become entrained in the gas injection to at least one of augment and replace the EM pump to pump molten metal through the injector tubes 5k61 and nozzles 5q. The injection rate may be controlled by controlling at least one of the flow rate and pressure of the gas pump or compressor 312a and by other means of the disclosure. The molten metal levels of the reservoirs 5c may be controlled by a level sensor and controller of the disclosure that controls at least one of the pressure and flow rate of one gas pump or compressor 312a relative to the other of a pair.

In an embodiment comprising a gas pump or compressor that pumps all of the working medium such as silver-seeded noble gas and an embodiment comprising a gas pump or compressor that pumps noble gas alone, the compression may be operated isothermally. The MHD converter may comprise a heat exchange or cooler to at least one of cool the gaseous working medium before and during compression. The gas pump or compressor may comprise an intercooler. The gas pump or compressor may comprise a plurality of stages such as a multistage intercooler compressor. The cooling may increase the efficiency of compressing the gas to match the operating pressure of the reaction cell chamber 5b31.

After the pumping stage in the return cycle, the return gaseous working medium may be heated to increase its pressure. The heating may be achieved with a heat exchanger that receives heat from the MID converter or the regenerator that may receive heat from the MHD condensation section 309 or other hot component such at least one of the group of the reaction cell chamber 5b31, MHD nozzle section 307, MHD generator section 308, and MHD condensation section 309. In an embodiment, the gas pump power may be reduced substantially, by using inlet and outlet valves for gas flow into the reaction cell chamber 5b31 and out the MHD nozzle, respectively, wherein low pressure gas is pumped into the reaction cell chamber and the pressure is increased to the desired pressure such as 10 atm by the plasma reaction power. The resulting pulsed MHD power may be conditioned to steady DC or AC power. The return MHD gas tube 313a may comprise a valve that opens to permit flow of gas of lower pressure than the peak reaction cell chamber operating pressure, and the MHD nozzle section 307 may comprise a valve that opens to allow high pressure gas to flow out the nozzle following the gas heating by the reaction cell chamber 5b31 plasma. The valves may facilitate low-pressure gas injection into the reaction cell chamber by the gas pump or compressor wherein the gas is heated to high pressure by the hydrino reaction plasma. The valves may be synchronized to permit the reaction chamber pressure build up by plasma heating. The valves may be 180° out of phase. The valves may comprise a rotating shutter type. The MHD nozzle may be cooled to permit operation of the MHD nozzle valve. The return gas conduit 313a valve may be at or near the base of the EM pump assembly 5kk1 to avoid silver condensation in the corresponding gas delivery tube 313b. The MHD converter may comprise a pulsed power system such as the one comprising inlet and outlet valves for the working medium gas of the reaction cell chamber 5b31. The pulsed MHD power may be leveled to a constant power output by power conditioning equipment such as equipment comprising power storage such as batteries or capacitors.

In an embodiment, the molten metal such as silver that is recirculated remains in a gaseous state wherein the temperatures of the MHD converter including any return lines 310a, conduits 313a, and pumps 312a are maintained at a temperature above the boiling temperature of the silver at the operating pressure or silver partial pressure in the MHD system.

The pump 312a may comprise a mechanical pump such as a gear pump such as a ceramic gear pump or another known in the art such one comprising an impeller. The pump 312a may operate at high temperature such as in the temperature range of about 962° C. to 2000° C. The pump may comprise a turbine type such as that used in a gas turbine or of the type used as a turbocharger of an internal combustion engine. The gas pump or compressor 312a may comprise at least one of a screw pump, an axial compressor, and a turbine compressor. The pump may comprise a positive displacement type. The gas pump or compressor may create a high gas velocity that would be converted to pressure in a fixed reaction cell chamber volume according to Bernoulli's law. The return gas conduit 313a may comprise valves such as backpressure arresting valves to force the flow from the compressor into the reaction cell chamber and then the MHD converter.

The mechanical parts that are prone to wear by the working medium such as the pump 312a vanes or turbine blades may be coated with molten metal such as molten silver to protect them from abrasion or wear. In an embodiment, at least one component of the gas and molten metal return system comprising a gas pump or compressor such as the components of the group of the MHD return conduit 310a, the return reservoir 311a, the MHD return gas pump or compressor 312a parts in contact with the return gas and molten metal such as the vanes, and the MHD pump tube 313a (FIGS. 2I67-2I73) comprise a coating that performs at least one function of thermal protection and prevention of wetting by the molten metal to facilitate the return metal flow to the reservoir 5c.

In an embodiment, during SunCell® startup the compressor 312a may recirculate the working medium such as helium or argon gas to preheat at least one of the reaction cell chamber 5b31 and an MHD component such as the MHD nozzle section 307, the MHD channel 308, the MHD condensation section 309, and at least one component of the EM return pump system comprising the MHD return conduit 310, the return reservoir 311, the MHD return EM pump 312, and MHD return EM pump tube 313. The working medium may be diverted to at least one component of the EM return pump system. The inductively coupled heater such as that corresponding to antenna 5f may heat the working medium that may be recirculated to cause preheating of at least one of the reaction cell chamber 5b31 and at least one MHD component.

In an exemplary embodiment, the MHD system comprises a working medium comprising silver-seeded or silver-copper-alloy-seeded argon or helium wherein most of the pressure may be due to argon or helium. The silver or silver-copper alloy mole fraction drops with increasing noble gas such as argon gas partial pressure that is controlled using an argon supply, sensing, and control system. The SunCell® may comprise cooling systems for the reaction cell chamber 5b31 and MHD components such as at least one of the MHD nozzle section 307, the MHD channel 308, and the MHD condensation section 309. At least one parameter such as the wall temperature of the reaction cell chamber 5b31 and MHD channel, and the reaction and gas mixture conditions may be controlled that determines the optimal silver or silver-copper alloy inventory or vapor pressure. In an embodiment, an optimal silver vapor pressure is one that optimizes the conductivity and energy inventory of the metal vapor to achieve optimal power conversion density and efficiency. In an embodiment, some metal vapor condenses in the MHD channel to release heat that is converter to additional kinetic energy and converted to electricity in the MHD channel. The pump or compressor 312a may comprise one such as a mechanical pump for both silver and argon, or the MHD converter may comprise two pump types, gas 312a and molten metal 312.

In an embodiment, the MHD converter may comprise a plurality of nozzles to create high velocity conducting streams of molten metal in a plurality of stages. The first nozzle may comprise nozzle 307 in connection with the reaction cell chamber 5b31. Another nozzle may be positioned at the condensation section 309 wherein heat released from condensing silver may create high pressure at the entrance of the nozzle. The MHD converter may comprise an MHD channel having crossed magnets and electrodes downstream of each nozzle to convert the high velocity conductive flow into electricity. In an embodiment, the MHD converter may comprise a plurality of reaction cell chambers 5b31 such as in a position immediately preceding the nozzle.

In an embodiment comprising no return reservoirs 311 wherein the end of the MHD channel 309 behaves like the lower hemisphere of the blackbody radiator 5b41 and the return EM pump 312 speeds are fast (not return rate limiting), then the silver will distribute back to the injector reservoirs 5c in the same manner as it does in the blackbody radiator design of the disclosure. The relative injection rates may then be controlled by the inlet riser tube 5qa of each reservoir 5c as in the case of the blackbody radiator design of the disclosure.

In an embodiment, the SunCell® comprises an EM pump at the position just downstream of the acceleration nozzle 307 to pump condensed molten metal back to at least one reservoir of a molten metal injector system such as the reservoirs 5c of an open dual molten metal injector system 5ka and 6k61.

In an embodiment, the SunCell® comprises other combinations and configurations of return conduits 310 and 310a, return reservoirs 311 and 311a, return EM pumps 312 and compressors 312a, open injector reservoirs 5c, closed injector reservoirs 5c, open EM pump injector sections 5k61 and nozzles 5q, and closed EM pump injector sections 5k61 and nozzles 5q that may be selected by one skilled in the art to achieve the desired flow circuit of the MHD working medium through the reaction cell chamber 5b31 and the MHD converter 300. In an embodiment, the molten metal level controller 5qa of any reservoir such as at least one of the return reservoir 311 and the injector reservoir 5c may comprise at least one of an inlet riser tube 5qa, another of the disclosure, and one known to those skilled in the art.

In an embodiment, the working medium may comprise a mixture of gaseous and liquid phases such as at least one liquid metal and at least one gas such as at least one of a metal vapor and a gas such as a noble gas. Exemplary working media comprise liquid silver and gaseous silver or liquid silver, gaseous silver, and at least one other gas such as a noble gas or another metal vapor.

In an embodiment, the MHD converter may comprise a liquid metal MHD (LMMHD) converter such as one known in the art. The LMMHD converter may comprise a heat exchanger to cause heat to flow form the reaction cell chamber 5b31 to the LMMHD converter. The MHD converter may comprise systems that exploit at least one of the Rankine, Brayton, Ericsson, and Allam cycles. In an embodiment, the working medium comprises a high density and retains a high density relative to a noble gas such that at least one of recuperation and recirculation pumping of the working fluid is achieved with at least one of less expansion of the working fluid and more heat retention. The working medium may comprise a molten metal and its vapor such as silver and silver vapor. The working medium may further comprise at least one of an additional metal in at least one of liquid and vapor state and a gas such as a noble gas, steam, nitrogen, Freon, nitrogen, and other known in the art of liquid metal MHD (LMMHD) converters. In an embodiment, the MHD converter may comprise at least one of an EM pump, a MHD compressor, and a mechanical compressor or pump to recirculate the working medium.

The MHD converter may further comprise a mixer to mix liquid with gas wherein at least one phase may be heated prior to mixing. Alternatively, the mixed phases may be heated. The hot working medium comprising the mixture of phases flows into the MHD channel to generate electricity due to the pressure created in the working medium due to the heating. In another embodiment, the liquid may comprise a plurality liquids such as one that serves as the conductive matrix such as silver and another that has a lower boiling point to serve as the gaseous working medium due to its vaporization in the reaction cell chamber. The vaporization of the metal may permit a thermodynamic MHD cycle. Electrical power is generated with two-phase conductive flow in the MHD channel. The working medium may be heated by a heat exchanger to produce the pressure to provide the flow in the channel. The reaction cell chamber may provide the heat to the inlet of the heat exchanger that flows to the heat exchanger outlet and then to the working medium.

In an embodiment, the hydrino plasma vapor is mixed with liquid silver in a mixer to form a two-phase working medium. The heating creates a high-pressure flow of predominantly molten silver through the MHD channel wherein the thermal-kinetic energy is converted to electricity and the cooler, lower-pressure working medium at the exit of the MHD channel is recirculated by the MHD EM pumps.

In an embodiment comprising a hybrid cycle that is an open gas cycle and a closed metal cycle, the working medium may comprise at least one of oxygen, nitrogen, and air that is seeded with metal vapor such as silver metal vapor. Liquid metal such as silver that is vaporized in the reaction cell chamber 5b31 to comprise gas seed may be condensed upon exit of the MHD channel 308 and recirculated to the reservoirs 5c. The gas such as air that exists the MHD channel may be separated from the seed and may be vented to atmosphere. The heat may be recuperated from the vented gas. Ambient gas such as air may be drawn in by the gas pumps or compressors 312a.

In an embodiment, the MHD converter may comprise a homogeneous MHD generator comprising a metal or metal mixture that is heated to cause metal vaporization at the inlet to the MHD channel. The converter may further comprise a channel inlet heat exchanger to transfer heat from the reaction cell chamber to the working medium to cause it to vaporization before the entrance to the MHD channel. The homogeneous MHD generator may further comprise a channel outlet heat exchanger at the exit of the MHD channel to serve as a regenerator to transfer heat to the working medium before it flow to the inlet heat exchanger. The inlet heat exchanger may comprise a working medium conduit through the reaction cell chamber. The metal working medium may be condensed at a condensation heat exchanger downstream of the outlet heat exchanger wherein the molten metal is then pumped by a recirculation EM pump.

In an embodiment, the working medium comprises a metal and a gas that is soluble in the molten metal at low temperature and insoluble or less soluble in the molten metal at elevated temperature. In an exemplary embodiment, the working medium may comprise at least one of silver and oxygen. In an embodiment, the oxygen pressure in the reaction cell chamber is maintained at a pressure that substantially prevents the molten metal such a silver form undergoing vaporization. The hydrino reaction plasma may heat the oxygen and liquid silver to a desired temperature such as 3500K. The mixture comprising the working medium may flow under pressure such as 25 atm through a tapered MHD channel wherein the pressure and temperature drop as the thermal energy is converted into electricity. As the temperature drops, the molten metal such as silver may absorb the gas such as oxygen. Then, the liquid may be pumped back to the reservoir to be recycled in the reaction cell chamber wherein the plasma heating releases the oxygen to increase the maintain the desired reaction cell chamber pressure and temperature condition to drive the MHD conversion. In an embodiment, the temperature of the silver at the exit of the MHD channel is about the melting point of the molten metal wherein the solubility of oxygen is about 20 cm³ of oxygen (STP) to 1 cm³ of silver at one atm O₂. The recirculation pumping power for the liquid comprising the dissolved gas may be much less than that of the free gas. Moreover, the gas cooling requirements and MHD converter volume to drop the pressure and temperature of the free gas during a thermodynamic power cycle may be substantially reduced.

In an embodiment, the MHD channel may be vertical and the pressure gradient of the working medium in the channel may be greater than the pressure equivalent due to the force of gravity such that working medium flow of the molten metal is maintained in a cycle from the reaction cell chamber 5b31 to the exit of the MHD channel where the molten metal is pumped back to the reservoirs 5c. In an embodiment, the minimum pressure P is

P=ρgh (39)

wherein ρ is the density (1.05×10⁴ kg/m³ for silver) g is the gravitational constant, and h is the height of the metal column. For an exemplary h=0.2 m, P=0.2 atm.

The expansion in the nozzle 307 may be isentropic. In an embodiment, the hydrino reaction conditions in the reaction cell chamber 5b31 may provide and maintain a suitable MHD nozzle 307 temperature and pressure such that the nozzle may produce a high velocity jet while avoiding condensation shock. At least one of about a constant velocity condition and continuity condition whereby the product of the density, velocity, and area is about constant may be maintained during the expansion in the MHD channel 308. In an embodiment, supersonic silver vapor is injected at the entrance to the MHD channel 308 from the MHD nozzle 307. Some silver may condense in the channel, but due to the isentropic expansion, the condensation may be limited. Remaining energy in the jet comprising vapor and any condensed liquid as well as the heat of vaporization of the silver may be by at least partially recovered by condensation at the condenser 309 and recirculation by a recirculator or regenerator such as a heat pipe. In an embodiment, regeneration is achieved using a heat pipe whereby the heat pipe recovers at least the silver heat of vaporization and recirculates it such that the recovered heat power is part of the power input to the MHD channel; then this component of power balance is only reduced by the efficiency of the heat pipe. The percentage of the metal vapor that condenses may be insignificant such as in the range of about 1 to 15%. In an embodiment, condensed vapor may be caused to form an aerosol. The reaction cell chamber, nozzle, and MHD channel may contain a gas such as argon that causes the condensing vapor to from an aerosol. The vapor may be condensed at the end of the MHD channel 308 at condenser such as condenser 309. The liquid metal may be recirculated, and the heat of vaporization may be at least partially recovered by the regenerator such as one comprising a heat pipe.

In another embodiment, the vapor may be forced to condense in a desired region such as the nozzle 307 section. The nozzle expansion may be isentropic wherein condensation of a pure gas such as silver vapor is limited to a liquid mole fraction of 50% starting at the critical temperature and critical pressure which for silver are 506.6 MPa and 7480 K, respectively. In an embodiment, this limitation for condensation from expansion of a pressurized vapor may be overcome by means such as at least one of removal of heat such that the entropy may decrease and by pressurizing the condensing region with at least one other gas. The gas pressure may be equal in all portions of the regions in which there is gas continuity such as in the reaction cell chamber 5b31, the nozzle 307, and the MHD channel 308 regions. The MHD converter may further comprise a tank of other gas, a gas pressure gauge, a gas pump, and a gas pressure controller. The at least one other gas pressure may be controlled by the pressure controller. The gas pressure may be controlled to cause the metal vapor to condense to a greater extent than that of the isentropic expansion of the pure metal vapor. In an embodiment, the gas comprises one that is soluble in the vapor metal. In an exemplary embodiment, the metal comprises silver and the gas comprises at least one of O₂ and H₂O.

In an embodiment, pressure generation in at least one of the nozzle 307 and MHD channel 308 is achieved by the creation of a condensation shock when the metal vapor phase is quickly condensed onto a stream of the liquid metal, producing rapid transformation from two-phase into single-phase flow with a resulting release of the heat of vaporization. The energy release is manifest as kinetic energy of the liquid stream. The kinetic energy of the liquid stream is converted into electricity in the MHD channel 308. In an embodiment, the vapor is condensed as a fog or aerosol. The aerosol may form in a gas ambient atmosphere such as one comprising an aerosol-forming gas such as oxygen and optionally a noble gas such as argon. The MHD channel 308 may be straight to maintain a constant velocity and pressure of the MHD channel flow. The aerosol-forming gas such as oxygen and optionally a noble gas such as argon may be flowed through at least one of the reservoirs 5c, the reaction cell chamber 5b31, the MHD nozzle 307, the MHD channel 308, and other MHD converter components such as any return lines 310a, conduits 313a, and pumps 312a. The gas may be recirculated by the MHD return gas pump or compressor 312a.

In an embodiment, the nozzle 307 comprises a condensing jet injector comprising a two-phase jet device in which the molten metal in the liquid state is mixed with its vapor phase, producing a liquid stream with a pressure that is higher than the pressure of either of the two inlet streams. The pressure may be developed in at least one of the reaction cell chamber 5b31 and in the nozzle 307. The nozzle pressure may be converted to stream velocity at the exit of the nozzle 307. In an embodiment, the reaction cell chamber plasma comprises one phase of the jet device. Molten metal from at least one EM pump injector may comprise the other phase of the jet device. In an embodiment, the other phase such as the liquid phase may be injected by an independent EM pump injector that may comprise an EM pump 5ka, a reservoir such as 5c, an nozzle section of the EM pump tube 5k61, and a nozzle 5q.

In an embodiment, the MHD nozzle 307 comprises an aerosol jet injector that converts the high-pressure plasma of the reaction cell chamber 5b31 into an high velocity aerosol flow or jet in the MHD channel 308. The kinetic energy of the jet may be from at least one source of the group of the pressure of the plasma in the reaction cell chamber 5b31 and the heat of vaporization of metal vapor condensed to form the aerosol jet. In an embodiment, the molar volume of the condensed vapor is about 50 to 500 times smaller than the corresponding vapor at standard conditions. The condensation of the vapor in the nozzle 307 may cause a decrease in pressure at the exit section of the nozzle. The decreased pressure may result in an increase in velocity of the condensed flow that may comprise at least one of a liquid and aerosol jet. The nozzle may be extended and may be convergent to convert the local pressure into kinetic energy. The channel may comprise a larger cross sectional area than that of the nozzle exit, and may be straight to allow the propagation of the aerosol flow. Other nozzle 307 and MHD channel 308 geometries such as ones having convergent, divergent, and straight sections may be selected to achieve the desired condensation of the metal vapor with at least a portion of the energy converted to a conductive flow in the MHD channel 308.

In an embodiment, some residual gas may remain uncondensed in the MHD channel 308. The uncondensed gas may support plasma in the MHD channel to provide an electrically conductive MHD channel flow. The plasma may be maintained by the hydrino reaction that may be propagated in the MHD channel 308. The hydrino reactants may be provided to at least one of the reaction cell chamber 5b31 and the MHD channel 308.

In an embodiment, pressure generation in at least one of the nozzle 307 and MHD channel 308 is achieved by the condensation of the metal vapor such as silver metal vapor with a release of the heat of vaporization. The energy release is manifest as kinetic energy of the condensate. The kinetic energy of the flow may be converted into electricity in the MHD channel 308. The MHD channel 308 may be straight to maintain a constant velocity and pressure of the MHD channel flow. In an embodiment, the vapor is condensed as a fog or aerosol. The aerosol may form in an ambient atmosphere comprising an inert gas such as one comprising argon. The aerosol may form in an ambient atmosphere comprising oxygen. The MHD converter may comprise a source of metal aerosol such as silver aerosol. The source may comprise at least one of the dual molten metal injectors. The aerosol source may comprise an independent EM pump injector that may comprise an EM pump 5ka, a reservoir such as 5c, an nozzle section of the EM pump tube 5k61, and a nozzle 5 wherein the molten metal injection at least partially converts to metal aerosol. The aerosol may flow or be injected into the region wherein it is desired to condense the metal vapor such as in the MHD nozzle 307. The aerosol may condense the metal vapor to a greater extent than that possible for metal vapor that undergoes isentropic expansion such as isentropic nozzle expansion. The metal vapor condensation may release the metal vapor heat of vaporization that may increase at least one of the temperature and pressure of the aerosol. The corresponding energy and power may contribute to the kinetic energy and power of the aerosol and plasma flow at the exit of the nozzle. The power of the flow may be converted to electricity with an increase in efficiency due to the contribution of the power from the metal vapor heat of vaporization. The MHD converter may comprise a controller of the source of metal aerosol to control at least one of the aerosol flow rate and aerosol mass density. The controller may control the rate of EM pumping of an EM pump source of aerosol. The aerosol injection rate may be controlled to optimize the vapor condensation to recover the vapor heat of vaporization and the MHD power conversion efficiency.

In an embodiment, the heat of vaporization released by the condensation of vapor in the nozzle is at least partially transferred to the reaction cell chamber plasma directly or indirectly. The nozzle may comprise a heat exchanger to transfer heat to the reaction cell chamber. The heat may be transferred by at least one method of radiation, conduction, and convection. The nozzle may be heated by the released heat of vaporization and the heat may be transferred by conduction to the reaction cell chamber. The nozzle may comprise a material that is highly heat conductive such as a refractory heat conductor that may comprise an oxidation resistant coating. In exemplary embodiments, the nozzle may comprise boron nitride or carbon that may be coated with an oxidation resistance refractory coat such as a ZrO₂ coating. The material may comprise other refractory materials and coatings of the disclosure.

In an embodiment, pressure generation in at least one of the nozzle 307 and MHD channel 308 is achieved by the condensation of the metal vapor such as silver metal vapor with a release of the heat of vaporization. The energy release is manifest as kinetic energy of the condensate. The kinetic energy of the flow may be converted into electricity in the MHD channel 308. The MHD channel 308 may be straight to maintain a constant velocity and pressure of the MHD channel flow. In an embodiment, the vapor is condensed as a fog or aerosol. The aerosol may form in an ambient atmosphere such as one comprising at least one of argon and oxygen. The aerosol may be formed by injection, passive flow, or forced flow of at least one of oxygen and a noble gas through the liquid silver. The gas may be recirculated using the compressor 312a. The gas may be recirculated in a high-pressure gas flow loop such as one that receives gas at the reaction cell chamber 531 and recirculates it to the reservoir 5c wherein it flows through molten silver to increase the aerosol formation. In an embodiment, the silver may comprise an additive to increase the aerosol formation rate and extent. In an alternative embodiment, a high rate of aerosol production may be a formed by circulating the liquid metal at a high rate. The metal may be injected at high rate by at least one molten metal injector such as the dual molten metal injectors comprising EM pumps 5kk. The pump rate may be in at least one range of about 1 g/s to 10 g/s, 10 g/s to 100 g/s, 1 kg/s to 10 kg/s, 10 kg/s to 100 kg/s, and 100 kg/s to 1000 kg/s. In an embodiment, the energy efficiency to form silver aerosol by pumping molten metal in a maintained cell atmosphere such as one comprising a desired concentration of oxygen may be higher than pumping the gas through the molten silver.

The MHD converter may comprise a source of metal aerosol such as silver aerosol. The source may comprise one or more of at least one of the dual molten metal injectors and aerosol formation from at least one reservoir due to a temperature of the metal contained in the reservoir of above the metal's melting point. The aerosol source may comprise an independent EM pump injector that may comprise an EM pump 5ka, a reservoir such as 5c, an nozzle section of the EM pump tube 5k61, and a nozzle 5q wherein the molten metal injection at least partially converts to metal aerosol. The aerosol may flow or be injected into the region wherein it is desired to condense the metal vapor such as in the MHD nozzle 307. The aerosol may condense the metal vapor to a greater extent than that possible for metal vapor that undergoes isentropic expansion such as isentropic nozzle expansion. The metal vapor condensation may release the metal vapor heat of vaporization that may increase at least one of the temperature and pressure of the aerosol. The corresponding energy and power may contribute to the kinetic energy and power of the aerosol and plasma flow at the exit of the nozzle. The power of the flow may be converted to electricity with an increase in efficiency due to the contribution of the power from the metal vapor heat of vaporization. The MHD converter may comprise a controller of the source of metal aerosol to control at least one of the aerosol flow rate and aerosol mass density. The controller may control the rate of EM pumping of an EM pump source of aerosol. The aerosol injection rate may be controlled to optimize the vapor condensation to recover the vapor heat of vaporization and the MHD power conversion efficiency.

The entropy decrease to cause condensation of the silver vapor during otherwise isentropic expansion can be estimated by the entropy of vaporization of silver ΔSᵥₐₚ, given by

$$Δ {S}_{vap} = \frac{Δ {H}_{vap}}{{T}_{vap}} = \frac{254 kJ / mol}{2435 K} = 104 J {mole}^{- 1} {K}^{- 1} \qquad ( 40 )$$

wherein Tᵥₐₚ is the silver boiling point and ΔHᵥₐₚ is the silver enthalpy of vaporization. In the case that silver vapor contacts silver fog or aerosol having the exemplary temperature of the reservoir of 1500 K, the entropy change to reach the boiling point is

$$\begin{matrix}Δ {S}_{fog} = \int \frac{{dH}_{fog}}{{T}_{fog}} = \int \frac{{C}_{p} dT}{{T}_{fog}} = {C}_{p} ln \frac{{T}_{vap}}{{T}_{res}} \\ = 25.4 J {mole}^{- 1} {K}^{- 1} ln \frac{2435 K}{1500 K} \\ = 12.3 J {mole}^{- 1} {K}^{- 1}\end{matrix} \qquad ( 41 )$$

wherein dH_{fog} is the differential fog enthalpy, T_{fog} is the fog temperature, Cₚ is the specific heat capacity of silver at constant pressure, and Tᵣₑₛ is the reservoir and the initial fog temperature. Thus, in the case that the mass flow of fog is about 8 times that of the metal vapor, the metal vapor will condense to release its heat of vaporization in the nozzle with the corresponding energy available to be significantly converted to kinetic energy. Given that an exemplary molar volume of the condensed vapor as fog or aerosol is about 50 times smaller than the corresponding vapor, the fog flow need only be about 15% of the total gas/plasma volumetric flow to achieve condensation of the vapor to result in about pure fog or aerosol plasma flow. The flog flow rate may be controlled by controlling the reservoir temperature, the fog source injection rate such as the EM pump rate, and the pressure of the aerosol-forming gas such as oxygen and optionally argon.

In an embodiment, the MHD thermodynamic cycle comprises the process of maintaining a hydrino reaction plasma that maintains superheated silver vapor and condensing it to a high kinetic energy aerosol jet of liquid droplets by adding at least one of cold silver aerosol or liquid silver metal injection. The aerosol jet power inventory may comprise predominantly kinetic energy power. The electrical power conversion may be predominantly from the kinetic energy power change in the MHD channel 308. The mode of operation of the MHD converter may comprise the opposite of that of a railgun or the opposite of a DC conductive electromagnetic pump.

The vapor condensation to form the high kinetic energy jet of liquid silver droplets may substantially avoid the loss of the heat of vaporization in the energy and power balance. The cold silver aerosol may be formed in the reservoirs and transported to at least one of the reaction cell chamber 5b31 and the MHD nozzle 307. The cell may further comprise a mixing chamber at the down-stream side of the plasma flow through the reaction cell chamber to the MHD converter. The mixing of cold aerosol and superheated vapor may occur in at least one of the reaction cell chamber 5b31, the mixing chamber, and the MHD nozzle 307. In an embodiment, the SunCell® comprises a source of oxygen to form fuming molten silver to facilitate silver aerosol formation. The oxygen may be supplied to at least one of the reservoirs 5c, the reaction cell chamber 5b31, the MHD nozzle 307, the MHD channel 308, the MHD condensation section 309, and another interior chamber of the SunCell®-MHD converter generator. The oxygen may be absorbed by molten silver to form an aerosol. The aerosol may be enhanced by the presence of a noble gas such as an argon atmosphere inside of the generator. The argon atmosphere may be added and maintained at a desired pressure by systems of the disclosure such as an argon tank, line, valve, controller and injector. The injector may be in the condensation section 309 or other appropriate region to avoid silver back flow. In an embodiment, the super heated silver vapor may be condensed to form an aerosol jet by the injection of silver directly or indirectly into the nozzle. In an embodiment, the reaction cell chamber 5b31 may be operated under at least one of lower temperature and lower pressure to permit a larger fraction of the vapor to be liquefied under expansion such as isentropic expansion. An exemplary lower temperature and pressure are about 2500 K and about 1 atm, versus 3500 K and 10 atm, respectively.

In the case that the flow velocity decreases, the density of the fog may increase to maintain constant flow in the channel. The density may increase by aggregation of silver fog droplets. The channel may comprise a straight channel. In other embodiments, the channel may be convergent or divergent or have another geometry appropriate to optimize the MHD power conversion.

In an embodiment, the nozzle may comprise at least one channel for relatively cold metal vapor aerosol and at least another for silver vapor or super heated silver vapor. The channels may deliver corresponding aerosol to be mixed in the nozzle 307. The mixing may decrease the entropy to cause silver vapor condensation. The condensation and nozzle flow may result in a fast aerosol jet at the nozzle exit. The flow rate of the relatively cold aerosol may be controlled by controlling the temperature of the source such as the reservoir temperature wherein the reservoir may serve as the source. The flow rate of the superheated vapor may be controlled by controlling at least one of the hydrino reaction rate and the rate of molten metal injection. In an embodiment, the SunCell® output power may be varied by varying the silver mass flow by controlling the EM pumps according the mass derivative term of Eq. (42). The hydrino reactants may be synchronously controlled to match the reaction rate and power to the desired output electrical power.

In an embodiment, the nozzle exit pressure and temperature are about those at the MHD channel 308 exit, and the input power Pᵢₙₚᵤₜ at the entrance of the MHD channel 308 is about that given by the kinetic energy associated with the mass flow rate \dot{m} at its velocity v.

Pᵢₙₚᵤₜ=0.5\dot{m}v² (42)

The electrical conversion power P_{electric} in the MHD channel is given by

P_{electric}=VI=ELJ=ELσ(vB−E)A=vBWLσ(vB−WvB)d²=σv²B²W(1−W)Ld² (43)

wherein V is the MHD channel voltage, I is the channel current, E is the channel electric field, J is the channel current density, L is the channel length, σ is the flow conductivity, v is the flow velocity, B is the magnetic field strength, A is the current cross sectional area (the nozzle exit area), d is the electrode separation, and W is the loading factor (ratio of the electric field across the load to the open circuit electric field). The efficiency η is given by the ratio of the electrical conversion power in the MHD channel (Eq. (43)) and the input power (Eq. (42)):

$$η = \frac{{P}_{electric}}{{P}_{input}} = \frac{σ {v}^{2} {B}^{2} W ( 1 - W ) {Ld}^{2}}{0.5 \dot{m} {v}^{2}} = \frac{σ {B}^{2} W ( 1 - w ) {Ld}^{2}}{0.5 \dot{m}} \qquad ( 44 )$$

In the case that the mass flow \dot{m} is 1 kg/s, the conductivity σ is 50,000 S/m, the velocity is 1200 m/s, the magnetic flux B is 0.25 T, the load factor W is 0.5, the channel width and the electrode separation d of the exemplary straight square rectangular channel is 0.05 m, and the channel length L is 0.2 m, the powers and efficiency are:

Pᵢₙₚᵤₜ=720 kW (45)

P_{electric}=562 kW (46)

and

η=78% (47)

Eq. (47) is the total enthalpic efficiency when the total energy inventory is essentially the kinetic energy wherein the heat of vaporization is also converted to kinetic energy in the nozzle 307.

In an embodiment, the differential Lorentz force dF_{L} is proportional to the silver plasma flow velocity and the differential distance dr along the MD channel 308:

dF_{L}=σvB²(1−W)d²dx (48)

The differential Lorentz force (Eq. (48)) can be rearranged as

$$\begin{matrix}\frac{{dF}_{L}}{dx} = \frac{{δ}^{2} ( mv )}{δ x δ t} = \frac{{δ}^{2} ( mv )}{δ t δ x} = \frac{δ}{δ t} ( m \frac{dv}{dx} ) = \dot{m} \frac{dv}{dx} = σ v {B}^{2} ( 1 - W ) {d}^{2} \\ or & ( 49 ) \\ \frac{dv}{dx} = \frac{σ v {B}^{2} ( 1 - W ) {d}^{2}}{\dot{m}} = \frac{σ {B}^{2} ( 1 - W ) {d}^{2}}{\dot{m}} v & ( 50 )\end{matrix}$$

wherein (i) the conductivity a and the magnetic flux B may be constant along the channel, (ii) ideally there is no mass loss along the channel such that the mass m is a constant with respect to distance and the mass flow rate in the channel t is constant due to a constant rate of injection into the channel entrance and continuity of flow under steady state conditions, and (iii) the differential of velocity with distance

$$\frac{d v}{d x}$$

is time independent at a steady flow condition. The constant mass flow rate with decreasing velocity along the channel may correspond to increasing aggregation of aerosol particles to the limit of complete liquefaction at the MHD channel exit. Then, the rate of change in velocity with respect to channel distance is proportional to the velocity:

$$\frac{d v}{d x} = - kv \qquad ( 51 )$$

wherein k is a constant determined by the boundary conditions. Integration of Eq. (51) gives

v=v₀e^{-kx} (52)

By comparing Eq. (51) to Eq. (50) the constant k is

$$k = \frac{σ {B}^{2} ( 1 - W ) {d}^{2}}{\dot{m}} \qquad ( 53 )$$

By combining Eq. (52) and Eq. (53) the velocity as a function of channel distance is

$$v = {v}_{0} {e}^{- \frac{σ {B}^{2} ( 1 - W ) {d}^{2}}{\dot{m}} x} \qquad ( 54 )$$

From Eq. (43), the corresponding power of the channel is given by

$$\begin{matrix}P = {\int }_{0}^{L} σ {v}_{0}^{2} {e}^{- \frac{2 σ {B}^{2} ( 1 - W ) {d}^{2}}{\dot{m}} x} {B}^{2} W ( 1 - W ) {d}^{2} dx \\ = σ {v}_{0}^{2} {B}^{2} W ( 1 - W ) {d}^{2} \frac{\dot{m}}{2 σ {B}^{2} ( 1 - W ) {d}^{2}} ( 1 - {e}^{- \frac{2 σ {B}^{2} ( 1 - W ) {d}^{2}}{\dot{m}} L} ) \\ = 0.5 \dot{m} {v}_{0}^{2} W ( 1 - {e}^{- \frac{2 σ {B}^{2} ( 1 - W ) {d}^{2}}{\dot{m}} L} )\end{matrix} \qquad ( 55 )$$

In the case that the mass flow \dot{m} is 0.5 kg/s, the conductivity σ is 50,000 S/m, the velocity is 1200 m/s, the magnetic flux B is 0.1 T, the load factor W is 0.7, the channel width and the electrode separation d of the exemplary straight square rectangular channel is 0.1 m, and the channel length L is 0.25 m, the powers and efficiency are:

Pᵢₙₚᵤₜ=360 kW (56)

P_{electric}=196 kW (57)

and

η=54% (58)

Eq. (58) corresponds to 54% of the initial channel kinetic energy converted to electricity to power an external load and 46% of the power dissipated in the internal resistance wherein the electrical power density is 80 kW/liter.

The electrical power converges to the kinetic energy power input to the MHD channel 0.5\dot{m}v₀² times the loading factor W of the MHD channel. The power density may be increased by increasing the input kinetic energy power and by decreasing the channel dimensions. The latter may be achieved by increasing at least one of the mass flow rate, the magnetic flux density, and the flow conductivity. In the case that the mass flow \dot{m} is 2 kg/s, the conductivity σ is 500,000 S/m, the velocity is 1500 m/s, the magnetic flux B is 1 T, the load factor W is 0.7, the channel width and the electrode separation d of the exemplary straight square rectangular channel is 0.05 m, and the channel length L is 0.1 m, the powers and efficiency are:

Pᵢₙₚᵤₜ=2.25 MW (59)

P_{electric}=1.575 MW (60)

and

η=70% (61)

Eq. (61) corresponds to 70% of the initial channel kinetic energy converted to electricity to power an external load and 30% of the power dissipated in the internal resistance wherein the electrical power density is 6.3 MW/liter.

The power given by Eq. (55) may be expressed as

$$P = {K}_{0} W ( 1 - {e}^{- \frac{2 σ {B}^{2} ( 1 - W ) {d}^{2}}{\dot{m}} L} ) \qquad ( 62 )$$

wherein K₀ is the initial channel kinetic energy. The maximum power output can be determined b taking the derivative of P with respect to W and setting it equal to 0.

$$\begin{matrix}\frac{dP}{dW} = - {K}_{0} W \frac{2 σ {B}^{2} {d}^{2}}{\dot{m}} {Le}^{- \frac{2 σ {B}^{2} ( 1 - W ) {d}^{2}}{\dot{m}} L} + {K}_{0} ( 1 - {e}^{- \frac{2 σ {B}^{2} ( 1 - W ) {d}^{2}}{\dot{m}} L} ) \\ = - {K}_{0} s W {e}^{- s ( 1 - W )} + {K}_{0} ( 1 - {e}^{- s ( 1 - W )} ) \\ = 0\end{matrix} \qquad ( 63 )$$

wherein

$$\begin{matrix}s = \frac{2 σ {B}^{2} {d}^{2}}{\dot{m}} L \\ Then , & ( 64 ) \\ ( 1 + sW ) = {e}^{s ( 1 - W )} & ( 65 )\end{matrix}$$

In the exemplary case of Eqs. (59-61) wherein s=125, using a reiterative method, the power is optimal when W=0.96. In this case, the efficiency for the conditions of Eqs. (59-60) is 96%.

In an embodiment, at least one of the reaction cell chamber 5b31 and the nozzle 307 may comprise a magnetic bottle that may selectively form a plasma jet along the longitudinal axis of the MHD channel 308. The power converter may comprise a magnetic mirror which is a source of a magnetic field gradient in a desired direction of ion flow where the initial parallel velocity of plasma electrons v_{∥} increases as the orbital velocity v_{⊥} decreases with conservation of energy according to the adiabatic invariant

$$\frac{{v}_{⊥}^{2}}{B} = constant ,$$

constant, the linear energy being drawn from that of orbital motion. As the magnetic flux B decreases, the ion cyclotron radius a will increase such that the flux πa²B remains constant. The invariance of the flux linking an orbit is the basis of the mechanism of a “magnetic mirror”. The principle of a magnetic mirror is that charged particles are reflected by regions of strong magnetic fields if the initial velocity is towards the mirror and are ejected from the mirror otherwise. The adiabatic invariance of flux through the orbit of an ion is a means to form a flow of ions along the z-axis with the conversion of v_{⊥} to v_{∥} such that v_{∥}>v_{⊥}. Two magnetic mirrors or more may form a magnetic bottle to confine plasma such as that formed in the reaction cell chamber 5b31. Ions created or contained in the bottle in the center region will spiral along the axis, but will be reflected by the magnetic mirrors at each end. The more energetic ions with high components of velocity parallel to a desired axis will escape at the ends of the bottle. The bottle may be more leaky at the MHD channel end. Thus, the bottle may produce an essentially linear flow of ions from the end of the magnetic bottle into the channel entrance of the magnetohydrodynamic converter.

Specifically, the plasma may be magnetized with a magnetic mirror that causes the component of ion motion perpendicular to the direction of the MHD channel or z-axis v_{⊥} to at least partially convert into to parallel motion v_{∥} due to the adiabatic invariant

$$\frac{{v}_{⊥}^{2}}{B} = constant .$$

The ions have a preferential velocity along the z-axis and propagate into the magnetohydrodynamic power converter wherein Lorentzian deflected ions form a voltage at electrodes crossed with the corresponding transverse deflecting field. The voltage may drive a current through an electrical load. In an embodiment, the magnetic mirror comprises an electromagnet or a permanent magnet that produces the field equivalent to a Helmholtz coil or a solenoid. In the case of an electromagnetic magnetic mirror, the magnetic field strength may be adjustable by controlling the electromagnetic current to control the rate at which ions flow from the reaction cell chamber to control the power conversion. In the case that v₈₀²=v_{⊥}²=0.5v₀² and

$$\frac{B ( z )}{{B}_{0}} = 0.1$$

at the entrance to the MHD channel 308, the velocity given by

$${v}_{‖ 0}^{2} - {v}_{0}^{2} - {v}_{⊥ 0}^{2} \frac{B ( z )}{{B}_{0}}$$

may be is about 95% parallel to the z-axis.

In an embodiment, the hydrino reaction mixture may comprise at least one of oxygen, water vapor, and hydrogen. The MHD components may comprise materials such as ceramics such as metal oxides such as at least one of zirconia and hafnia, or silica or quartz that are stable under an oxidizing atmosphere. In an embodiment, the MHD electrodes 304 may comprise a material that may be less susceptible to corrosion or degradation during operation. In an embodiment, the MHD electrodes 304 may comprise a conductive ceramic such as a conductive solid oxide. In another embodiment, the MHD electrodes 304 may comprise liquid electrodes. The liquid electrodes may comprise a metal that is liquid at the electrode operating temperature. The liquid metal may comprise the working medium metal such as molten silver. The molten electrode metal may comprise a matrix impregnated with the molten metal. The matrix may comprise a refectory material such as a metal such as W, carbon, a ceramic that may be conductive or another refractory material of the disclosure. The negative electrode may comprise a solid refractory metal. The negative polarity may protect the negative electrode from oxidizing. The positive electrode may comprise a liquid electrode.

The liquid electrode may comprise a means to apply electromagnetic restraint (Lorentz force) to maintain free surface liquid metal. The liquid metal electrodes may comprise a source of magnetic field and a source of current to maintain the electromagnetic restraint. The magnetic field source may comprise at least one of the MHD magnets 306 and another set of magnetic such a permanent magnets, electromagnets, and superconducting magnets. The current source may comprise at least one of the MHD current and an applied current from an external current source.

In an embodiment, the conductive ceramic electrodes may comprise one of the disclosure such as a carbide such as ZrC, HfC, or WC or a boride such as ZrB₂ or composites such as ZrC—ZrB₂, ZrC—ZrB₂—SiC, and ZrB₂ with 20% SiC composite that may work up to 1800° C. The electrodes may comprise carbon. In an embodiment, a plurality of liquid electrodes may be supplied liquid metal through a common manifold. The liquid metal may be pumped by an EM pump. The liquid electrodes may comprise molten metal impregnated in a non-reactive matrix such as a ceramic matrix such as a metal oxide matrix. Alternatively, the liquid metal may be pumped through the matrix to continuous supply molten metal. In an embodiment, the electrodes may comprise continuously injected molten metal such as the ignition electrodes. The injectors may comprise a non-reactive refractory material such as a metal oxide such as ZrO₂. In an embodiment, each of the liquid electrodes may comprise a flow stream of molten metal that is exposed to the MHD channel plasma.

In an embodiment, the electrodes may be arranged in a Hall generator design. The negative electrode may be in proximity to the entrance of the MHD channel and the positive electrode may be in proximity to the exit of the MHD channel. The electrode may be in proximity to the entrance of the MHD channel may comprise a liquid electrode such as a submerged electrode. The electrode in proximity to the exit of the MHD channel may comprise a conductor that is resistant to oxidation at the electrode operating temperature wherein the operating temperature may be significantly lower at the exit than that entrance of the MHD channel. Exemplary oxidation resistant electrodes at the MHD exit may comprise a carbide such as ZrC or a boride such as ZrB₂. In an embodiment, the electrodes may comprise a series of electrode sections separated by insulator sections that comprise protrusions of the MHD channel wall that may comprise and electrical insulator. The protruding sections may be maintained at a temperature that prevents the metal vapor from condensing. The insulating sections may comprise wall strips that are at least one of heated and insulated to maintain the strip temperature above the boiling point of the metal at the operating pressure of the MHD channel. The electrode at the exit of the channel may comprise an oxidation resistant electrode such as a carbide or boride that may be stable to oxidation at the exit temperature. In an embodiment, the MHD channel may be maintained at a temperature below that which results in at least one of condensation of metal vapor on the insulator portion of the walls and corrosion of the electrodes such as carbide or boride electrodes such as ones comprising ZrC or ZrB₂ or composites such as ZrC—ZrB₂ and ZrC—ZrB₂—SiC composite that may work up to 1800° C. In an embodiment, the working medium comprises a metal such silver that may sublime at a temperature below its boiling point to prevent the metal from condensing on the walls of the MHD channel such that it flows to the recirculation system.

In an embodiment, the MHD magnets 306 may comprise alternating field magnets such as electromagnets that may apply a sinusoidal or alternating magnetic field to the MHD channel 308. The sinusoidal or alternating applied field may cause the MHD electrical output to be alternating (AC) power. The alternating current and voltage frequency may be a standard one such as 50 or 60 Hz. In an embodiment, the MHD power is transferred out of the channel by induction. The induction generator may eliminate the electrodes that contact the plasma.

The unions and seals between components such as the seal 314 connecting the reaction cell chamber 5b31 and MHD acceleration channel or nozzle 307 to the MHD expansion or generator channel 308 may comprise a gasketed flange seal or other of the disclosure. Other seals such as ones of the return conduits 310, the return reservoirs 311, the return EM pumps 312, the injector reservoirs 5c, and the injection EM pump assembly 5kk may comprise one of the disclosure. An exemplary gasket comprises carbon such as graphite or Graphoil wherein joined metal oxide parts such as ones comprising at least one of alumina, hafnia, zirconia, and magnesia are maintained below the carboreduction temperature such as below the range of about 1300° C. to 1900° C. The components may comprise different materials of the disclosure such as the refractory materials and stainless steel based on their operating parameters and requirements. In an exemplary embodiment, i.) at least one of the EM pump assembly 5kk, return conduits 310, return reservoirs 311, and return EM pump tube 312 comprises stainless steel wherein the inside may be coated with an oxidation protective coating such as nickel, Pt, rhenium, or other noble metal, ii.) at least one of the reservoirs 5c, the reaction cell chamber 5b31, the nozzle 307, and the MHD expansion section 308 comprises an electrical insulating refractory material such as boron nitride or a refractory oxide such as MgO (M.P. 2825° C.), ZrO₂ (M.P. 2715° C.), magnesia zirconia that is stable to H₂O, strontium zirconate (SrZrO₃ M.P. 2700° C.), HfO₂ (M.P. 2758° C.), or thorium dioxide (M.P. 3300° C.) that is stable to oxidation at the operating temperature, iii.) the reaction cell chamber 5b31 comprises graphite such as at least one of isotropic and pyrolytic graphite, and iv.) at least one of the inlet riser tube 5qa, the nozzle section of the electromagnetic pump tube 5k61, the nozzle 5q, and the MHD electrodes 304 may comprise at least one of carbon, Mo, W, rhenium, rhenium coated Mo, rhenium coated W. In an exemplary embodiment, at least one of the EM pump assembly 5kk, return conduits 310a, return reservoirs 311a, and return gas pump or compressor 312a comprises stainless steel wherein the inside may be coated with an oxidation protective coating such as nickel, Pt, rhenium, or other noble metal.

The electrodes may comprise a noble metal coated conductor such as Pt on copper, nickel, nickel alloys, and cobalt alloys or these metals uncoated wherein cooling may be applied by a backing heat exchanger or cold plate. The electrodes may comprise spinel type electrodes such as 0.75 MgAl₂O₄-0.25 Fe₃0₄, 0.75 FeAl₂0₄-0.25 Fe₃0₄, and lanthanum chromite La(Mg)CrO₃. In an embodiment, the MHD electrodes 304 may comprise liquid electrodes such as liquid silver coated refractory metal electrodes or cooled metal electrodes. At least one of the Ni and rhenium coatings may protect the coated component from reaction with H₂O. The MHD atmosphere may comprise hydrogen to maintain a reducing condition of metals such as those of the EM pump tube 5k6, inlet riser tube 5qa, the nozzle section of the electromagnetic pump tube 5k61, the nozzle 5q, and the MHD electrodes 304. The MHD atmosphere may comprise water vapor to maintain the oxide ceramic such as strontium zirconate, hafnia, ZrO₂ or MgO of the ceramic components such as at least one of the reaction cell chamber 5b31, the nozzle 307, and the MHD expansion section 308. Metal oxides parts may be glued or cemented together using ceramic glues such as zirconia phosphate cement, ZrO₂ cement, or calcia-zirconia cement. Exemplary Al₂O₃ adhesives are Rescor 960 Alumina (Cotronics) and Ceramabond 671. Further exemplary ceramic glues are Resbond 989 (Cotronics) and Ceramabond 50 (Aremco). In an embodiment, the wall components may comprise a thermally insulating ceramic such as ZrO₂ or HfO₂ that may be stabilized with MgO, and the electrode insulators of the segmented electrodes may comprise a thermally conducting ceramic such as MgO. To prevent loss by vaporization from the outer surface, the ceramic may be at least one of thick enough to be sufficiently cool externally, actively or passively cooled, or wrapped in insulation. In an embodiment, at least one component of the SunCell® and MHD converter may comprise a composite of a ceramic such as zirconium carbide and the metal such as tungsten.

Several oxides may be add to the ZrO₂ (zirconia) or HfO₂ (hafnia) to stabilize the materials such as yttrium oxide (Y₂O₃), magnesium oxide (MgO), calcium oxide (CaO), strontium oxide (SrO), tantalum oxide (Ta₂O₅), boron oxide (B₂O₃), TiO₂, cerium oxide (Ce₂O₃), SiC, yttrium, and iridium. The crystal structure may be cubic phase that is referred to as cubic stabilized zirconia (hafnia) or stabilized zirconia (hafnia). In an embodiment, at least one cell component such as the reaction cell chamber 5b31 is permeable to at least one of oxygen and oxide ions. An exemplary oxide permeable material is ZrO₂. The oxygen content of the reaction cell chamber 5b31 may be controlled by controlling the oxide diffusion rate through the oxide permeable or oxide mobile material such as ZrO₂. The cell may comprise a voltage and current source across the oxide permeable material and a voltage and current control system wherein the flow of oxide ions across the material is controlled by the voltage and current. Other suitable refractory component materials comprise at least one of SiC (M.P.=2830° C.), BN (M.P.=2970° C.), HfB₂ (M.P.=3250° C.), and ZrB₂ (M.P.=3250° C.).

To avoid MHD electrode electrical shorting by the molten metal vapor, the electrodes 304 (FIG. 2I161) may comprise conductors, each mounted on an electrical-insulator-covered conducting post 305 that serves as a standoff for lead 305a and may further serve as a spacer of the electrode from the wall of the generator channel 308. The electrodes 304 may be segmented and may comprise a cathode 302 and anode 303. Except for the standoffs 305, the electrodes may be freely suspended in the generator channel 308. The electrode spacing along the vertical axis may be sufficient to prevent molten metal shorting. The electrodes may comprise a refractory conductor such as W or Mo. The leads 305a may be connected to wires that may be insulated with a refractory insulator such as BN. The wires may join in a harness that penetrates the channel at a MHD bus bar feed through flange 301 that may comprise a metal. Outside of the MHD converter, the harness may connect to a power consolidator and inverter.

In an exemplary embodiment, the blackbody plasma initial and final temperatures during MHD conversion to electricity are 3000K and 1300K. In an embodiment, the MHD generator is cooled on the low-pressure side to maintain the plasma flow. The Hall or generator channel 308 may be cooled. The cooling means may be one of the disclosure. The MHD generator 300 may comprise a heat exchanger 316 such as a radiative heat exchanger wherein the heat exchanger may be designed to radiate power as a function of its temperature to maintain a desired lowest channel temperature range such as in a range of about 1000° C. to 1500° C. The radiative heat exchanger may comprise a high surface are to minimize at least one of its size and weight. The radiative heat exchanger 316 may comprise a plurality of surfaces that may be configured in pyramidal or prismatic facets to increase the radiative surface area. The radiative heat exchanger may operate in air. The surface of the radiative heat exchanger may be coated with a material that has at least one property of the group of (i) capable of high temperature operation such as a refractory material, (ii) possesses a high emissivity, (iii) stable to oxidation, and provides a high surface area such as a textured surface with unimpeded or unobstructed emission. Exemplary materials are ceramics such as oxides such as MgO, ZrO₂, HfO₂, Al₂O₃, and other oxidative stabilized ceramics such as ZrC—ZrB₂ and ZrC—ZrB₂—SiC composite.

The generator may further comprise a regenerator or regenerative heat exchanger. In an embodiment, flow is returned to the injection system after passing in a counter current manner to receive heat in the expansion section 308 or other heat loss region to preheat the metal that is injected into the cell reaction chamber 5b31 to maintain the reaction cell chamber temperature. In an embodiment, at least one of working medium such as at least one of silver and a noble, a cell component such as the reservoirs 5c, the reaction cell chamber 5b31, and an MHD converter component such as at least one of the MHD condensation section 309 or other hot component such as at least one of the group of the reservoirs 5c, reaction cell chamber 5b31, MHD nozzle section 307, MHD generator section 308, and MHD condensation section 309 may be heated by a heat exchanger that receives heat from at least one other cell or MHD component such as at least one of the group of the reservoirs 5c, reaction cell chamber 5b31, MHD nozzle section 307, MHD generator section 308, and MHD condensation section 309. The regenerator or regenerative heat exchanger may transfer the heat from one component to another.

In an embodiment, at least one of the emissivity, area, and temperature of the radiative heater exchanger 316 may be controlled to control the rate of heat transfer. The area may be controlled by controlling the extent of covering of a heat shield over the radiator. The temperature may be controlled by controlling the heat flow to the radiator. In another embodiment, the heat exchanger 316 may comprise coolant loops wherein the MHD heat exchanger 316 receives coolant through the MHD coolant inlet 317 and removes heat through the MHD coolant outlet 318. The heat may be used in the regenerative heat exchanger to preheat the return silver flow, a cell component or a MHD component. Alternatively, the heat may be used for heating and cogeneration applications.

The nozzle throat 307 may comprise a refractory material that is resistant to wear such as a metal oxide such as ZrO₂, HfO₂, Al₂O₃, or MgO, a refractory nitride, a refractory carbide such as tantalum carbide, tungsten carbide, or tantalum tungsten carbide, pyrolytic graphite that may comprise a refractory cladding such as tungsten, or another refractory material of the disclosure alone or one that may be clad on a refractory material such as carbon. The electrodes 304 may comprise a refractory conductor such as W or Mo. The generator channel 308 or an electrically insulating support 305 such as those of the electrodes 304 may be a refractory insulator such as one of the disclosure such as a ceramic oxide such as ZrO₂, boron nitride, or silicon carbide. In another embodiment wherein the MHD component is cooled, the MHD component such as at least one of the nozzle 307 and channel 308 may comprise a transition metal such as Cu or Ni that may be coated with a refractory material such as Al₂O₃, ZrO₂, Mullite, or another of the disclosure. The electrodes may comprise a transition metal that may be cooled wherein the surface may be coated with a refractory conductor such as W or Mo. The component may be cooled by water, molten salt, or other coolant known by those skilled in the art such as at least one of thermal oils such as silicon based polymers, molten metals such as Sn, Pb, Zn, alloys, molten salts such as alkali salts and eutectic salt mixtures such as alkali halide-alkali hydroxide mixtures (MX-MOHM=Li, Na, K, Rb, Cs; X=F, Cl, Br, I). The hot coolant may be recirculated to preheat the molten metal injected into the reaction cell chamber 5b31. The corresponding heat recovery system may comprise a recuperator.

In an embodiment, the MHD component such as the MHD nozzle 307, MHD channel 308, and MHD condensation section 309 may comprise a refractory material such as one of the disclosure such as at least one of carbide, carbon, and boride, and metal. The refractory material may be susceptible to oxidation to at least one of oxygen and water. To suppress the oxidation reaction, the source of oxygen for the HOH catalyst may be comprise a compound comprising oxygen such as at least one of CO, an alkaline or alkaline earth oxide, or another oxide or compound comprising oxygen of the disclosure. The boride may comprise ZrB₂ that may be doped with SiC. The carbide may comprise at least one of ZrC, WC, SiC, TaC, HfC, and Ta₄HfC₅. Conductive materials such as carbides may be electrically isolated with an insulating spacer or bushing where indicated such as in the case of electrical isolation of at least one of the ignition and MH electrodes.

An exemplary MHD volumetric conversion density is about 70 MW/m³ (70 kW/liter). Most of the problems with historical MHD originate from the low conductivity feature in the gas-fired case and in the low conductivity plus slagging environments in the coal-fired counterpart. The conductivity of the silver SunCell® plasma is estimated to be about 1 mΩ from the current of 10,000 A at a voltage of 12 V. From the arc dimensions, the corresponding conductivity is estimated to be 1×10⁵ S/m compared to about 20 S/m for an alkali seeded inert MHD working gas wherein the power density is proportional to the conductivity.

In an embodiment, the working medium may comprise at least one of silver vapor and silver-vapor-seeded noble gas such as He, Ne, or Ar. In an embodiment, the conductivity of the working medium may be controlled by controlling at least one of the molten metal vapor pressure such as the silver vapor pressure and the ionization of the working medium. The ionization of the working medium may be controlled by controlling at least one of the hydrino reaction power, the intensity of the EUV and UV light emitted by the hydrino reaction, the ignition voltage, the ignition current, the EM pumping rate of the molten metal streams, and the operating temperatures such as at least one of the gas, electron, ion, and blackbody temperatures. At least one temperature may be controlled by controlling at least one of the ignition and hydrino reaction conditions. Exemplary hydrino reaction conditions are the gas pressure and gas composition such as H₂O, H₂, and inert gas composition. The hydrino reaction conditions and the corresponding controls may be ones of the disclosure or other suitable ones.

In an embodiment, the SunCell® may further comprise a molten metal overflow system such as one comprising an overflow tank, at least one pump, a cell molten metal inventory sensor, a molten metal inventory controller, a heater, a temperature control system, and a molten metal inventory to store and supply molten metal as required to the SunCell® as may be determined by at least one sensor and controller. A molten metal inventory controller of the overflow system may comprise a molten metal level controller of the disclosure such as an inlet riser tube and an EM pump. The overflow system may comprise at least one of the MHD return conduit 310, return reservoir 311, return EM pump 312, and return EM pump tube 313.

In an embodiment, the expansion of the working medium is maintained under conditions to assure isentropic flow. In an embodiment, the inlet working medium conditions are selected for the supersonic nozzle expansion that would ensure reversible expansion in the nozzle and a strong driving pressure gradient in the MHD channel. Since saturation, if it occurs in the nozzle, will lead to strong non-equilibrium sub-cooling due to the rapid cooling rate (such as of about 15 K/us) and this may further will trigger condensation shock in the diverging portion of the nozzle, the nozzle inlet conditions may be highly superheated in order that the vapor does not become saturated during the expansion. In an embodiment, condensation shock is to be avoided because it causes irreversibilities that deviates from the desired isentropic flow condition and sharply reduces the nozzle exit velocity, and the resulting highly dense liquid Ag droplets entrained in the vapor flow in the supersonic/diverging part of the nozzle may lead to accelerated erosion of the nozzle surface. In an embodiment wherein the Lorentz force acts adverse to the flow direction such that a weak driving pressure gradient in the MHD channel may lead to reduced volume flow through the system, the nozzle inlet temperature is as high as possible to allow adequate superheat, and the pressure is also moderately high to assure a strong driving pressure gradient in the MHD section downstream of the nozzle. In an exemplary embodiment, the reaction cell chamber 5b31 pressure at the nozzle entrance is about 6 atm, and the plasma temperature is about 4000 K to result in an isentropic expansion and dry vapor exiting the nozzle at about Mach number 1.24 with about 722 m/s velocity and a pressure of more than 2 atm. Lower inlet temperatures are also possible but these may each yield smaller exit velocity and pressure.

In an embodiment wherein the Lorentz force may stall the plasma jet before the desired MHD channel 308 exit temperature is achieved, at least one of the plasma conductivity, magnetic field strength, gas temperature, electron temperature, ion temperature, channel inlet pressure, jet velocity, and working medium flow parameters are optimized to achieve the desired MHD conversion efficiency and power density. In an embodiment comprising a molten metal seeded noble gas plasma such as a silver vapor seeded argon or helium plasma, the relative flow of metal vapor to noble gas is controlled to achieve at least one of the desired conductivity, plasma gas temperature, reaction chamber 5b31 pressure, and MHD channel 308 inlet jet velocity, pressure, and temperature. In an embodiment, the noble gas and metal vapor flows may be controlled by controlling the corresponding return pumps to achieve the desired relative ratios. In an embodiment, the conductivity may be controlled by controlling the amount of seeding by controlling the relative noble gas and metal injection rates to the reaction cell chamber 5b31. In an embodiment, the conductivity may be controlled by controlling the hydrino reaction rate. The hydrino reaction rate may be controlled by means of the disclosure such as by controlling the injection rate of at least one of the source of catalyst, the source of oxygen, the source of hydrogen, water vapor, hydrogen, the flow of the conductive matrix such as the injection of molten silver, and the ignition parameters such as at least one of the ignition voltage and current. In an embodiment, the MHD converter comprises sensors and control systems for the hydrino reaction and MHD operating parameters such as (i) the reaction conditions such as reactant pressures, temperatures, and relative concentrations, reactant flows such as those of HOH and H or their sources and the flow and pumping rate of the conductive matrix such as liquid and vaporized silver, and ignition conditions such as the ignition current and voltage, (ii) plasma and gas parameters such as pressures, velocities, flow rates, conductivities, and temperatures through the stages of the MHD converter, (iii) return and recycle material parameters such as the pumping rates and physical parameters of the noble gas and molten metal such as flow rates, temperatures, and pressures, and (iv) plasma conductivity sensors in at least one of the reaction cell chamber 5b31, MHD nozzle section 307, MHD channel 308, and MHD condensation section 309.

In an embodiment, a source of gas such as hydrogen such as at least one of H₂ gas and H₂O may be supplied to the reaction cell chamber 5b31. The SunCell® may comprise at least one mass flow controller to supply the source of hydrogen such as at least one of H₂ gas and H₂O that may be in at least one of liquid and gaseous form. The supply may be through at least one of the base if the EM pump assembly 5kk1, the reservoir 5c wall, the wall of the reaction cell chamber 5b31, the injection EM pump tube 5k6, the MHD return conduit 310, the MHD return reservoir 311, the pump tube of the MHD return EM pump 312, and the MHD return EM pump tube 313. The gas added to the cell or MHD interior may be injected in the MHD condensor section 309 or at any convenient cell or MHD converter component that is connected to the interior. In an embodiment, hydrogen gas may be supplied through a selective membrane such as a hydrogen permeable membrane. The hydrogen supply membrane may comprise a Pd or Pd—Ag H₂ permeable membrane or similar membrane known by those skilled in the art. The penetration into the EM pump tube wall for the gas may comprise a flange that may be welded-in or threaded in. The hydrogen may be supplied from a hydrogen tank. The hydrogen may be supplied from release from hydride wherein the release may be controlled be means known by those skilled in the art such as by controlling at least one of pressure and temperature of the hydride. Hydrogen may be supplied by electrolysis of water. The water electrolyzer may comprise a high-pressure electrolyzer. At least one of the electrolyzer and the hydrogen mass flow controller may be controlled by a controller such as one comprising a computer and corresponding sensors. The hydrogen flow may be controlled based on the power output of the SunCell® that may be recorded by a converter such as a thermal measuring device, the PV converter, or the MHD converter.

In an embodiment, H₂O may be supplied to the reaction cell chamber 5b31. The supply may comprise a line such as one through the EM pump tube 5k6 or EM pump assembly 5kk. The H₂O may provide at least one of H and HOH catalyst. The hydrino reaction may produce O₂ and H₂(1/p) and products. The H₂(1/p) such as H₂(¼) may diffuse from at least one of the reaction cell chamber and MHD converter to an outside region such as ambient atmosphere or a H₂(1/p) collection system. H₂(1/p) may diffuse through the wall of at least one of the reaction cell chamber and MHD converter due to its small volume. The O₂ product may diffuse from at least one of the reaction cell chamber and MHD converter to an outside region such as ambient atmosphere or an O₂ collection system. The O₂ may diffuse through a selective membrane, material, or value. The selective material or membrane may comprise one capable of conducting oxide such as a yttria, nickel/yttria stabilized zirconia (YSZ)/silicate layered, or other oxygen or oxide selective membrane known by those skilled in the art. The O₂ may diffuse through a permeable wall such as one capable of conducting oxide such as a yttria wall. The oxygen permeable membrane may comprise a porous ceramic of a low-pressure component of the reaction cell and MHD converter such as a ceramic wall of the MHD channel 308. The oxygen selective membrane may comprise BaCo_{0.7}Fe_{0.2}Nb_{0.1}O_{3-δ} (BCFN) oxygen permeable membrane that may be coated with Bi₂₆Mo₁₀O₆₉ to increase the oxygen permeation rate. The oxygen selective membrane may comprise at least one of Gd₁₋ₓCaₓCoO_{3-d} and Ce₁₋ₓGdₓO_{2-d}. The oxygen selective membrane may comprise a ceramic oxide membrane such as at least one of SrFeCo_{0.5}Oₓ, SrFe_{0.2}Co_{0.5}Oₓ, Ba_{0.5}Sr_{0.5}Co_{0.8}Fe_{0.2}Oₓ, BaCo_{0.4}Fe_{0.4}Zr_{0.2}Oₓ, La_{0.6}Sr_{0.4}CoOₓ, and Sr_{0.5}La_{0.5}Fe_{0.8}Ga_{0.2}Oₓ.

The EM pump or components such as at least one of the EM pump assembly 5kk, the EM pump 5ka, the EM pump tube 5k6, the inlet riser 5qa, and the injection EM pump tube 5k61 may comprise a material or coating that is stable to the oxygen such as a ceramic such as at least one of Al₂O₃, ZrC, ZrC—ZrB₂, ZrC—ZrB₂—SiC, and ZrB₂ with 20% SiC composite or at least one noble metal such as at least one of platinum (Pt), palladium (Pd), ruthenium (Ru), rhodium (Rh), and iridium (Ir).

In an embodiment shown in FIGS. 2I174-2I181, at least one of the EM pump assembly 5kk, the EM pump 5ka, the EM pump tube 5k6, the inlet riser 5qa, and the injection EM pump tube 5k61 may comprise a ceramic that is resistant to oxidation. The ceramic may be non-reactive with O₂. The ceramic may comprise an electrical conductor that is stable to reaction with oxygen to elevated temperature. Exemplary ceramics are ZrC, ZrB₂, ZrC—ZrB₂, ZrC—ZrB₂—SiC, and ZrB₂ with 20% SiC composite. The conductive ceramic may be doped with SiC to provide protection from oxidation.

Iridium (M.P.=2446° C.) does not form an alloy or solid solution with silver; thus, iridium may serve as a suitable anti-oxidation coating of at least one of the EM pump assembly 5kk and EM pump tube 5k6 to avoid oxidation. The iridium coating may be applied to a metal of about matching coefficient of thermal expansion (CTE). In an exemplary embodiment, the inside of the EM pump assembly 5kk and EM pump tube 5k6 are electroplated with iridium wherein the electroplated components comprise stainless steel (SS) such as Haynes 230, 310 SS, or 625 SS that has a similar CTE as iridium. Alternatively, a molybdenum EM pump assembly 5kk may be coated with iridium wherein there is a CTE match (e.g. ˜7 ppm/K). In an embodiment, the interior of the EM pump tube is electroplated using the tube as the cathode, and the counter electrode may comprise a wire with insulating spacers that is periodically moved on the counter electrode to electroplate areas covered by the spacers. In an embodiment, the iridium coating may be applied by vapor deposition such a method comprising the chemical deposition of an organic molecule comprising iridium such as thermal decomposition of tetrairidium dodecacarbonyl to cause the iridium to deposit on the desired surface maintained at an elevated temperature. Iridium may be deposited by one or more methods known in the art such as at least one of magnetron sputtering (both direct current magnetron sputtering (DCMS) and radio frequency magnetron sputtering (RFMS)), chemical vapor deposition (CVD), metal-organic CVD (MOCVD), atomic layer deposition (ALD), physical vapor deposition (PVD), laser-induced chemical vapor deposition (LCVD), electrodeposition, pulsed laser deposition (PLD), and double glow plasma (DGP). In an embodiment, the inside of the EM pump 5k6 tube may be clad with iridium. The ends of the cladding may be coated with iridium by a means of the disclosure such as CVD or electroplating.

In another embodiment, the EM pump assembly such as a stainless steel EM pump assembly may be coated with a refractory, oxidation resistant coating such as at least one of an oxide and a carbide. The coating may comprise at least one of a carbide such as hafnium carbide/silicon carbide (HfC/SiC) and an oxide such as at least one of HfO₂, ZrO₂, Y₂O₃, Al₂O₃, SiO₂, Ta₂O₅, and TiO₂.

In another embodiment, the EM pump tube 5k6 comprises an oxidation-resistant stainless steel (SS) such as that used in the water wall of coal fireboxes and boiler tubes such as austenitic stainless steels. Exemplary materials are Haynes 230, SS 310, and SS 625, an austenitic nickel-chromium-molybdenum-niobium alloy possessing a rare combination of outstanding corrosion resistance coupled with high strength from cryogenic temperatures to 1800° F. (982° C.). In an embodiment, the material such as Haynes 230, SS 310, or SS 625 may be pre-oxidized to form a protective oxide coat. The protective oxide coat may be formed by heating in an atmosphere comprising oxygen. The SS such as Haynes 230 may be pre-oxidized in air or a controlled atmosphere such as one comprising oxygen and a noble gas such as argon. In exemplary embodiments, the Haynes 230 such as Ni—Cr alloy with W and Mo alloy is pre-oxidized in air at 1000° C. or in argon 80%/oxygen 20% for 24 hours. The oxide coat may be formed under the desired operating temperature and oxygen concentration. In an embodiment, metal parts such as those comprising SS 625 such as the EM pump assembly 5kk may be 3D printed. In an embodiment, the outside of the EM pump assembly may be protected from oxidation. The protection may comprise a coating with an oxidation resistant coating such as one of the disclosure. Alternatively, at least a portion of the EM pump assembly 5kk may be embedded in an oxidation resistant material such as ceramic, quartz, glass, and cement. The oxidation-protected part may be operated in air. In an embodiment, the molten metal such as silver may comprise an additive that may prevent or reduce the oxidation of the interior of the EM pump tube. The additive may comprise a reducing agent such as thiosulfate or an oxidation product of the EM pump tube such that further oxidation is inhibited by stabilization of a protective oxide of the tube wall. Alternatively, the molten metal additive may comprise a base that stabilizes the protective metal oxide on the wall of the pump tube. In an embodiment, the EM pump bus bars 5k2 supply the current that is crossed with the applied magnetic field to produce the Lorentz force on the molten metal in the EM pump tube 5k6. Any oxide coat that is present on the inside of the EM pump tube 5k6 in the region of EM pump bus bars 5k2 may be removed to facilitate current flow from the bus bars through the molten metal in the EM pump tube 5k6. The oxide coat may be removed by at least one electrical, chemical, or mechanical means. The oxide may be removed by chemical etching such as acid etching, chemical reduction, electroplating, electrowinning, vapor deposition, chemical deposition, coating techniques, electrical discharge machining, mechanical machining, abrasion, sand blasting, and other methods known in the art.

In an embodiment, the EM pump assembly may comprise a plurality of ceramics such as conductive and non-conductive ceramics. In an exemplary embodiment, the EM assembly 5kk except the EM pump bus bars 5k2 may comprise a non-conductive ceramic such as an oxide such as Al₂O₃, zirconia, or hafnia, and the EM pump bus bars 5k2 may comprise a conductive ceramic such as ZrC, ZrB₂, or a composite such as ZrC—ZrB₂—SiC. The reservoirs 5c may comprise the same non-conductive ceramic as the EM pump assembly 5kk. In an embodiment, the ceramic EM pump may comprise at least one brazed or metallized ceramic part to form a union between parts.

The electromagnetic pumps may each comprise one of two main types of electromagnetic pumps for liquid metals: an AC or DC conduction pump in which an AC or DC magnetic field is established across a tube containing liquid metal, and an AC or DC current is fed to the liquid through electrodes connected to the tube walls, respectively; and induction pumps, in which a travelling field induces the required current, as in an induction motor wherein the current may be crossed with an applied AC electromagnetic field. The induction pump may comprise three main forms: annular linear, flat linear, and spiral. The pumps may comprise others know in the art such as mechanical and thermoelectric pumps. The mechanical pump may comprise a centrifugal pump with a motor driven impeller.

The molten metal pump may comprise a moving magnet pump (MMP) such as that described in M. G. Hvasta, W. K. Nollet, M. H. Anderson“Designing moving magnet pumps for high-temperature, liquid-metal systems”, Nuclear Engineering and Design, Volume 327, (2018), pp. 228-237 which is incorporated in its entirety by reference. The MMP may MMP's generate a travelling magnetic field with at least one of a spinning array of permanent magnets and polyphase field coils. In an embodiment, the MMP may comprise a multistage pump such as a two-stage pump for MHD recirculation and ignition injection. A two-stage MMP pump may comprise a motor such as an electric motor that turns a shaft. The two-stage MMP may further comprise two drums each comprising a set of circumferentially mounted magnets of alternating polarity fixed over the surface of each drum and a ceramic vessel having a U-shaped portion housing the drum wherein each drum may be rotated by the shaft to cause a flow of molten metal in the ceramic vessel. In another MMP embodiment, the drum of alternating magnets is replaced by two discs of alternating polarity magnets on each disc surface on opposite sites of a sandwiched strip ceramic vessel containing the molten metal that is pumped by rotation of the discs. In another embodiment, the vessel may comprise a magnetic field permeable material such as a non-ferrous metal such as stainless steel or ceramic such as one of the disclosure. The magnets may be cooled by means such as air-cooling or water-cooling to permit operation at elevated temperature.

An exemplary commercial AC EM pump is the CMI Novacast CA15 wherein the heating and cooling systems may be modified to support pumping molten silver. The heater of the EM pump tube comprising the inlet and outlet sections and the vessel containing the silver may be heated by a heater of the disclosure such as a resistive or inductively coupled heater. The heater such as a resistive or inductively coupled heater may be external to the EM pump tube and further comprise a heat transfer means to transfer heat from the heater to the EM pump tube such as a heat pipe. The heat pipe may operate at high temperature such as one with a lithium working fluid. The electromagnets of the EM pump may be cooled by systems of the disclosure such as by water-cooling loops and chiller.

In an embodiment (FIGS. 2I184-2I185), the EM pump 400 may comprise an AC, inductive type wherein the Lorentz force on the silver is produced by a time-varying electric current through the silver and a crossed synchronized time-varying magnetic field. The time-varying electric current through the silver may be created by Faraday induction of a first time-varying magnetic field produced by an EM pump transformer winding circuit 401a. The source of the first time-varying magnetic field may comprise a primary transformer winding 401, and the silver may serve as a secondary transformer winding such as a single turn shorted winding comprising an EM pump tube section of a current loop 405 and a EM pump current loop return section 406. The primary winding 401 may comprise an AC electromagnet wherein the first time-varying magnetic field is conducted through the circumferential loop of silver 405 and 406, the induction current loop, by a magnetic circuit or EM pump transformer yoke 402. The silver may be contained in a vessel such as a ceramic vessel 405 and 406 such as one comprising a ceramic of the disclosure such as silicon nitride (MP 1900° C.), quartz, alumina, zirconia, magnesia, or hafnia. A protective SiO₂ layer may be formed on silicon nitrite by controlled passive oxidation. The vessel may comprise channels 405 and 406 that enclose the magnetic circuit or EM pump transformer yoke 402. The vessel may comprise a flattened section 405 to cause the induced current to have a component of flow in a perpendicular direction to the synchronized time-varying magnetic field and the desired direction of pump flow according to the corresponding Lorentz force. The crossed synchronized time-varying magnetic field may be created by an EM pump electromagnetic circuit or assembly 403c comprising AC electromagnets 403 and EM pump electromagnetic yoke 404. The magnetic yoke 404 may have a gap at the flattened section of the vessel 405 containing the silver. The electromagnet 401 of the EM pump transformer winding circuit 401a and the electromagnet 403 of the EM pump electromagnetic assembly 403c may be powered by a single-phase AC power source or other suitable power source known in the art. The magnet may be located close to the loop bend such that the desired current vector component is present. The phase of the AC current powering the transformer winding 401 and electromagnet winding 403 may be synchronized to maintain the desired direction of the Lorentz pumping force. The power supply for the transformer winding 401 and electromagnet winding 403 may be the same or separate power supplies. The synchronization of the induced current and B field may be through analog means such as delay line components or by digital means that are both known in the art. In an embodiment, the EM pump may comprise a single transformer with a plurality of yokes to provide induction of both the current in the closed current loop 405 and 406 and serve as the electromagnet and yoke 403 and 404. Due to the use of a single transformer, the corresponding inducted current and the AC magnetic field may be in phase.

In an embodiment (FIGS. 2I184-2I185), the induction current loop may comprise the inlet EM pump tube 5k6, the EM pump tube section of the current loop 405, the outlet EM pump tube 5k6, and the path through the silver in the reservoir 5c that may comprise the walls of the inlet riser 5qa and the injector 561 in embodiments that comprise these components. The EM pump may comprise monitoring and control systems such as ones for the current and voltage of the primary winding and feedback control of SunCell power production with pumping parameters. Exemplary measured feedback parameters may be temperature at the reaction cell chamber 5b31 and electricity at MHD converter. The monitoring and control system may comprise corresponding sensors, controllers, and a computer. In an embodiment, the SunCell® may be at least one of monitored and controlled by a wireless device such as a cell phone. The SunCell® may comprise an antenna to send and receive data and control signals.

In an MHD converter embodiment having only one pair of electromagnetic pumps 400, each MHD return conduit 310 is extended and connects to the inlet of the corresponding electromagnetic pump 5kk. The connection may comprise a union such as a Y-union having an input of MHD return conduit 310 and the bosses 308 of the base of the reservoir such as those of the reservoir baseplate assembly 409. In an embodiment comprising a pressurized SunCell® having an MID converter, the injection side of the EM pumps, the reservoirs, and the reaction cell chamber 5b31 operate under high pressure relative to the MHD return conduit 310. The inlet to each EM pump may comprise only the MHD return conduit 310. The connection may comprise a union such as a Y-union having an input of MHD return conduit 310 and the boss of the base of the reservoir wherein the pump power prevents back flow from the inlet flow from the reservoir to the MHD return conduit 310.

In an MHD power generator embodiment, the injection EM pumps and the MHD return EM pump may comprise any of the disclosure such as DC or AC conduction pumps and AC induction pumps. In an exemplary MHD power generator embodiment (FIG. 2I184), the injection EM pumps may comprise an induction EM pump 400, and the MHD return EM pump 312 may comprise an induction EM pump or a DC conduction EM pump. In another embodiment, the injection pump may further serve as the MHD return EM pump. The MHD return conduit 310 may input to the EM pump at a lower pressure position than the inlet from the reservoir. The inlet from MHD return conduit 310 may enter the EM pump at a position suitable for the low pressure in the MHD condensation section 309 and the MHD return conduit 310. The inlet from the reservoir 5c may enter at a position of the EM pump tube where the pressure is higher such as at a position wherein the pressure is the desired reaction cell chamber 5b31 operating pressure. The EM pump pressure at the injector section 5k61 may be at least that of the desired reaction cell chamber pressure. The inlets may attach to the EM pump at tube and current loop sections 5k6, 405, or 406.

The EM pump may comprise a multistage pump (FIGS. 2I186-2I206). The multistage EM pump may receive the input metal flows such as that from the MHD return conduit 310 and that from the base of the reservoir 5c at different pump stages that each correspond to a pressure that permits essentially only forward molten metal flow out the EM pump outlet and injector 5k61. In an embodiment, the multistage EM pump assembly 400a (FIG. 2I188) comprises at least one EM pump transformer winding circuit 401a comprising a transformer winding 401 and transformer yoke 402 through an induction current loop 405 and 406 and further comprises at least one AC EM pump electromagnetic circuit 403c comprising an AC electromagnet 403 and an EM pump electromagnetic yoke 404. The induction current loop may comprise an EM pump tube section 405 and an EM pump current loop return section 406. The electromagnetic yoke 404 may have a gap at the flattened section of the vessel or EM pump tube section of a current loop 405 containing the pumped molten metal such as silver. In an embodiment shown in FIG. 21201, the induction current loop comprising EM pump tube section 405 may have inlets and outlets located offset from the bends for return flow in section 406 such that the induction current may be more transverse to the magnetic flux of the electromagnets 403a and 403b to optimize the Lorentz pumping force that is transverse to both the current and the magnetic flux. The pumped metal may be molten in section 405 and solid in the EM pump current loop return section 406.

In an embodiment, the multistage EM pump may comprise a plurality of AC EM pump electromagnetic circuits 403c that supply magnetic flux perpendicular to both the current and metal flow. The multistage EM pump may receive inlets along the EM pump tube section of a current loop 405 at locations wherein the inlet pressure is suitable for the local pump pressure to achieve forward pump flow wherein the pressure increases at the next AC EM pump electromagnetic circuit 403c stage. In an exemplary embodiment, the MHD return conduit 310 enters the current loop such the EM pump tube section of a current loop 405 at an inlet before a first AC electromagnet circuit 403c comprising AC electromagnets 403a and EM pump electromagnetic yoke 404a. The inlet flow from the reservoir 5c may enter after the first and before a second AC electromagnet circuit 403c comprising AC electromagnets 403b and EM pump electromagnetic yoke 404b wherein the pumps maintain a molten metal pressure in the current loop 405 that maintains a desired flow from each inlet to the next pump stage or to the pump outlet and the injector 5k61. The pressure of each pump stage may be controlled by controlling the current of the corresponding AC electromagnet of the AC electromagnet circuit. An exemplary transformer comprises a silicon steel laminated transformer core 402, and exemplary EM pump electromagnetic yokes 404a and 404b each comprise a laminated silicon steel (grain oriented steel) sheet stack.

In an embodiment, the EM pump current loop return section 406 such as a ceramic channel may comprise a molten metal flow restrictor or may be filled with a solid electrical conductor such that the current of the current loop is complete while preventing molten metal back flow from a higher pressure to a lower pressure section of the EM pump tube. The solid may comprise a metal such as a stainless steel of the disclosure such as Haynes 230, Pyromet® alloy 625, Carpenter L-605 alloy, BioDur® Carpenter CCM® alloy, Haynes 230, 310 SS, or 625 SS. The solid may comprise a refractory metal. The solid may comprise a metal that is oxidation resistant. The solid may comprise a metal or conductive cap layer or coating such as iridium to avoid oxidation of the solid conductor.

In an embodiment, the solid conductor in the conduit 406 that provides a return current path, but prevents silver black flow comprises solid molten metal such as solid silver. The solid silver may be maintained by maintaining a temperature at one or more locations along the path of the conduit 406 that is below the melting point of silver such that it maintains a solid state in at least a portion of the conduit 406 to prevent silver flow in the 406 conduit. The conduit 406 may comprise at least one of a heat exchanger such as a coolant loop, that absence of trace heating or insulation, and a section distanced from hot section 405 such that the temperature of at least one portion of the conduit 406 may be maintained below the melting point of the molten metal.

In an embodiment, the magnetic windings of at least one of the transformers and electromagnets are distanced from the EM pump tube section of a current loop 405 containing flowing metal by extension of at least one of the transformer magnetic yoke 402 and the electromagnetic circuit yoke 404. The extensions allows for at least one of more efficient heating such as inductively coupled heating of the EM pump tube 405 and more efficient cooling of at least one of the transformer windings 401, transformer yoke 402, and the electromagnetic circuits 403c comprising AC electromagnets 403 and EM pump electromagnetic yoke 404. In the case of a two-stage EM pump, the magnetic circuits may comprise AC electromagnets 403a and 403b and EM pump electromagnetic yokes 404a and 404b. At least one of the transformer yokes 402 and electromagnetic yokes 404 may comprise a ferromagnetic material with a high Curie temperature such as iron or cobalt. The windings may comprise high temperature insulated wire such as ceramic coated clad wire such as nickel clad copper wire such as Ceramawire HT. At least one of the EM pump transformer winding circuits or assemblies 401a and EM pump electromagnetic circuits or assemblies 403c may comprise a water-cooling system such as one of the disclosure such as one of the magnets 5k4 of the DC conduction EM pump (FIGS. 2I62-2I183). At least one of the induction EM pumps 400b may comprise an air-cooling system 400b (FIGS. 2I190-2I191). At least one of the induction EM pumps 400c may comprise a water-cooling system (FIG. 2I192). The cooling system may comprise heat pipe such as one of the disclosure. The cooling system may comprise a ceramic jacket to serve as a coolant conduit. The coolant system may comprise a coolant pump and a heat exchanger to reject heat to a load or ambient. The jacket may at least partially house the component to be cooled. The yoke cooling system may comprise an internal coolant conduit. The coolant may comprise water. The coolant may comprise silicon oil.

An exemplary transformer comprises a silicon steel laminated transformer core. The ignition transformer may comprise (i) a winding number in at least one range of about 10 to 10,000, 100 to 5000, and 500 to 25,000 turns; (ii) a power in at least one range of about 10 W to 1 MW, 100 W to 500 kW, 1 kW to 100 kW, and 1 kW to 20 kW, and (iii) a primary winding current in at least one range of about 0.1 A to 10,000 A, 1 A to 5 kA, 1 A to 1 kA, and 1 to 500 A. In an exemplary embodiment, the ignition current is in a voltage range of about 6 V to 10 V and the current is about 1000 A; so a winding with 50 turns operates at about 500 V and 20 A to provide an ignition current of 10 V at 1000 A. The EM pump electromagnets may comprise a flux in at least one range of about 0.01 T to 10 T, 0.1 T to 5 T, and 0.1 T to 2 T. In an exemplary embodiment, about 0.5 mm diameter magnet wire is maintained under about 200° C.

In an embodiment comprising a SunCell® that does not form an alloy or react with aluminum at the cell operating temperature, the molten metal may comprise aluminum. In an exemplary embodiment, the SunCell® such as one shown in FIGS. 2I184-2I206 comprises components that are in contact with the molten aluminum metal such as the reaction cell chamber 5b31 and the EM pump tubes 5k6 that comprise quartz or ceramic wherein the SunCell® further comprises inductive EM pumps and an induction ignition system.

The EM pump tube may be heated with an inductively coupled heater antenna such as a pancake coil antenna. The antenna may be water-cooled. In an embodiment, the reservoirs 5c may be heated with an inductively coupled heater. The heater antenna 5f may comprise two cylindrical helices around the reservoirs 5c that may further connect to a coil such as a pancake coil to heat the EM pump tube. The turns of the opposing helices about the reservoirs may be wound such that the currents are in the same direction to reinforce the magnetic fields of the two coils or opposite directions to cancel in the space between the helices. In an exemplary embodiment, the inductively coupled heater antenna 5f may comprise a continuous set of three turnings comprising two helices circumferential to each reservoirs 5c and a pancake coil parallel to the EM pump tubes as shown in FIGS. 2I182-2I183, 2I186, and 2I190-2I192 wherein both helices are wound clockwise and the current flows from the top to bottom of one helix, flows into the pancake coil, and then flows from the bottom to the top of the second helix. The EM pump tube section of a current loop 405 may be selectively heated by at least one of flux concentrators, additives to the EM pump tube 405 material such as additives to quartz or silicon nitride, and cladding to the pump tube 405 such as carbon sleeves that increase the absorption of RF from the inductively coupled heater. In an embodiment, the EM pump tube section of a current loop 405 may be selectively heated by an inductively coupled heater antenna or resistive heater wire comprising a helix about the pump tube 405. In embodiments, the inductively coupled heater antenna may be replaced by a resistive heater wire such as Kanthal or other of the disclosure. At least one line (FIGS. 2I192-2I203) such as at least one of the MHD return conduit 310, EM pump reservoir line 416, and EM pump injection line 417 may be heated by an inductively coupled heater that may comprise an antenna 415 wrapped around the line wherein the antenna may be water-cooled. The components wrapped with the inductively coupled heater antenna such as 5f and 415 may comprise an inner layer of insulation. The inductively coupled heater antenna can serve a dual function or heating and water-cooling to maintain a desired temperature of the corresponding component. The SunCell may further comprise structural supports 418 that secure components such as the MHD magnet housing 306a, the MHD nozzle 307, and MHD channel 308, electrical output, sensor, and control lines 419 that may be mounted on the structural supports 418, and heat shielding such as 420 about the EM pump reservoir line 416, and EM pump injection line 417.

The EM pump tube section of a current loop 405 may comprise molten metal inlet and outlet channels that connect to corresponding EM pump tube 5k6 sections (FIG. 2I185). Each inlet and outlet of the EM pump tube 5k6 may be fastened to the corresponding reservoir 5c, inlet riser 5qa, and injector 5k61. The fastener may comprise a joint, fastener, or seal of the disclosure. The seal 407a may comprise ceramic glue. The joints may each comprise a flange sealed with a gasket such as a graphite gasket. Each reservoir 5c may comprise ceramic such as a metal oxide connected to a reservoir baseplate that may be ceramic. The baseplate connection may comprise a flange and gasket seal wherein the gasket may comprise carbon. The baseplate may comprise a reservoir baseplate assembly 409 (FIG. 2I187) comprising a baseplate 409a with attached inlet riser 5qa and injector tube 5k61 having nozzle 5q. The tubes may penetrate the base of the reservoir baseplate 409a as bosses 408. The bosses 408 from the reservoir 5c may be connected to the ceramic inlet and outlet of the EM pump tube of the induction-type EM pump 400 by at least one of flanged unions 407 having fasteners such as bolts such as carbon, molybdenum, or ceramic bolts, and a gasket such as a carbon gasket wherein the union comprising at least one ceramic component is operated below the carbo-reduction temperature. In other embodiments, the unions may comprise others known in the art such as Swageloks, slip nuts, or compression fittings. In an embodiment, the ignition current is supplied by a source of electricity having its positive and negative terminals connected to conductive component of one of opposing pump tubes, reservoirs, bosses, and unions.

In an embodiment, the ignition bus bar such as 5k2a may comprise an electrode in contact with a portion of the solidified molten metal of a wet seal joint such as one at the reservoirs 5c. In another embodiment, the ignition system comprises an induction system (FIGS. 2I186, 2I189-2I206) wherein the source of electricity applied to the conductive molten metal to cause ignition of the hydrino reaction provides an induction current, voltage, and power. The ignition system may comprise an electrode-less system wherein the ignition current is applied by induction by an induction ignition transformer assembly 410. The induction current may flow through the intersecting molten metal streams from the plurality of injectors maintained by the pumps such as the EM pumps 400. In an embodiment, the reservoirs 5c may further comprise a ceramic cross connecting channel 414 such as a channel between the bases of the reservoirs 5c. The induction ignition transformer assembly 410 may comprise an induction ignition transformer winding 411 and an induction ignition transformer yoke 412 that may extend through the induction current loop formed by the reservoirs 5c, the intersecting molten metal streams from the plurality of molten metal injectors, and the cross connecting channel 414. The induction ignition transformer assembly 410 may be similar to that of the EM pump transformer winding circuit 401a.

In an embodiment, the ignition current source may comprise an AC, inductive type wherein the current in the molten metal such as silver is produced by Faraday induction of a time-varying magnetic field through the silver. The source of the time-varying magnetic field may comprise a primary transformer winding, an induction ignition transformer winding 411, and the silver may at least partially serve as a secondary transformer winding such as a single turn shorted winding. The primary winding 411 may comprise an AC electromagnet wherein an induction ignition transformer yoke 412 conducts the time-varying magnetic field through a circumferential conducting loop or circuit comprising the molten silver. In an embodiment, the induction ignition system may comprise a plurality of closed magnetic loop yokes 412 that maintain time varying flux through the secondary comprising the molten silver circuit. At least one yoke and corresponding magnetic circuit may comprise a winding 411 wherein the additive flux of a plurality of yokes 412 each with a winding 411 may create induction current and voltage in parallel. The primary winding turn number of each yoke 412 winding 411 may be selected to achieve a desired secondary voltage from that applied to each winding, and a desired secondary current may be achieved by selecting the number of closed loop yokes 412 with corresponding windings 411 wherein the voltage is independent of the number of yokes and windings, and the parallel currents are additive.

The transformer electromagnet may be powered by a single phase AC power source or other suitable power source known in the art. The transformer frequency may be increased to decrease the size of the transformer yoke 412. The transformer frequency may be in at least range of about 1 Hz to 1 MHz, 1 Hz to 100 kHz, 10 Hz to 10 kHz, and 10 Hz to 1 kHz. The transformer power supply may comprise a VFD-variable frequency drive. The reservoirs 5c may comprise a molten metal channel such as the cross connecting channel 414 that connects the two reservoirs 5c. The current loop enclosing the transformer yoke 412 may comprise the molten silver contained in the reservoirs 5c, the cross connecting channel 414, the silver in the injector tube 5k61, and the injected streams of molten silver that intersect to complete the induction current loop. The induction current loop may further at least partially comprise the molten silver contained in at least one of the EM pump components such as the inlet riser 5qa, the EM pump tube 5k6, the bosses, and the injector 5k61.

The cross connecting channel 414 may be at the desired level of the molten metal such as silver in the reservoirs. Alternatively, the cross connecting channel 414 may be at a position lower than the desired reservoir molten metal level such that the channel is continuously filled with molten metal during operation. The cross connecting channel 414 may be located towards the base of the reservoirs 5c. The channel may form part of the induction current loop or circuit and further facilitate molten metal flow from one reservoir with a higher silver level to the other with a lower level to maintain the desired levels in both reservoirs 5c. A differential in molten metal head pressure may cause the metal flow between reservoirs to maintain the desired level in each. The current loop may comprise the intersecting molten metal streams, the injector tubes 5k61, a column of molten metal in the reservoirs 5c, and the cross connecting channel 414 that connects the reservoirs 5c at the desired molten silver level or one that is lower than the desired level. The current loop may enclose the transformer yoke 412 that generates the current by Faraday induction. In another embodiment, at least one EM pump transformer yoke 402 may further comprise the induction ignition transformer yoke 412 to generate the induction ignition current by additionally supplying the time-varying magnetic field through an ignition molten metal loop such as the one formed by the intersecting molten metal streams and the molten metal contained in the reservoirs and the cross connecting channel 414. The reservoirs 5c and the channel 414 may comprise an electrical insulator such as a ceramic. The induction ignition transformer yoke 412 may comprise a cover 413 that may comprise at least one of an electrical insulator and a thermal insulator such as a ceramic cover. The section of the induction ignition transformer yoke 412 that extends between the reservoirs that may comprise circumferentially wrapped inductively coupled heater antennas such as helical coils may be thermally or electrically shielded by the cover 413. The ceramic of at least one of the reservoirs 5c, the channel 414, and the cover 413 may be one of the disclosure such as silicon nitride (MP 190° C.), quartz such as fused quartz, alumina, zirconia, magnesia, or hafnia. A protective SiO₂ layer may be formed on silicon nitrite by controlled passive oxidation.

The ceramic parts such as quartz parts may be cast using a mold such as carbon, SiC on carbon, SiC on quartz, SiC, Al₂O₃, MgO, ZrO₂, or other refractory inert mold. In an embodiment, the cell components may comprise Pyrex that may be cast according to methods known by those skilled in the art. In an exemplary embodiment, the mold to cast quartz by hot or cold liquid methods known in the art such as that of Hellma Analytics (http://www.hellma-analytics.com/assets/adb/32/32e6a909951dc0e2.pdf) comprises four parts comprising two mirror pairs of inner and outer surfaces of the cell components such as the reservoirs 5c and reaction cell chamber 5b31. In an exemplary embodiment, the cast may form semicircles indentations in each half of the reservoir at the base wherein a hollow tube is inserted into each semicircular indentation, and the two halves of each reservoir are brought together to house the tube such that it forms the channel connecting the reservoirs 414. The cast parts and tube may be glued or fused together.

In an embodiment, the cross-connecting channel 414 maintains the reservoir silver levels near constant. The SunCell® may further comprise submerged nozzles 5q of the injector 5k61. The depth of each submerged nozzle and therefore the head pressure through which the injector injects may remain essentially constant due to the about constant molten metal level of each reservoir 5c. In an embodiment comprising the cross-connecting channel 414, inlet riser 5qa may be removed and replaced with a port into the reservoir boss 408 or EM pump reservoir line 416.

At least one of the transformer windings 401 and 411, electromagnets 403, yokes 402, 404, and 412, and magnetic circuits 401a, 403a, and 410 of at least one of the EM pumps and the ignition system may be shielded from the RF magnetic field of the inductively coupled heater to reduce the heating effect. The shield may comprise a Faraday cage. The cage wall thickness may be greater than the skin depth of the RF field of the inductively coupled heater. In an embodiment, the ignition transformer yoke or core 412 may be shield for the RF of the inductively coupled heater by a low-pas filter. In an embodiment comprising an induction ignition system 410, the ignition transformer yoke 412 may be at least partially cooled by proximity of the water-cooled antenna 5f that may further serve to cool at least one of the SunCell® and reservoirs 5c during operation. In an embodiment, the ignition transformer yoke 412 may be externally cooled. In an exemplary embodiment, at least one of the ignition transformer assembly 410 or primary comprising components of a yoke 412 or core and the winding 411 may be thermally insulated and water-cooled by a jacket such as a Teflon jacket that surrounds the component. The ignition transformer assembly 410 may further comprise a low frequency filter/Faraday cage around the core 412 to shield it from RF heating power. In an embodiment, the components such as the EM pump tube 405, MHD return conduits 310, and reservoirs 5c may be heated with a resistive heater or flame heater such as a hydrogen flame heater wherein the electromagnets and transformer components maybe protected from excessive heating by distancing the temperature sensitive components such as the windings and cores of the electromagnets and the windings and cores of the transformer primaries from the hot zones as shown in FIGS. 2I196-2I203.

In an embodiment, the ignition transformer yoke 412 may be retractable by an actuator such as a mechanical, pneumatic, hydraulic, electromagnetic, or other actuator known in the art. The yoke may be removed during generator heating with the inductively coupled heater and engaged to maintain the ignition. The yoke may comprise a plurality of pieces such as an E shape with a removable bar across the end to open and close the magnetic circuit as the yoke is removed and engaged, respectively. The yoke may comprise a UI or EI type. In an exemplary embodiment, the ignition core 412 is mechanically removed during startup and engaged once the generator is up to operating temperature. Alternatively, the heater may comprise a resistive heater that does not significantly heat the yoke wherein the heater coils may be permanent. The resistive heater may comprise a refractory resistive filament or wire that may be wrapped around the components to be heated. Exemplary resistive heater elements and components may comprise high temperature conductors such as carbon, Nichrome, 300 series stainless steels, Incoloy 800 and Inconel 600, 601, 718, 625, Haynes 230, 188, 214, Nickel, Hastelloy C, titanium, tantalum, molybdenum, TZM, rhenium, niobium, and tungsten. The filament or wire may be potted in a potting compound to protect it from oxidation. The heating element as filament, wire, or mesh may be operated in vacuum to protect it from oxidation. An exemplary heater comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Another exemplary filament is Kanthal APM that forms a non-scaling oxide coating that is resistant to oxidizing and carburizing environments and can be operated to 1475° C. The heat loss rate at 1375 K and an emissivity of 1 is 200 kW/m² or 0.2 W/cm². Commercially available resistive heaters that operate to 1475 K have a power of 4.6 W/cm². The heating may be increased using insulation external to the heating element.

In an embodiment, the metal that flows into the EM pump components such as the pump tube 5k6 and 405 may be heated well above the metal melting point such that the metal does not solidify as it passes through the pump. The superheating of the flowing molten metal may remove or lessen the requirement of the heating of the EM pump components such as the pump tube. In an exemplary embodiment, the super heating of the in flowing molten metal may at least partially reduce the requirement for heating with the antenna 5f of the inductively coupled heater or the resistive heater.

The SunCell® may comprise a heat source to heat at least one component during operational startup. The heat source may be selected to at least one of avoid excessive heating of the yoke of at least one of the inductive EM pump and the inductive ignition system. The heat source may be permissive of high efficiently heat transfer to an external heat exchanger of a thermal power source embodiment of the SunCell®. The heat may maintain the molten metal for the molten metal injection system such as the dual molten metal injection system comprising EM pumps. In an embodiment, the SunCell® comprises a heater or source of heating such as at least one of a chemical heat source such as a catalytic chemical heat source, a flame or combustion heat source, a resistive heater such as a refractory filament heater, a radiative heating source such as an infrared light source such as a heat lamp or high-power diode light source, and an inductively coupled heater.

The radiative heating source may comprise a means to scan the radiant power over a surface to be heated. The scanning means may comprise a scanning mirror. The scanning means may comprise at least one mirror and may further comprise a means to move the mirror over a plurality of positions such as a mechanical, pneumatic, electromagnetic, piezoelectric, hydraulic, and other actuator known in the art.

The heater 415 may be a resistive heater or an inductively coupled heater. An exemplary heater 415 comprises Kanthal A-1 (Kanthal) resistive heating wire, a ferritic-chromium-aluminum alloy (FeCrAl alloy) capable of operating temperatures up to 1400° C. and having high resistivity and good oxidation resistance. Additional FeCrAl alloys for suitable heating elements are at least one of Kanthal APM, Kanthal AF, Kanthal D, and Alkrothal. The heating element such as a resistive wire element may comprise a NiCr alloy that may operate in the 1100° C. to 1200° C. range such as at least one of Nikrothal 80, Nikrothal 70, Nikrothal 60, and Nikrothal 40. Alternatively, the heater 415 may comprise molybdenum disilicide (MoSi₂) such as at least one of Kanthal Super 1700, Kanthal Super 1800, Kanthal Super 1900, Kanthal Super RA, Kanthal Super ER, Kanthal Super HT, and Kanthal Super NC that is capable of operating in the 1500° C. to 1800° C. range in an oxidizing atmosphere. The heating element may comprise molybdenum disilicide (MoSi₂) alloyed with Alumina. The heating element may have an oxidation resistant coating such as an Alumina coating. The heating element of the resistive heater 415 may comprise SiC that may be capable of operating at a temperature of up to 1625° C. The heater may comprise insulation to increase at least one of its efficiency and effectiveness. The insulation may comprise a ceramic such as one known by those skilled in the art such as an insulation comprising alumina-silicate. The insulation may be at least one of removable or reversible. The insulation may be removed following startup to more effectively transfer heat to a desired receiver such as ambient surroundings or a heat exchanger. The insulation may be mechanically removed. The insulation may comprise a vacuum-capable chamber and a pump, wherein the insulation is applied by pulling a vacuum, and the insulation is reversed by adding a heat transfer gas such as a noble gas such as helium. A vacuum chamber with a heat transfer gas such as helium that can be added or pumped off may serve as adjustable insulation.

The resistive heater 415 may be powered by at least one of series and parallel wired circuits to selectively heat SunCell® different components. The resistive heating wire may comprise a twisted pair to prevent interference by systems that cause a time-varying field such as induction systems such as at least one induction EM pump, an induction ignition system, and electromagnets. The resistive heating wires may be oriented such that any linked time-varying magnetic flux is minimized. The wire orientation may be such that any closed loops are in a plane parallel with the magnetic flux. At least one of the catalytic chemical heat source and flame or combustion heat source may comprise a fuel such as a hydrocarbon such as propane and oxygen or hydrogen and oxygen. The SunCell® may comprise an electrolyzer that may supply about a stoichiometric mixture of H₂ and O₂. The electrolyzer may comprise a gas separator to supply at least one of H₂ or O₂ separately. The electrolyzer may comprise a high-pressure electrolysis unit such as one having a proton-exchange membrane for a separate source of at least one of H₂ and O₂. The electrolysis unit may be powered by a battery during startup. The SunCell® may comprise a gas storage and supply system for H₂ and O₂ gas from H₂O electrolysis. The gas storage may store at least one of the H₂ and O₂ gas from H₂O electrolysis over time. The electrolysis power over time may be provided by the SunCell® or the battery. The storage may release the gases as fuel to the heater at a rate to achieve higher power than that available from the battery. Electrolysis can be better than 90% efficient. Hydrogen-oxygen recombination on a catalyst and combustion can be almost 100% efficient.

In an embodiment, the heating system comprises at least one of pipes, manifolds, and at least one housing to supply at least one fuel or fuel mixture such as at least one of H₂ and O₂ to a surface impregnated with a catalyst to burn the fuel gases over the surface of at least one component of the SunCell® to serve as the heating source. The maximum temperature of a stoichiometric mixture of hydrogen and oxygen is about 2800° C. The surface of any component to be heated may be coated with a hydrogen-oxygen recombiner catalyst such as Raney nickel, copper oxide, or a precious metal such as platinum, palladium, ruthenium, iridium, rhenium, or rhodium. Exemplary catalytic surfaces are at least one of Pd, Pt, or Ru coated alumina, silica, quartz, and alumina-silicate.

In an embodiment, the catalytic chemical heater such as one that recombines H₂+O₂ may comprise at least one of (i) SiO₂ supported Pt, Ni, Rh, Pd, Ir, Ru, Au, Ag, Re, Cu, Fe, Mn, Co, Mo, or W, (ii) Zeolite supported Pt, Rh, Pd, Ir, Ru, Au, Re, Ag, Cu, Ni, Co, Zn, Mo, W, Sn, In, Ga, and (iii) at least one of Mullite, SiC, TiO₂, Zr₂, Ce₂, Al₂O₃, SiO₂, and mixed oxides supported noble metals, noble metal alloys, and noble metal mixtures. The catalyst may comprise a supported bimetallic such as one comprising Pt, Pd Ir, Rh and Ru. Exemplary bimetallic catalysts are supported Pd—Ru, Pd—Pt, Pd—Ir, Pt—Ir, Pt—Ru and Pt—Rh. The catalytic chemical heater may comprise a material of a catalytic converter such as supported Pt. At least one of a ceramic and catalytic metal coat may be applied by a method of the disclosure. In an exemplary embodiment, a noble metal is applied to the SunCell® component by thermal spray or other coating technique. In an embodiment, the coating is applied by dip-coating the catalyst on the SunCell® components such as a quartz wall or conduit. The quartz may be pre-coated with a base coat such as high surface-area SiO₂ coating before the catalyst coating is applied or the coating is impregnated with noble metal catalyst. Fine particles of the coating may be suspended in a liquid such as water to form slurry such as about a 60 wt % water slurry into which the SunCell component is dip to form the dip-coating. The dip-coat may be heat treated between a plurality of dip-coatings. An exemplary base coating thickness is about 200 to 300 um. The catalyst coating comprising a noble metal may be applied by dissolving or suspending the metal in a liquid such as water and dip-coating or spray coating the base coating. A coating of varying catalytic activity between SunCell® components or over the area of a SunCell® component may be selectively applied. The variation in activity may be achieved by application with partial masking to full masking to achieve the desired catalytic activity on the corresponding surface coated.

An exemplary embodiment comprising a chemical heater is shown in FIGS. 2I204-2I206. The SunCell® may comprise a water tank 429 that supplies an electrolyzer 430 such as a high-pressure proton exchange membrane electrolyzer which provides H₂+O₂. The gas may be flowed over the surface to maintain the reaction to provide a desired heating rate. The gas may be confined in a housing 427 that is resistant to oxidation such as a cast iron, ceramic, or oxidation resistant stainless steel such as SS 625. The housing may comprise a dehumidifier 426, condensor, or vent for removal of the product H₂O. The water may be recycled the water tank 429 and then to the electrolyzer 430 wherein the water resupply and electrolysis gas system may be closed. The SunCell® may comprise at least one heat exchanger 428 to remove heat from the housing 427. The SunCell® may comprise a computer and control electronics 431 that controls the operation of the SunCell® such as the operation of the chemical heater and power generation. The operational performance data may be wirelessly communicated to an operator. The computer and controls system 431 may comprise a cell phone.

In an embodiment, the combustible mixture of hydrogen and oxygen may further comprise a dilution gas such as a noble gas such as argon or nitrogen to prevent the H₂+O₂ mixture from exploding. The dilution and explosion suppression gas such as an inert gas may be added to the sealed chamber, and the H₂+O₂ combustion gases may be flowed in the sealed chamber at a rate to maintain a desired rate of heating of the SunCell® components. Controlling the gas parameters such as the combustion gas flow rate and partial pressure as well as the identity and partial pressure of the dilution gas may control the heating rate. The gas parameters may be controlled while considering the factors that influence the rate of recombination such as the recombination catalyst temperature, the total gas pressure, and the partial pressure of the combustion gases. The total gas pressure may be in at least one range such as about 0.1 atm to 100 atm, 0.5 atm to 50 atm, and 1 atm to 10 atm. The combustion gas pressure may be in at least one range such as about 0.1 atm to 100 atm, 0.5 atm to 50 atm, and 1 atm to 10 atm. To prevent explosion, the stoichiometric mixture of H₂+O₂ may be maintained at about 5 mole % or less. In an exemplary embodiment, selected components of the SunCell® are heated by the recombination of a 4% stoichiometric mixture of H₂+O₂ with a dilution gas. At least one of the flow rates of the combustion gas and the mixture comprising the combustion gas and the dilution gas may be controlled to maintain a desired heating power. Given that the energy of combustion is 285 I/mole, the flow rate of the stoichiometric mixture of H₂ and O₂ per watt is at least 1 J/s/285 kJ/mole=3.5 micromoles/s. In an embodiment, the SunCell® comprises a gas control system to supply at least one of the combustion gases and dilution gas. The gas control system may comprise at least one of valves, mass flow controller, controllers, sensors, pumps, tanks, and a computer.

In an embodiment, the dilution gas may comprise a heat transfer gas such as helium. The heat transfer gas may transfer excess heat from at least one the SunCell® component to a heat exchanger that may comprise a heater component such as 114. The heat transfer may to at least one of cool the SunCell® component and heat a coolant of a heat exchanger 114 of a SunCell® heater. The heat transfer gas pressure may be adjusted to control the heat transfer.

The flame or combustion heat source or heater may comprise at least one burner or nozzle with corresponding flow conduits and valves to control the distribution of fuel gas flow to different sections of the generator to be heated. The SunCell® flame heater may comprise a series or plurality of burners or nozzles comprising gas conduits or tubes that supply the fuel to the burners or nozzles. The flow may be regulated by valves, mass flow controller, controllers, sensors, pumps, tanks, and a computer. The gas supply may comprise hydrogen that is burned in air. In an exemplary embodiment, the flame heater comprises a plurality of nozzles for H₂ to flow to the outside atmosphere to become ignited to support a heating flame at each nozzle that heats a desired SunCell® component or a section of a SunCell® component. The gas supply may comprise about a stoichiometric mixture of hydrogen and oxygen. Hydrogen and oxygen may be supplied separately and mixed before combustion or during combustion. Alternatively, the SunCell may comprise a fuel supply comprising a hydrocarbon such as propane wherein the fuel supply may further comprise oxygen. At least one of the hydrocarbon supply and oxygen supply may comprise a tank of the corresponding pure gas or a mixture of the gases. In an embodiment, the oxygen supply may comprise the atmosphere. The nozzles may be directed to the surface of the component to be heated. Each nozzle may comprise a geometry such as fan-shape or another known in the art to spread the flame is a desired distribution such as a fan-shape to cover a desired heating area more uniformly.

In an embodiment, the SunCell® such as one with a MHD converter comprises a plurality of burners distributed to apply flame about uniformly over the surface of components to be heated. The burners may heat the generator during startup. Each burner may be supplied by a single gas line that flows about a stoichiometric mixture of H₂+O₂ from a source such as at least one tank or directly from a water electrolysis unit. The gas may be flowed in a manner to prevent the flame from traveling back into the nozzle and gas line. The gas pressure and flow rate to each burner may be maintained such that the gas velocity at each burner nozzle exit is higher than the flame propagation speed such as about 6 m/s.

In an embodiment, the source of H₂+O₂ gas may comprise an oxyhydrogen torch system such as one comprising a design like a commercially unit such as Honguang H160 Oxygen Hydrogen HHO Gas Flame Generator. Given the electrolysis voltage of H₂O 1.48 V and a typical electrolysis efficiency of about 90%, the required current is about 0.75 A per 1 W burner. In an embodiment, a plurality of burners may be supplied by a common gas line such as one that supplies a stoichiometric mixture of H₂+O₂. The flame heater may comprise a plurality of such gas lines and burners. The lines and burners may be arranged in a suitable structure to achieve the desired heating of the SunCell® components. The structure may comprise at least one helix such as the single helix oxyhydrogen flame heater 423 shown in FIG. 2I204 having a gas line 424 and a plurality of burners or nozzles 425. In an alternative design also shown in FIG. 2I204, the oxyhydrogen flame heater 423 may comprise a plurality of gas lines 424 and a plurality of burners or nozzles 425 to achieve a series of annular rings about the SunCell® components to be heated. A further exemplary structure to give a good heating surface coverage of the SunCell® components is a DNA-like double helix or a triple helix. Linear shaped components such as MHD return conduit 310 may be heated by at least one linear-burner structure.

The heater may further comprise at least one heat transfer means such as heat transfer blocks, heat pipes, heat spreaders and other heat transfer means known in the art. The heat transfer means may comprise an oxidation resistant material having a high thermal conductivity such as corrosion resistant stainless steel (SS) such as SS 625 and cast iron. The flame heater may comprise at least one burner and a means to move or scan the at least one burner over a plurality of positions such that the flame covers a larger area. The scanner may comprise at least one of a cam and a mechanical, pneumatic, electromagnetic, piezoelectric, hydraulic, and other actuator known in the art. The movement may be programmed to control the dwell time and position of the burner over the surfaces to be heated. The fuel gas supply lines may comprise flexible lines to accommodate the movement. The burner may comprise a flame spreader to spread the flame over a larger area to be heated. The SunCell® flame heater may comprise at least one of a pilot light and an igniter such as an electronic igniter such as spark gap or resistive igniter that may be powered by a battery. The heater may further comprise insulation about the gas burners. The hydrogen or hydrogen-oxygen mixture fuel may be produced on demand to limit the combustible gas inventory to increase safety. In the case that a combustible mixture such as a hydrogen-oxygen mixture is flowed through the burners, the burners may comprise a flash back arrestor to confine the combustion reaction external to the burner gas supply. The rapid heat-up ability of the combustion heating is favorable for stop-start applications such as motive ones.

The rate that fuel is supplied to at least one of the chemical catalytic and combustion heater may be such that the SunCell® component is not thermally shocked. The heating rate may be controlled by controlling at least one of the gas flow rate and the stoichiometry of the gas. The heater may comprise at least one of valves, flow regulators, flow meters, pressure controller, nozzles, a controller, and a computer to control the gas flow rate and stoichiometry of the combustible gas or gas mixture to the external surface of each cell component that is heated. The SunCell® may comprise a material that is resistant to thermal shock such as quartz or fused silica.

The SunCell® may comprise a heat transfer means to transfer heat from a source such as a flame burner to a SunCell® component or between components. The heat exchanger may transfer heat passively. An exemplary passive heat transfer means comprises a heat pipe or an isothermal furnace liner such as one produced by Thermacore that is incorporated by reference (https://www.thermacore.com/products/isothermal-furnace-liners.aspx). The heat pipe may comprise materials that operate at high temperature such as at least one of carbon, 300 series stainless steels, Incoloy 800 and Inconel 600, 601, 718, 625, Haynes 230, 188, 214, Nickel, Hastelloy C, titanium, tantalum, molybdenum, TZM, rhenium, niobium, and tungsten. The working medium that may be wicked in the heat pipe may comprise sodium, lithium, or other suitable high temperature medium known in the art.

In an embodiment, the SunCell® may further comprise a heat transfer means such as one comprising a heat exchanger and heat transfer medium or coolant to transfer heat from at least one hotter component to at least one other component. The heat exchanger may transfer heat from the flame heater to at least one SunCell® component. The heat transfer medium or coolant may comprise a metal with at least one property of a low melting point, a high boiling point, a high heat capacity, a high conductivity, and a high heat of vaporization. An exemplary coolant is gallium having a melting point of 29.8° C., and heat capacity of 25.86 J/(mol K), a boiling point of 2400° C., and a heat of vaporization of 256 kJ/mol. The heat exchanger may comprise a heated tank such as at least one of a flame heater, inductively coupled heater, or resistive heater heated tank, a coolant pump, and coolant conduit to circulate coolant such as molten gallium and transfer heat between components. The pump may comprise an electromagnetic pump such as an inductive AC type or another of the disclosure or known in the art. The conduit may comprise a refractory material that is resistant to oxidation such as an oxide ceramic or an oxidation resistant stainless steel such as SS 625. An exemplary oxide conduit material that can be molded and formed around the SunCell® components to be heated is quartz or fused silica. The exchanger such as quartz conduit may comprise a thermal contact medium such as thermal or heat transfer paste to better thermally couple to the SunCell® component to be heated. The heat transfer paste may be resistant to oxidation. The quartz conduit may be operated to high temperature such as up to its softening temperature of 1683° C. The molding and forming may be achieved with an oxy-hydrogen torch. In another embodiment, the ceramic may comprise one of the disclosure such as a carbide with a high thermal conductivity such as ZrC, HfC, or WC or a boride such as ZrB₂ or composites such as ZrC—ZrB₂, ZrC—ZrB₂—SiC, and ZrB₂ with 20% SiC composite that may work up to 1800° C. In an embodiment, the coolant may be operated under boiling conditions. The coolant may be vaporized, transported in the conduit, and condensed at the site to be heated wherein the large heat of vaporization of the coolant may increase the effectiveness of the heating and increase the heating rate.

In an embodiment, the heat from the flame heater may be transferred by at least one of convection, radiation, and conduction. The heat may be transferred from the flame to a component of the SunCell® to be heated by forced gas convention such as forced air or forced coolant gas convection. The SunCell® heater may comprise a convection heat transfer means such as one comprising a gas duct system, a gas blower or circulator, and a gaseous coolant. The coolant gas may comprise a noble gas such as helium or argon that may be recirculated by a blower or fan in the gas ducts.

In an embodiment, the heater such as a resistive, burner, or heat exchanger type may heat from inside of the SunCell component such as inside of the reservoir 5c through an internal well that may be cast in the bottom of the reservoir for example.

The ignition current may be time varying such as about 60 Hz AC, but may have other characteristics and waveforms such as a waveform having a frequency in at least one range of 1 Hz to 1 MHz, 10 Hz to 10 kHz, 10 Hz to 1 kHz, and 10 Hz to 100 Hz, a peak current in at least one range of about 1 A to 100 MA, 10 A to 10 MA, 100 A to 1 MA, 100 A to 100 kA, and 1 kA to 100 kA, and a peak voltage in at least one range of about 1 V to 1 MV, 2 V to 100 kV, 3 V to 10 kV, 3 V to 1 kV, 2 V to 100 V, and 3 V to 30 V wherein the waveform may comprise a sinusoid, a square wave, a triangle, or other desired waveform that may comprise a duty cycle such as one in at least one range of 1% to 99%, 5% to 75%, and 10% to 50%. To minimize the skin effect at high frequency, the windings such as 411 of the ignition system may comprise at least one of braided, multiple-stranded, and Litz wire. In an embodiment, controlling the frequency of the ignition current controls the reaction rate of the hydrino reaction. Controlling the frequency of the power supply of the induction ignition winding 411 may control the frequency of the ignition current. The ignition current may be an induction current caused by a time varying magnetic field. The time varying magnetic field may influence the hydrino reaction rate. In an embodiment, at least one of the strength and the frequency of the time varying magnetic field is controlled to control the hydrino reaction rate. The strength and the frequency of the time varying magnetic field may be controlled by controlling the power supply of the induction ignition winding 411.

In an embodiment, the ignition frequency is adjusted to cause a corresponding frequency of hydrino power generation in a least one of the reaction cell chamber 5b31 and the MHD channel 308. The frequency of the power output such as about 60 Hz AC may be controlled by controlling the ignition frequency. The ignition frequency can be adjusted by varying the frequency of the time-varying magnetic field of the induction ignition transformer assembly 410. The frequency of the induction ignition transformer assembly 410 may be adjusted by varying the frequency of the current of the induction ignition transformer winding 411 wherein the frequency of the power to the winding 411 may be varied. The time-varying power in the MHD channel 308 may prevent shock formation of the aerosol jet flow. In another embodiment, the time-varying ignition may drive a time-varying hydrino power generation that results in a time-varying electrical power output. The MHD converter may output AC electricity that may also comprise a DC component. The AC component may be used to power at least one winding such as at least one of one or more of the transformer and the electromagnet windings such as at least one of the winding of the EM pump transformer winding circuit 401a and the winding of the electromagnets of the EM pump electromagnetic circuit 403c.

The pressurized SunCell® having an MHD converter may operate without a dependency on gravity. The EM pumps such as 400 such as two-staged air-cooled EM pumps 400b may be located in a position to optimize at least one of the packing and the minimization of the molten metal inlet and outlet conduits or lines. An exemplary packaging is one wherein the EM pumps are located midway between the end of the MHD condensation section 309 and the base of the reservoirs 5c (FIGS. 2I193-2I198).

In an embodiment, the silver vapor-silver aerosol mixture that exits the MHD nozzle 307 and enters the MHD channel 308 comprises a majority liquid fraction. To achieve the majority liquid fraction at the MHD channel 308 inlet, the mixture may comprise a majority liquid at the entrance to the MHD nozzle 307. The thermal power of the reaction cell chamber 5b31 generated by the hydrino reaction may be majority converted to kinetic energy by the MHD nozzle 307. In an embodiment to achieve the condition that the majority of energy inventory at the exit of the MHD nozzle 307 is kinetic energy, the mixture must be a majority liquid fraction, and the temperature and pressure of the mixture should approach that of the molten metal at its melting point. To convert a larger fraction of the thermal energy inventory of the mixture into kinetic energy, the nozzle area of the diverging section of a converging-diverging MHD nozzle 307 such as a de Laval nozzle must increase. As the thermal energy of the mixture is converted to kinetic energy in the MHD nozzle 307, the temperature of the mixture drops with a concomitant pressure drop. The low-pressure condition corresponds to a low vapor density. The low vapor density decreases the cross section to transfer forward momentum and kinetic energy to the liquid fraction of the mixture. In an embodiment, the nozzle length may be increased to create a longer liquid acceleration time before nozzle exit. In an embodiment, the cross sectional area of the aerosol jet at the MHD nozzle exit may be decreased. The area decrease may be achieved by one or more of at least one focusing magnet, baffles, and other means known in the art. The focused aerosol jet having a decreased area may permit the MHD channel 308 cross sectional area to be smaller. The MHD channel power density may be higher. The MHD magnets 306 may be smaller due to smaller volume of the magnetized channel 308.

In an embodiment, the temperature of the mixture at the entrance of the MHD channel 308 is close to the melting point of the molten metal. In the case of silver, the mixture temperature may be in at least one range of about 965° C. to 2265° C., 1000° C. to 2000° C., 1000° C. to 1900° C., and 1000° C. to 1800° C. In an embodiment, the silver liquid may be recirculated to the reservoirs 5c by the EM pumps 400, 400a, 400b, or 400c to recover at least a portion of the thermal energy in the liquid.

In an embodiment comprising unions comprising ceramic parts and carbon gaskets, the temperature of the recirculated silver may be below at least one of the carbo-reduction temperature of graphite with the ceramic and the failure temperature of the materials of the SunCell® components such as ceramic components. In an exemplary embodiment comprising yttria-stabilized-zirconia parts such as return conduits 310, EM pump tube section of the current loop 405, reservoirs 5c, reaction cell chamber 5b31, MHD nozzle 307, MHD channel 308, and MHD condensation section 309 having at least one carbon-gasketed flange union 407 between ceramic components, the silver temperature is lower than about 1800° C. to 2000° C. In an embodiment, the bolt-holes of the flange union 407 may be slotted to permit expansion. Alternatively, a section such as the elbow of the MHD return conduit 310 such as one comprising quartz may be maintained at a temperature at which it is somewhat malleable. The power of the aerosol comprising kinetic energy and thermal energy may be converted to electricity in the MHD channel. The aerosol kinetic energy may be converted to electricity by a liquid MHD mechanism. Some residual thermal power such as that of any vapor of the mixture in the MHD channel 308 may be converted to electricity by the Lorentz force acting on the corresponding vapor. The conversion of thermal energy causes a drop in mixture temperature. The silver vapor pressure may be low corresponding to the low mixture temperature. The MHD channel 308 may be maintained at a low background pressure such as a pressure in at least one range of about 0.001 Torr to 760 Torr, 0.01 Torr to 100 Torr, 0.1 Torr to 10 Torr to prevent the aerosol jet from the nozzle 307 from undergoing shock such as condensation shock or turbulent flow whereby the aerosol creates increased pressure such as back pressure in the MHD channel 308.

In an embodiment, the vapor fraction of the mixture is minimized at the nozzle inlet to reduce it at the nozzle outlet. The vapor fraction may be in at least one range of about 0.01 to 0.3, 0.05 to 0.25, 0.05 to 0.20, 0.05 to 0.15, and 0.05 to 0.1. Given nozzle exemplary inlet parameters of 20 atm pressure, 0 m/s velocity, 3253 K temperature, 0.9 liquid mass fraction of the mixture, sonic velocity 137 m/s, Mach number 0, and 0 kJ/kg kinetic energy, exemplary parameters of the mixture at the nozzle outlet are about those given in TABLE 1.

TABLE 1
Nozzle Outlet Parameters for Initial Inlet Parameters of Pressure of
20 atm, Liquid Fraction of 0.9, and Mass Flow of 1 kg/s.

| | Pressure [atm] | | | | | |
|---|---|---|---|---|---|---|
| | | Nozzle | | | | |
| Parameter | 20 | Throat | 1 | 0.1 | 0.01 | 0.001 |
| Velocity (m/s) | 0 | 149 | 412 | 548 | 647 | 727 |
| Temperature (K) | 3253 | 3108 | 2480 | 2104 | 1830 | 1613 |
| Liquid Mass | 0.9 | 0.887 | 0.847 | 0.836 | 0.832 | 0.833 |
| Fraction | | | | | | |
| Kinetic Energy | 0 | 11.2 | 84.7 | 150 | 209 | 264 |
| (kJ/kg) | | | | | | |
| Sonic Velocity (m/s) | 137 | 149 | 174 | 168 | 159 | 155 |
| Mach Number | 0 | 1 | 2.37 | 3.26 | 4.06 | 4.71 |
| Nozzle Radius (cm) | | 0.656 | 1.50 | 3.94 | 10.9 | 31.7 |
| Liquid Volume | 9717 | 5450 | 340 | 35.6 | 3.80 | 0.397 |
| Fraction (ppm) | | | | | | |

In an embodiment, the vapor may be at least partially condensed at the end of the MHD channel such as in the MHD condensation section 309. The heat exchanger 316 may remove heat to cause the condensation. Alternatively, the vapor pressure may be sufficiently low that the MHD efficiency is increased by not condensing the vapor wherein the vapor maintains a static equilibrium pressure in the MHD channel 308. In an embodiment, the Lorentz force is greater than the collision frictional force of any uncondensed vapor in the MHD channel 308. The Lorentz force may be increased to that desired by increasing the magnetic field strength. The magnetic flux of the MHD magnets 306 may be increased. In an embodiment, the magnetic flux may be in at least one range of about 0.01 T to 15 T, 0.05 T to 10 T, 0.1 T to 5 T, 0.1 T to 2 T, and 0.1 T to 1 T. In an embodiment, the silver vapor is condensed such that the heat of vaporization heats the silver that is recycled to the reservoirs or the EM pump tube of a two-stage EM pump wherein the output is the injector 5k61. The vapor may be compressed with compressor 312a. The compressor may be connected to a two-stage EM pump such as 400c.

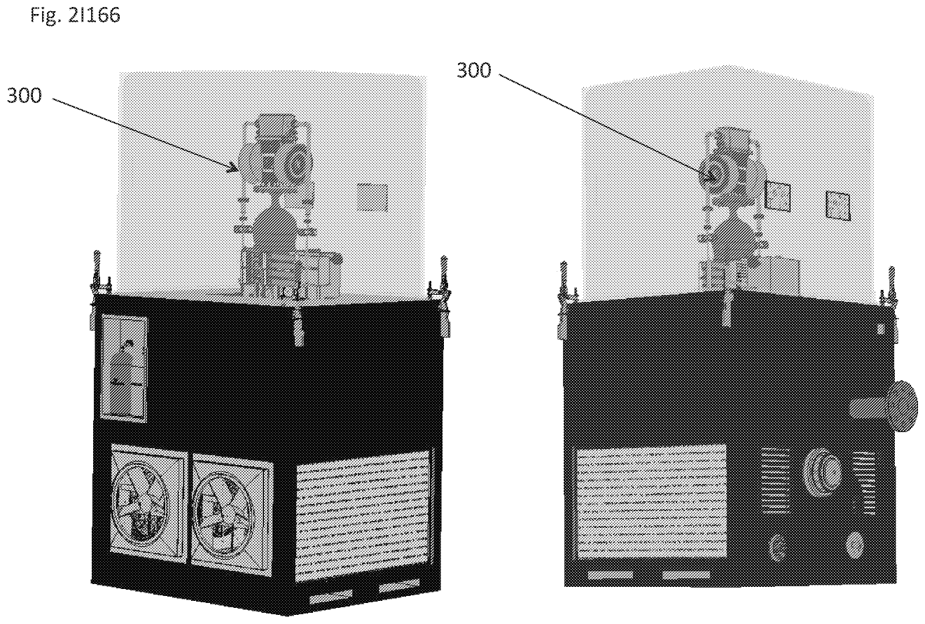

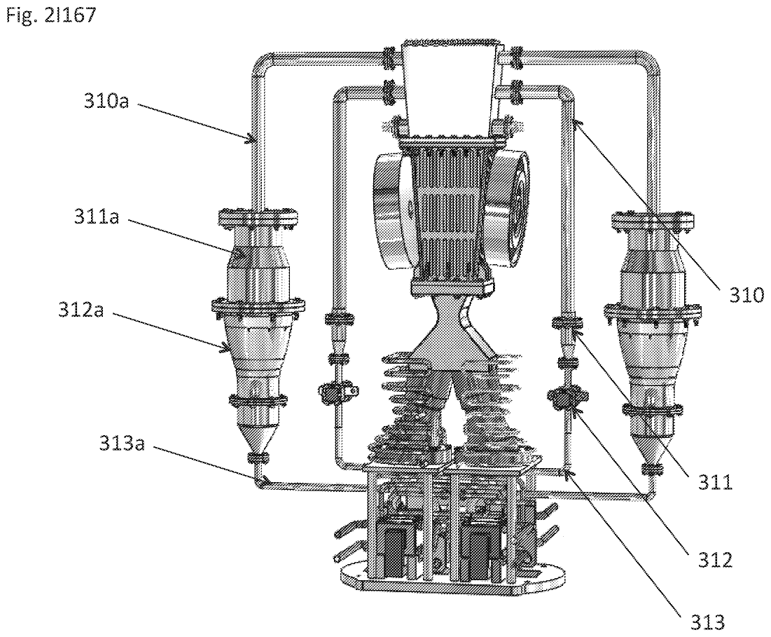

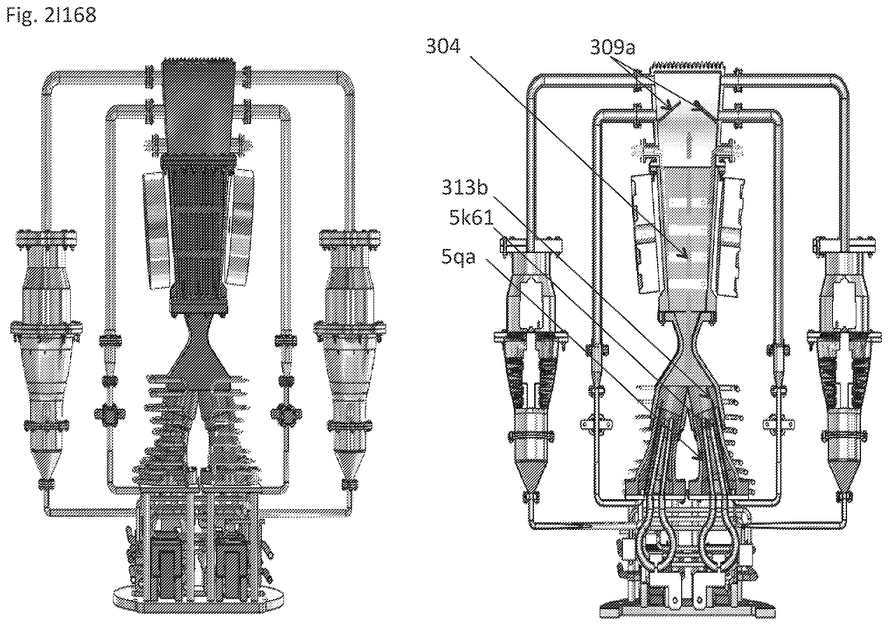

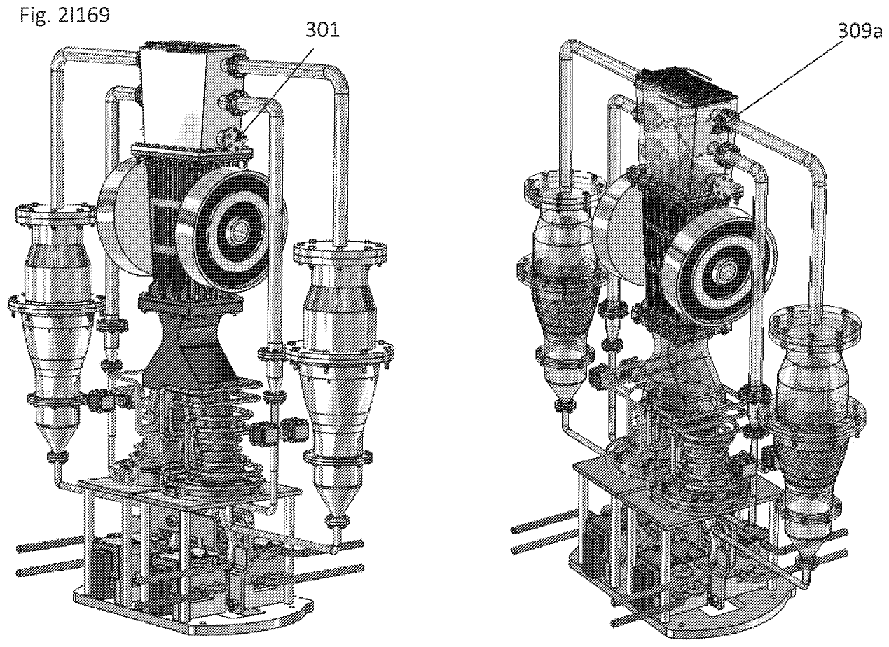

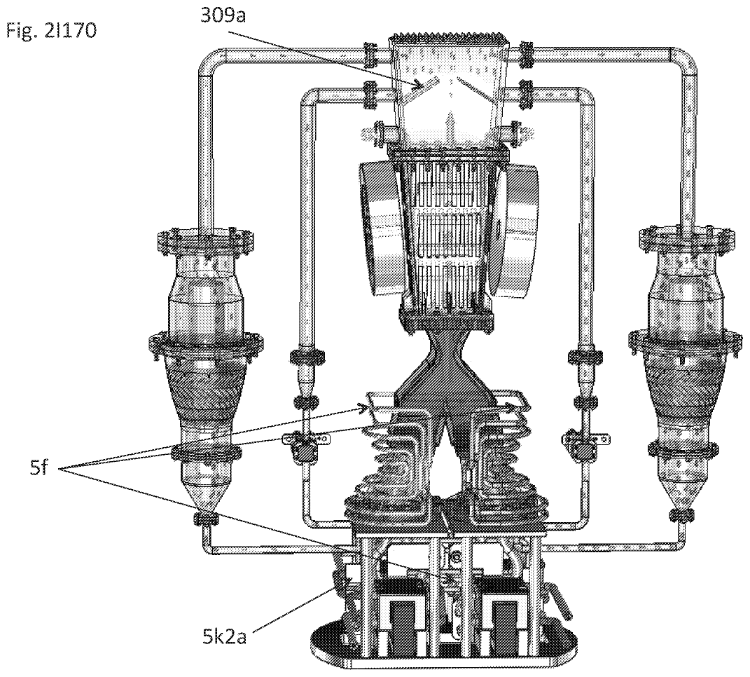

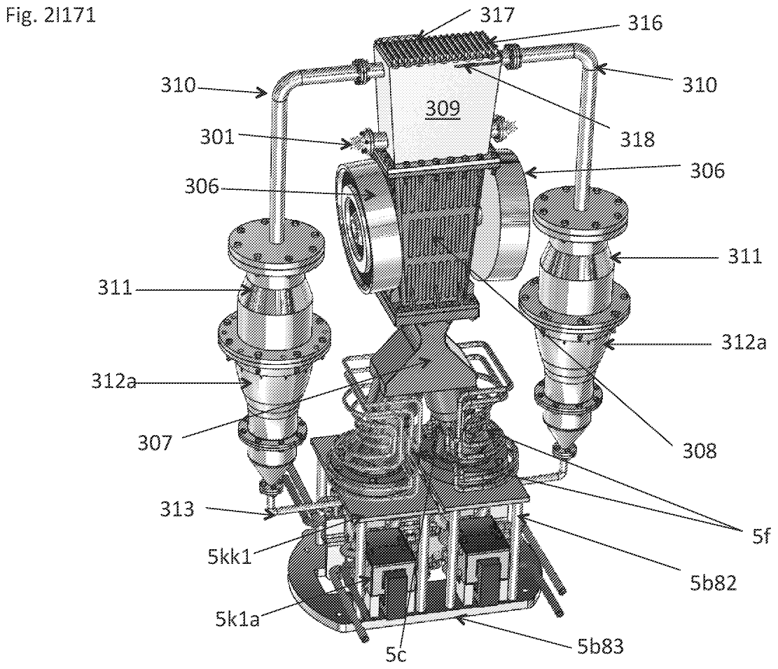

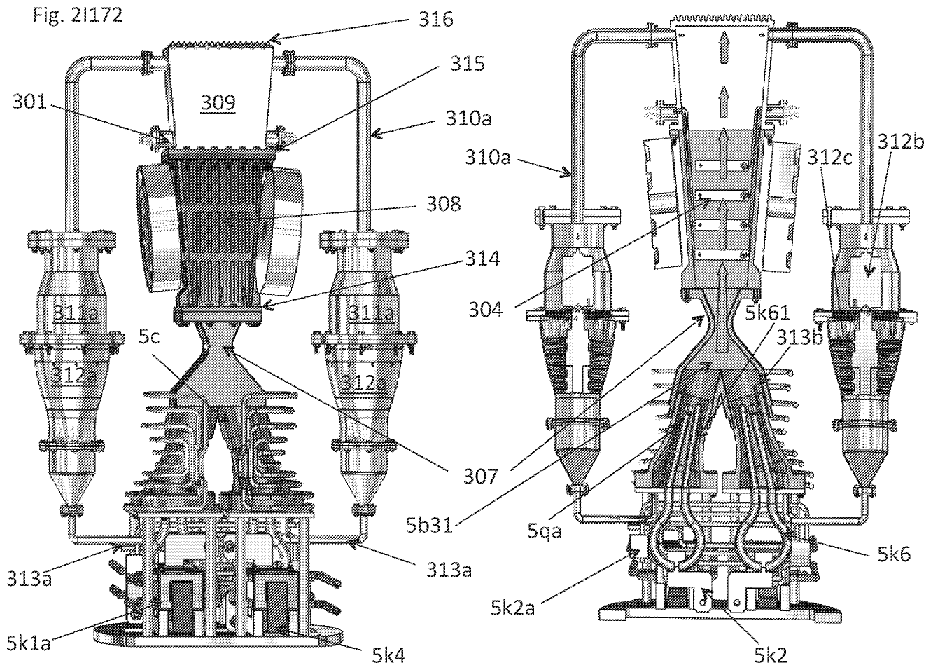

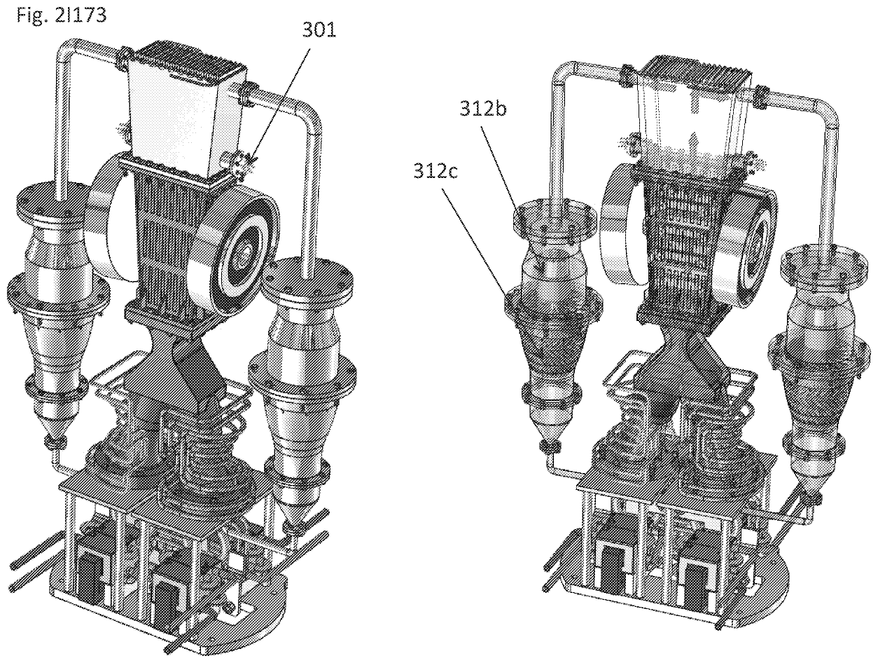

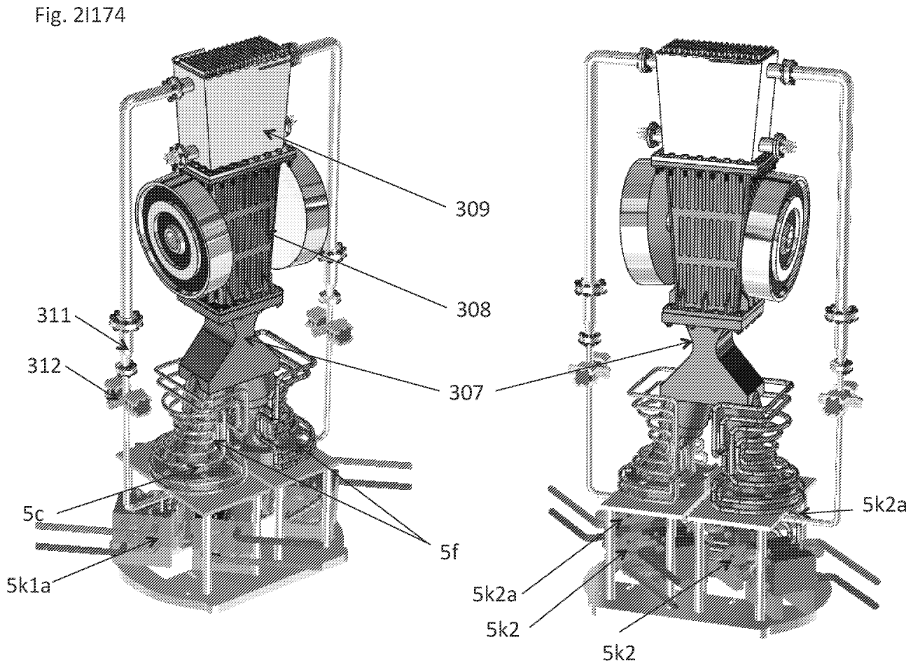

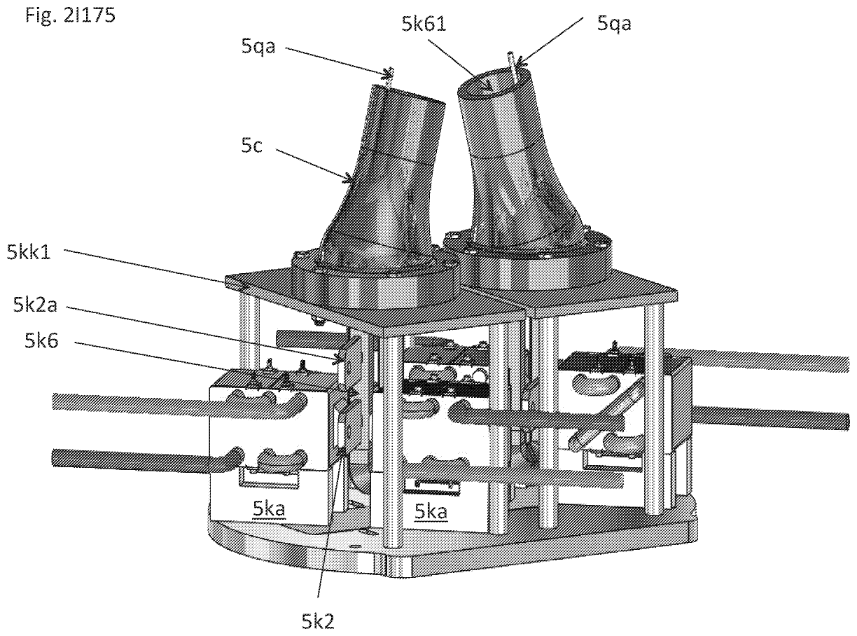

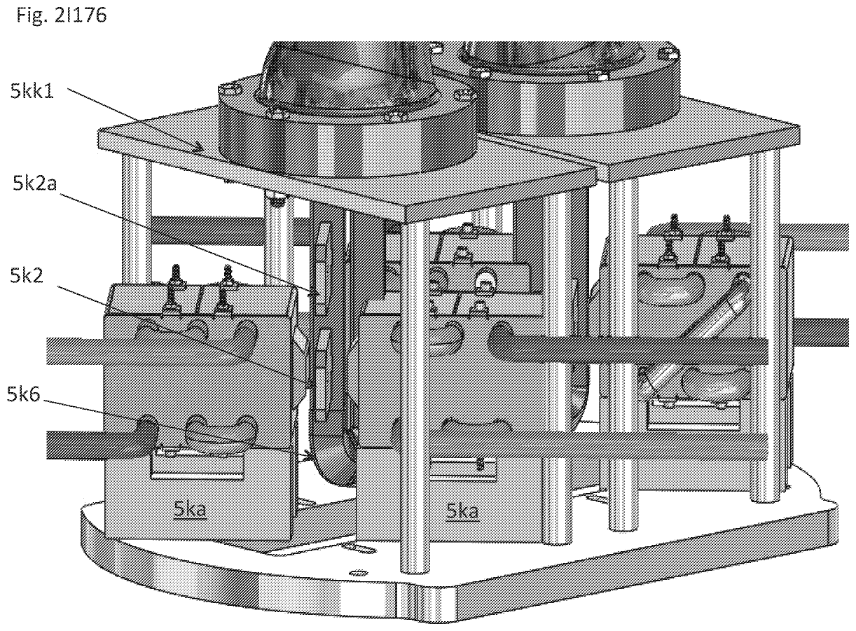

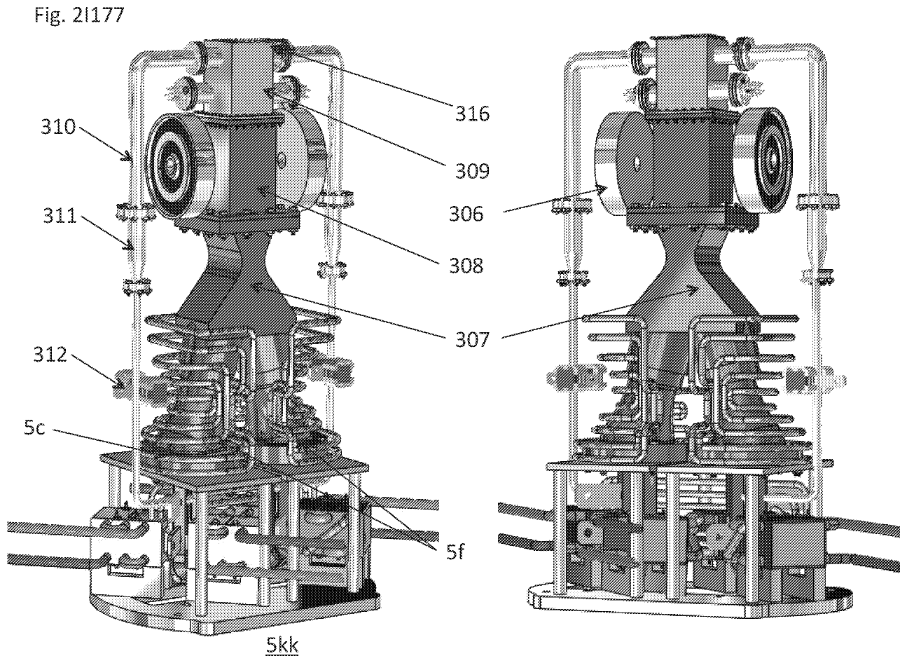

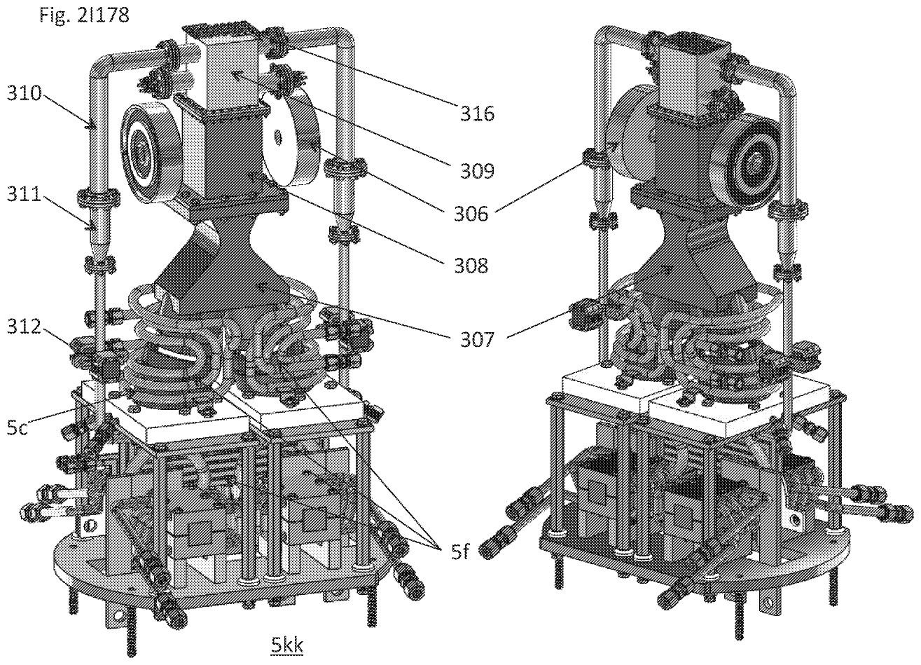

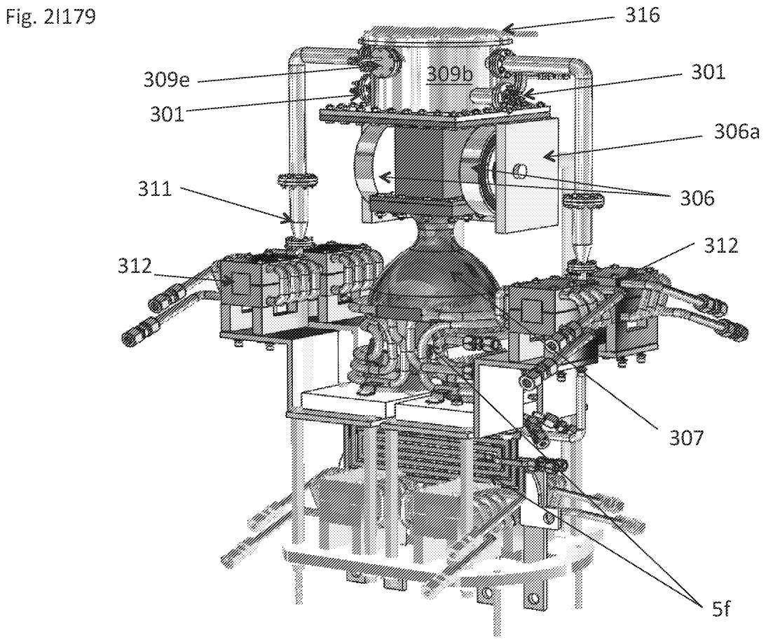

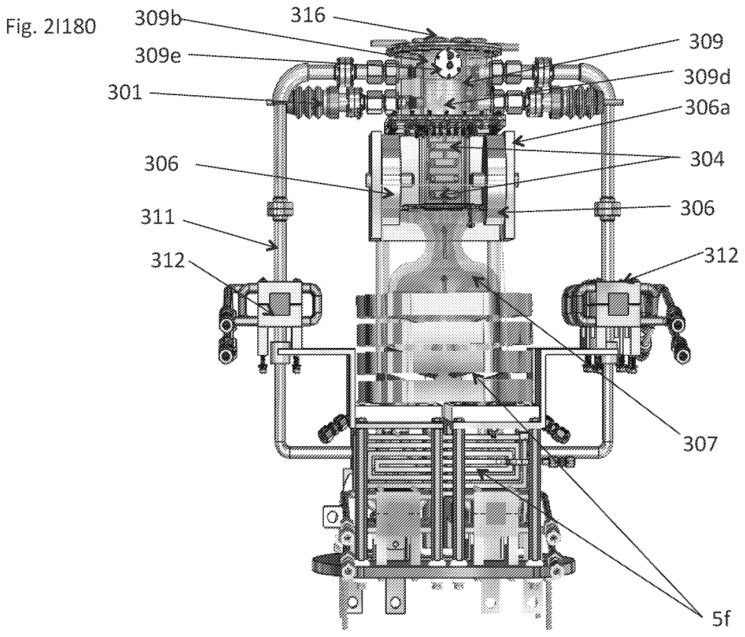

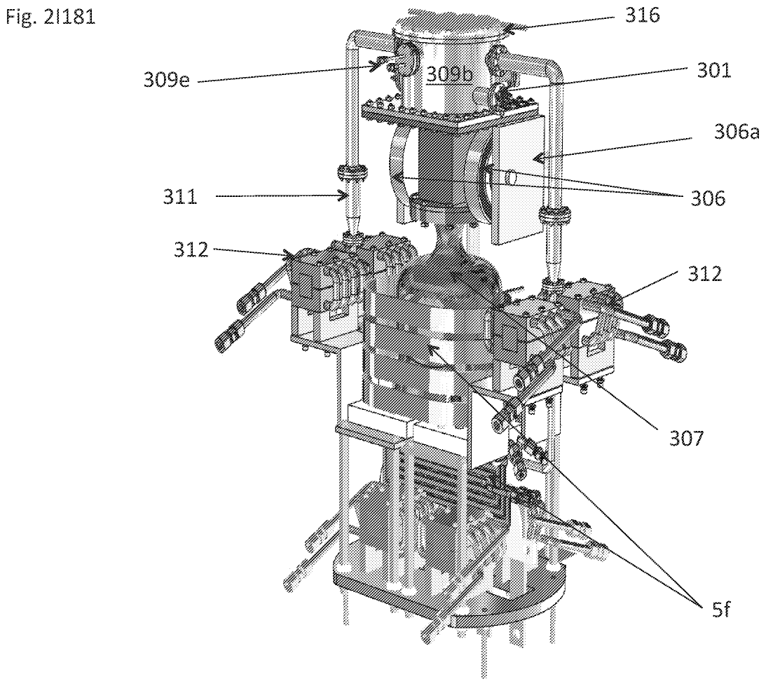

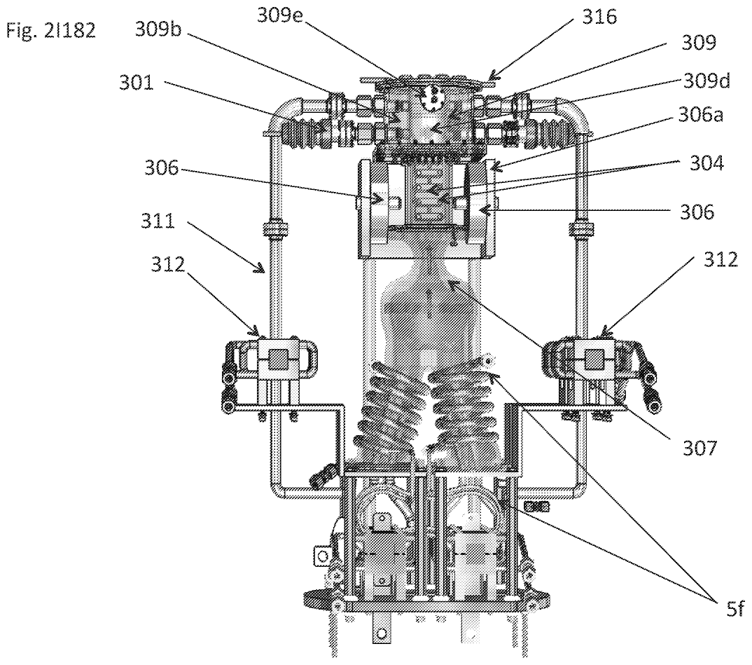

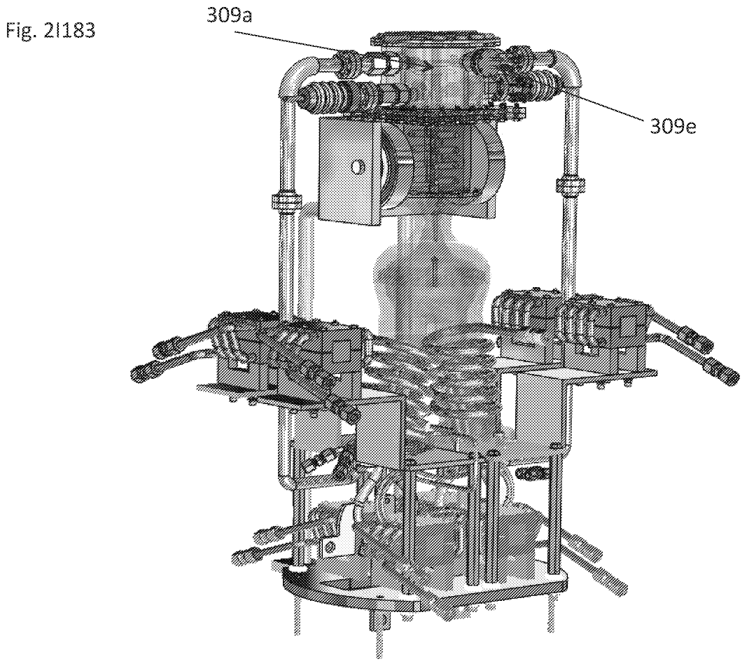

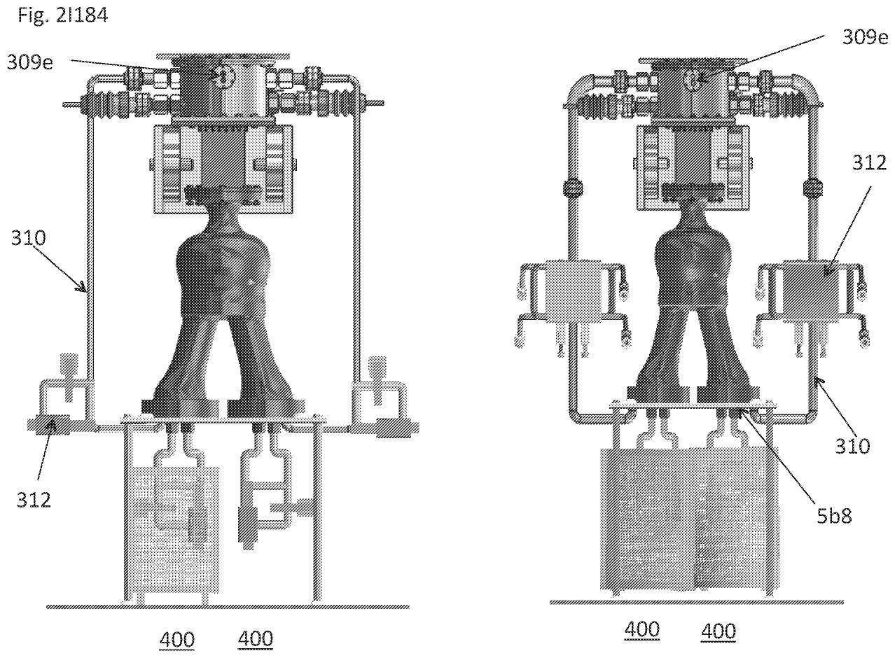

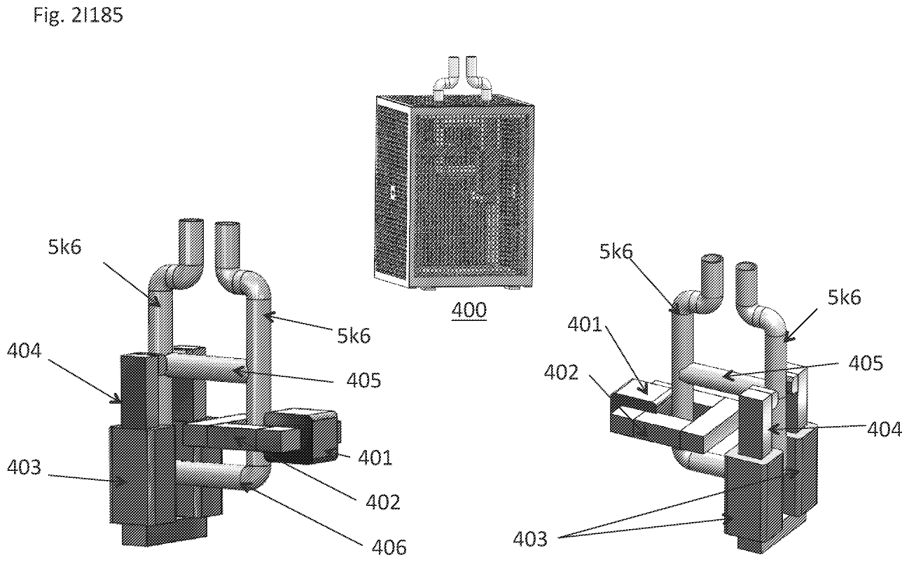

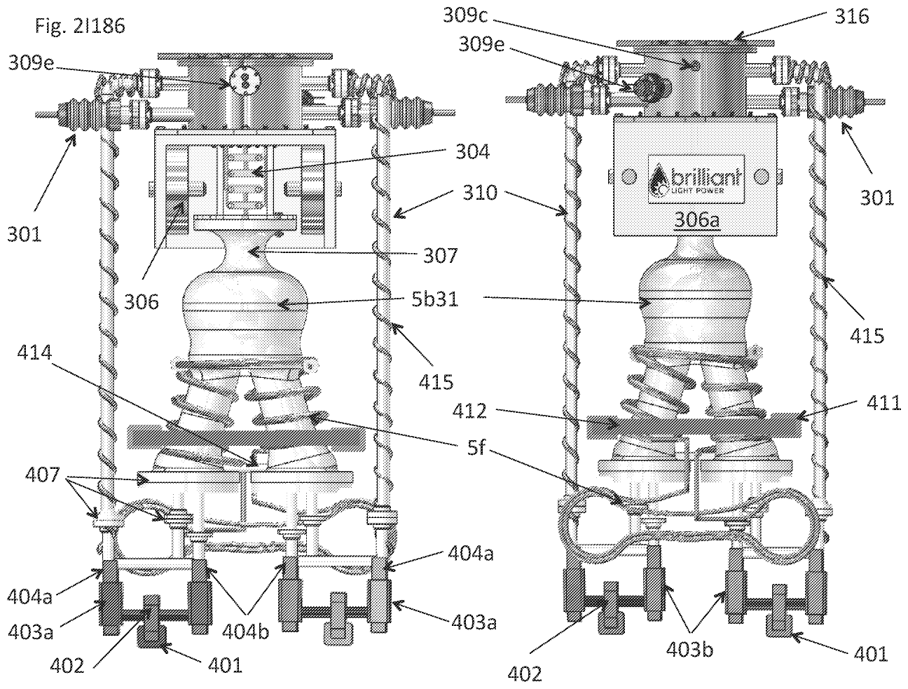

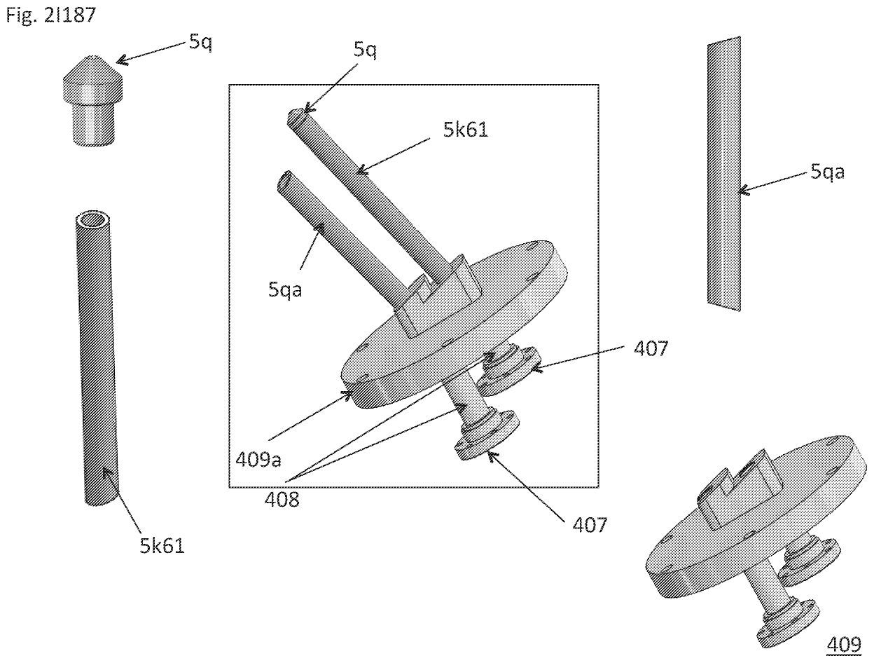

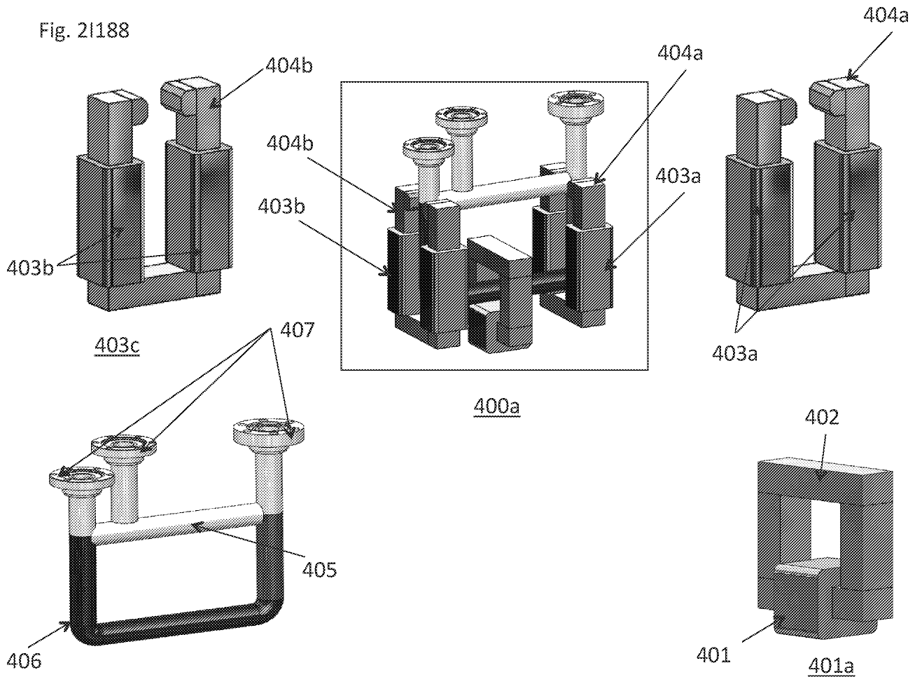

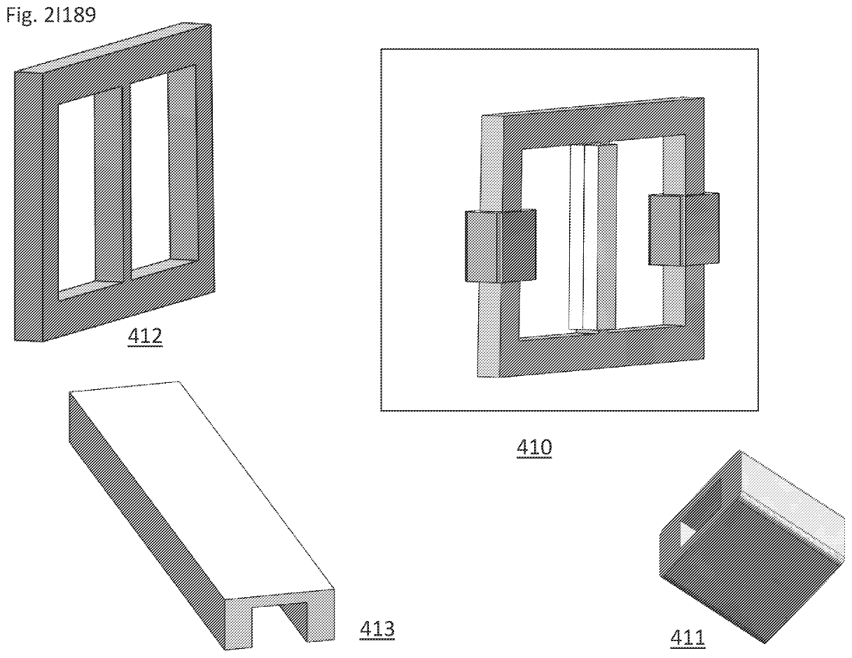

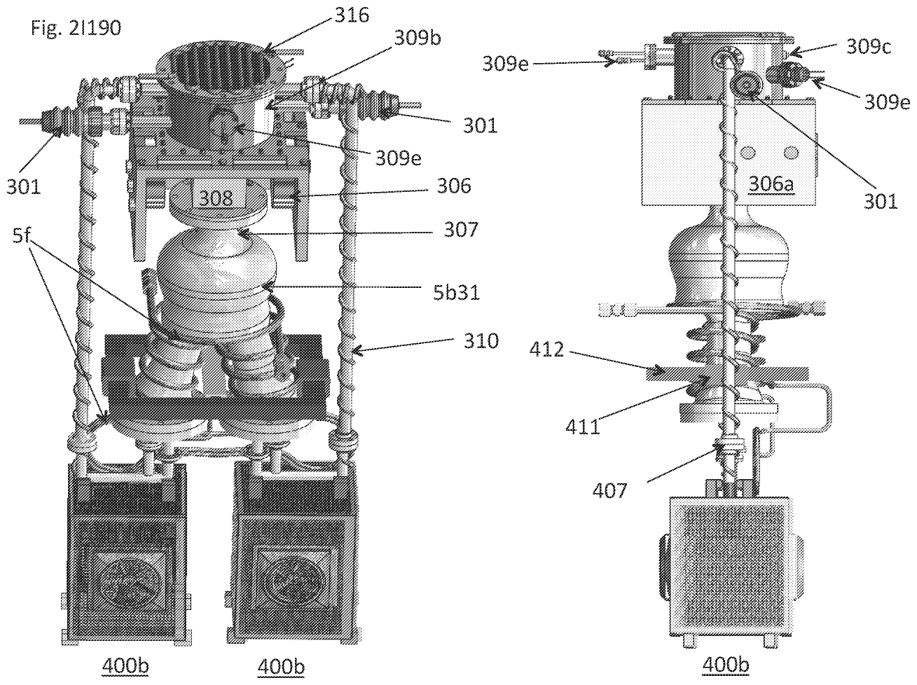

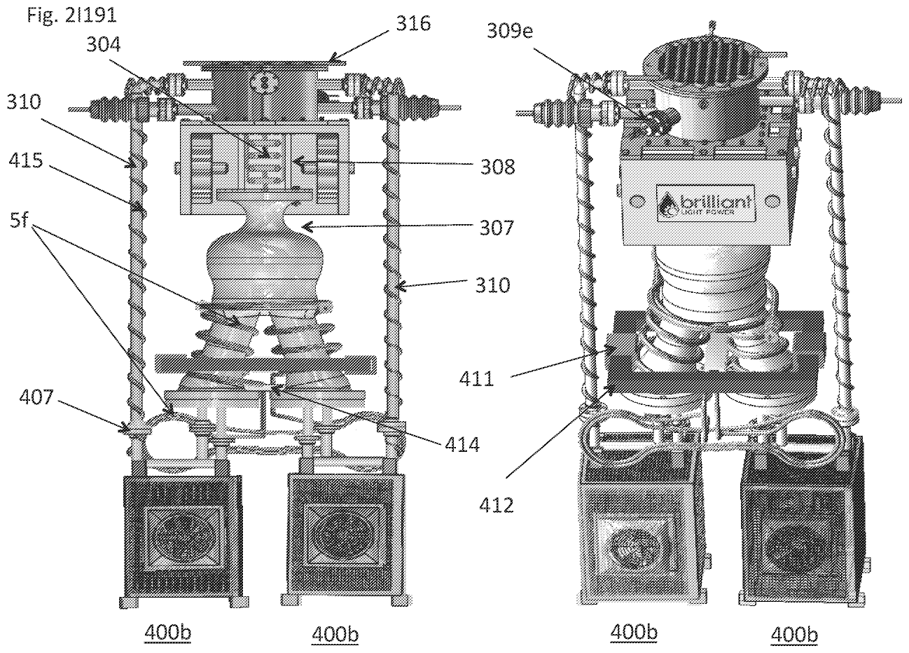

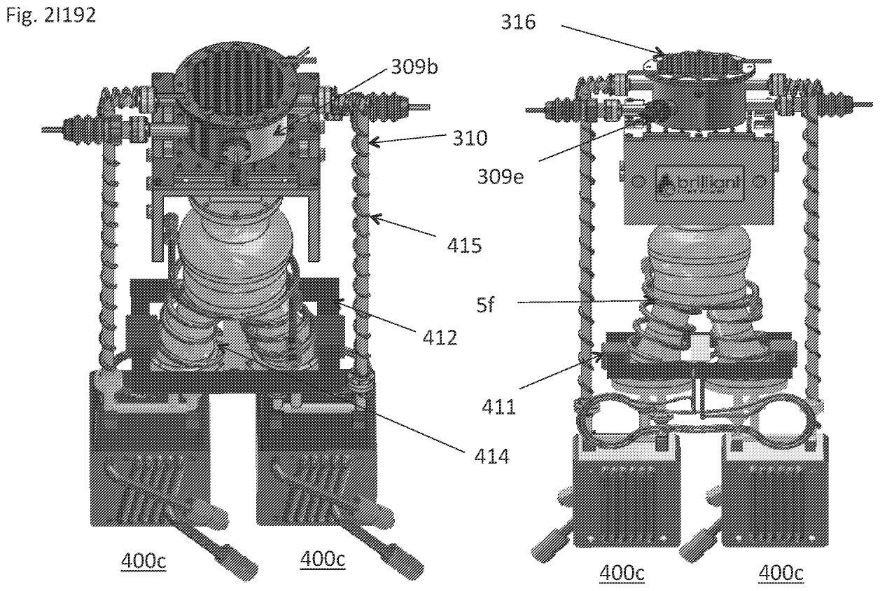

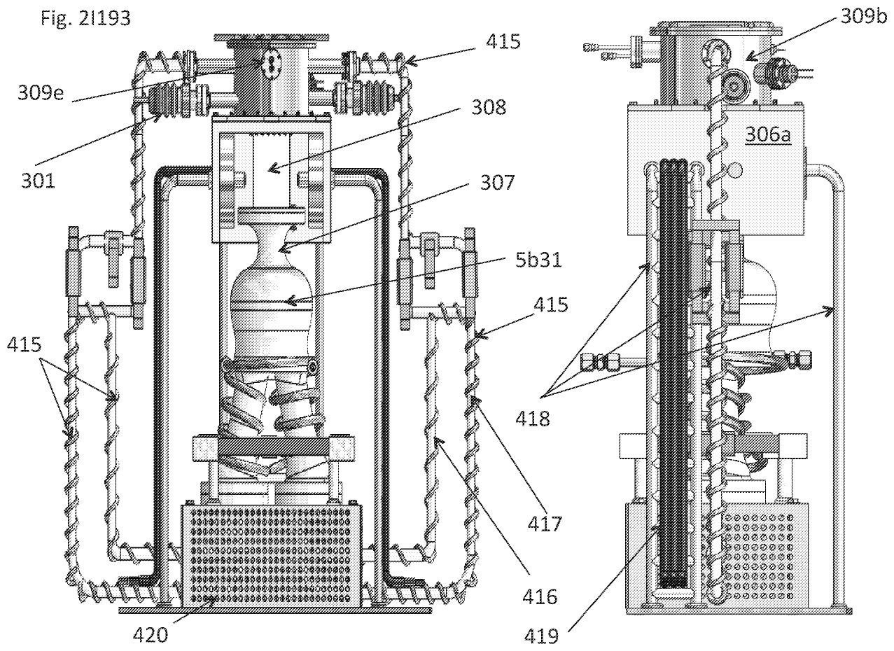

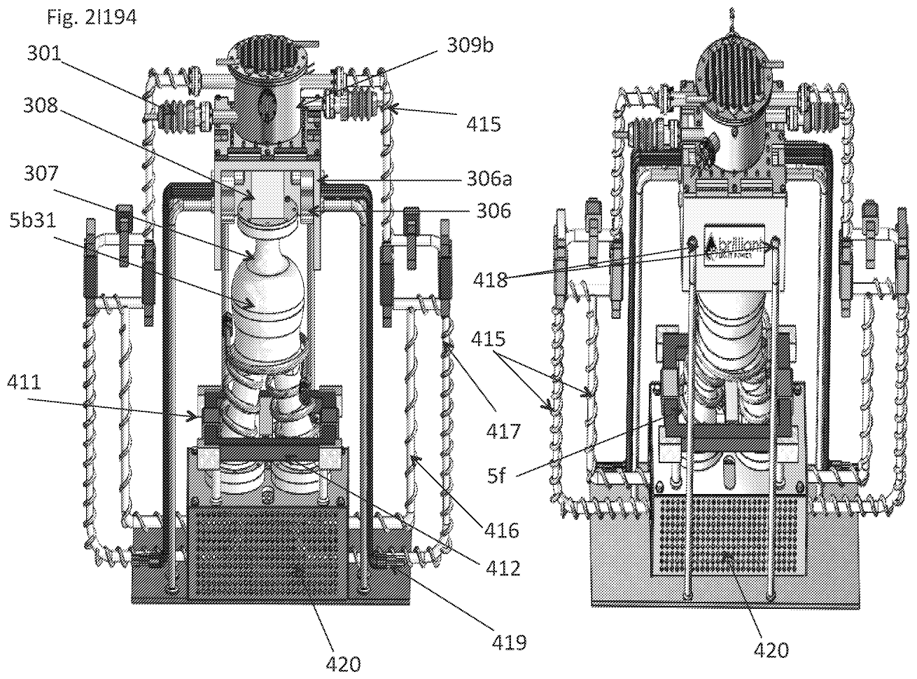

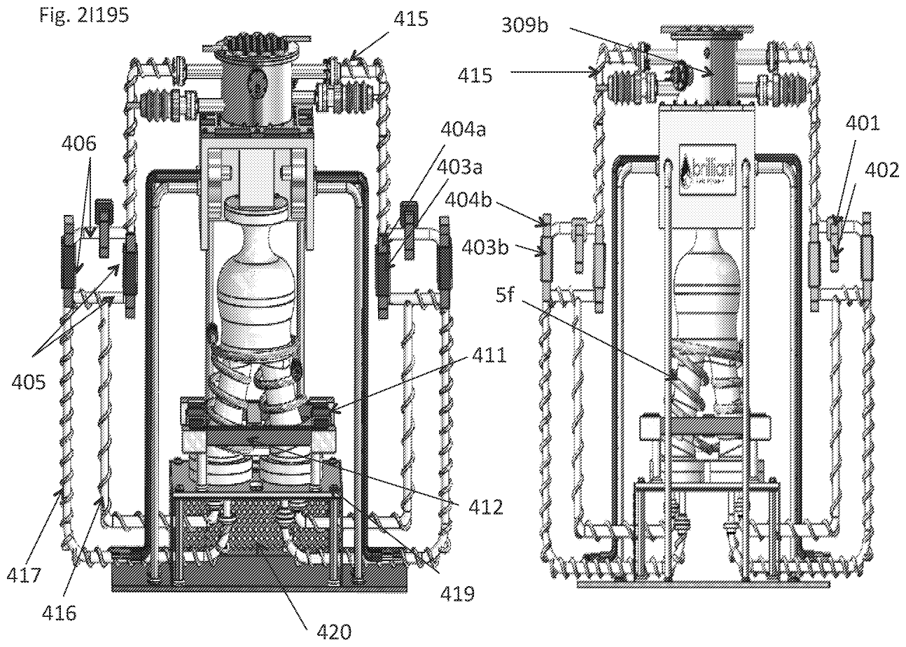

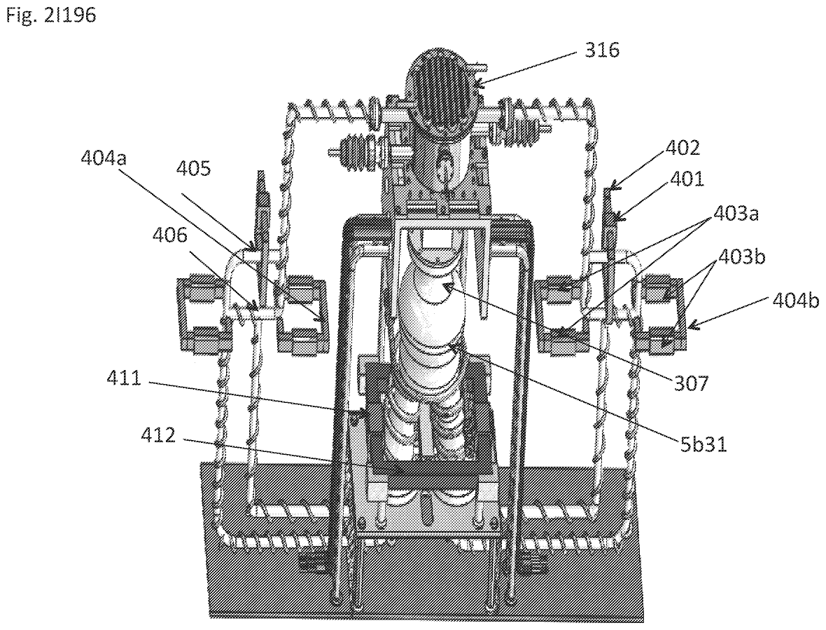

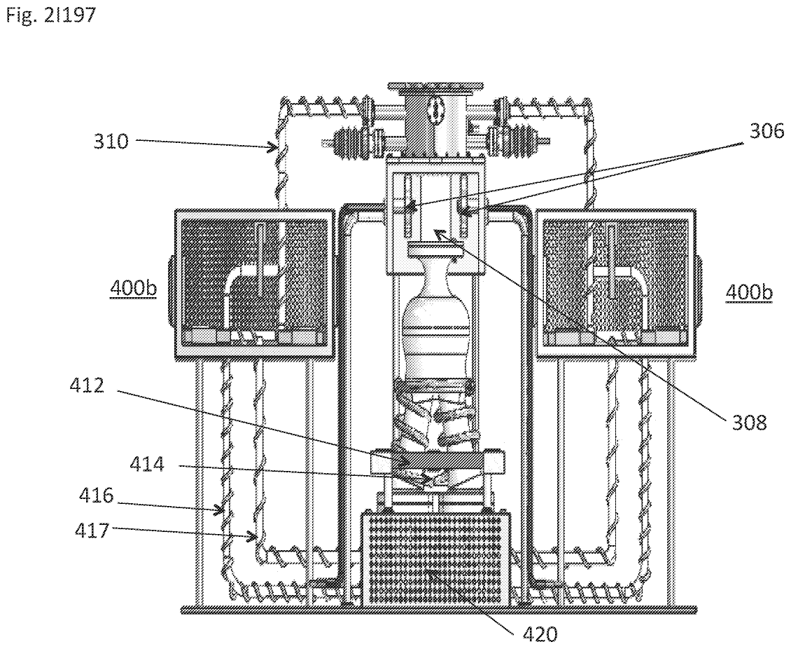

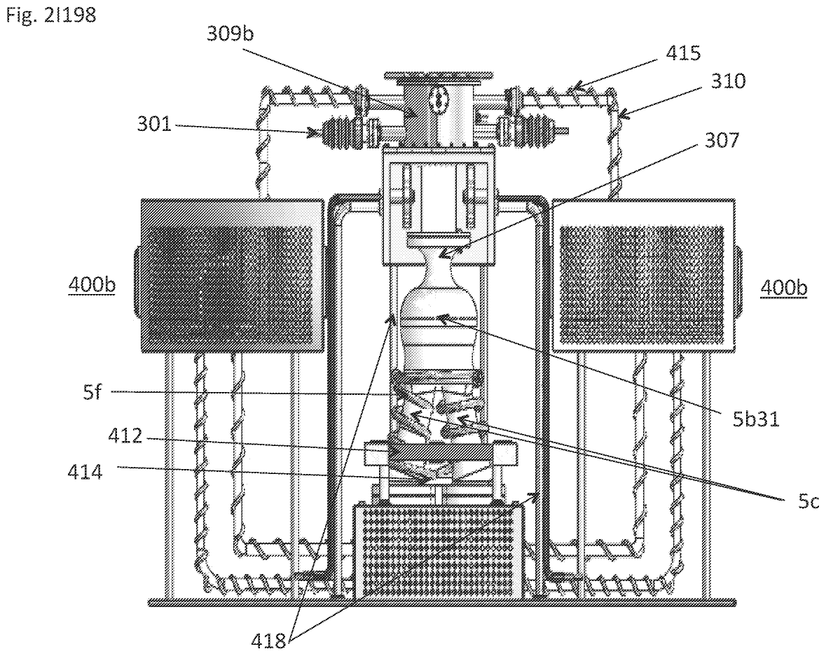

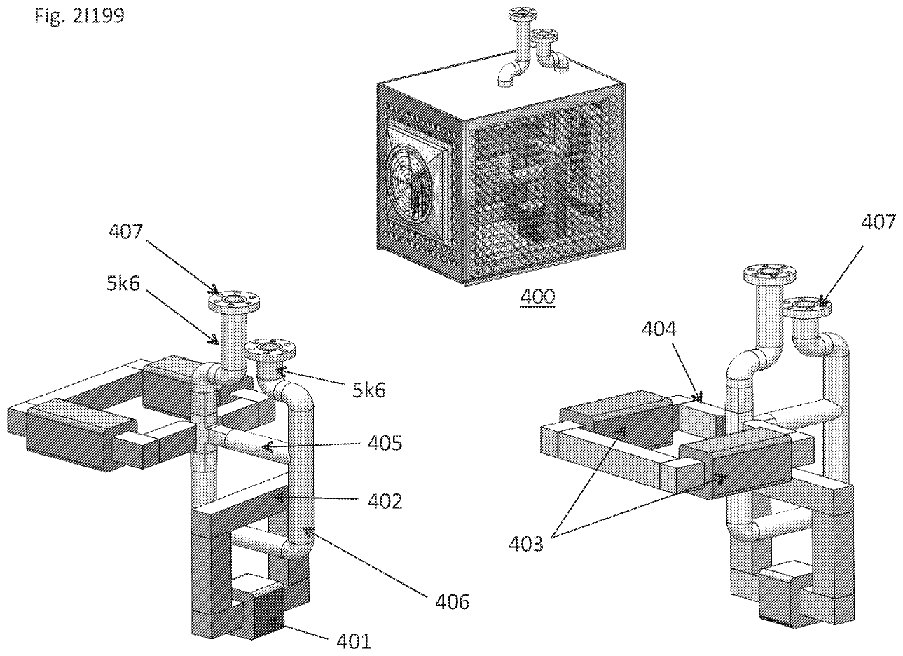

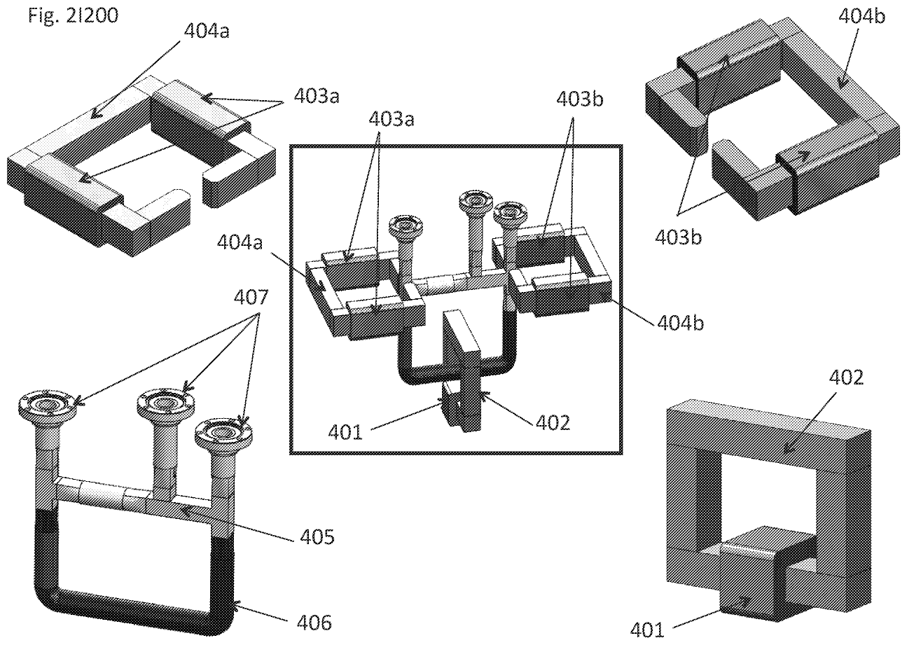

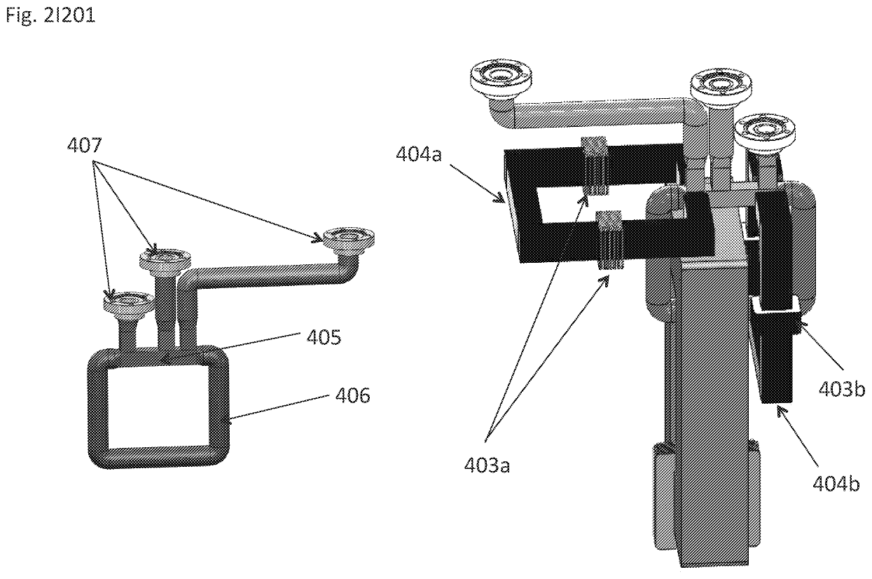

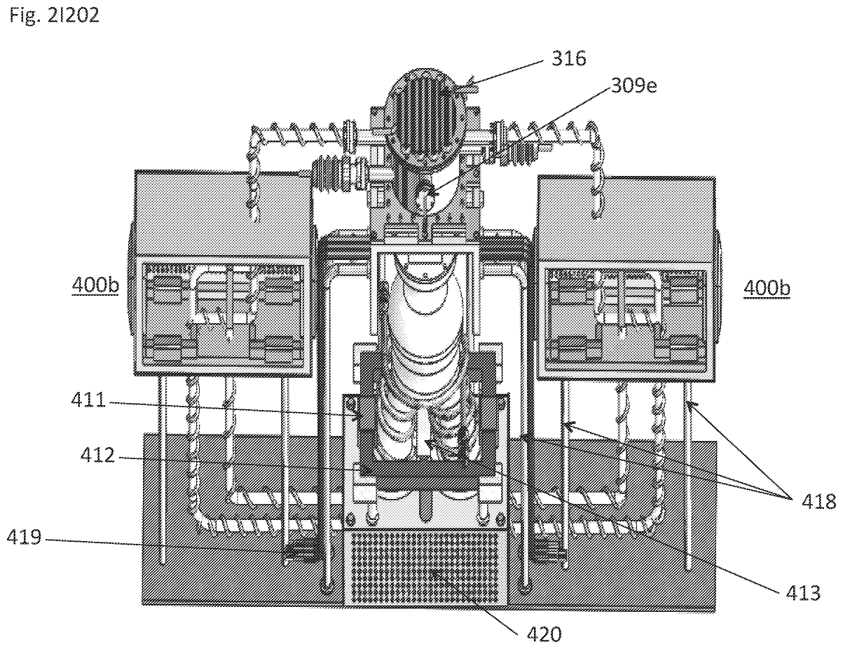

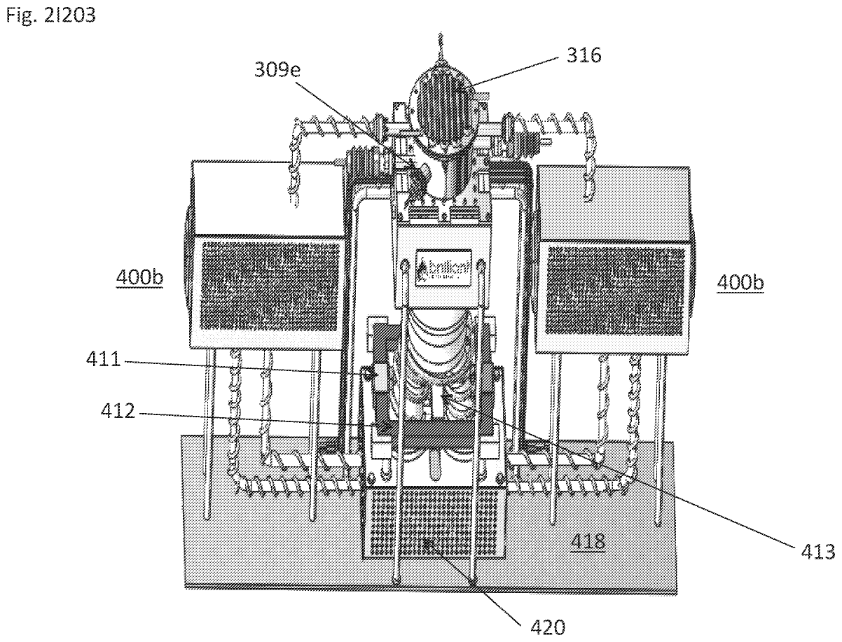

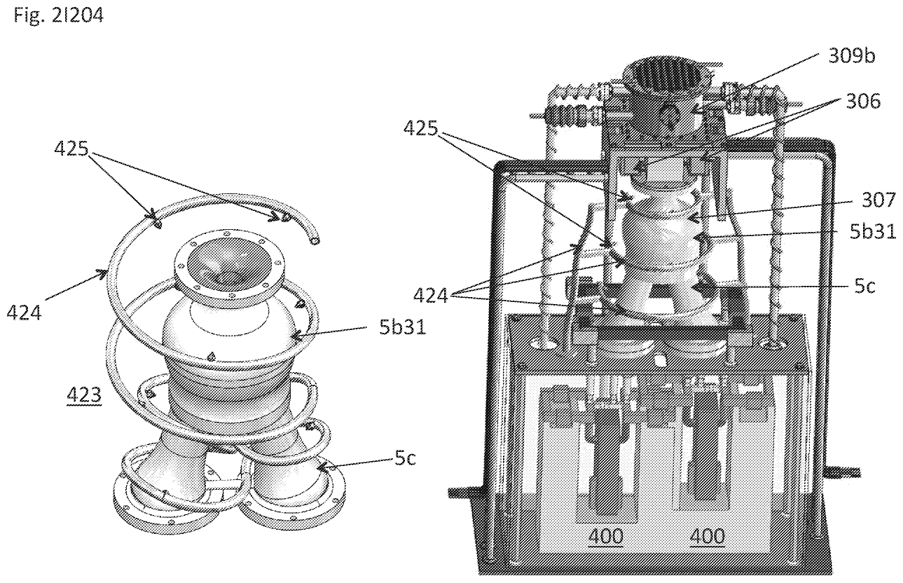

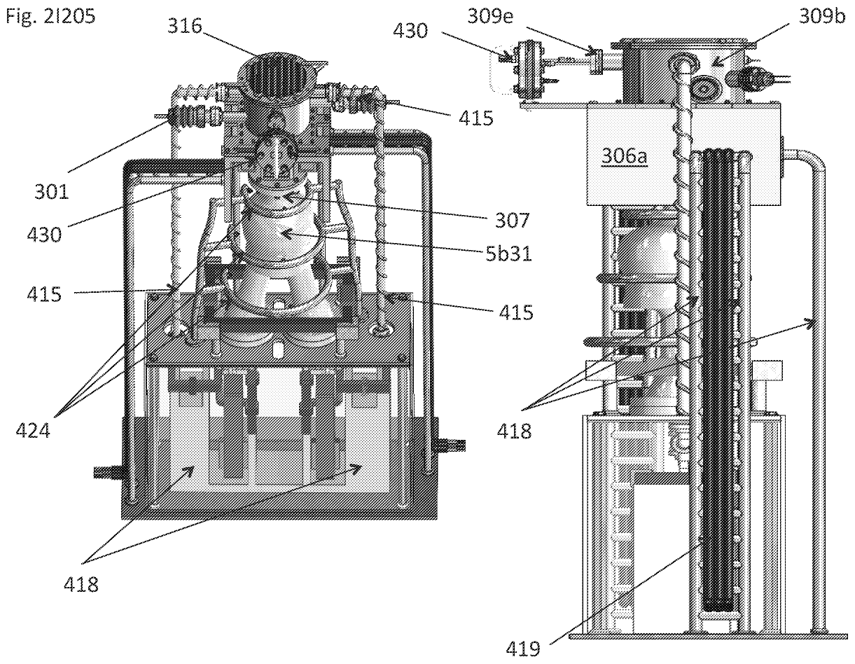

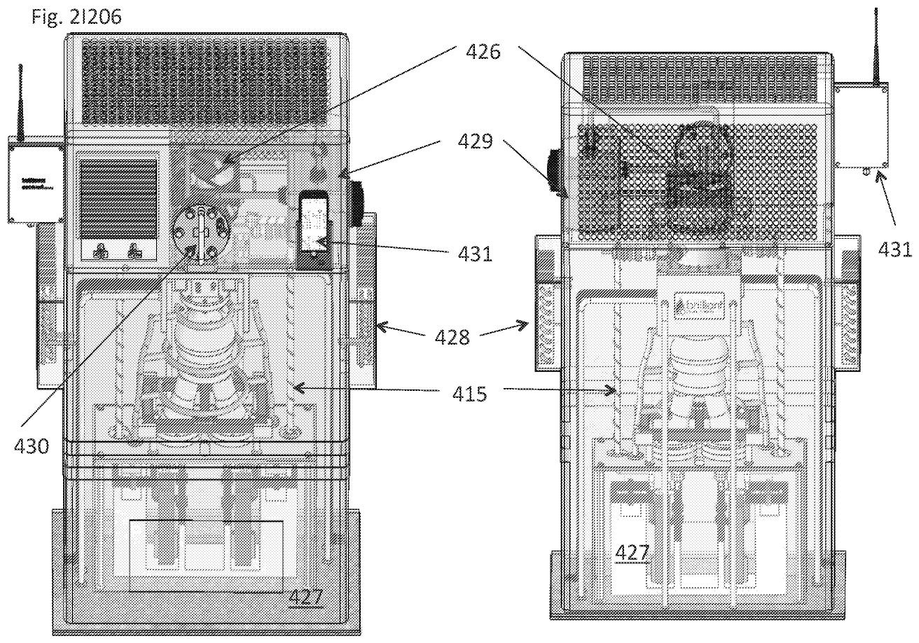

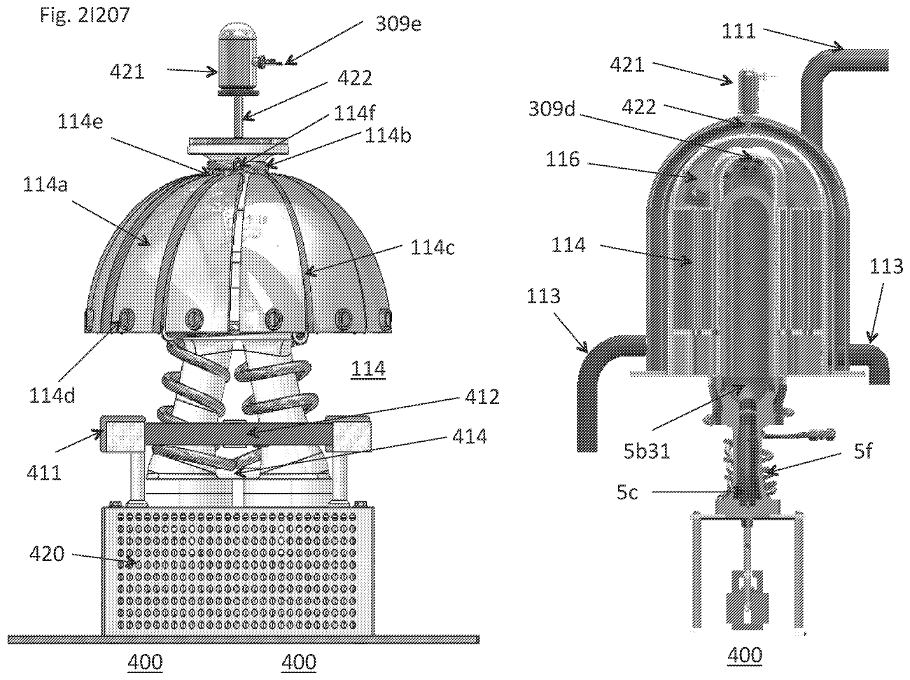

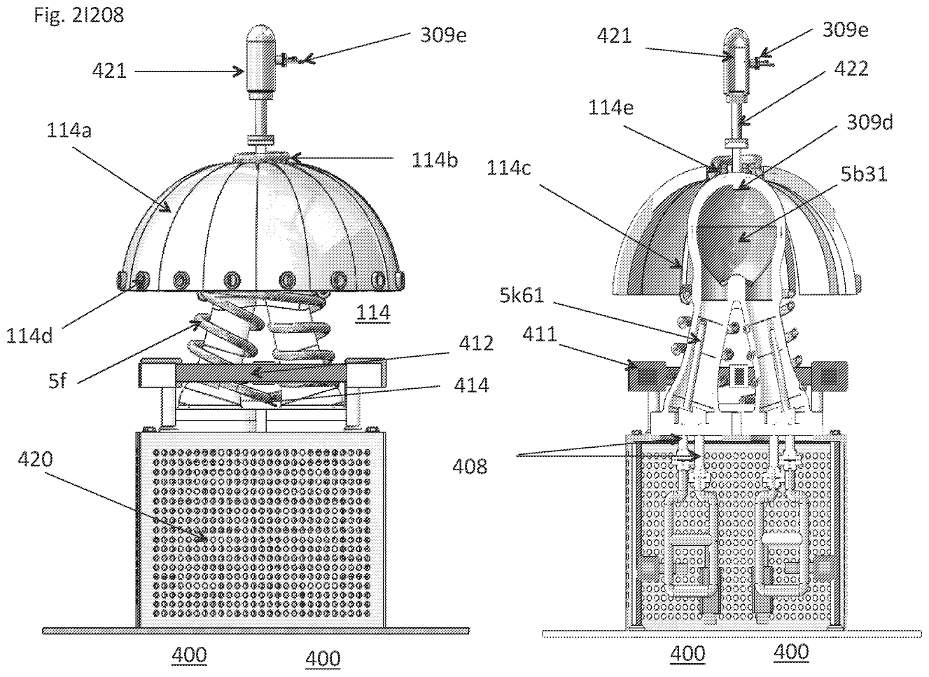

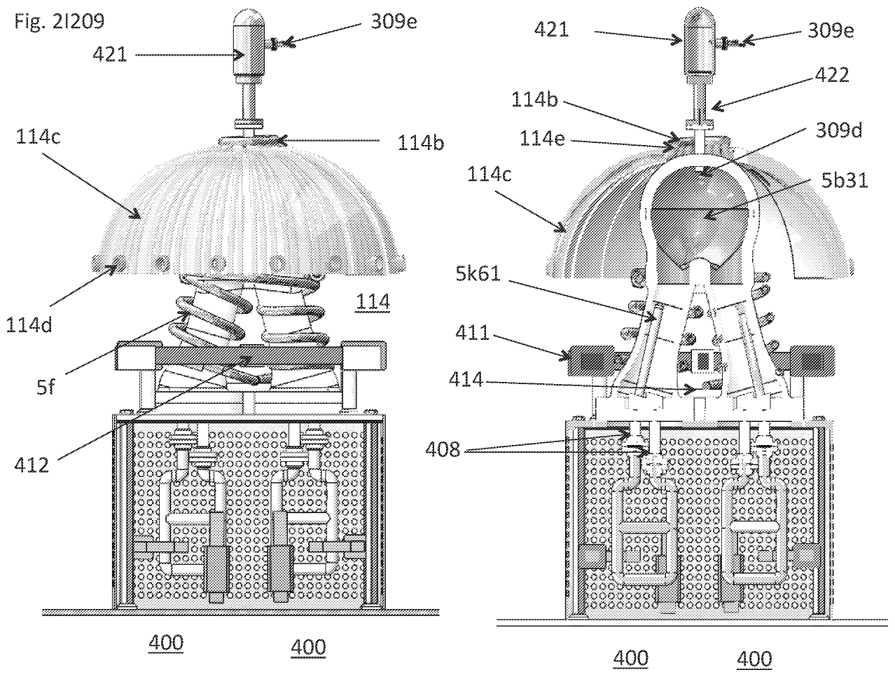

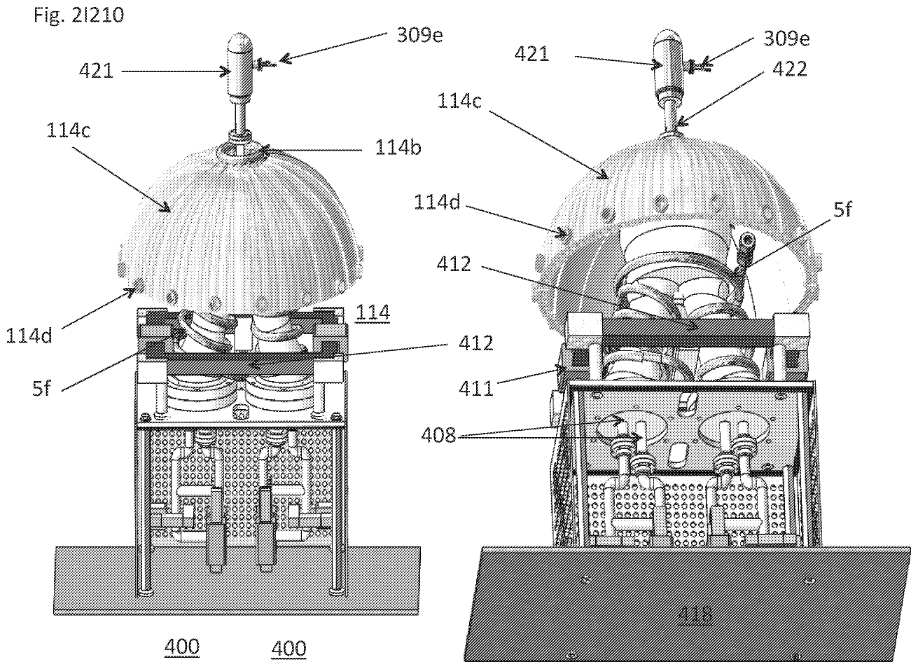

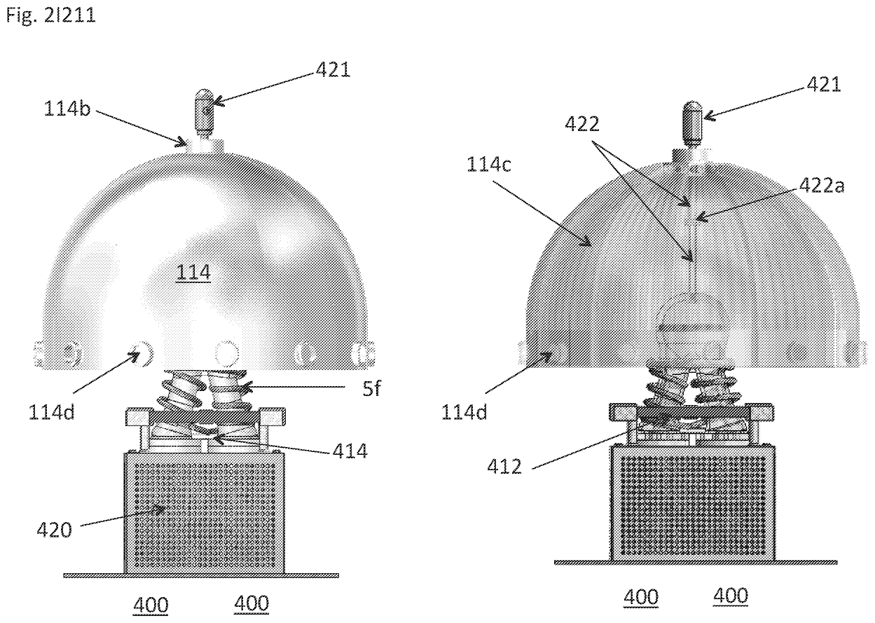

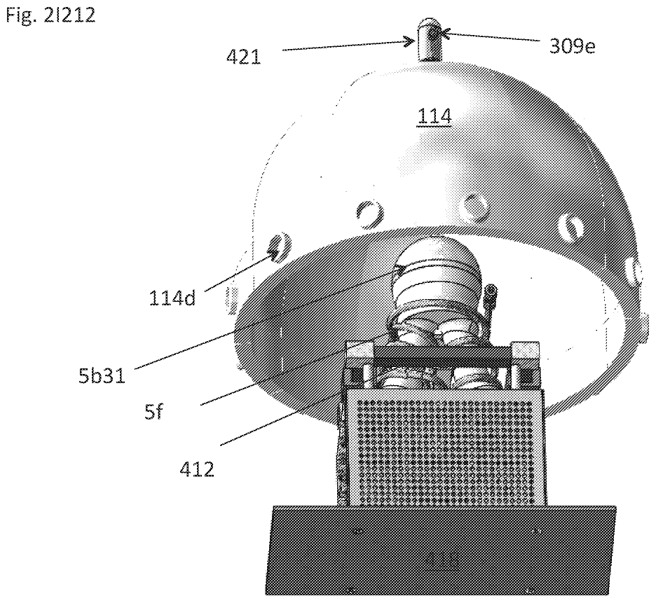

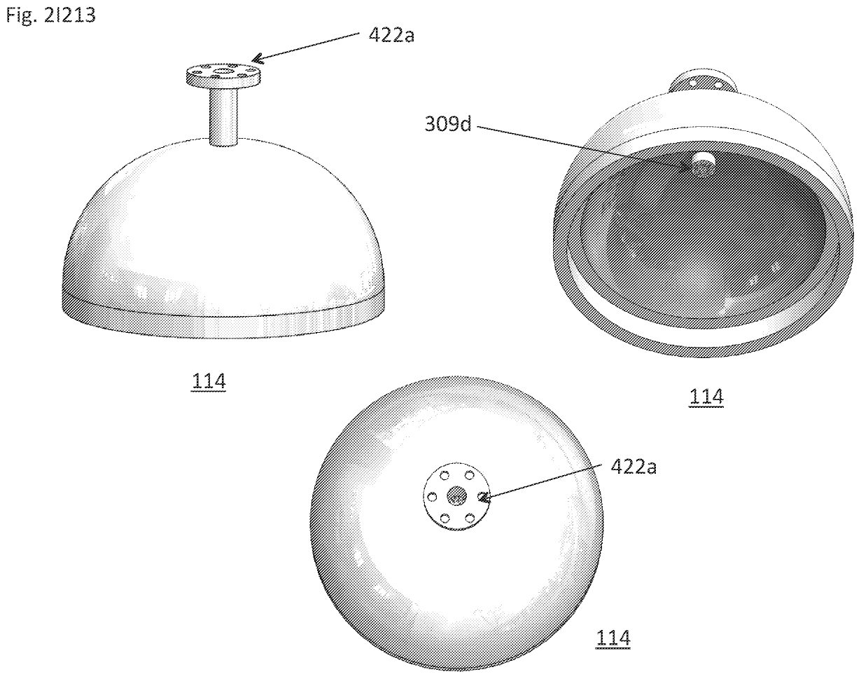

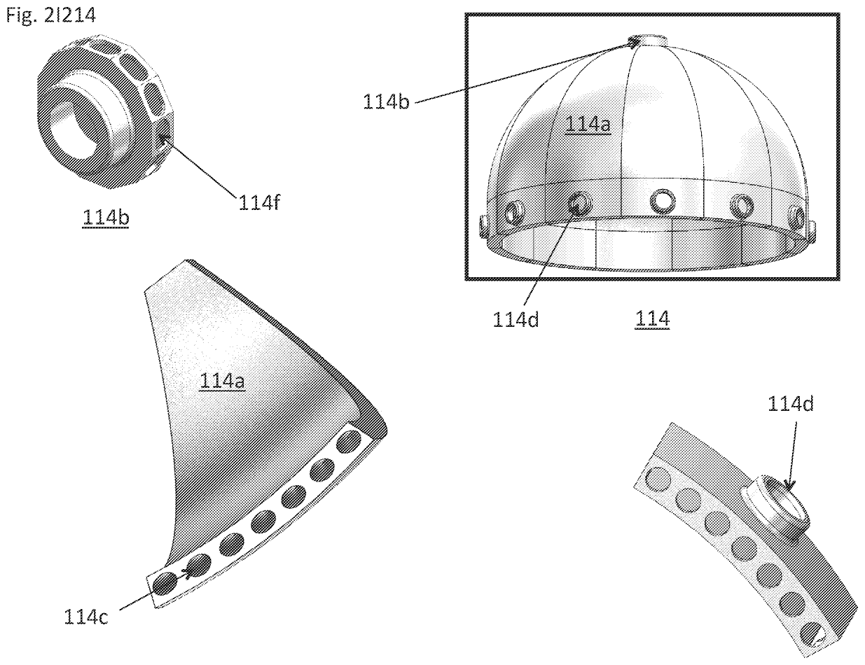

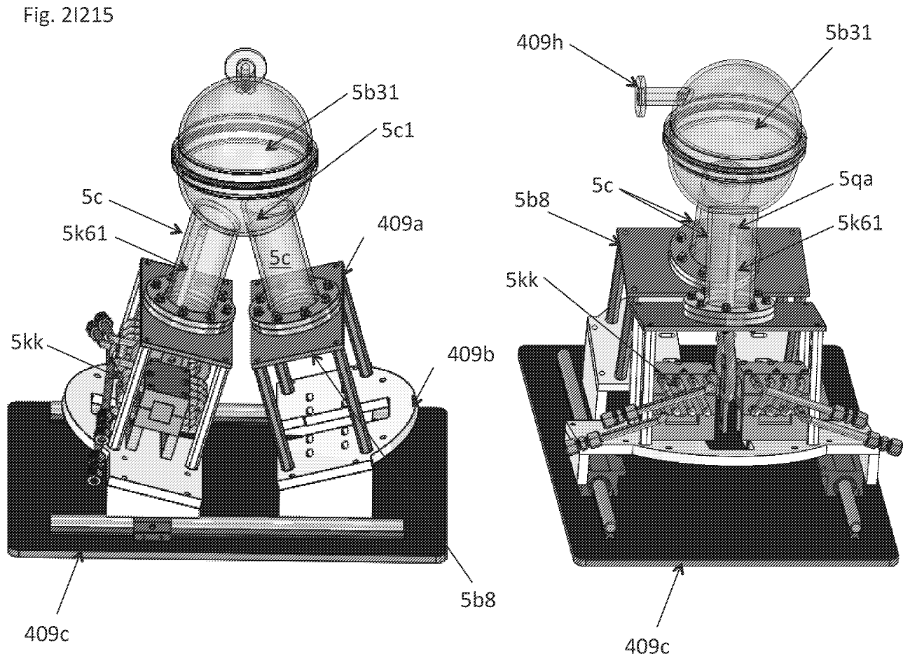

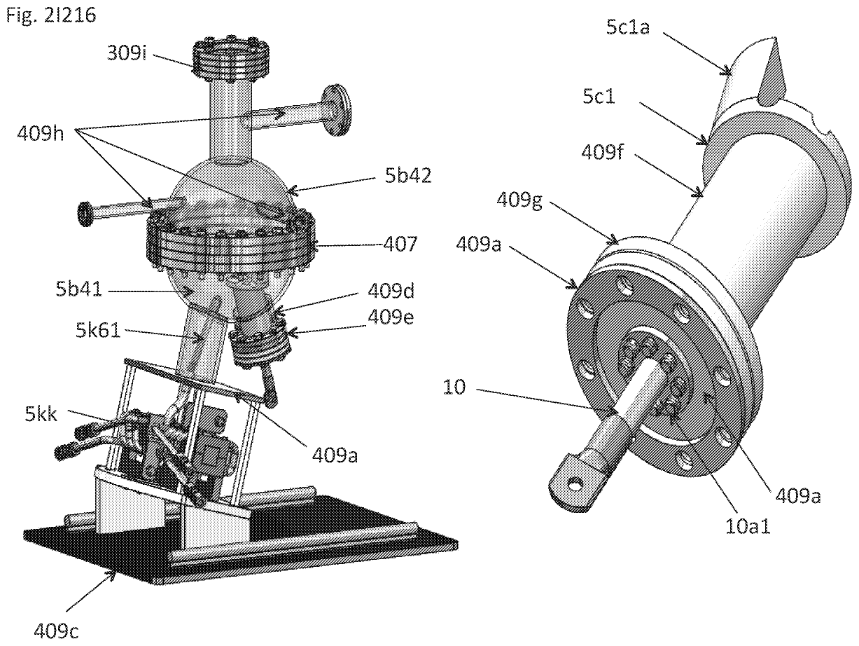

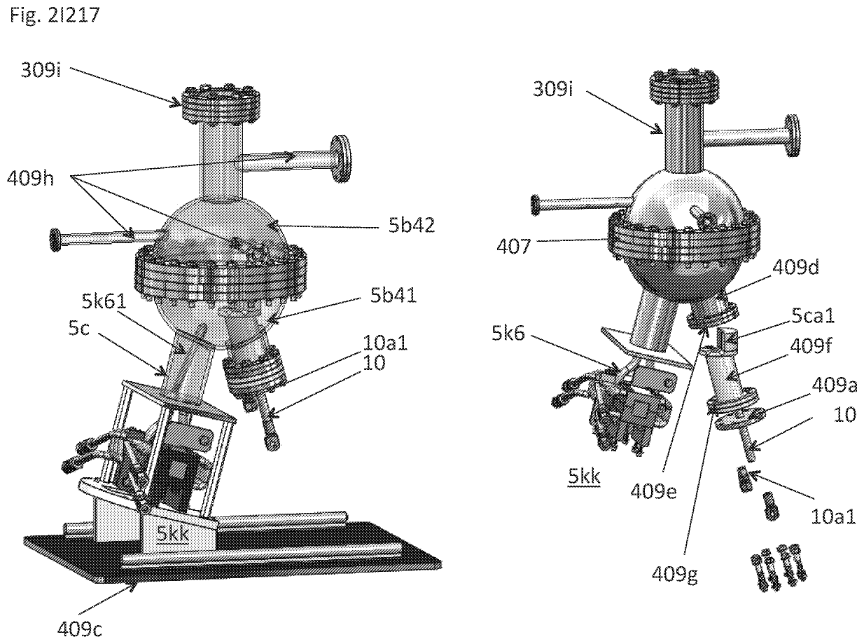

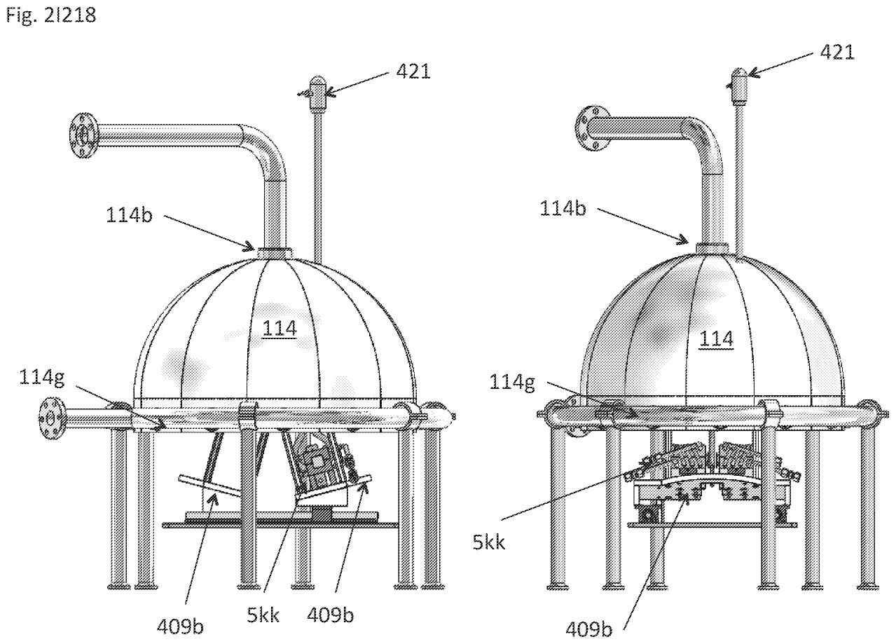

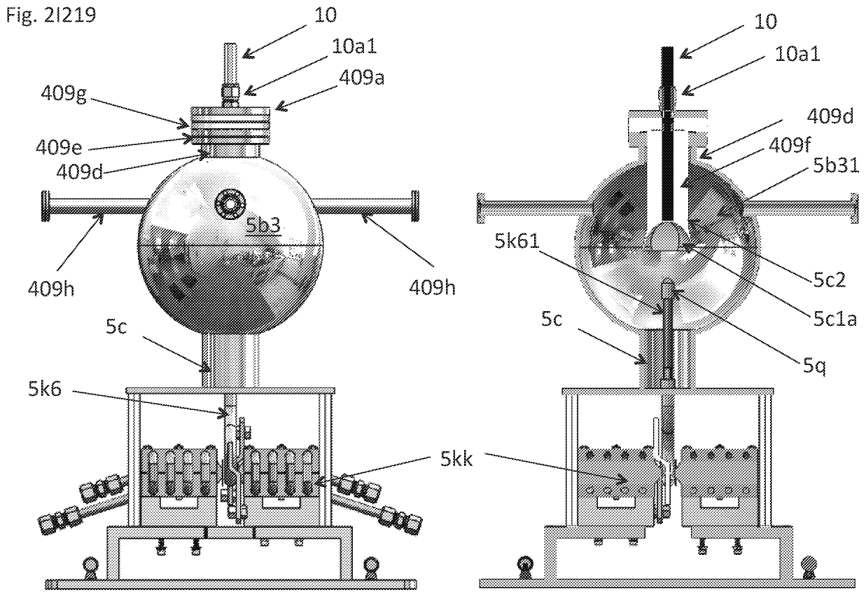

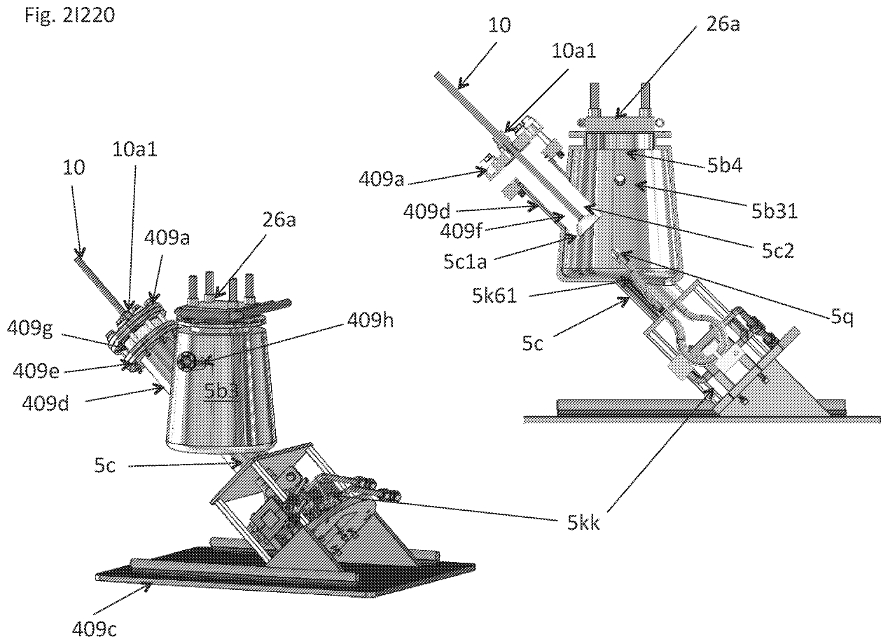

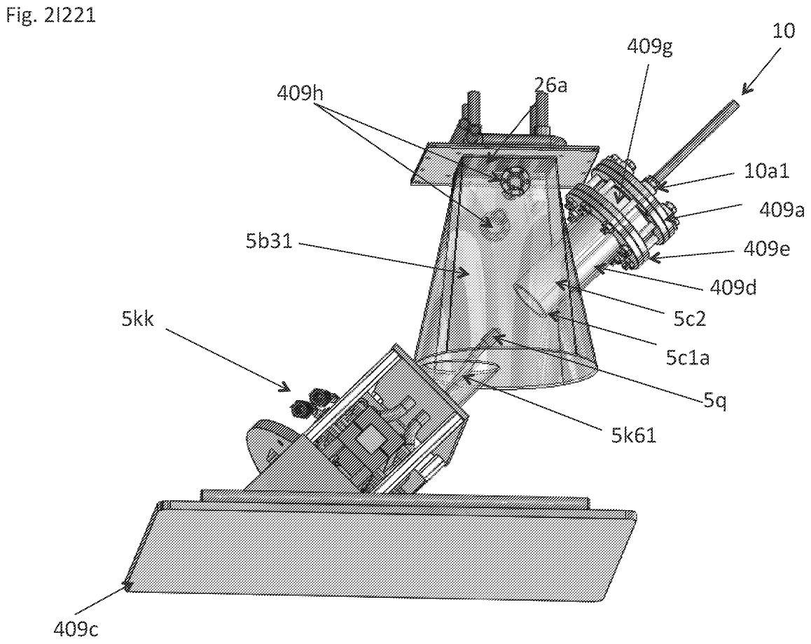

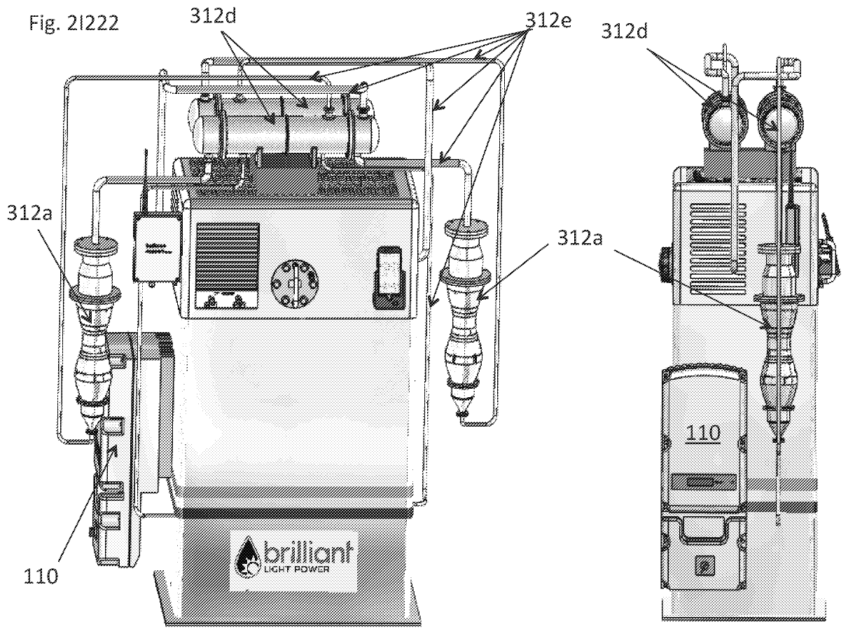

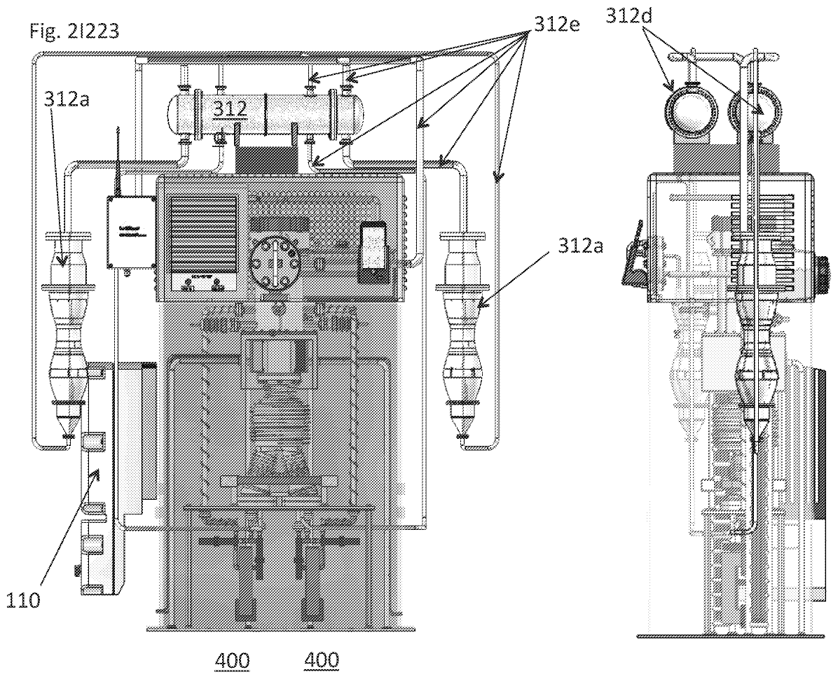

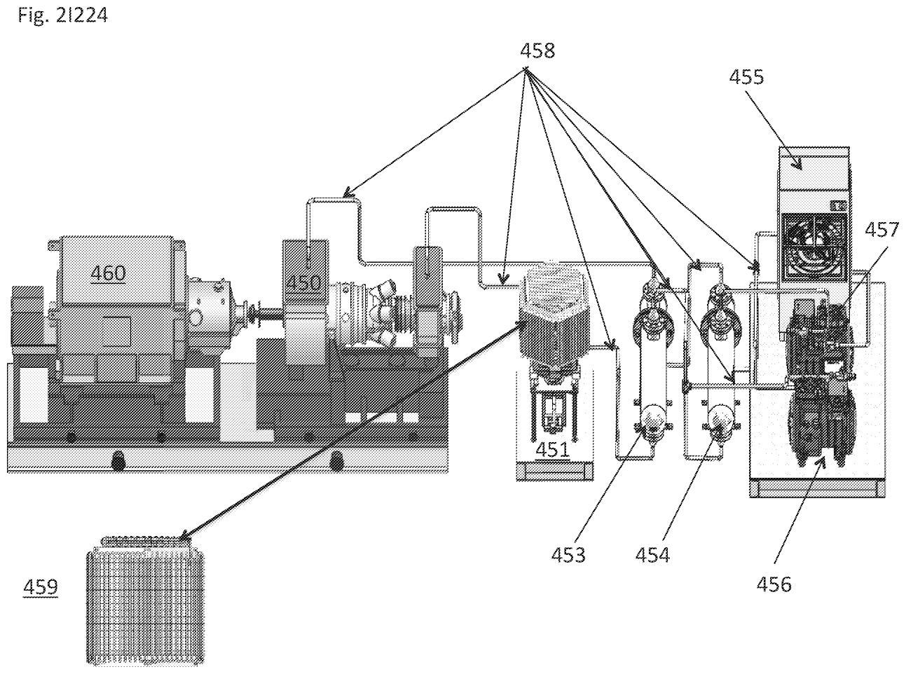

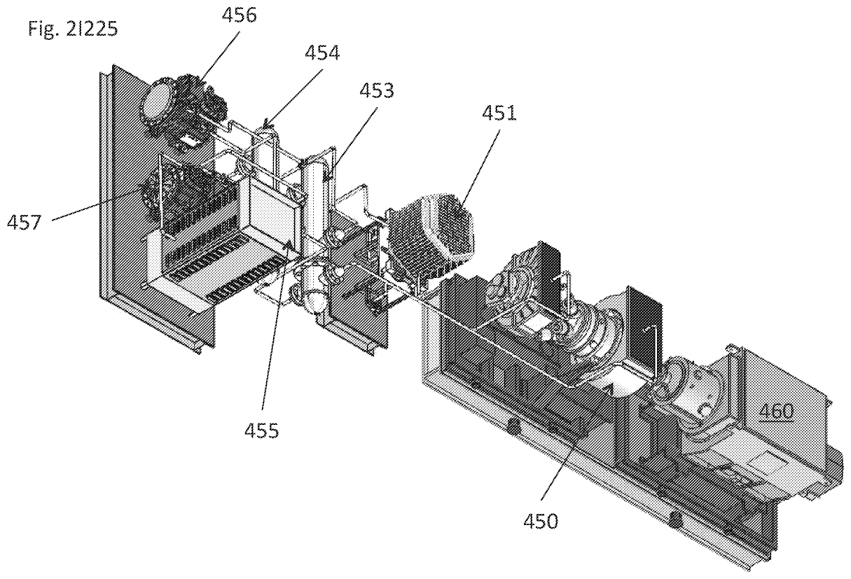

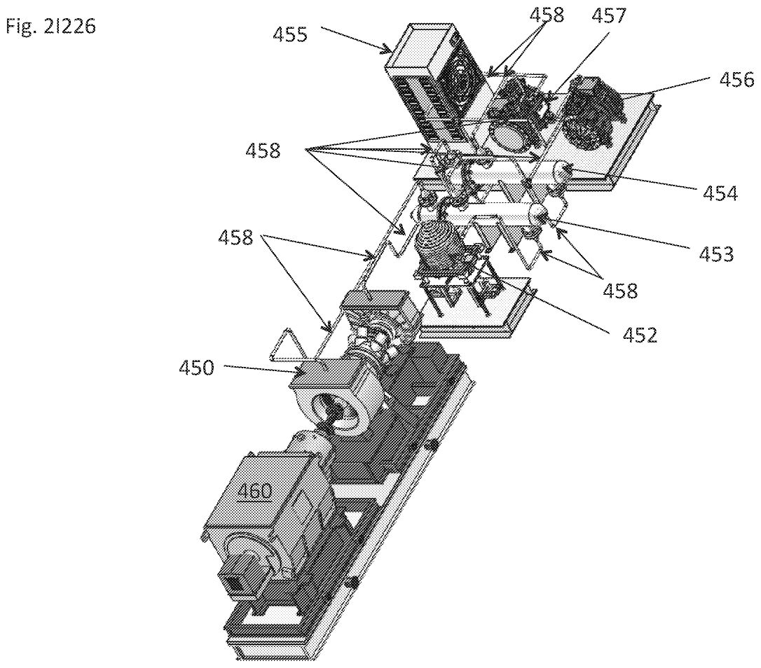

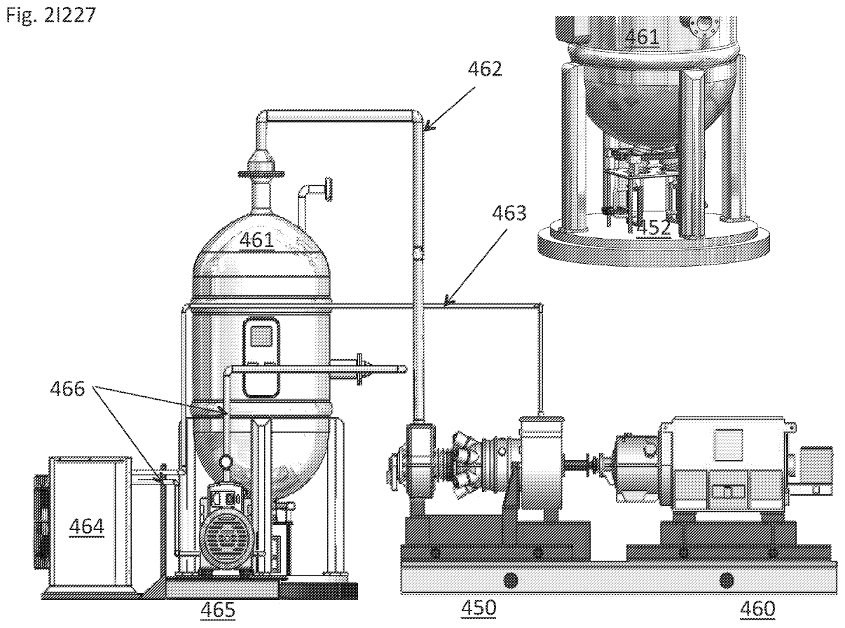

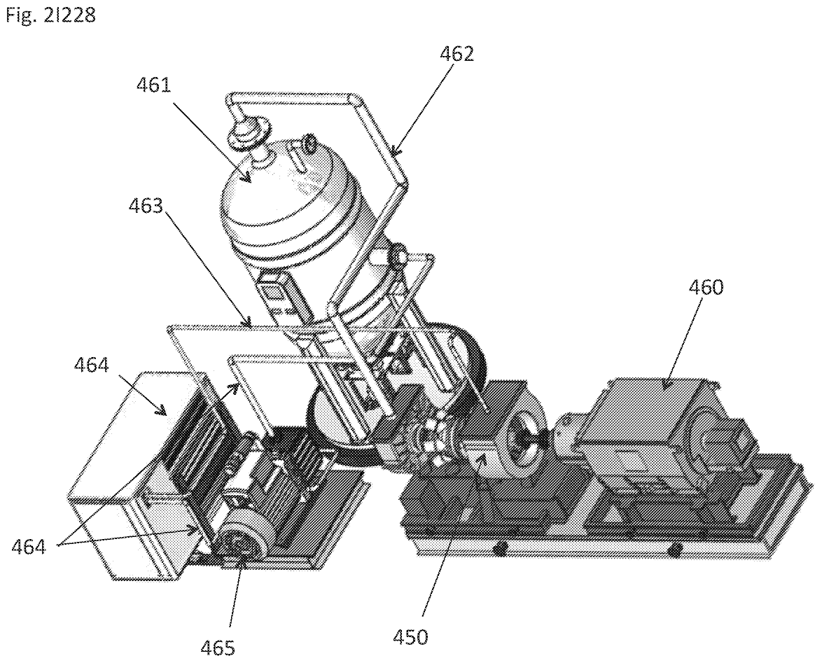

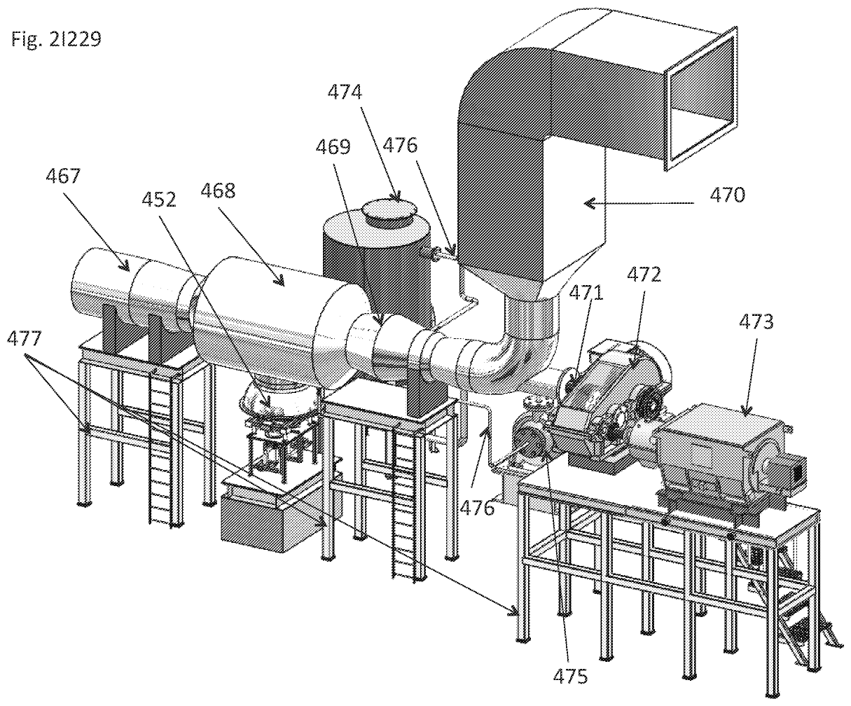

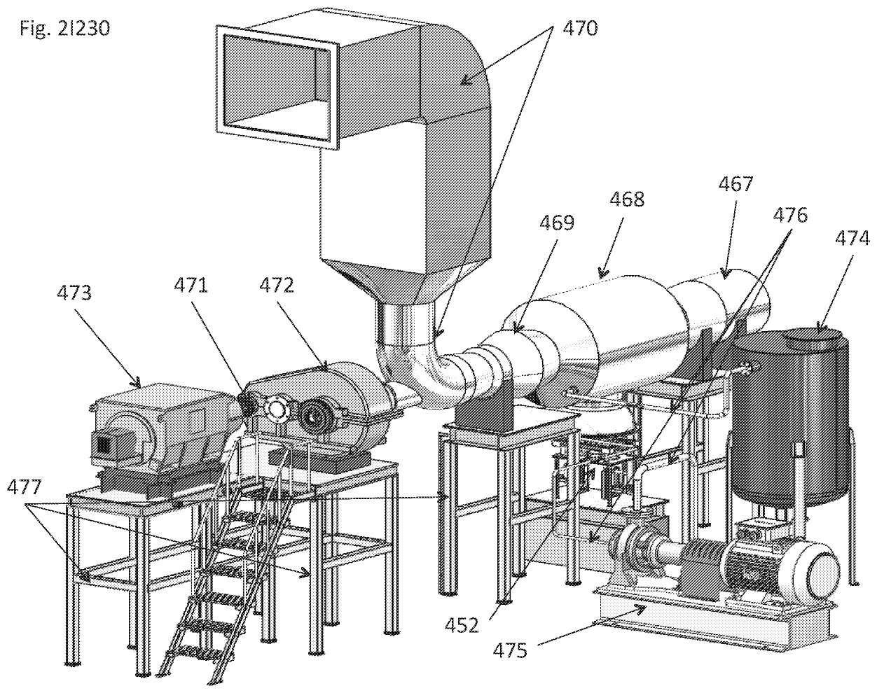

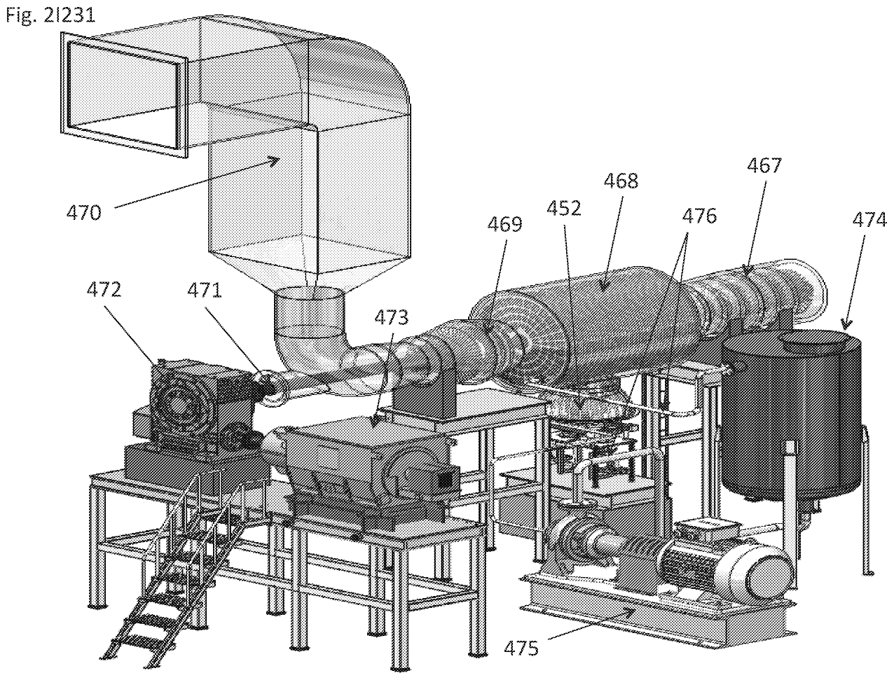

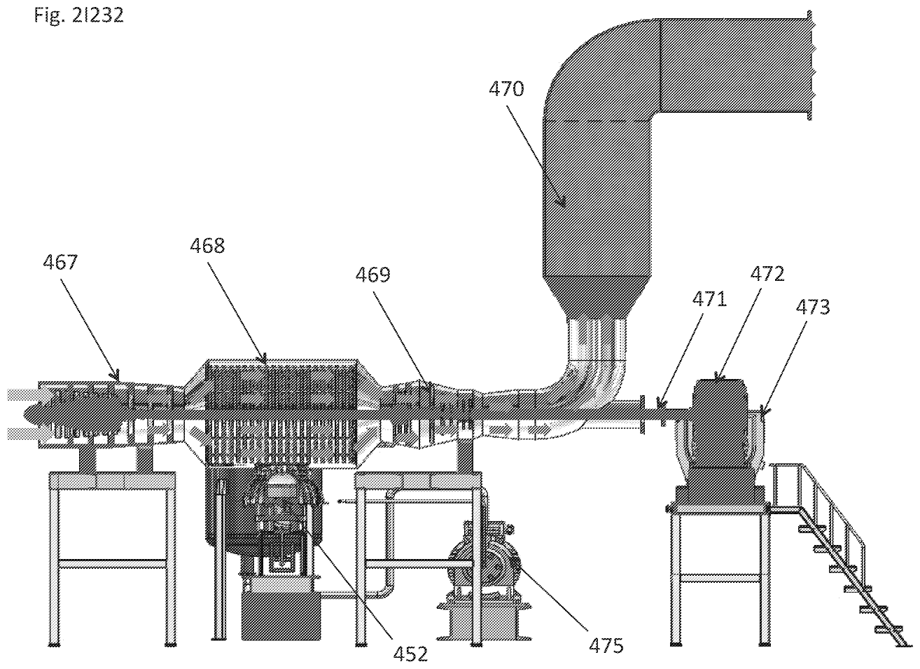

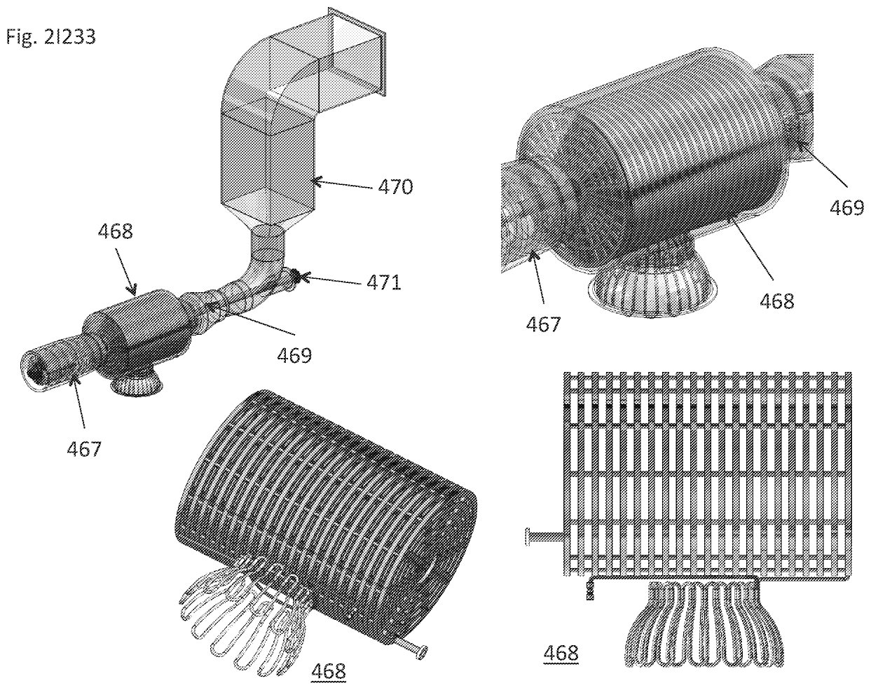

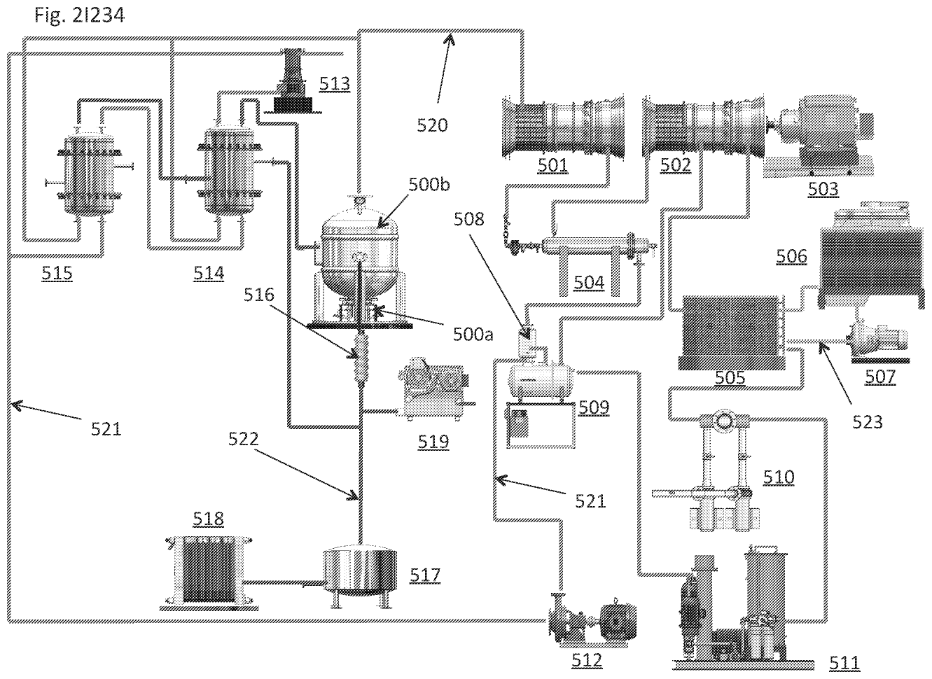

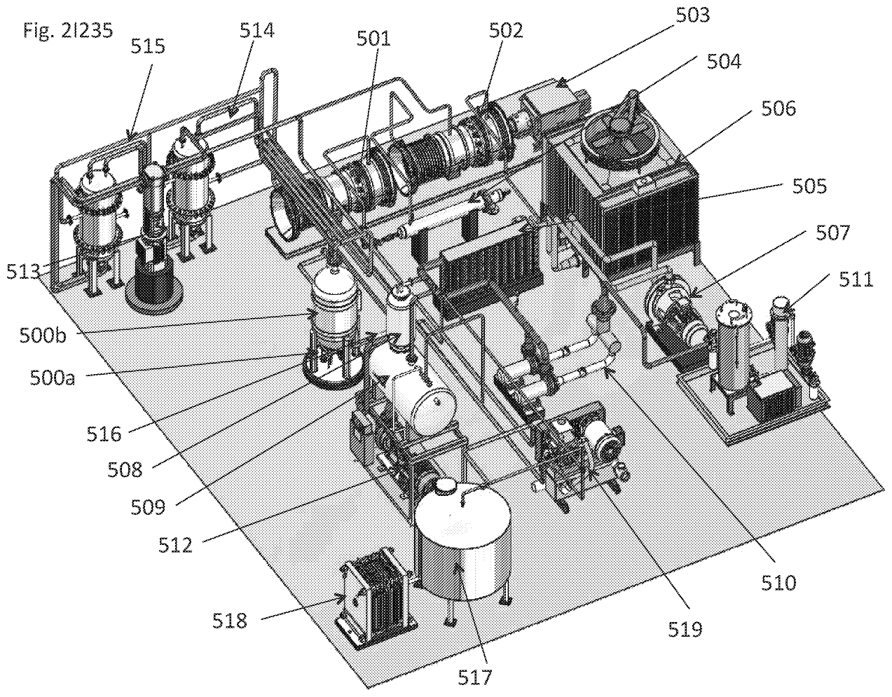

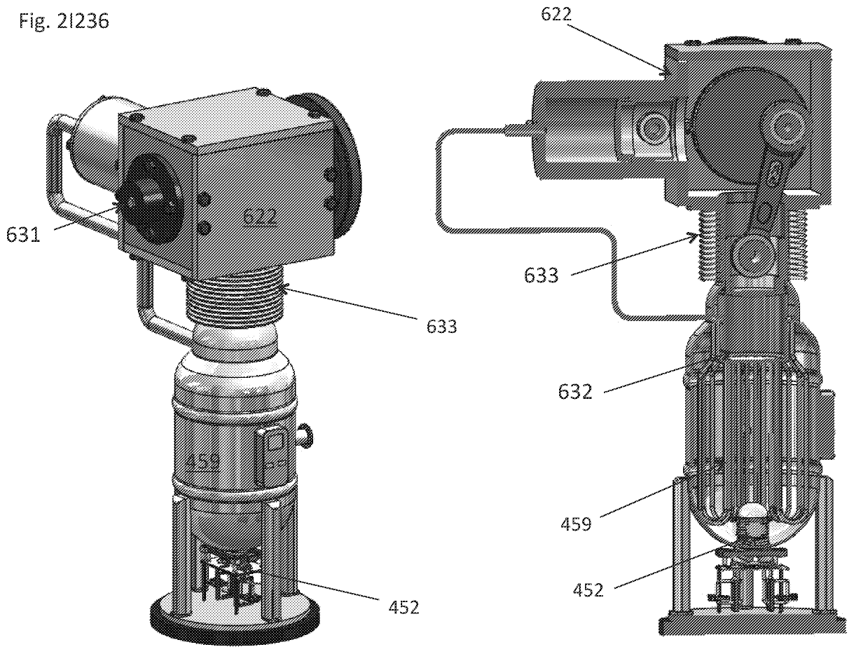

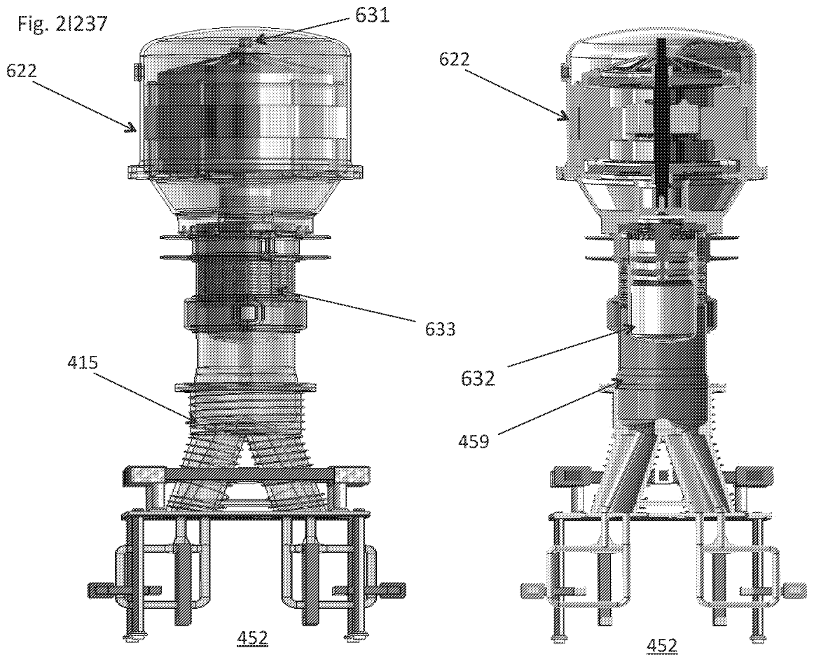

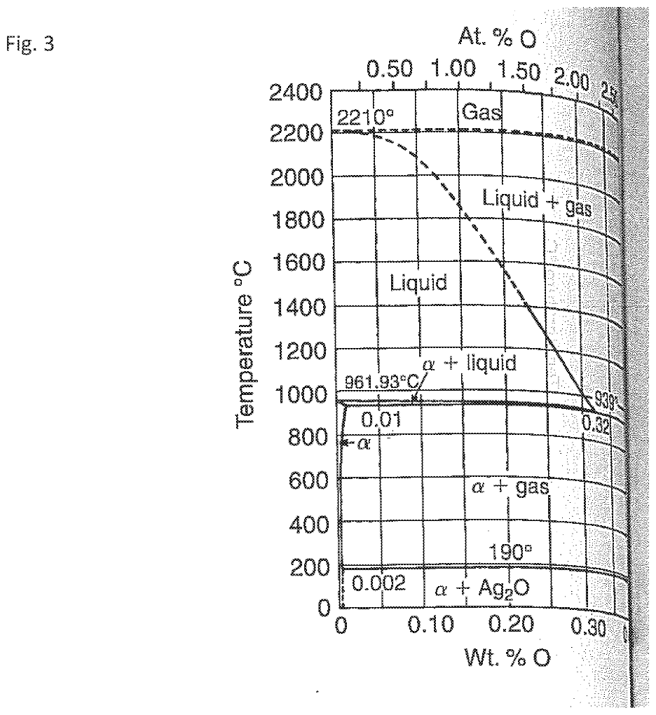

In an embodiment, the silver vapor/aerosol mixture is almost pure liquid plus oxygen at the exit of the MHD nozzle 307. The solubility of oxygen in silver increases as the temperature approaches the melting point wherein the solubility is up to about 40 to 50 volumes of oxygen for volume of silver (FIG. 3). The silver absorbs the oxygen at the MHD channel 308 such as at the exit and both the liquid silver and oxygen are recirculated. The oxygen may be recirculated as gas absorbed in molten silver. In an embodiment, the oxygen is released in the reaction chamber 5b31 to regenerate the cycle. The temperature of the silver above the melting point also serves as a means for recirculation or regeneration of thermal power. The oxygen concentration is optimized to enable a thermodynamic cycle wherein the temperature of the recirculated silver is less than the maximum operating temperature of the SunCell® components such as 1800° C. In an exemplary embodiment, (i) the oxygen pressure in at least one of the reaction cell chamber 5b31 and the MHD nozzle 307 is 1 atm, (ii) the silver at the exit of the MHD channel 308 is almost all liquid such as aerosol, (iii) the oxygen mass flow rate is about 0.3 wt %, and (iv) the temperature at the exit of the MHD channel is about 1000° C. wherein the O₂ accelerates the aerosol and then is absorbed by the 1000° C. silver. The liquid silver-oxygen mixture is recirculated to the reaction cell chamber 5b31 wherein the oxygen is released to form a thermodynamic cycle. The requirement of a gas compressor such as 312a and the corresponding parasitic power load may be reduced or eliminated. In an embodiment, the oxygen pressure may be in at least one range of about 0.0001 atm to 1000 atm, 0.01 atm to 100 atm, 0.1 atm to 10 atm, and 0.1 atm to 1 atm. The oxygen may have a higher partial pressure in one cell region such as at least one of the reaction cell chamber 5b31 and the nozzle 307 relative to the MHD channel exit 308. The SunCell® may have a background oxygen partial pressure than may be elevated in one cell region such as at least one of the reaction cell chamber 5b31 and the nozzle 307 relative to the MHD channel exit 308. In an exemplary embodiment, the oxygen pressures in the reaction cell chamber 5b31 and the MHD condensation section 309 are about 100 atm and 10 atm, respectively. Due to the much higher heat capacity of oxygen and non-condensability at operating temperature, the MHD nozzle may be reduced in size relative to that of an MHD converter that uses only silver vapor to achieve the aerosol jet acceleration.

The effectiveness of using the two-component working fluid comprising the liquid-vapor silver-oxygen system was analyzed as a means of providing extra vapor phase mass early in the nozzle expansion to enhance the aerosol acceleration while minimizing the amount of silver vapor at the nozzle exit. Exemplary parameters of oxygen and silver distributed in liquid and vapor phases before and after nozzle expansion are given in TABLE 2.

TABLE 2
State Parameters of a Silver Vapor, Silver Liquid Aerosol,
Gaseous Oxygen, and Silver Solubilized Oxygen System
Before and after Nozzle Expansion.

| | Initial | Expanded |
|---|---|---|
| | State | State |
| Mixture pressure, [atm] | 10 | 0.1 |
| Temperature, [K] | 3030 | 1800 |
| Mole fraction O in liquid | 0.004533 | 0.004081 |
| Mole fraction O₂ in liquid | 0.002272 | 0.002045 |
| Mole fraction Ag in liquid, | 0.9977 | 0.9980 |
| Mole fraction O₂ in vapor | 0.02443 | 0.9206 |
| Mole fraction Ag in vapor | 0.9756 | 0.07942 |
| Liquid specific volume, | 0.0001240 | 0.0001111 |
| [m³/kg] | | |
| Vapor specific volume, | 0.2345 | 38.84 |
| [m³/kg] | | |
| Mixture specific volume, | 0.08103 | 0.1195 |
| [m³/kg] | | |
| Molar quality | 0.3487 | 0.008661 |
| Mass quality | 0.3451 | 0.003075 |
| Liquid volume fraction | 0.001002 | 0.0009270 |

The thermodynamic cycle may be optimized to maximize the electrical conversion efficiency. In an embodiment, the mixture kinetic energy is maximized while minimizing the vapor fraction. In an embodiment, the recirculation or regeneration of thermal power is achieved as a function of the temperature of recirculated silver from the exit of the MHD channel 308 to the reaction cell chamber 5b31. The temperature of the recirculated silver may be maintained less than the maximum operating temperature of the SunCell® components such as 1800° C. In another embodiment, the Lorentz force may cool the mixture to at least partially condense the liquid phase wherein the corresponding released heat of vaporization is at least partially transferred to the liquid phase. At least one of the MHD nozzle expansion, MHD channel 308 expansion, and Lorentz force cooling in the MHD channel 308 may lower the temperature of the mixture at one or more of the MHD nozzle 307 exit and the MHD channel 308. The heat released by condensation of the vapor may be absorbed by silver to maintain a temperature elevation with power loss to conversion. The silver heated by the heat of vaporization of condensed vapor may be recirculated to regenerate the corresponding thermal power. In another embodiment to raise the efficiency, relatively cold aerosol may be injected into a power conversion component such as the MHD nozzle 307 or the MHD channel 308 by means such as ducting from the reservoir 5c.

In an embodiment, silver aerosol is accelerated in a converging-diverging nozzle by a gas such as at least one of oxygen and a noble gas such as argon or helium. The MHD working medium, the medium that flows through the MHD channel that possesses kinetic energy and electrical conductivity, may comprise silver aerosol, the accelerating gas, and silver vapor. In the case that the working medium comprises oxygen and silver, the working medium may further comprise oxygen absorbed in liquid silver that may be in the form of fine liquid particles or aerosol. The working medium may be recirculated at the end of the MHD channel by a pump such as a compressor (FIGS. 2I167-2I173). At least one of silver vapor, liquid silver, and accelerating gas in the working medium may be recirculated by the pump. The liquid silver may be in the form of aerosol such that the recirculation of about all of the species of the working medium may be recirculated with a gas pump such as a compressor. The accelerating gas may comprise oxygen to cause liquid silver to form or be maintained as silver aerosol to facilitate the recirculation by the gas pump. The accelerating gas such as oxygen may comprise the majority of the mole fraction of the working medium. The accelerating gas mole fraction may be in at least one range of about 50-99 mol %, 50-95 mol %, and 50-90 mol %. In another embodiment, the liquid silver may be recirculated by a liquid metal pump such as one of the disclosure such as an EM pump.

In an embodiment, oxygen may be recirculated by dissolving in silver that is pumped in a loop. The silver is exposed to oxygen at the end of the MHD channel to absorb the oxygen, and the silver comprising oxygen is pumped to release the oxygen to the reaction cell chamber 5b31. The silver comprising oxygen may be heated to release the oxygen at the reaction cell chamber and the silver may be cooled to absorb the oxygen at the end of the MHD channel. In an embodiment, an offset O₂ pressure is maintained in the cell and MHD converter such as in at least one pressure range of about 1 atm to 100 at, 1 atm to 50 atm, and 1 atm to 10 atm. The offset pressure may increase the oxygen absorption in the MHD condensation section 309. In an embodiment, the reaction cell chamber 5b31 temperature may be maintained at a level to avoid formation of significant silver vapor that does not condense during expansion in at least one of the MHD nozzle 307 and MHD channel 308. In an embodiment, condensation shock may be avoided by condensation of silver vapor on aerosol particles during expansion wherein the particles increase in mass. The particle size and expansion operating conditions are maintained to facilitate the vapor condensation on the silver aerosol particles.

In an embodiment, the SunCell® may further comprise a gas-liquid metal separator such as a cyclone separator, a gravity separator, a baffle system, or another known to those skilled in the art. The liquid metal may be recirculated by a pump such as EM pump 312. The SunCell® may comprise a pump or compressor such as 312a to recirculate oxygen (FIGS. 2I167-2I70). The pump may comprise at least one of regenerators and intercoolers to increase the efficiency. In an embodiment to increase the MHD efficiency, the SunCell® may comprise an inlet and exhaust and control systems to perform at least one of exhaust hot O₂ to the atmosphere and input atmospheric O₂ to the compressor such as 312a.

In an embodiment, the SunCell® comprises a separate silver absorption-desorption loop system. The silver absorption-desorption loop system may comprise a pump such as an electromagnetic liquid pump and a heat exchanger. The temperature difference between the reaction chamber 5b31 and the MHD condensation section 309 may drive the cycle. In an embodiment, an offset O₂ pressure is maintained in the cell and MHD converter. In an embodiment, the absorption-desorption loop system comprises a counter current heat exchanger to recover thermal power as hot silver is pumped to the relatively cold MHD condensation section 309 to absorb O₂ and silver comprising absorbed oxygen is pumped to the reaction cell chamber 5b31 to release the O₂. The absorption-desorption loop may operate in parallel with the oxygen-silver aerosol mixture in the MHD channel and the recirculation of silver that may comprise absorbed oxygen. In an embodiment, the silver absorption-desorption loop system may comprise a means to increase the surface area of oxygen-silver contact to increase the absorption rate.

In an embodiment, an MHD cycle comprises isenthalpic expansion in the MHD nozzle section 307 to form an aerosol jet and isobaric flow of the jet in the MHD channel 308. The aerosol may be accelerated in the nozzle 307 by an accelerator gas such as at least one of H₂, O₂, H₂O, or a noble gas. In an embodiment, the pressure of the accelerator gas in the reaction cell chamber 5b31 and the MHD condensation section 309 are above atmospheric such as in at least one range of about 2 to 1000 atmospheres, 5 to 500 atmospheres, and 10 to 100 atmospheres wherein the ratio of the pressures of the accelerator gas in the reaction chamber and the MHD condensation section is greater than one. The pressure ratio may be in at least one range of about 1.5 to 1000, 2 to 500, and 10 to 20. Exemplary pressures of the accelerator gas in the reaction chamber and the MHD condensation section are 100 atmospheres and 10 atmospheres, respectively. The gas temperature of at least one of the reaction cell chamber and the MHD condensation section may be in a range whereby the metal vapor pressure is low such as below 2200° C. in the case of silver vapor. In an embodiment, the mole fraction of the accelerator gas compared to the molten metal such as silver is in at least one range of about 1 to 95 mole %, 10 to 90 mole %, and 20 to 90 mole %. The higher mole % accelerator gas may provide a higher jet kinetic energy at the exit of the MHD nozzle 307.

The accelerator gas may be compressed and recycled. The SunCell® may further comprise a gas-liquid metal separator such as a cyclone separator, a gravity separator, a baffle system, or another known to those skilled in the art. The cyclone separator may comprise the MHD return reservoir 311 or MHD return gas reservoir 311a. The liquid metal may be recycled by EM pump 312. The gas may be cooled before compression. The cooler to cool the gas may comprise a heat exchanger that may transfer heat to compressed gas as it flows from the compressor to the reaction cell chamber. The heat exchanger may comprise a recuperator. The compressor such as MHD return gas pump or compressor 312a may comprise at least one of a multi-stage compressor and at least one intercooler that may be between compression stages. The compression may be performed at about isothermally. In an embodiment, the compressor comprises turbo machinery such as at least one turbocharger.

In another embodiment, the flow form the nozzle 307 comprises silver vapor. The silver vapor may be condensed by a condenser such as heat exchanger 316, which may further serve as a recuperator to supply heat to the recycled stream comprising at least one of molten metal and accelerator gas.

The solubility of oxygen in silver increases with oxygen atmospheric pressure in equilibrium with the dissolved oxygen. A high mole fraction of oxygen in silver may be achieved as shown by J. Assal, B. Hallstedt, and L. J. Gauckler, “Thermodynamic assessment of the silver-oxygen system”, J. Am Ceram. Soc. Vol. 80 (12), (1997), pp. 3054-3060. For example, there is a eutectic between Ag and Ag₂O at a temperature of 804 K, an oxygen partial pressure of 526 bar (5.26×10⁷ Pa), and an oxygen mole fraction in the liquid phase of 0.25. In an embodiment, this eutectic or a similar composition comprising oxygen incorporated in silver may be formed an pumped from the MHD condensation section 309 to the reaction cell chamber 5b31 to recycle the silver and oxygen. The relationship of oxygen solubility in liquid silver is about proportional to the gaseous oxygen pressure to the 1/2 power. In an embodiment, the solubility of oxygen in silver may be increased beyond that which may be achieved by gaseous solvation at a given oxygen pressure by application of at least one of an electric field, an electric potential, and a plasma to the molten silver. In an embodiment, electrolysis or plasma may be applied to the molten silver to increase the O₂ solubility in the liquid silver wherein the molten silver may comprise as an electrolysis or plasma electrode. The application of at least one of an electric field, an electric potential, and a plasma to the molten silver such as application of O₂ electrolysis or plasma may also increase the rate that O₂ dissolves in silver. In an embodiment, the SunCell® may comprise a source of at least one of an electric field, an electric potential, and a plasma to the molten silver. The source may comprise electrodes and at least one of a source of electrical power and plasma power such as glow discharge, RF, or microwave plasma power. The molten silver may comprise an electrode such as a cathode. Molten or solid silver may comprise the anode. Oxygen may be reduced at the anode and react with silver to be absorbed. In another embodiment, the molten silver may comprise an anode. Silver may be oxidized at the anode and react with oxygen to cause oxygen absorption. In an embodiment, the plasma maintains the formation of O atoms from O₂ molecules. When O-atoms instead of O₂ molecules are involved in the oxidation reaction with silver, AgO as well as Ag₂O are thermodynamically stable even at very low O₂ pressures, AgO is more stable than Ag₂O, and it is thermodynamically possible to oxidize Ag₂O to AgO, which may be impossible with O₂ molecules.

The atmosphere at the MHD condensation section 309 may comprise a very low silver vapor pressure, and may comprise predominantly oxygen. The silver vapor pressure may be low due to a low operating temperature such as in at least one range of about 970° C. to 2000° C., 970° C. to 1800° C., 970° C. to 1600° C., and 970° C. to 1400° C. The SunCell® may comprise a means to remove any silver aerosol in the MHD condensation section 309. The means of aerosol removal may comprise a means to coalesce the silver aerosol such as a cyclone separator. The cyclone separator may comprise the MHD return reservoir 311 or MHD return gas reservoir 311a. The silver comprising dissolved oxygen may be recirculated to the reaction cell chamber 5b31 by pumping wherein the pump may comprise an electromagnetic pump. The higher temperature and absence of at least one of an electric field, an electric potential, and plasma applied to the molten silver may cause oxygen to be released from the silver in the reaction cell chamber. In an exemplary embodiment, the silver pressure is very low at the MHD condensation section due to a low operating temperature such as about 1200° C., and a cyclone separator is used to coalesce the silver aerosol into silver liquid which then serves as a negative electrode to electrolyze O₂ into the liquid silver.

In an embodiment, an MHD cycle comprises isenthalpic expansion in the MHD nozzle section 307 to form an aerosol jet and isobaric flow of the jet in the MHD channel 308. The aerosol may be accelerated in the nozzle 307 by an accelerator gas such as at least one of H₂, O₂, H₂O, or a noble gas. In an embodiment, the pressure of the accelerator gas in the MHD condensation section 309 is capable of maintaining plasma of the accelerator gas wherein the ratio of the pressures of the accelerator gas in the reaction chamber and the MHD condensation section is greater than one. The pressure ratio may be in at least one range of about 1.5 to 1000, 2 to 500, and 10 to 20. Exemplary pressures of the oxygen accelerator gas in the reaction chamber and the MHD condensation section are in the range of about 1 to 10 atmosphere and 0.1 to 1 atmospheres, respectively. The reaction cell chamber may comprise some released and plasma maintained O versus O₂ to increase the vapor phase with a corresponding increase in accelerator-caused jet kinetic energy. Some O may recombine to O₂ in at least one of the MHD channel 308 and the MHD condensation sections 309 to increase the pressure gradient from the reaction cell chamber 5b31 to the MHD condensation section 309 to increase the jet kinetic energy and converted electrical power. The gas temperature of at least one of the reaction cell chamber and the MHD condensation section may be in a range whereby the metal vapor pressure is low such as below 2200° C. in the case of silver vapor. In an embodiment, the mole fraction of the accelerator gas such as oxygen compared to the molten metal such as silver is in at least one range of about 1 to 95 mole %, 10 to 90 mole %, and 20 to 90 mole %. The higher mole % accelerator gas may provide a higher jet kinetic energy at the exit of the MHD nozzle 307.

Consider the case that the reaction cell chamber atmosphere is oxygen and silver aerosol that promotes the formation of an aerosol of silver particles. In an embodiment, the aerosol may comprise molten metal nanoparticles such as silver or gallium nanoparticles. The particles may have a diameter in at least one range of about 1 nm to 100 microns, 1 nm to 10 microns, 1 nm to 1 micron, 1 nm to 100 nm, and 1 nm to 10 nm. The silver particles are in the free molecular regime when the particles comprise nanoparticles that are small compared to the mean free path of the suspending gas. Mathematically, the Knudsen number Kₙ given by

$${K}_{n} = \frac{2 λ}{{d}_{Ag}} \qquad ( 66 )$$

is such that Kₙ>>1 wherein λ is the mean path of the suspending oxygen gas and d_{Ag} is the diameter of the silver particle. After Levine [I. Levine, Physical Chemistry, McGraw-Hill Book Company, New York, (1978), pp. 420-421.], the mean path λ_{A} of a gas A of diameter d_{A} colliding with a second gas B of diameter d_{B} and mole fraction f_{B} is given by

$${λ}_{A} = \frac{{k}_{B} T}{{π [ \frac{{d}_{A}}{2} + \frac{{d}_{B}}{2} ]}^{2} {f}_{B} P} \qquad ( 67 )$$

For the gas parameters of 6000 K temperature T, 5 atmospheres (5×10⁵ N/m²) pressure P, 2 mole % oxygen corresponding to a gas fraction f_{O2} of 0.02, and 98 mole % silver corresponding to a silver gas fraction f_{Ag} of 0.98, the mean path λ_{O}_{₂} of the suspending gas oxygen of molecular diameter d_{O}_{₂} of 2.76×10⁻¹⁰ m colliding with a silver particle of diameter d_{Ag} of 2.5×10⁻⁹ m given by Eq. (67) is

$$\begin{matrix}{λ}_{{O}_{2}} = \frac{{k}_{B} T}{{π [ \frac{{d}_{{O}_{2}}}{2} + \frac{{d}_{Ag}}{2} ]}^{2} {f}_{Ag} P} \\ = \frac{( 1.38 \times {10}^{- 23} {JK}^{- 1} ) ( 6000 K )}{{π [ 1.38 \times {10}^{- 10} m + 1.25 \times {10}^{- 9} m ]}^{2} ( 0.98 ) ( 5 \times {10}^{5} {Nm}^{- 2} )} \\ = 2.79 \times {10}^{- 8} m\end{matrix} \qquad ( 68 )$$

wherein k_{B} is the Boltzmann constant. The molecular regime is satisfied for silver aerosol particles having a 2.5 nm diameter. In this regime, particles interact with the suspending gas through elastic collisions with the gas molecules. Thereby, the particles behave similarly to gas molecules wherein the gas molecules and particles are in continuous and random motion, there is no loss or gain of kinetic energy when any particles collide, and the average kinetic energy is the same for both particles and molecules, and the average kinetic energy is a function of the common temperature.

In an embodiment, the working medium of the MHD converter comprises a mixture of the metal nanoparticles such as silver nanoparticles and a gas such as oxygen gas that may at least one of serve as a carrier or expansion assisting gas and at least one of assisting in forming or maintaining the stability of the nanoparticles. In another embodiment, the working medium may comprise metal nanoparticles. The nanoparticle atmosphere may be maintained by maintaining at least one of the cell and plasma temperatures above that which maintains the vapor pressure of the nanoparticles at a desire vapor pressure such as one in at least one range of about 1 to 100 atm, 1 to 20 atm and 1 to 10 atm. The at least one of the cell and plasma temperatures may be within at least one range of about 1000° C. to 6000° C., 1000° C. to 5000° C., 1000° C. to 4000° C., 1000° C. to 3000° C., and 1000° C. to 2500° C.

In an embodiment wherein the temperature of O₂ and silver nanoparticles in the free molecular regime is the same, the ideal gas equations apply to estimate the acceleration of the gas mixture in nozzle expansion. The random kinetic energy of the nanoparticles is about the same as O₂ at the given temperature of the mixture of O₂ and nanoparticles. The root mean squared (RMS) velocity v_{RMS} of a molecules or nanoparticle of mass m that obeys the ideal gas law is given by

$$\begin{matrix} {v}_{RMS} = \sqrt{\frac{3 kT}{m}} \\ For {O}_{2} at 2000 K , & ( 69 ) \\ {v}_{RMS} = \sqrt{\frac{3 kT}{m}} = \sqrt{\frac{3 ( 1.38 \times {10}^{- 23} {JK}^{- 1} ) ( 2000 K )}{5.3 \times {10}^{- 26} kg}} = 1.25 \times {10}^{3} {ms}^{- 1} \\ For a nanoparticle of 345 silver atoms at 2000 K , & ( 70 ) \\ {v}_{RMS} = \sqrt{\frac{3 kT}{m}} = \frac{3 ( 1.38 \times {10}^{- 23} {JK}^{- 1} ) ( 2000 K )}{6.21 \times {10}^{- 23} kg} = 36.5 {ms}^{- 1} & ( 71 )\end{matrix}$$

In an exemplary MHD thermodynamic cycle: 70 mole/O₂-30 mole % silver nanoparticle gases undergoes nozzle expansion, and the resulting kinetic energy of the jet is converted to electricity in the MHD channel. Nanoparticles coalesce to silver liquid at the end of the MHD channel, absorb 0.2 wt % O, and electromagnetic pumps pump the liquid mixture back to the reaction cell chamber. The hydrino reaction in the presence of the released O₂ forms high temperature and pressure 70 mole % O₂-30 mole % silver nanoparticle gas to flow into the nozzle entrance. The corresponding nanoparticle parameter analysis is

Silver forms 0.2 wt % solution with silver, which corresponds to

0.002/MW O/(0.998/MW Ag)=0.0135 atoms O to atoms Ag

In order for O₂ to be 70 mole % with silver nanoparticle treated as a gas, each nanoparticle must comprise the following number of atoms:

2×70/30/0.0135 atoms O to atoms Ag=345 silver atoms per nanoparticle

The corresponding volume is

345 atoms×1 mole/6×10²³ atoms×108 g/mole×1 cm³/10.5 g=6×10²¹ cm³

The nanoparticle diameter D is

D=2×(6×10⁻²¹ cm³×3/(4π))^{1/3}=2.25×10⁻⁷ cm=2.25 nm

which is in the free molecular regime. In an embodiment, the O₂ pressure is increased to achieve 2 wt % O solubility such that the nanoparticle diameter is 1/10 the size. In an embodiment, the size of the metal nanoparticles is controlled such that they behave about as molecules regarding the thermodynamics of nozzle expansion.

In the case that the reaction cell chamber atmosphere comprises silver aerosol having 2 mole % oxygen that is released from being dissolved in silver upon injection into the reaction cell chamber and the aerosol particles behave as a gas in the molecular regime, the volume of the reaction cell chamber per mole gas V′ given by the ideal gas law is

$$\begin{matrix}{V}^{′} = \frac{V}{n} = \frac{RT}{P} = \frac{( 8.315 {Jmole}^{- 1} {K}^{- 1} ) ( 6000 K )}{( 5 \times {10}^{5} {Nm}^{- 2} )} \\ = 9.98 \times {10}^{- 2} {m}^{3} {mole}^{- 1} = 9.98 \times {10}^{1} liters \cdot {mole}^{- 1}\end{matrix} \qquad ( 72 )$$

In an embodiment, the acceleration of the gas mixture comprising molten metal nanoparticles such as silver or gallium nanoparticles in a converging-diverging nozzle may be treated as the isentropic expansion of ideal gas/vapor in the converging-diverging nozzle. Given stagnation temperature T₀; stagnation pressure p₀; gas constant Rᵥ; and specific heat ratio k, the thermodynamic parameters may be calculated using the equations of Liepmann and Roshko [Liepmann, H. W. and A. Roshko Elements of Gas Dynamics, Wiley (1957)]. The stagnation sonic velocity c₀ and density ρ₀ are given by

$${c}_{0} = \sqrt{{kR}_{v} {T}_{0}} , \\ {ρ}_{0} = \frac{{p}_{0}}{{R}_{v} {T}_{0}} \qquad ( 73 )$$

The nozzle throat conditions (Mach number Ma*=1) are given by:

$${T}^{*} = \frac{{T}_{0}}{1 + \frac{( k + 1 )}{2}} , {p}^{*} = \frac{{p}_{0}}{{[ 1 + \frac{( k - 1 )}{2} ]}^{k / ( k - 1 )}} , {ρ}^{*} = \frac{{p}^{*}}{{R}_{v} {T}^{*}} \\ {c}^{*} = \sqrt{{kR}_{v} {T}^{*}} , {u}^{*} = {c}^{*} , {A}^{*} = \frac{m}{{ρ}^{*} {u}^{*}} \qquad ( 74 )$$

where u is the velocity, m is the mass flow, and A is the nozzle cross sectional area. The nozzle exit conditions (exit Mach number=Ma) are given by:

$$T = \frac{{T}_{0}}{1 + \frac{( k + 1 )}{2} Ma} , p = \frac{{p}_{0}}{{[ 1 + \frac{( k - 1 )}{2} {Ma}^{2} ]}^{k / ( k - 1 )}} , ρ = \frac{p}{{R}_{v} T} \\ c = \sqrt{{kR}_{v} T} , u = cMa , A = \frac{m}{ρ u} \qquad ( 75 )$$

Due to the high molecular weight of the nanoparticles, the MHD conversion parameters are similar to those of liquid MHD wherein the MHD working medium is dense and travels at low velocity relative to gaseous expansion.

In an embodiment, the atmosphere in the reaction cell chamber 5b31 is maintained with parameters such as oxygen partial pressure, total pressure, temperature, gas composition such as the addition of a noble gas in addition to at least one of oxygen, hydrogen, and water vapor, and hydrino reaction flow rate that facilities the formation of aerosol particles of sufficiently small size to be in the molecular regime. In an embodiment, at least one of the suspending gas such a silver and the particles such as silver particles may be electrically charged to inhibit collisions between species such that the gas mixture exhibits molecular regime behavior. The silver may comprise an additive to facilitate the particle charging. In an embodiment, the SunCell® may comprise a size selection means to separate the flow of nanoparticles by size. The size selection means may selectively maintain flow of nanoparticles having a size appropriate for molecular regime behavior into the nozzle 307 entrance. The size selection means to select particles of the molecule regime size may comprise a cyclone separator, a gravity separator, a baffle system, screen, thermophoresis separator, or electric field such as an electric or magnetic field separator before the entrance to nozzle 307. In the case of thermophoresis, the large particles may exhibit a positive thermodiffusion effect wherein the large nanoparticles migrate form the hot central region of the plasma to the colder reaction chamber cell 5b31 walls. The plasma may be selectively directed or ducted to flow from the hot central portion into the nozzle entrance.

The nanoparticles may be formed by the vaporization of the metal by the intense local power density of the hydrino reaction in one section of the reaction cell chamber 5b31 with rapid cooling in another cooler section of the reaction cell chamber wherein the temperature may be below the boiling point of the metal at the ambient pressure. In an embodiment, the nanoparticles such a silver or gallium nanoparticles may form by vaporization and condensation of the metal in an atmosphere that comprises oxygen wherein an oxide layer may form on the surfaces of the nanoparticles. The oxide layer may prevent coalescence of the nanoparticles in the aerosol state. At least one of the oxygen concentration, the rate of metal vaporization, the reaction cell chamber temperature and pressure and temperature and pressure gradients may be controlled to control the size of the nanoparticles. The size may be controlled such that the nanoparticles are of size of the molecular regime. The nanoparticles may be accelerated in the MHD section 307, the corresponding kinetic energy may be converted to electricity in the MHD channel section 308, and the nanoparticles may be caused to coalescence in the MHD condensation section 309. The SunCell® may comprise a coalescence surface in the condensation section. The nanoparticles may impact the coalescence surface, coalesce, and the resulting liquid metal that may comprise absorbed oxygen may flow into the MHD return EM pump 312 to be pumped to the reaction cell chamber 5b31.

In an embodiment, the SunCell® may comprise a reduction means to at least partially reduce the oxide coat on the metal nanoparticles. The reduction may permit the nanoparticles to coagulate or coalesce. The coalescence may permit the resulting liquid to be pumped back to the reaction cell chamber 5b31 by the MHD return EM pump 312. The reduction means may comprise an atomic hydrogen source such as hydrogen plasma or chemical dissociator source of atomic hydrogen. The plasma source may comprise a glow, arc, microwave, RF, or other plasma source of the disclosure or known in the art. The hydrogen plasma source may comprise a glow discharge plasma source comprising a plurality of microhollow cathodes that are capable of operating at high pressure such as one atmosphere such as one of the disclosure. The chemical dissociator to serve as an atomic hydrogen source may comprise a ceramic supported noble metal hydrogen dissociator such as Pt on alumina or silica beads such as one of the disclosure. The chemical dissociator may be capable of recombining H₂+O₂. The hydrogen dissociator may comprise at least one of (i) SiO₂ supported Pt, Ni, Rh, Pd, Ir, Ru, Au, Ag, Re, Cu, Fe, Mn, Co, Mo, or W, (ii) Zeolite supported Pt, Rh, Pd, Ir, Ru, Au, Re, Ag, Cu, Ni, Co, Zn, Mo, W, Sn, In, Ga, and (iii) at least one of Mullite, SiC, TiO₂, ZrO₂, CeO₂, Al₂O₃, SiO₂, and mixed oxides supported noble metals, noble metal alloys, and noble metal mixtures. The hydrogen dissociator may comprise a supported bimetallic such as one comprising Pt, Pd Ir, Rh and Ru. Exemplary bimetallic catalysts of the hydrogen dissociator are supported Pd—Ru, Pd—Pt, Pd—Ir, Pt—Ir, Pt—Ru and Pt—Rh. The catalytic hydrogen dissociator may comprise a material of a catalytic converter such as supported Pt. The reduction means may be located in at least one of the MHD condensation section 309 and the MHD return reservoir 311.

In an embodiment, the aerosol that is accelerated in the MHD section 307 comprises a mixture of gas such as at least one of oxygen, H₂, and a noble gas, silver or gallium nanoparticles in the molecular regime, and larger particles such as silver or gallium particles in the diameter range of about 10 nm to 1 mm. At least one of the gas and the nanoparticles in the molecular regime may serve as a carrier gas to accelerate the larger particles as at least one of the gas and nanoparticles in the molecular regime accelerates in the MHD nozzle section 307. The gas and nanoparticles in the molecular regime may comprise a sufficient mole fraction to achieve high kinetic energy conversion of the pressure and thermal energy inventory of the aerosol mixture in the reaction cell chamber 5b31. The mole percentage of the gas and nanoparticles in the molecular regime may comprise at least one range of about 1% to 100%, 5% to 90%, 5% to 80%, 5% to 70%, 5% to 60%, 5% to 50%, 5% to 40%, 5% to 30%, 5% to 20%, and 5% to 10%.

In an embodiment, the nanoparticles may be transported by at least one of thermophoresis or thermal gradients and fields such as at least one of electric and magnetic fields. The nanoparticles may be charged so that the electric field is effective. The charging may be achieved by applying a coating such as an oxide coat by the controlled addition of oxygen.

In an embodiment, at least one of the silver aerosol is coalesced and the hydrino reaction plasma is not maintained in the MHD condensation section 309 such that the conductivity of the ambient atmosphere in the MHD condensation section 309 is such that an electric field, potential, or plasma may be applied to the oxygen gas to cause oxygen to be absorbed into silver which is then recycled to the reaction cell chamber. In an embodiment, the SunCell® may comprise a means to apply a discharge to the vapor phase at the MHD condensation section 309. The discharge may comprise at least one of glow, arc, RF, microwave, laser, and other plasma forming means or discharges known in the art that can dissociate O₂ to atomic O. The discharge means may comprise at least one of a discharge power supply or plasma generator, discharge electrodes or at least one antenna, and wall penetrations such as liquid electrode penetrations or induction coupling power connectors. In another embodiment, the source of atomic oxygen may comprise a hyperthermal generator wherein O₂ absorbs onto the surface of a silver membrane, dissociates into atomic O that diffuses through the membrane to provide O atoms on the opposite surface. The oxygen atoms may be desorbed and then absorbed by molten silver. The means of desorption may comprise a low energy electron beam.

In an embodiment, a high-pressure glow discharge may be maintained by means of a microhollow cathode discharge. The microhollow cathode discharge may be sustained between two closely spaced electrodes with openings of approximately 100 micron diameter. Exemplary direct current discharges may be maintained up to about atmospheric pressure. In an embodiment, large volume plasmas at high gas pressure may be maintained through superposition of individual glow discharges operating in parallel. The electron density in the plasma may be increased at a given current by adding a species such as a metal such as cesium having a low ionization potential. The electron density may also be increased by adding a species such as a filament material from which electrons are thermally emitted such as at least one of rhenium metal and other electron gun thermal electron emitters such as thoriated metals or cesium treated metals. In an embodiment, the plasma voltage is elevated such that each electron of the plasma current gives rise to multiple electrons by colliding with at least one of the silver aerosol particles, the accelerator gas, or an added gas or species such as cesium vapor. The plasma current may be at least one of DC or AC. The AC power may be transfer by an induction power source and receiver, outside and inside of the chamber of the MHD condensation section, respectively.

In an embodiment, the MHD converter may comprise a reservoir such as the MHD return reservoir 311 or MHD return gas reservoir 311a to increase at least one of the dwell time and silver area for oxygen to be absorbed in the silver before recycling to the reaction cell chamber 5b31. The size of the reservoir may be selected to achieve the desired oxygen absorption. The MHD return reservoir 311 or MHD return gas reservoir 311a may further comprise a cyclone separator. The cyclone separator may coalesce silver aerosol particles. The reservoir may comprise an electrolysis or plasma discharge chamber.

In an embodiment, the SunCell® may comprise a means to at least partially reduce any oxide coating on the metal nanoparticles such a silver or gallium nanoparticles. The partial removal of the oxide coat may facilitate the coalescence of the nanoparticles in a desired region of the SunCell® such as in the MHD condensation section 309. The reduction may be achieved by reacting the particles with hydrogen. Hydrogen gas may be introduced into the MHD condensation section at a controlled pressure and temperature to achieve the at least partial reduction. The SunCell® may comprise a means of the current disclosure to maintain a plasma comprising hydrogen to at least partially reduce the oxide coatings. Additional oxygen that is not hydrogen reduced may be absorbed into the coalesced molten metal to be return-pumped to the reaction cell chamber 5b31 to provide oxygen for a cycle of nanoparticle surface oxide formation and reduction.

Due to the energy released in the formation of hydrinos, an observation predicted by Eqs. (1) and (5) is the formation of fast, excited state H atoms from recombination of fast H wherein the fast atoms give rise to greater than 50 eV Balmer α line broadening that reveals a population of extraordinarily high-kinetic-energy hydrogen atoms in certain mixed hydrogen plasmas. In an embodiment, the SunCell® is operated under conditions such as low pressure such as in the range of 0.1 Torr to 10 Torr to facilitate formation of fast H atoms. The fast H atoms may serve as a carrier gas that accelerates silver aerosol particles in an expansion of the aerosol in the MHD nozzle section 307 to form a conductive aerosol jet. The kinetic energy of the jet may be converted into electricity in the MHD channel 308.

In another embodiment, the MHD cycle may comprise gallium metal and a gas that absorbs into molten gallium such as least one of hydrogen and nitrogen as the MHD working medium. Hydrogen may be absorbed by gallium in the MHD condensation section 309. The absorption of at least one of hydrogen and nitrogen in molten gallium may be enhanced by plasma. The plasma may be maintained by a plasma source of the disclosure. The mixture of gallium and absorbed gas may be pumped back to the reaction cell chamber 5b31 where it is released to serve as an accelerator gas to produce a gallium aerosol jet in the MHD nozzle section 307. The pumping may be achieved with an electromagnetic pump such as 312, a mechanical pump, or another pump of the disclosure. The hydrogen gas may also serve as a reactant to form hydrinos.

In an embodiment, at least one component of the power system may comprise ceramic wherein the ceramic may comprise at least one of a metal oxide, alumina, zirconia, magnesia, hafnia, silicon carbide, zirconium carbide, zirconium diboride, silicon nitride, and a glass ceramic such as Li₂O×Al₂O₃×nSiO₂ system (LAS system), the MgO×Al₂O₃×nSiO₂ system (MAS system), the ZnO×Al₂O₃×nSiO₂ system (ZAS system). Ceramic parts of SunCell® may be joined by means of the disclosure such as by ceramic glue of two or more ceramic parts, braze of ceramic to metallic parts, slip nut seals, gasket seals, and wet seals. The gasket seal may comprise two flanges sealed with a gasket. The flanges may be drawn together with fasteners such as bolts. The slip nut joint or gasket seal may comprise a carbon gasket. At least one of the nut, the EM pump assembly 5kk, the reservoir base plate 5b8, and the lower hemisphere 5b41 may comprise a material that is resistant to carbonization and carbide formation such and nickel, carbon, and a stainless steel (SS) that is resistant of carbonization such as SS 625 or Haynes 230 SS. The slip nut joint between the EM pump assembly and a ceramic reservoir may comprise an EM pump assembly 5kk comprising a threaded collar and nut comprising a stainless steel (SS) that is resistant of carbonization such as SS 625 or Haynes 230 SS and a graphite gasket wherein the nut threads onto the collar to tighten against that gasket. The flange seal joint between the EM pump assembly 5kk and the reservior 5c may comprise a reservior base plate 5b8 with bolt holes, a ceramic reservoir having a flange with bolt holes, and a carbon gasket. The EM pump assembly having a reservoir base plate may comprise a stainless steel (SS) that is resistant of carbonization such as SS 625 or Haynes 230 SS. The flange of the reservoir may be fastened to the base plate 5b8 by the bolts tightened against the carbon or graphite gasket. In an embodiment, the carbon reduction reaction between carbon such as a carbon gasket a part comprising an oxide such as an oxide reservoir 5c such as a MgO, Al₂O₃, or ZrO₂ reservoir is avoided by maintaining the joint comprising oxide in contact with carbon at a non-reactive temperature, one below the carbon reduction reaction temperature. In an embodiment, the MgO carbon reduction reaction temperature is above the range of about 2000° C. to 2300° C.

In an exemplary embodiment, a ceramic such as an oxide ceramic such as zirconia or alumina may be metalized with an alloy such as Mo—Mn. Two metalized ceramic parts may be joined by braze. A metalized ceramic part and a metal part such as the EM pump bus bars 5k2 may be connected by braze. The metallization may be coated to protect it from oxidation. Exemplary coatings comprise nickel and noble metals in the case of water oxidant, and a noble metal in the case of oxygen. In an exemplary embodiment, an alumina or zirconia EM pump tube 5k6 is metallized at penetrations for the EM pump bus bars 5k2, and the EM pump bus bars 5k2 are connected to the metallized EM pump tube penetrations by braze. In another exemplary embodiment, the parts from the list of at least two of the EM pump assembly 5kk, the EM pump 5ka, the EM pump tube 5k6, the inlet riser 5qa, the injection EM pump tube 5k61, the reservoirs, the MHD nozzle 307, and the MHD channel 308 may be glued together with ceramic glue. Ceramic parts may be fabricated using methods of the disclosure or known in the art. Ceramic parts may be molded, cast, or sintered from powder, or glued together, or threaded together. In an embodiment, the component may be fabricated in green ceramic and sintered. In an exemplary embodiment, alumina parts may be sintered together. In another embodiment, a plurality of parts may be fabricated as green parts, assembled, and sintered together. The dimensions of the parts and the materials may be selected to compensate for part shrinkage.

In an embodiment, a ceramic SunCell® part such as one comprising at least one of ZrC—ZrB₂—SiC may be formed by ball milling a stoichiometric mixture of the component powders, formed into the desired shape in a mold, and sintered by means such as hot isostatic pressing (HIP) or spark plasma sintering (SPS). The ceramic may have relatively high density. In an embodiment, hollow parts such as the EM pump tube 5k6 may be cast using a balloon for the hollow part. The balloon may be deflated following casting and the part sintered. Alternatively, the parts may be fabricated by 3D printing. Parts such as at least one of the lower hemisphere 5b41 and upper hemisphere 5b42 may be slip cast, and parts such as the reservoirs 5c may be formed by at least one of extrusion and pressing. Other methods of fabrication comprise at least one of spray drying, injection molding, machining, metallization, and coating.

In an embodiment, carbide ceramic parts may be fabricated as graphite that is reacted with the corresponding metal such as zirconium or silicon to make ZrC or SiC parts, respectively. Parts comprising different ceramics may be joined together by methods of the disclosure or methods known in the art such as threading, gluing, wet sealing, brazing, and gasket sealing. In an embodiment, the EM pump tube may comprise tube sections and elbows and bus bar tabs 5k2 that are glued together. In an exemplary embodiment, the glued EM pump tube parts comprise ZrC or graphite that is reacted with Zr metal to form ZrC. Alternatively, the parts may comprise ZrB₂ or similar non-oxidative conductive ceramic.

In an embodiment, at least one of the MHD electrodes 304 and the corresponding bus bars may comprise a conductor that is resistant to oxidation. The conductor may comprise a metal such as a noble metal. The conductor may comprise a coated metal. The coated metal may be capable of operating at high temperature such as a refractory metal such as Mo or W. The coating may comprise a metal such as a noble metal. The noble metal may be a refractory metal. The metal coating may be resistant to forming an alloy with silver. Alternatively, the MHD electrodes 304 may comprise an oxidation resistant stainless steel, such as SS 625. The corresponding bus bars may penetrate the SunCell® wall such as a ceramic wall at a feed through. The feed through seal may comprise a wet seal. The wet seal may be formed by solidification of molten silver. The solidification may be achieved by cooling the penetration. The cooling may be achieved by at least one of conduction, convection, and radiation. The wet seal may comprise a heat exchanger such as a heat radiator that may be cooled by air or by a coolant such as water. The air-cooling may be passive or forced. An exemplary embodiment, the SunCell® comprises Ir coated Mo MHD electrodes 304, and the corresponding bus bars comprise Ir coated Mo wires or rods with silver wet seals at the ceramic penetrations in the quartz-walled MHD condensation section 309 wherein the wet seal is forced air-cooled. The solid electrodes 304 may be offset from the MHD channel 308 wall by insulating spacers 305 that may be resistant to wetting by molten silver.

In an embodiment, the MHD electrodes 304 comprise liquid electrodes such as liquid silver electrodes. The liquid electrodes may comprise a frit such as a ceramic frit such as a quartz frit that is impregnated with silver. The frit may comprise trans-pores. Alternatively, the frit may be drilled with micro holes using at least one of a laser, drill, water jet, or other drilling instrument or method known in the art. The porous ceramic liquid MHD electrodes may be impregnated or loaded with silver by electrodeposition by adhering the porous ceramic such as quartz frit to the cathode of a silver electroplating cell, electroplating silver that extends through the ceramic, and then remove the cathode following deposition in the porous ceramic. The porous liquid electrodes may be loaded with silver by at least one method of centrifugation of molten silver, application of gas pressure gradient on molten silver, use of a fluxing agent such as B₂O₃ with molten silver, dissolving a silver salt and chemically reducing the silver ions such that metal deposits in the pores, deposition such as a high velocity plasma spray such as cold spray, and flow of silver vapor through the frit to be loaded with liquid silver in the pores to serve as the liquid electrode as well as other methods known in the art. The liquid electrode may be fabricated by forming a silver metal alloy and oxidizing the metal such a aluminum, zirconium, or hafnium to form a ceramic such as alumina, zirconia, or hafnia, respectively. The wettability of molten silver towards the frit such as one comprising a ceramic such as quartz may be increased by dissolving O₂ into molten silver. The solubility of O₂ into silver may be increased by increasing an O₂ concentration in an atmosphere in contact with the molten silver.

The liquid electrodes 304 may be offset from the MHD channel 308 wall by electrically insulating spacers 305 such as ceramic spacers such as ones comprising Al₂O₃ that may be resistant to wetting by molten silver. At least one of the MHD electrical leads 305a and feed throughs 301 may comprise solidified molten metal such as solidified silver analogous to a wet seal wherein at least one of the leads or feed throughs may be cooled to maintain the solid metal state. The MHD converter may comprise a patterned structure that comprises at least one component of the group of the MHD electrodes 304, electrically insulated leads such as 305a, insulating electrode separators 305, and feed throughs such as ones that penetrate MHD bus bar feed through flange such as 310. The patterned structure components comprising the liquid electrodes such as silver ones and insulating separators may comprise a wicking material to maintain the liquid metal in the desired shape and spacing of the liquid electrodes such as silver ones with the insulating electrode separators in between. At least one of the wicking material and insulating separators of the patterned structure may comprise ceramic. The wicking material of the liquid electrodes may comprise porous ceramic. In an exemplary embodiment, at least one of the liquid electrode matrix and the gas permeable membrane 309d may comprise a quartz frit. The electrical insulating separator may comprise dense ceramic that may be non-wetting towards the silver. The leads may comprise electrical insulating channels and tubes that may be cooled such as water-cooled to maintain the solidity of the lead. An exemplary embodiment comprises the electrically insulated MHD electrode lead 305a that is cooled to maintain solidified silver inside to serve as the conductive lead. In another embodiment, at least one of the MHD electrical leads 305a and feed throughs 301 may comprise iridium such as a coating such as iridium-coated Mo or an oxidation resistant stainless steel such as 625 SS.

In an embodiment, the ignition system may comprise liquid electrodes. The ignition system may be DC or AC. The reactor may comprise a ceramic such as quartz, alumina, zirconia, hafnia, or Pyrex. The liquid electrodes may comprise a ceramic frit that may further comprise micro-holes that are loaded with the molten metal such as silver.

In an embodiment, each MHD power feed-through 301 comprises a collared-conduit such as one of the wall material such a ceramic that stands off from the wall where the feed through penetrates such through the wall of at least one of the MHD channel 308 or condensation section 309. The feed-through 301 may further comprise an under-sized conductor that does not form an alloy with silver such as a stainless steel or nickel wire or rod. During operation, the outermost portion of the standoff collared-conduit is operated at a temperature that is below the melting point of the molten metal such as silver. The molten metal may fill the conduit to form a solid seal at the outer portion. The inner portion that contacts the cell interior may be contiguous with or connect to at least one molten metal electrode structure such as a mesh that retains molten metals to form a liquid electrode during operation. The rod or wire may be connected to an external bus bar and an internal bus bar or liquid electrode wherein the rod or wire may be coated with silver during operation. In another embodiment, feed-through 301 may connect to a bus bar and penetrate through the cell wall sufficiently to make contact with silver that solidifies to make the electrical connection and seal the wall penetration. In an exemplary embodiment, the MHD feed-through 301 comprises a wet seal MHD feed-through comprising a ceramic collar that stands off from the penetrated wall and a current conductor. The current conductor may externally connect to a bus bar such as a copper bus bar and extent along the standoff collar and wall penetration sufficiently to make contact with silver inside of the cell that solidifies to make an electrical connection and seal the wall penetration. The solidified silver may make electrical contact with at least one liquid silver electrode. The liquid electrode may comprise a material into which silver wicks. The wick material may be the same or a different material than that of the wall of the MHD component. The wick material may comprise the same material as that of the wall of the MHD component, but may have a different porosity or roughness such as at least one of a higher porosity and roughness.

Exemplary materials for the SunCell® with a MHD converter comprise (i) reservoirs 5c, reaction cell chamber 5b31, and nozzle 307: solid oxide such as stabilized zirconia or hafnia, (ii) MHD channel 308: MgO or Al₂O₃, (iii) electrodes 304: ZrC, or ZrC—ZrB₂, ZrC—ZrB₂—SiC, and ZrB₂ with 20% SiC composite that may work up to 1800° C., or metal coated with a noble metal, (iv) EM pump 5ka: metal such as stainless steel coated with a noble metal such as at least one of platinum (Pt), palladium (Pd), ruthenium (Ru), rhodium (Rh), and iridium (Ir) or 410 stainless steel coated with a material having a similar coefficient of thermal expansion such as Paloro-3V palladium-gold-vanadium alloy (Morgan Advanced Materials), (v) reservoir 5c-EM pump assembly 5kk union: an oxide reservoir such as ZrO₂, HfO₂, or Al₂O₃ that is brazed to a 410 stainless steel EM assembly 5kk base plate wherein the braze comprises Paloro-3V palladium-gold-vanadium alloy (Morgan Advanced Materials), (vi) injector 5k61 and inlet riser tube 5qa: solid oxide such as stabilized zirconia or hafnia, and (vii) oxygen selective membrane: BaCo_{0.7}Fe_{0.2}Nb_{0.1}O_{3-δ} (BCFN) oxygen permeable membrane that may be coated with Bi₂₆Mo₁₀O₆₉ to increase the oxygen permeation rate.

In an embodiment, the SunCell® further comprises an oxygen sensor and an oxygen control system such as a means to at least one of dilute the oxygen with a noble gas and pump away the noble gas. The former may comprise at least one of a noble gas tank, valve, regulator, and pump. The latter may comprise at least one of a valve and pump.

The hydrino reaction mixture of the reaction cell chamber 5b31 may further comprise a source of oxygen such as at least one of H₂O and a compound comprising oxygen. The source of oxygen such as the compound comprising oxygen may be in excess to maintain a near constant oxygen source inventory wherein during cell operation a small portion reversibly reacts with the supplied source of H such as H₂ gas to form HOH catalyst. Exemplary compounds comprising oxygen are MgO, CaO, SrO, BaO, Zr₂, HfO₂, Al₂O₃, Li₂O, LiVO₃, Bi₂O₃, Al₂O₃, WO₃, and others of the disclosure. The oxygen source compound may be the one used to stabilize the oxide ceramic such as yttria or hafnia such as yttrium oxide (Y₂O₃), magnesium oxide (MgO), calcium oxide (CaO), strontium oxide (SrO), tantalum oxide (Ta₂O₅), boron oxide (B₂O₃), TiO₂, cerium oxide (Ce₂O₃), strontium zirconate (SrZrO₃), magnesium zirconate (MgZrO₃), calcium zirconate (CaZrO₃), and barium zirconate (BaZrO₃).

In an exemplary embodiment wherein the conductivity is greater than about 20 kS/m and the plasma gas temperature is about 4000 K, the reaction chamber pressure is maintained in the range of about 15 MPa to 25 MPa to maintain flow in the MHD channel 308 against the Lorentz force. In an exemplary embodiment, the conductivity is maintained at about 700 S/m, the plasma gas temperature is about 4000 K, the reaction cell chamber 5b31 pressure is about 0.6 MPa, the nozzle 307 exit velocity is about Mach 1.24, the nozzle exit area is about 3.3 cm², the nozzle exit diameter is about 2.04 cm, the nozzle exit pressure is about 213 kPa, the temperature at the nozzle exit is about 2640 K, mass flow through the nozzle is about 250 g/s, the magnetic field strength in the MHD channel 308 is about 2 T, the MHD channel 308 length is about 0.2 m, the MHD channel exit pressure is about 11 kPa, the MHD channel exit temperature is about 1175 K, and the output electrical power is about 180 kW. In an ideal embodiment, the efficiency is determined by the Carnot equation wherein the non-avoidable losses of power from the plasma temperature to ambient temperature are the gas and liquid metal pump losses.

In an embodiment, an MHD converter for any power source such as nuclear or combustion capable of heating silver to form at least one of silver vapor and silver aerosol comprises the MHD converter of the disclosure further comprising at least one heat exchanger to transfer heat from the power source to heat at least one of the reservoirs 5c and the reaction cell chamber 5b31 to produce at least one of silver vapor and silver aerosol. The MHD converter may further comprise a source of ionization such as at least one of seeding such as an alkali metal such as cesium that is thermally ionized and an ionizer such as a laser, an RF discharge generator, a microwave discharge generator, and a glow discharge generator.

In an embodiment of the SunCell® power system comprising a heater power converter, the EM pumps of the dual molten metal injectors may each comprise an inductive type electromagnetic pump to inject the stream of the molten metal that intersects with the other inside of the vessel. The source of electrical power of the ignition system may comprise an induction ignition system 410 that may comprise a source of alternating magnetic field through a shorted loop of molten metal that generates an alternating current in the metal that comprises the ignition current. The source of alternating magnetic field may comprise a primary transformer winding 411 comprising a transformer electromagnet and a transformer magnetic yoke 412, and the silver may at least partially serve as a secondary transformer winding such as a single turn shorted winding that encloses the primary transformer winding and comprises as an induction current loop. The reservoirs 5c may comprise a molten metal cross connecting channel 414 that connects the two reservoirs such that the current loop encloses the transformer yoke 412 wherein the induction current loop comprises the current generated in molten silver contained in the reservoirs 5c, the cross connecting channel 414, the silver in the injector tubes 5k61, and the injected streams of molten silver that intersect to complete the induction current loop. The reaction gases such as hydrogen and oxygen may be supplied to the cell through the gas inlet and evacuation assembly 309e of gas housing 309b. The gas housing 309e may be outside of a spherical heat exchanger along the axis of the top pole of the sphere. The gas housing may comprise a thin gas line connection to the top of the spherical reaction cell chamber 5b31 at a flange connection. The gas line connection may run inside of a concentric coolant flow pipe that supplies coolant flow to the spherical heat exchanger. On the reaction cell side, the flange connection to the gas line may connect to a semipermeable gas 309d membrane such as a porous ceramic membrane.

A SunCell® heater or thermal power generator embodiment (FIGS. 2I207-2I214) comprises a spherical reactor cell 5b31 with a spatial separated circumferential half-spherical heat exchanger 114 comprising panels or sections 114a that receive heat by radiation from the spherical reactor 5b4. Each panel may comprise a section of a spherical surface defined by two great circles through the poles of the sphere. The heat exchanger 114 may further comprise a manifold 114b such as a toroid manifold with coolant lines 114c from each of the panels 114a of the heat exchanger and a coolant outlet manifold 114f. Each collant line 114c may comprise a coolant inlet port 114d and a coolant outlet port 114e. The thermal power generator may further comprise a gas cylinder 421 with has inlet and outlet 309e and a gas supply tube 422 that runs through the top of the heat exchanger 114 to the gas permeable membrane 309d on top of the spherical cell 5b31. The gas supply tube 422 can run through the coolant collection manifold 114b at the top of the heat exchanger 114. In another SunCell® heater embodiment (FIG. 2I207), the reaction cell chamber 5b31 may be cylindrical with a cylindrical heat exchanger 114. The gas cylinder 421 may be outside of the heat exchanger 114 wherein the gas supply tube 422 connects to the semipermeable gas membrane 309d on the top of the reaction cell chamber 5b31 by passing through the heat exchanger 114. At least one of the reaction cell chamber 5b31, the gas membrane 309d on the top of the reaction cell chamber 5b31, and at least a portion of the gas supply tube 422 may comprise ceramic. The gas supply tube 422 that connects to the gas cylinder 421 may comprise metal such a stainless steel. The ceramic and metal portions of the gas supply tube 422 may be joined by a gas supply tube ceramic to metal flange 422a that may comprise a gasket such as a carbon gasket.

Cold water may be fed in inlet 113 and heated in heat exchanger 114 to form steam that collects in boiler 116 and exists steam outlet 111. The thermal power generator may further comprise dual molten metals injectors comprising induction EM pumps 400, reservoirs 5c, and reaction cell chamber 5b31. At least one SunCell® heater component such as the reservoirs 5c may be heated with an inductively coupled heater antenna 5f or other heater such as a resistive, flame, or catalytic chemical heater such as one of the disclosure. The SunCell® heater may comprise an induction ignition system such as one comprising an induction ignition transformer winding 411 and an induction ignition transformer yoke 412.

In an embodiment, the molten metal may comprise any conductive metal or alloy known in the art. The molten metal or alloy may have a low melting point. Exemplary metals and alloys are gallium, indium, tin, zinc, and Galinstan alloy wherein an example of a typical eutectic mixture is 68% Ga, 22% In, and 10% Sn (by weight) though proportions may vary between 62-95% Ga, 5-22% In, 0-16% Sn (by weight). In an embodiment wherein the metal may be reactive with at least one of oxygen and water to form the corresponding metal oxide, the hydrino reaction mixture may comprise the molten metal, the metal oxide, and hydrogen. The metal oxide may comprise one that thermally decomposes to the metal to release oxygen such as at least one of Sn, Zn, and Fe oxides. The metal oxide may serve as the source of oxygen to form HOH catalyst. The oxygen may be recycled between the metal oxide and HOH catalyst wherein hydrogen consumed to form hydrino may be resupplied. The cell material may be selected such that they are non-reactive at the operating temperature of the cell. Alternatively, the cell may be operated at a temperature below a temperature at which the material is reactive with at lest one of H₂, O₂, and H₂O. The cell material may comprise at least one of stainless steel, a ceramic such as silicon nitride, SiC, BN, a boride such as YB₂, a silicide, and an oxide such as Pyrex, quartz, MgO, Al₂O₃, and ZrO₂. In an exemplary embodiment, the cell may comprise at least one of BN and carbon wherein the operating temperature is less than about 500 to 600° C. In an embodiment, at least one component of the power system may comprise ceramic wherein the ceramic may comprise at least one of a metal oxide, alumina, zirconia, magnesia, hafnia, silicon carbide, zirconium carbide, zirconium diboride, silicon nitride, and a glass ceramic such as Li₂O×Al₂O₃×nSiO₂ system (LAS system), the MgO×Al₂O₃×nSiO₂ system (MAS system), the ZnO×Al₂O₃×nSiO₂ system (ZAS system).

In an embodiment the injection metal may have a low melting point such as one having a melting point below 700° C. such as at least one of bismuth, lead, tin, indium, cadmium, gallium, antimony, or alloys such as Rose's metal, Cerrosafe, Wood's metal, Field's metal, Cerrolow 136, Cerrolow 117, Bi—Pb—Sn—Cd—In—Tl, and Galinstan. At least one component such as the reservoirs 5c may comprise a ceramic such as zirconia, alumina, quartz, or Pyrex. The end of the reservoirs may be metalized to facilitate connection to a metal reservoir base plate or base of electromagnetic pump assembly 5kk1. The union between the reservoir and the base of electromagnetic pump assembly 5kk1 may comprise braze or solder such as silver solder. Alternatively, the union may comprise a gasketed flange seal. The EM pumps may comprise metal EM pump tubes 5k6, ignition electromagnetic pump bus bars 5k2, and ignition connections such as ignition electromagnetic pump bus bars 5k2a. At least one of the molten metal injection and ignition may be driven by DC current wherein the injection pumps may comprise DC EM pumps. At least one of the DC EM pump tube 5k6, the reservoir support 5kk1, the EM pump bus bars 5k2, and the ignition bus bars 5k2a may comprise metal such as stainless steel. The ignition bus bars 5k2a may connect to at least one of the reservoir support 5kk1 and the DC EM pump tube 5k6. The reaction cell chamber 5b31 may comprise a ceramic such as zirconia, alumina, quartz, or Pyrex. Alternatively, the reaction cell chamber 5b31 may comprise SiC coated carbon. The SunCell® may comprise inlet risers 5qa such as ones with tampered channels or slots from the top to the bottom or a plurality of holes that throttle the inflowing molten metal as the reservoir level drops. The throttling may serve to balance the reservoirs levels while avoiding extremes in disparity on the levels. The initial molten metal fill level and the height of the bottom on the inlet may be selected to set the maximum and minimum reservoirs heights.

In an embodiment, the molten metal comprises gallium or an alloy such as Ga—In—Sn alloy. The SunCell® having a low-melting point metal such as one that melts below 300° C. may comprise a mechanical pump to inject the molten metal into the reaction cell chamber 5b31. The mechanical pump may replace the EM pump such as induction EM pump 400 for an operating temperature below the maximum capability of a mechanical pump, and an EM pump may be used in case that the operating temperature is higher. Typically mechanical pumps operate up to a temperature limit of about 300° C.; however, ceramic gear pumps operate as high as 1400° C. Lower temperature operation such as below 300° C. is well suited for hot water and low pressure steam applications wherein the heater SunCell® comprise a heat exchanger 114 such as one shown in FIG. 2I207. Reactant gases such as H₂ and O₂ may be added to the cell such as the reaction cell chamber 5b31 by diffusion through a gas permeable membrane 309d from a tank 422 and line 422.

In an embodiment, the molten metal may comprise an alloy such as Ga—Ag alloy. The alloy may comprise at least one desirable property such as (i) corrosion resistant that may permit the reaction mixture gas to comprise at least one of water vapor, (ii) the ability to fume, (iii) the ability to support plasma in the absence of ignition power, (iv) the ability to enable MHD conversion, (v) the ability to reduce ignition current resistance, and (vi) the ability to ionize to support more conductive plasma. At least one of the reaction mixture gas may and the molten metal comprise an additive with relatively low ionization energy such as xenon gas or an alkali or alkaline earth metal that may form an alloy. In the case that the added metal oxide such as Cs₂O is less stable that the oxide such as gallium oxide of the molten metal such as gallium, the former oxide may be added to achieve the addition of the additive having lower ionization energy. The additive may increase at least one of the electron density, plasma conductivity, and plasma intensity.

In an embodiment, the positive reservoir 5c and molten metal injector 5kk and 5q that comprises the positive ignition electrode is selectively melted due to the favorability of the hydrino reaction at the corresponding cathode. In an embodiment, the SunCell® comprises at least one of submerged nozzles 5q, refractory nozzles 5q, refractory inlet risers 5qa, and an alternating current (AC) ignition power supply 2 to switch the hydrino reaction between the two corresponding injector electrodes that alternate the positive polarity. The AC frequency may be selected to achieve electrode protection by alternating the site of the hydrino reaction. Ceramic nozzles may prevent current flow through the inlet riser and distribute the hydrino reaction over a larger area while being stable to high operating temperature. Suitable refractory materials are those of the disclosure such as Mo, W, SiC, alumina, zirconia, and quartz. In an embodiment, the SunCell® comprises at least one of an induction ignition system with a cross connecting channel of reservoirs 414 and induction EM pumps that permit deeply submerged nozzles 5q of the present disclosure to avoid damage of at least one of the inlet risers and the nozzles.

In an embodiment such as a SunCell® comprising an ignition system comprising ignition bus bars such as ignition electromagnetic pump bus bars 5k2a, the resistance is decreased to increase the ignition current. The SunCell® may comprise ignition bus bars that directly contact the molten metal such as that in the reservoirs 5c. The ignition bus bars may comprise a penetration of the reservoir support plate 5b8 to directly contact the molten metal such as silver or gallium. The SunCell® may comprise submerged electrodes such as submerged EM pump injectors 5k61 that provide direct electrical contact between the reservoir molten metal and the molten metal of the stream created by a corresponding electromagnetic pump. The electrical circuit of at least one injected molten metal stream may comprise ignition bus bars 5k2a that penetrate the reservoir support plate 5b8, the molten metal in the reservoirs 5c, and the reservoir molten metal that contacts the corresponding stream from the submerged EM pump injector wherein the stream penetrates the molten metal to reach the counter stream or corresponding counter electrode. The reservoir may comprise a sufficient area at the top to provide a sufficient molten metal volume to avoid fluctuations in injection wherein the volume is given by the area times the submersion depth. The fluctuations in injection may be due to variations in flow rate of the return molten metal stream that effect at least one of the submersion depth and turbulence at the molten metal surface.

The plasma reaction was observed to be much more intense on the positive electrode as predicted based on the arc current mechanism of ion recombination to greatly increase the hydrino reaction kinetics. In a hydrino reactor, the positive electrode is unique in contrast to a glow discharge wherein the negative electrode is where the plasma power is dissipated and the glow is generated. In an embodiment, the injector reservoir 5c may further comprise a portion of the bottom of the reaction cell chamber 5b31 wherein the counter electrode may comprise a non-injector reservoir comprising an extension or pedestal 5c comprising a raised pedestal electrode that is electrically isolated from the injector reservoir and electrode (FIG. 2I215). The counter electrode or non-injector electrode may comprise an electrical insulator and may further comprise a drip edge to provide the electrical isolation. The injector electrode and counter electrode may be negative and positive, respectively.

In an embodiment, the top of the non-injector reservoir and electrode may comprise at least one of a backboard to receive the incident injected molten metal stream from the injector electrode and a drip edge. In another embodiment, the injector electrode nozzle 5qa, which may be submerged, may comprise a shield that dampens turbulence while maintaining enough flow to the nozzle to maintain its submersion.

To further reduce resistance, the components such as at least one of the ignition bus bars 5k2a and reservoir support plate 5b8 that maintain the electrical circuit comprising at least one molten metal stream may comprise a highly electrically conductive material such as Mo. The material may be selected such that it does not react with the component. The material may be stable to alloy formation with the molten metal. In an embodiment, a highly conductive bus bar such as one comprising copper may run below a reservoir base plate 5b8 comprised of a material that does not react with the molten metal such a stainless steel wherein the current from the external bus bar flows across the reservoir base plate 5b8 to the region wherein the molten metal is in contact on the other side of the base plate. The components of one reservoir and corresponding electrode are electrically isolated form that of the other except by the injected molten metal streams.

In an embodiment such as one shown in FIGS. 2I215-2I218, the SunCell® comprises two molten metal reservoirs 5c that may be mounted on tilted reservoir baseplates 409a and tilted EM pump assembly baseplates 409b to support tilted reservoirs 5c. But the SunCell® may comprise only one molten metal injector such as a gallium or silver injector comprising an electromagnetic pump 5kk, EM pump tube injector section 5k61, and nozzle 5qa that injects molten metal from the corresponding injector reservoir 5c into the reaction cell chamber 5b31, and the other reservoir may comprise a non-injector reservoir. The tilted EM pump assembly baseplates 409b may be mounted on a slide table 409c to permit adjustments in the alignment of cell components during assembly. Gases may be supplied to the reaction cell chamber 5b31, or the chamber may be evacuated through gas ports such as 409h. In an embodiment, at least one of the reservoirs 5c and the reaction cell chamber 5b31 may comprise quartz or Pyrex wherein the reservoirs may be sealed to a metal baseplate comprising a metal EM pump tube 5k6 by a flange and a gasket such as a carbon gasket, flexible ceramic gasket, ones comprising spiralwound plies of metal and filler such as stainless steel and ceramic such as Thermiculite (Flexitallic) and those of Henning Inc. gasket and seals, or other known in the art. The flange seal may be achieved with a fastener such as bolts or a clamp such as a band clamp, or another clamp known by those skilled in the art. The metal components may comprise oxidation resistant stainless steel such as SS 625. In a thermal SunCell® embodiment shown in FIG. 2I218, the heat exchanger 114 may comprise an coolant inlet manifold 114g to supply coolant to the coolant inlet ports 114d, and the EM pump 5kk may comprise a DC conductive EM pump.

In another exemplary embodiment, the SunCell® having a pedestal electrode shown in FIGS. 2I216-2I217 comprises (i) an injector reservoir 5c, EM pump tube 5k6 and nozzle 5q, a reservoir base plate 409a, and a spherical reaction cell chamber 5b31 dome comprising lower 5b41 and upper 5b42 hemispheres joined by a fastener such as a bolted flange 407 that may comprise stainless steel (SS) wherein the unions between components may be welded together, (ii) a non-injector reservoir comprising a sleeve reservoir 409d that may comprise SS welded to the lower hemisphere 5b41 with a sleeve reservoir flange 409e at the end of the sleeve reservoir 409d, (iii) an electrical insulator insert reservoir 409f comprising a pedestal 5c1 at the top and an insert reservoir flange 409g at the bottom that mates to the sleeve reservoir flange 409e wherein the insert reservoir 409f, pedestal 5c that may further comprise a drip edge 5c1a, and insert reservoir flange 409g may comprise a ceramic such as boron nitride, silicon carbide, alumina, zirconia, hafnia, or quartz, or a refractory material such as a refractory metal, carbon, or ceramic with a protective coating such as SiC or ZrB₂ such as one comprising SiC or ZrB₂ carbon and (iv) a reservoir base plate 409a such as one comprising SS having a penetration for the ignition bus bar 10a1 and an ignition bus bar 10 wherein the baseplate bolts to the sleeve reservoir flange 409e to sandwich the insert reservoir flange 409g. The penetration for the ignition bus bar 10a1 may comprise a welded in ignition bus bar 10. The flange joints may be sealed with gaskets, O-rings, or other sealing means such as one of the disclosure. The flange fasteners such as bolts or clamps may be nonconductive or protected by an insulator such as at least one of non-conductive sleeves, bushings, plates, shims, and washers. The bolts or fasteners may comprise ceramic bolts or fasteners, or the bolts or fasteners may be ceramic coated. An exemplary fastener comprises TiO₂ coated titanium blots. In an embodiment, the fasteners may comprise a metal that is oxidized to provide an electrically insulating coat such as fasteners comprising one or more of TiO₂ coated Ti, ZrO₂ coated Zr, HfO₂ coated Hf, and Al₂O₃ coated Al. Alternatively, the reservoir base plate 409a may be coated with a non-conductor such as a ceramic coating where the bolts make contact with the baseplate. In another embodiment, the electrical insulator insert reservoir 409f comprising a pedestal 5c1 at the top comprises an insert reservoir flange 409g at the bottom that mates to the sleeve reservoir flange 409e wherein the insert reservoir flange 409g is part of a reservoir base plate 409a. The reservoir base plate 409a further comprises a penetration for the ignition bus bar 10a1 and an ignition bus bar 10 such as a Swagelok or other type of sealing penetration known by those skilled in the art. Other materials such as other ceramics such as Pyrex, quartz, silicon carbide, alumina, hafnia, or yttria and other fasteners and ignition bus bar penetrations 10a1 known by those skilled in the art that may perform about the same function may be substituted for those of the disclosure. Components of multi-component ceramic systems such as those of the non-injector electrode comprising the drip edge 5c1a, insert reservoir 409f, and sleeve reservoir flange 409e may be joined by an adhesive such as ceramic glue or may be molded or cast as integrated components. Glued parts may have topographic relief patterns such as counter sunk or lowered or raised portions to facilitate the component gluing. The components such as the reservoirs, insert reservoir, pedestal, and drip edge may comprise other materials and coatings of the disclosure or known in the art.

In an embodiment shown in FIG. 2I219, an inverted pedestal 5c2 and ignition bus bar and electrode 10 are at least one of oriented in about the center of the cell 5b3 and aligned on the negative z-axis wherein at least one counter injector electrode 5k61 injects molten metal from its reservoir 5c in the positive z-direction against gravity where applicable. The injected molten stream may maintain a coating or pool of liquid metal in the pedestal 5c2 against gravity where applicable. The pool or coating may at least partially cover the electrode 10. The pressure of the stream may be adjusted to counter any pressure wave from the ignition that may deflect the molten metal injection stream. The pressure may be adjusted by adjusting the EM pump power by means such as by adjustment of the EM pump current. In an exemplary embodiment, the upward injection force (pressure) is increased by controlling the EM pump current until the molten metal stream is not deflected. The pedestal may be located in a position such as in about the center of the reaction cell chamber 5b31 to reduce pressure wave stream deflection. The pedestal may be positively biased and the injector electrode may be negatively biased. In another embodiment, the pedestal may be negatively biased and the injector electrode may be positively biased wherein the injector electrode may be submerged in the molten metal. The molten metal such as gallium may fill a portion of the lower portion of the reaction cell chamber 5b31. In addition to the coating or pool of injected molten metal, the electrode 10 such as a Mo electrode may be stabilized from corrosion by the applied negative bias. In an embodiment, the electrode 10 may comprise a coating such as an inert conductive coating such as an iridium coating to protect the electrode from corrosion. In an embodiment the electrode may be cooled. The cooling may reduce at least one of the electrode corrosion rate and the rate of alloy formation with the molten metal. The cooling may be achieved by means such as centerline water cooling.

In an embodiment, the sleeve reservoir 409d may comprise a tight fitting electrical insulator of the ignition bus bar and electrode 10 such that molten metal is contained about exclusively in a cup or drip edge 5c1a at the end of the inverted pedestal 5c2. The insert reservoir 409f having insert reservoir flange 409g may be mounted to the cell chamber 5b3 by reservoir baseplate 409a, sleeve reservoir 409d, and sleeve reservoir flange 409e. The electrode may penetrate the reservoir baseplate 409a through electrode penetration 10a1.

The SunCell® may further comprise a photovoltaic (PV) converter and a window to transmit light to the PV converter. In an embodiment, a PV window for the transmission of light generated by the hydrino reaction from the reaction cell chamber 5b31 to a photovoltaic (PV) power converter may be positioned behind the inverted pedestal. The inverted pedestal may block the flow of metal to the PV window to prevent it from becoming opacified. In an embodiment, the SunCell® may further comprise at least one plasma permeable baffle or screen to block the flow of metal particles to the PV window while permitting the permeation of the light-emitting plasma formed by the hydrino reaction. The baffle or screen may comprise one or more of at least one grating or cloth such as ones comprising stainless steel or other refractory corrosion resistant material such as a metal or ceramic.

In an embodiment, the union comprising a slipnut 5k14 union shown in FIG. 2I163 may be replaced by the design shown in FIGS. 2I216-2I217. The SunCell® may comprise at least one injector reservoir 5c wherein each may comprise an injection EM pump 5ka, a nozzle section of the EM pump tube 5k61, and a nozzle 5q. The union may comprise at least one of a sleeve reservoir 409d and sleeve reservoir flange 409e. An EM pump assembly 5kk may replace the reservoir baseplate 409a.

The injected molten metal stream from the injector reservoir maintains the non-injector reservoir in a filled state wherein the molten metal overflows the non-injector reservoir and flows back into the injector reservoir. The pump-filled reservoir may comprise the counter electrode for the electrode comprising the injector reservoir. The EM pump may pump a molten metal stream from the injector reservoir such that the molten metal is injected to impact the top surface of the molten counter electrode. The non-injector reservoir may be biased positive and comprise the positive ignition electrode, and the injector reservoir may be biased negative and comprise the negative ignition electrode wherein each is biased through corresponding polarity connections from the ignition source of electric power 2 to the ignition bus bars such as the ignition electromagnetic pump bus bars 5ka. In embodiment, the non-injector reservoir comprises an extension or pedestal 5c1 inside of the reaction cell chamber 5b31 so that the returning molten metal flows over the edge of the extension in a manner to break the electrical connectivity of the corresponding metal stream. The extension may serve as a pedestal to elevate and support the molten counter electrode such as the positive electrode. The pedestal may comprise a drip edge or protrusion to further facilitate the molten metal stream breakup.

The return flow to the injector reservoir may be along channels in the reaction cell chamber floor. The top of the injector reservoir may comprise at least one of a drip edge and wall protrusions to facilitate electrical isolation of the positively biased returning molten metal streams from the negatively biased injector reservoir by preventing electrical continuity of the streams. In an embodiment, at least one of cathode and anode reservoir drip edges and return molten metal flow channels may comprise a material or coating such as alumina, carbon, or MoS₂ that beads up the molten metal such as gallium. Alternatively, an additive may be selective to increase the gallium surface tension such that the return flow will form beads that break the electrical connectivity of the returning molten metal streams. In another embodiment, the molten metal or alloy may be selected that has a high surface tension such that it does not wet the surfaces of the return flow path. In an embodiment, the reservoirs and reaction cell chamber may comprise an inverted Y geometry wherein the reservoirs and reaction cell chamber may comprise a square, rectangle, circle, oval, or other optimized shape in cross section. In an embodiment, the pedestal cathode may comprise a partial dome at the top to cause the returning molten metal to spread over the partial dome surface rather than pool. The spreading may enhance the beading of the molten metal from the drip edge to cause the molten stream continuity to be broken. In an embodiment, the negative injector electrode may be at least one of coated or covered with an insulator such as a ceramic coating or sleeve and submerged to prevent contact between the negative electrode and the returning molten metal streams. The ceramic coating may be a ceramic of the disclosure such as one comprising at least one of quartz, alumina, zirconia, hafnia, boron nitride, zirconia diboride, silicon nitride, and silicon carbide.

In an embodiment, the nozzle 5q is placed within suitable proximity to the counter electrode such as one comprising a pedestal 5c to minimize interruption of the injection stream by the pressure wave caused by the ignition. In another embodiment, the injector may comprise a plurality of negative injection nozzles 5q supplied by a single or multiple EM pumps 5ka. At least one of the nozzles and at least one EM pump inlet may be submerged in a common negative molten metal pool. The pool may be contained in at least one of the corresponding reservoir 5c and the bottom of the reaction cell chamber 5b31. In an embodiment, the injector electrode may comprise at least one of a geometry, position, flow rate, and pressure to maintain a trajectory of the metal injection to avoid interruption of the stream by the blast. The nozzle 5q may be located over, to the side, or under the pedestal electrode. The injection may maintain a steady state molten counter electrode wherein the flow rate, trajectory, and injection kinetic energy of the injected metal may be sufficient to maintain the desired geometry of the counter electrode. The maintenance may be achieved considering the rate and pattern of flow of the metal once delivered to the counter electrode caused by at least one of gravity and any pressure gradients in the reaction cell chamber 5b31. The nozzle section of the EM pump tube 5k61 may comprise an arch that serves as a conduit of the molten metal to a position over the counter electrode wherein the nozzle 5q injects the molten metal in a direction that is at least partially in the negative vertical direction. The nozzle 5q may inject the molten metal horizontally to the counter electrode. The nozzle may be located lower than the counter electrode and inject molten metal upward at an angle to impact the counter electrode. In exemplary embodiments, the angle may be in the range of 0 to 90°. The backboard may have a geometry and size suitable to maintain the molten counter electrode when the molten metal is steadily injected by the injector electrode. The backboard may comprise an arch. In another embodiment, at least one nozzle of a plurality of injector nozzles may be suspended above the molten metal pool of the counter electrode wherein the injection trajectory may have a downward component. In an exemplary embodiment, the plurality of injectors may comprise a shower head suspended above the molten metal pool of the counter electrode. The showerhead injector may inject downward into the pool of the counter electrode.

The injection flow rate may be controlled by controlling the current supplied to the EM pump through EM pump bus bars 5k2 wherein an inlet riser 5qa is optional. The EM pump nozzle 5q may be maintained submerged by selecting an initial filling of the reservoirs such that the nozzle remains submerged during pumping and ignition operation. The nozzle may comprise a refractory material such as Mo, W, C, or a ceramic such as alumina, zirconia, or quartz to protect it from thermal damage.

In an embodiment, the molten metal stream injected by the injector nozzle 5q is injected along a trajectory that avoids disruption by traveling pressure waves from the ignition. The position of the injector electrode and the counter electrode may be selected to avoid the disruption. The distance between electrodes and a stream trajectory relative the position of any traveling pressure waves from the ignition may be controlled to avoid stream disruption. At least one of the injection nozzle 5q may comprise a plurality of injectors or nozzles and the angle of injection by the nozzle may be lower that that which would result in the stream encountering disruptive waves along its trajectory. The SunCell® may comprise and injector electrode and counter electrode with a suitable backboard to catch the injected stream. In an embodiment, the injector electrode may comprise a plurality of nozzles such as two opposing nozzles that eject molten metal streams along intersecting trajectories to cause the molten metal be selectively injected onto the molten metal pool of the non-injector electrode. The intersecting streams may at least partially mitigate disruption from the ignition blasts. In an embodiment, the counter electrode may comprise a vertically oriented backboard substantially in the centerline of the top of the counter electrode wherein the opposing injectors may independently maintain molten metal streams that contact the molten pool of the counter electrode. The backboard may shield the molten metal stream from one injection nozzle from the pressure wave formed by the other injection nozzle. In other embodiments comprising more than one set of opposing injection nozzles, the vertical backboard may comprise sections to receive the stream from the section's corresponding injection nozzle. In an embodiment, the streams facilitate maintenance of the current connection between the injection and counter electrodes for sufficient time that a plasma forms in the region of the streams, the inter-electrode region, wherein the plasma at least partially completes the current connection.

In an embodiment, the reaction cell chamber 5b31 that contains the ignition plasma may comprise an acoustic cavity. The cavity geometry, scale, dimensions, and any optional acoustic baffles may be selected to stabilize the injected molten metal stream. The acoustic cavity may achieve the stabilization to improve the injection stream stability by maintaining resonant acoustic standing waves that do not disrupt the stream. In an embodiment, the reaction cell chamber 5b31 is symmetrical to suppress traveling pressure waves form ignition events that disrupt the molten metal injection stream. The injection stream may be maintained at a position that is centered in the reaction cell chamber 5b31 to suppress traveling pressure waves along the stream trajectory. The cavity may comprise a cube, rectangular cuboid, right cuboid, rectangular box, rectangular hexahedron, right rectangular prism, or rectangular parallelepiped with the stream about in the center or about at the origin of Cartesian coordinates.

In another embodiment, the disruptive pressure wave may be actively canceled. The SunCell® may comprise an active noise cancelation system such one known by those skilled in the art such as those that comprise at least one microphone to measure the sound waves and generate about the exact negative of the measured blast sound to cancel the corresponding disruptive pressure wave at a desired position such as at about the position of the molten metal stream trajectory. Exemplary microphones comprise electromagnetic and piezoelectric ones. In another embodiment, the generation of the cancelling waves may be controlled by sensing another signal than sound, such as the ignition current. The frequency of the sound may be selected to more effectively achieve the desire cancellation of the blast disruption. The molten metal stream may be maintained at about the position of a node of active or blast produced standing acoustic waves to maintain its stability. The reactor wall may comprise a material suitable for generating a sound wave internally. In an embodiment, at least a portion of the SunCell® such as the lower hemisphere 5b41 may comprise a metal such as stainless steel. In a SunCell® embodiment comprising a PV converter, the upper hemisphere 5b42 may comprise a material transparent to a desired spectral region of light such as visible and near infrared light. In an exemplary embodiment, the lower hemisphere may comprise stainless steel.

In another embodiment, the SunCell® may further comprise an ignition EM pump such as one disclosed as an electrode EM pump or second electrode EM pump in Mills Prior Applications such as one comprising at least one set of magnets to produce a magnetic field perpendicular to the ignition current to produce a Lorentz force to counteract the pressure wave created by ignition. In an exemplary embodiment, the ignition current may be along the x-axis, the magnetic field may be along the y-axis, and the Lorentz force may be along the negative z-axis to counter the effect of ignition blast.

The molarity equivalent of H₂ in liquid H₂O is 55 moles/liter wherein H₂ gas at STP occupies 22.4 liters. In an embodiment, H₂ is supplied to the reaction cell chamber 5b31 as a reactant to form hydrino in a form that comprises at least one of liquid water and steam. The SunCell® may comprise at least one injector of the at least one of liquid water and steam. The injector may comprise at least one of water and steam jets. The injector orifice into the reaction cell chamber may be small to prevent backflow. The injector may comprise an oxidation resistant, refractory material such as a ceramic or another or the disclosure. The SunCell® may comprise a source of at least one of water and steam and a pressure and flow control system. The H₂O may react with the molten metal such as gallium to form the corresponding oxide such as Ga₂O₃ and H₂(g). The gallium oxide may be reduced to gallium metal, and the oxygen may be removed in a form such as O₂ or H₂O. The gallium oxide may be reduced in the reaction cell chamber 5b31, and the product of the Ga₂O₃ reduction reaction comprising oxygen may be removed from the reaction cell chamber. Alternatively, Ga₂O₃ may be removed from the reaction cell chamber and reduced externally with the gallium metal returned to reaction cell chamber 5b31.

In an embodiment, Ga₂O₃ volatilizes as Ga₂O in an atmosphere at elevated temperatures comprising hydrogen such as a noble gas-hydrogen atmosphere such as an argon-H₂ atmosphere. An exemplary gas composition to from Ga₂O is Ar-6%-H₂. The levated temperatures may be in the range of about 1000 K to 2000 K or higher. The SunCell® may comprise at least one cold region in contact with the reaction cell chamber wherein the Ga₂O may be further reduced to Ga metal with the formation of water. During the thermal reduction reaction, Ga₂O may back react with H₂(g) and H₂O(g) and condense out as Ga metal and Ga₂O₃(s). The gallium metal may be recycled to at least one of the reaction cell chamber and the reservoir 5c. The recycling may be achieved by gravity flow through a return channel or conduit or by pumping with a pump such as an EM pump.

In another embodiment, the SunCell® comprises a means to remove the Ga₂O₃ from the reaction cell chamber, reduce the Ga₂O₃ to gallium metal while exhausting the Ga₂O₃ reduction product comprising oxygen and returning the gallium metal to the reaction cell chamber. The means to remove Ga₂O₃ may comprise at least one of a mechanical, pneumatic, jet such as at least one water jet, and electromagnetic skimmer to remove a Ga₂O₃ film from the surface of the liquid gallium in the reaction cell chamber. The SunCell® may further comprise a Ga₂O₃ reduction reaction chamber and a channel, conduit, or passage of the skimmed Ga₂O₃ to flow or be pumped to the Ga₂O₃ reduction reaction chamber. An exemplary mechanical skimmer is a stirring bar inside of the reaction cell chamber that is spun by an external spinning magnetic in phase with the internal stirring bar. The stirring bar may comprise a magnetic or ferromagnetic material such a cobalt or iron that has a high Curie temperature. The reaction cell chamber may comprise at least one flat vertical wall such as one of the walls of a cubic or rectangular reaction cell chamber wherein the stirring bar operates in the plane parallel to the wall. The stirring bar may propel the Ga₂O₃ into the passage to the Ga₂O₃ reduction reaction chamber. Ga₂O₃ reduction reaction chamber may comprise a molten salt electrolysis cell. The Ga₂O₃ may undergo electrolysis to gallium metal and O₂, H₂O, or another oxide such as a volatile or gaseous oxide such as CO₂ that is selectively vented from the G₂O₃ reduction reaction chamber. In the latter case, at least one electrode such as the anode may comprise carbon. The gallium metal may be returned to at least on of the reservoir 5c and the reaction cell chamber 5b31 by an EM pump that selectively return pumps the gallium metal.

In an embodiment, the SunCell® may comprise a molten metal such as gallium. The SunCell® may further comprise a photovoltaic (PV) converter and a window to transmit light to the PV converter, and may further an ignition EM pump such as one disclosed as an electrode EM pump or second electrode EM pump in Mills Prior Applications such as one comprising at least one set of magnets to produce a magnetic field perpendicular to the ignition current to produce a Lorentz force to confine the plasma and molten metal such that the plasma light can transmit through the window to the PV converter. The ignition current may be along the x-axis, the magnetic field may be along the y-axis, and the Lorentz force may be along the negative z-axis. In another embodiment, the SunCell® comprising a photovoltaic (PV) converter and a window to transmit light to the PV converter further comprises at least one of a mechanical window cleaner and a gas jet or air knife to remove the molten metal. The gas of the gas jet or knife may comprise reaction cell chamber gas such as at least one of reactants, hydrogen, oxygen, water vapor, and noble gas. In an embodiment, the PV window comprises a coating such as one of the disclosure that prevents the molten metal such as gallium from sticking wherein the thickness of the coating is sufficiently thin to be highly transparent to the light to be PV converted into electricity. Exemplary coatings for a quartz reaction cell chamber section are thin-film boron nitride and carbon. Quartz may be a suitable material by itself to serve as a reaction cell chamber wall and PV window material.

In an embodiment of the SunCell® comprising an acoustic cavity, a PV window, and a PV converter, the cavity geometry, scale, dimensions, and any optional acoustic baffles may be selected to prevent molten metal from coating the PV window. The acoustic cavity may achieve the avoidance of metal coating of the PV window by suppressing molten metal impact with the window by maintaining resonant acoustic standing waves that force molten metal away from the window. In another embodiment, the molten metal may be actively forced away from the window actively. The SunCell® may comprise an active noise cancelation system such one known by those skilled in the art such as those that comprise at least one microphone to measure the sound waves and generate about the exact negative of the measured blast sound to cancel the corresponding pressure wave propagating to the window. In another embodiment, the generated sound or pressure wave may be in a direction away from the PV window. The frequency of the sound may be selected to more effectively achieve the desired suppression of the impact of the molten metal with the PV window. In another embodiment, the PV window is positioned at sufficient vertical distance from a source of molten metal particles accelerated by the blast wave such that gravitational deceleration prevents the particles from impacting the PV window.

In an embodiment, the SunCell® may be operated at a sufficient pressure such that a increasing pressure gradient in the direction of the PV window suppresses flow of metal particles to the PV window such that PV window metallization is suppressed. The reaction cell chamber 5b31 pressure may be in at least one range of about 100 Torr to 100 atm, 500 Torr to 10 atm, and 500 Torr to 2 atm. In an embodiment, a pressure gradient is maintained inside of the reaction cell chamber 5b31 such that molten metal particles are forced away from the PV window. In an embodiment, the SunCell® comprises a blower to provide the pressure gradient by applying forced flow. In another embodiment, the SunCell® comprises a nozzle to provide the pressure gradient by causing forced flow using the power of the hydrino reaction to heat the gases in the reaction cell chamber 5b31. Alternatively, the reaction cell chamber may be shaped to cause convection currents that produce high flow rates and low pressures away from the PV window and high pressure, low flow in closer proximity to the PV window. The pressure gradient may be according to Bernoulli's principle. Exemplary pressure gradients are in at least one range of about 0.01 to 100 atm per meter, 0.1 to 50 atm per meter, and 0.2 to 10 atm per meter. In an embodiment, the pressure is high in proximity of the window wherein pressure waves are reflected to produce a low gas flow rate. In an exemplary embodiment, the reaction cell chamber 5b31 may comprise a decreasing volumetric gradient in the direction of the PV window such that metal-particle carrying gas flowing towards the PV window is retarded in flow towards the PV window. The retarded flow may be achieved by slowing the flow towards the PV window such that a backpressure is produced against the gas flow. The decreasing volumetric gradient may comprise a conical section with the decreased radius end towards the PV window.

In an embodiment shown in FIGS. 2I220-2I221, the SunCell® comprises a reaction cell chamber 5b31 with a tapering cross section along the vertical axis and a PV window 5b4 at the apex of the taper. The window with a mating taper may comprise any desired geometry that accommodates the PV array 26a such as circular (FIG. 2I220) or square or rectangular (FIG. 2I221). The taper may suppress metallization of the PV window 5b4 to permit efficient light to electricity conversion by the photovoltaic (PV) converter 26a. The PV converter 26a may comprise a dense receiver array of concentrator PV cells such as PV cells of the disclosure and may further comprise a cooling system such as one comprising microchannel plates. The PV window 5b4 may comprise a coating that suppresses metallization. The PV window may be cooled to prevent thermal degradation of the PV window coating. The SunCell® may comprise at least one partially inverted pedestal 5c2 having a cup or drip edge 5c1a at the end of the inverted pedestal 5c2 similar to one shown in FIG. 2I219 except that the vertical axis of each pedestal and electrode 10 may be oriented at an angle with respect to the vertical or z-axis. The angle may be in the range of 1 to 90°. In an embodiment, at least one counter injector electrode 5k61 injects molten metal from its reservoir 5c obliquely in the positive z-direction against gravity where applicable. The injection pumping may be provided by EM pump assembly 5kk mounted on EM pump assembly slide table 409c. In exemplary embodiments, the partially inverted pedestal 5c2 and the counter injector electrode 5k61 are aligned on an axis at 135° to the horizontal or x-axis as shown in FIG. 2I220 or aligned on an axis at 45 to the horizontal or x-axis as shown in FIG. 2I221. The insert reservoir 409f having insert reservoir flange 409g may be mounted to the cell chamber 5b3 by reservoir baseplate 409a, sleeve reservoir 409d, and sleeve reservoir flange 409e. The electrode may penetrate the reservoir baseplate 409a through electrode penetration 10a1. The nozzle 5q of the injector electrode may be submerged in the liquid metal such as liquid gallium contained in the bottom of the reaction cell chamber 5b31 and reservoir 5c. Gases may be supplied to the reaction cell chamber 5b31, or the chamber may be evacuated through gas ports such as 409h.

The reaction cell chamber 5b31 may comprise a geometry that maintains a vortex. Exemplary geometries comprise conical and parabolic ones wherein at least one of the molten metal stream and the electrode at which the hydrino reaction is preferred such as the positive electrode are located at about the focus or along the cylindrical symmetry axis, the z-axis. The parabolic reaction cell chamber 5b31 may further comprise a plurality of sections that may have different geometries to better maintain directional flow of plasma from a parabolic section such as a right cylinder on top of the parabolic section. In an embodiment, the reaction cell chamber 5b31 may comprise a at least two sections such as an upper and lower section along the vertical axis wherein the cross sectional area decrease along the vertical axis due to the plurality of section having different geometries. The upper section may comprise a PV window. In an embodiment, the upper section may have a smaller radius of curvature than the bottom section. In an exemplary embodiment, the upper section may comprise a dome and the lower section may comprise a parabola. The gas flow may be reduced with a concomitant pressure increase along the vertical axis. The pressure gradient may suppress metallization of PV window.

In an embodiment, the SunCell® comprises a separator to separate molten metal and any oxide particles from the cell gas at the position of the PV window to prevent the particles from opacifying the window. The separator may comprise a cyclone separator. The reaction cell chamber 5b31 may further comprise the cyclone separator. In an embodiment at least one of the following group occurs: (i) the plasma may be formed asymmetrically and (ii) the plasma may produce pressure asymmetrically within the reaction cell chamber 5b3. At least one of the asymmetric plasma formation and the asymmetric pressure formation may propagate a cyclone with in the reaction cell chamber. The cyclone or vortex may form along the walls of the reaction cell chamber. The reaction cell chamber may comprise baffles to at least one of form the asymmetric plasma, form the asymmetric pressure, and form the cyclone or vortex. The cyclone may produce a high gas pressure along the wall relative to that in the center of the reaction cell chamber. The corresponding high-pressure cyclone flow along the walls may at least one of entrap, entrain, and separate the particles from the reaction cell chamber gas. The PV window may be positioned in a location where the particles have been removed or are prohibited from contacting the window due to the cyclone flow. The PV window may be positioned over the center region of the cyclone wherein the pressure may be low.

In an embodiment, the SunCell® comprises an induction ignition system with a cross connecting channel of reservoirs 414, a pump such as an induction EM pump, a conduction EM pump, or a mechanical pump in an injector reservoir, and a non-injector reservoir that serves as the counter electrode. The cross connecting channel of reservoirs 414 may comprise restricted flow means such that the non-injector reservoir may be maintained about filled. In an embodiment, the cross connecting channel of reservoirs 414 may contain a conductor that does not flow such as a solid conductor such as solid silver.

In an embodiment, the reaction mixture gases may be monitored by a gas analyzer. The gas analyzer may comprise at least one of a mass spectrometer, thermal conductivity sensor, and flame ionization detector for H₂ concentration such as one used as on a gas chromatograph. In an embodiment, there is no plasma initially present in the reaction cell chamber 5b31 upon SunCell® startup, and the reaction cell chamber 5b31 temperature may be relatively low compared hydrogen thermolysis temperatures. In the case that the reaction gas comprises a gas that promotes atomic H lifetime such as a noble gas such as argon in mixture with hydrogen or a source of hydrogen, the mole fraction of hydrogen in the gas mixture such as an argon-hydrogen gas mixture may be increased as at least one of the thermal and plasma temperatures increase to support atomic hydrogen.

In an embodiment, the molten metal such as silver or gallium may form nanoparticles and may further comprise an oxygen-carrier chemical such as a metal capable of reversibly forming an oxide wherein oxidized oxygen-carrier chemical selectively releases oxygen or a source of oxygen such as H₂O in the reaction cell chamber 5b31, and the reduced form selectively reacts with oxygen in a region following the MHD channel 308 such as MHD condensation section or the MHD return reservoir 311. In an exemplary embodiment, oxygen supplied to the SunCell® may form gallium oxide such as Ga₂O₃ that is reduced by hydrogen at elevated temperature to form HOH catalyst. Gallium has a low reactivity with water. For example, gallium does not react with water up to 100° C. which may be favorable to maintaining HOH catalyst. In an embodiment comprising a molten metal that forms an oxide with the reaction of at least one of oxygen and H₂O, the reaction conditions such as at least one of the temperature and hydrogen pressure in the cell may be maintained to a least partially reduce the metal oxide. An exemplary reaction is the H₂ reduction of gallium oxide to gallium metal and water:

Ga₂O₃+3H₂ to 2Ga+3H₂O (700° C.) (76)

Another exemplary reaction to from metal from the oxide is the thermal decomposition of HgO to Hg metal and oxygen:

2HgO to 2Hg+O₂ (>500° C.) (77)

Lead oxide and mercury oxide are further exemplary oxides for H₂ reduction.
The reaction gases supplied to the reaction cell chamber may comprise at least one of oxygen, hydrogen, and H₂O vapor. The reaction gasses may be supplied to gas housing 309b. The gases may be supplied through gas inlet and evacuation assembly 309e. The gases may diffuse from the gas housing 309b into the cell through gas permeable membrane 309d.

Additional systems to increase the efficiency of the MHD power converter as well as alternative thermal to electric systems are within the scope of the present disclosure. In an exemplary embodiment shown in FIGS. 2I222-2I223, a magnetohydrodynamic (MHD) SunCell® power generator comprises two recuperators 312d and two paired gas compressors 312a connected to each other as well as to the condensation section of the MHD channel 309 and the reaction cell chamber 5b31 by recuperator and compressor gas lines 312e wherein each recuperator 312d removes heat from the MHD gas flow before the corresponding compressor 312a and returns the heat to the compressed gas output of the compressor. The output electrical power may be conditioned by power condition system 110. In another embodiment, the recuperators 312d may remove heat from the MHD flow such as at least one of gas, metal vapor, liquid metal, metal nanoparticles, and solidified metal at a MHD section such as at the end of the MHD condensation section 309 and return the heat to the flow before the flow is recirculated to the reaction cell chamber 5b31. The recuperators 312d may heat the return flow following at least one of EM pumping by EM pumps 312 and gas compression by gas compressors or pumps 312a (FIGS. 2I167-2I170).

In addition to UV photovoltaic, thermal photovoltaic, and magnetohydrodynamic power converters of the current disclosure, the SunCell® may comprise other electric conversion means known in the art such as thermionic, turbine, microturbine, Rankine or Brayton cycle turbine, chemical, and electrochemical power conversion systems. The Rankine cycle turbine may comprise supercritical CO₂, an organic such as hydrofluorocarbon or fluorocarbon, or steam working fluid. Power conversion systems that may comprise closed coolant systems or open systems that reject heat to the ambient atmosphere are supercritical CO₂, organic Rankine, or external combustor gas turbine systems.

An exemplary supercritical CO₂ power conversion system powered by a SunCell® shown in FIGS. 2I224-2I226. The corresponding supercritical CO₂ SunCell® electrical power generator may comprise a turbine 450 that turns the shaft of an electrical generator 460, a SunCell® power generator comprising a cylindrical heat exchanger 451 or a SunCell® power generator comprising a spherical heat exchanger 452, a high temperature recuperator 453, a low temperature recuperator 454, a precooler 455, a main compressor, 456, a recompressing compressor 457, and coolant lines 458 for CO₂ coolant flow between components of the supercritical CO₂ power conversion system. The cylindrical heat exchanger for the SunCell® 459 is shown in FIG. 2I224. Other embodiments of a supercritical CO₂ power conversion system powered by a SunCell® that uses a supercritical CO₂ power conversion system known to those skilled in the art are within the scope of the present disclosure.

An exemplary closed Rankine cycle power conversion system such as one comprising an organic working medium or coolant powered by a SunCell® is shown in FIGS. 2I227-2I228. The corresponding closed Rankine SunCell® electrical power generator may comprise a SunCell® power generator 452 that may be embedded in a boiler 461 to heat a coolant. Details of the SunCell® 452 embedded in the boiler 461 is shown in FIG. 2I227. The heated coolant may undergo a phase change to drive a turbine 450 that turns the shaft of an electrical generator 460. Following the performance of pressure-volume work by the coolant, a condenser or chiller 464 may condense the coolant. The coolant may flow into the turbine through an inlet turbine line 462 and out of the turbine through outlet turbine line 463. The condensed coolant may be pumped from the condenser 464 to the boiler 461 by pump 465. The flow may be through pump lines 466. Other Rankine cycle power conversion systems such as open systems such as open steam-based systems known in the art as well as closed systems are within the scope of the present disclosure.

An exemplary external-combustor-type, open Brayton electrical power conversion system powered by a SunCell® is shown in FIGS. 2I229-2I233. The corresponding external-combustor-type, open Brayton SunCell® electrical power generator may comprise a turbine compressor 467 to draw in air, a SunCell® 452 with heat exchanger 468 to extract heat from the SunCell® 452 and transfer it to the air, and a power turbine 469 that is turned by the heated air as it flows through the power turbine 469 and is exhausted by turbine air exhaust vent 470. Details of the airflow pattern are shown in FIG. 2232 using arrows. The heat exchanger 468 further comprises a coolant tank 474 and a coolant pump 475 to maintain at least one of about a constant coolant flow and pressure. The coolant in the portion of the heat exchanger 468 that at least partially surrounds the SunCell® 452 increases in temperature along the coolant flow path, flows into a portion of the heat exchanger 468 next to the power turbine 469, losses temperature along it flow path to the air flowing in the opposition direction, and exits the heat exchanger at the turbine compressor end. The coolant is pumped by the coolant pump 475 through coolant lines 476 into the coolant tank 474 and returned to the SunCell® 452 portion of the heat exchanger 468. In an embodiment, the coolant is cable of high temperature operation such as greater than 300° C. Exemplary high-temperature-capable coolants are molten metals such as gallium or lithium, and molten salts such as mixtures of alkali halides, hydroxides, carbonates, nitrates, sulfates, and others known to those skilled in the art. Details of the turbine compressor 467 to draw in air, the heat exchanger 468 to extract heat from the SunCell® 452 and transfer it to the air, the power turbine 469, and the turbine air exhaust duct 470 are shown in FIG. 2I234. Components of the electrical power generator may be supported by structural supports 477.

An exemplary open Rankine cycle power conversion system such as one comprising steam as the working medium or coolant powered by a SunCell® is shown in FIGS. 2I234-2I235. The corresponding open Rankine SunCell® electrical power generator may comprise a SunCell® power generator 500a that may be embedded in a boiler 500b to heat a coolant. The heated coolant may undergo a phase change to drive a high-pressure turbine 501 and a low-pressure turbine 502 that turn the shaft of an electrical generator 503. Following the performance of pressure-volume work by the coolant, a plant service cooling system may reject the heat from the power conversion system to the ambient by evaporating steam and resupplying coolant such as makeup water from an ambient source. The plant service cooling system may comprise a condenser 505, a cooling tower 506, and cooling water pumps 507 wherein the flow may be through cooling tower lines 523. To improve the conversion efficiency, the coolant from the condensor 505 may be pumped to a first stage feed water heater 509 by a condensate pump 510. The first stage feed water heater 509 may further receive coolant from the low-pressure turbine 502. Make up water may be supplied from a boiler feedwater purification system 511. The coolant may be pumped from the first stage feedwater heater 509 to a dearating feed water tank 508 that may further receive coolant from a water separator 504 that receives flow from the high-pressure turbine 501 and returns steam to the low pressure turbine 502 after the separation of the moisture in the steam. The coolant may be pumped from the dearating feedwater tank 508 to the boiler 500b by the feedwater pump 512. Hot coolant may be pumped through hot coolant lines 520 and cold coolant may be pumped through cold coolant lines 521. The SunCell® electrical power generator may comprise (i) a water electrolyzer 518 to produce at least one of H₂, O₂, and H₂O vapor that may be stored in reactant supply tank 517, (ii) a vacuum pump and gas pump system 519 to maintain the flow of reactant gases, (iii) an additional reactant supply 514 to at least one of add reactants to support the hydrino reaction and form desired hydrino products, (iv) a reaction mixture recirculation and product extraction system 515, and a heater 516 that may be in a position of the gas and vacuum lines 522 to maintain a desired temperature of the reactants entering the SunCell 500a and boiler 500b. Components of the SunCell® electrical power generator such as at least one of the additional reactant supply 514 and the reaction mixture recirculation and product extraction system 515 may be at least one of heated and cooled by hot and cold coolant lines 520 and 521, respectively, wherein the coolant may be pumped by booster pump 513.

An exemplary Sterling cycle power conversion system powered by a SunCell® is shown in FIGS. 2I236-2I237. The corresponding Sterling-engine SunCell® electrical power generator may comprise a SunCell® power generator 452 that may be embedded in heat exchanger 459 to heat a coolant. The heated coolant many transfer heat from the SunCell® power generator 452 to the hot plate 632 of the Sterling engine 622 wherein the thermal power drives the Sterling engine, and the waste heat is rejected at the Sterling engine cooling fins 633. The operation of the Sterling engine causes the Sterling engine shaft 631 to turn (FIG. 2I236) or linearly oscillate (FIG. 2I237) which may subsequently power an electrical generator or power a mechanical load. In an embodiment, the heat exchanger 459 may comprise at least one heat pipe such as one of the disclosure that operates at one or more of high temperature and power flux.

### Exemplary Embodiments

In an exemplary embodiment of a SunCell® electrical generator of the disclosure comprising a PV converter: (i) the EM pump assembly 5kk may comprise stainless steel wherein surfaces exposed to oxidation such as the inside of the EM pump tube 5k6 may be coated with an oxidation resistant coating such as a nickel coating wherein the stainless steel such as Inconel is selected to have a similar coefficient of thermal expansion as that of nickel, (ii) the reservoirs 5c may comprise boron nitride such as BN—Ca that may be stabilized against oxidation, (iii) the union between the reservoir and the EM pump assembly 5kk may comprise a wet seal, (iv) the molten metal may comprise silver, (v) the inlet riser 5qa and injection tube 5k61 may comprise ZrO₂ threaded into a collar in the EM pump assembly base plate 5kk1, (vi) the lower hemisphere 5b41 may comprise carbon such a pyrolytic carbon that is resistant to reaction with hydrogen, (vii) the upper hemisphere 5b42 may comprise carbon such a pyrolytic carbon that is resistant to reaction with hydrogen, (viii) the source of oxygen may comprise CO wherein the CO may be added as a gas, supplied by the controlled thermal or other decomposition of a carbonyl such as a metal carbonyl (e.g. W(CO)₆, Ni(CO)₄, Fe(CO)₅, Cr(CO)₆, Re₂(CO)₁₀, and Mn₂(CO)₁₀), and supplied as a source of CO₂ or CO₂ gas wherein the CO₂ may decompose in the hydrino plasma to release CO or may react with carbon such as supplied sacrificial carbon powder to supply the CO, or O₂ may be added through an oxygen permeable membrane of the disclosure such as one of the disclosure such as Bi₂₆Co_{0.7}Fe_{0.2}Nb_{0.1}O₃₋₈ (BCFN) oxygen permeable membrane that may be coated with Bi₂₆Mo₁₀O₆₉ to increase the oxygen permeation rate wherein added O₂ that may react with sacrificial carbon powder to maintain a desired CO concentration as monitored with a detector and controlled with a controller, (ix) the source of hydrogen may comprise H₂ gas that may be supplied through a hydrogen permeable membrane such as a Pd or Pd—Ag membrane in the EM pump tube 5k4 wall using a mass flow controller to control the hydrogen flow from a high-pressure water electrolyzer, (x) the union between the reservoir and the lower hemisphere 5b41 may comprise a slip nut that may comprise a carbon gasket and a carbon nut, and (xi) the PV converter may comprise a dense receiver array comprising multi-junction III-V PV cells that are cooled by cold plates. The reaction cell chamber 5b31 may comprise a source of sacrificial carbon such as carbon powder to scavenge O₂ and H₂O that would otherwise react with the walls of a carbon reaction cell chamber. The reaction rate of water with carbon is dependent on the surface area that is many orders of magnitude greater in the case of the sacrificial carbon compared to the surface area of the reaction cell chamber 5b31 walls. In an embodiment, the inside wall of the carbon reaction cell chamber comprises a carbon passivation layer. In an embodiment, the inner wall of the reaction cell chamber is coated with a rhenium coating to protect the wall from H₂O oxidation. In an embodiment, the oxygen inventory of the SunCell® remains about constant. In an embodiment, addition oxygen inventory may be added as at least one of CO₂, CO, O₂, and H₂O. In an embodiment, the added H₂ may react with the sacrificial powdered carbon to form methane such that the hydrino reactants comprise at least one hydrocarbon formed from the elements of O, C, and H such as methane and at least one oxygen compound formed from the elements of O, C, and H such as CO or CO₂. The oxygen compound and hydrocarbon may serve as the oxygen source and H source, respectively, to form HOH catalyst and H.

The SunCell® may further comprise carbon monoxide safety systems such as at least one of CO sensors, a CO vent, a CO diluent gas, and a CO absorbent. CO may be limited in at least one of concentration and total inventory to provide safety. In an embodiment, the CO may be confined to the reaction chamber 5b31 and optionally the outer vessel chamber 5b3a1. In an embodiment, the SunCell® may comprise a secondary chamber to confine and dilute any CO that leaks from the reaction cell chamber 5b31. The secondary chamber may comprise at least one of the cell chamber 5b3, the outer vessel chamber 5b3a1, the lower chamber 5b5, and another chamber that may receive the CO to at least one of contain and dilute leaked CO to a safe level. The CO sensor may detect any leaked CO. The SunCell® may further comprise at least one of a tank of dilution gas, a diluent gas tank valve, an exhaust valve, and a CO controller to receive input from the CO sensor and control the opening and flow in the valves to dilute and release or vent the CO at a rate such that its concentration does not exceed a desired or safe level. A CO absorbent in a chamber to which the leaked CO is contained may also absorb the leaked CO. Exemplary CO absorbents are cuprous ammonium salts, cuprous chloride dissolved in HCl solution, ammoniacal solution, or ortho anisidine, and others known by those skilled in the art. Any vented CO may be in a concentration of less than about 25 ppm. In an exemplary embodiment wherein the reaction cell chamber CO concentration is maintained at about 1000 ppm CO and the reaction cell chamber CO comprises the total CO inventory, the outer containment or secondary chamber volume relative to reaction cell chamber volume is greater than 40 times larger such that the SunCell® is inherently safe to CO leakage. In an embodiment, the SunCell® further comprises a CO reactor such as an oxidizer such as a combustor or a decomposer such as a plasma reactor to react CO to a safe product such as CO₂ or C and O₂. An exemplary catalytic oxidizer product is Marcisorb CO Absorber comprising Moleculite (Molecular, http://www.molecularproducts.com/products/marcisorb-co-absorber).

In an embodiment, hydrogen may serve as the catalyst. The source of hydrogen to supply nH (n is an integer) as the catalyst and H atoms to form hydrino may comprise H₂ gas that may be supplied through a hydrogen permeable membrane such as a Pd or Pd—Ag such as 23% Ag/77% Pd alloy membrane in the EM pump tube 5k4 wall using a mass flow controller to control the hydrogen flow from a high-pressure water electrolyzer. The use of hydrogen as the catalyst as a replacement for HOH catalyst may avoid the oxidation reaction of at least one cell component such as a carbon reaction cell chamber 5b31. Plasma maintained in the reaction cell chamber may dissociate the H₂ to provide the H atoms. The carbon may comprise pyrolytic carbon to suppress the reaction between the carbon and hydrogen.

In an exemplary embodiment of the SunCell® heater of the disclosure: (i) the EM pump assembly 5kk may comprise stainless steel wherein surfaces exposed to oxidation such as the inside of the EM pump tube 5k6 may be coated with an oxidation resistant coating such as a nickel coating, (ii) the reservoirs 5c may comprise ZrO₂ stabilized in the cubic form by MgO or Y₂O₃, (iii) the union between the reservoir and the EM pump assembly 5kk may comprise a wet seal, (iv) the molten metal may comprise silver, (v) the inlet riser 5qa and injection tube 5k61 may comprise ZrO₂ threaded into a collar in the EM pump assembly base plate 5kk1, (vi) the lower hemisphere 5b41 may comprise ZrO₂ stabilized in the cubic form by MgO or Y₂O₃, (vii) the upper hemisphere 5b42 may comprise ZrO₂ stabilized in the cubic form by MgO or Y₂O₃, (viii) the source of oxygen may comprise a metal oxide such as and alkali or alkaline earth oxide or mixtures thereof, (ix) the source of hydrogen may comprise H₂ gas that may be supplied through a hydrogen permeable membrane in the EM pump tube 5k4 wall using a mass flow controller to control the hydrogen flow from a high-pressure water electrolyzer, (x) the union between the reservoir and the lower hemisphere 5b41 may comprise ceramic glue, (x) the union between the lower hemisphere 5b41 and the upper hemisphere 5b42 may comprise ceramic glue and (xi) the heat exchanger may comprise a radiant boiler. In an embodiment, at least one of the lower hemisphere 5b41 and the upper hemisphere 5b42 may comprise a material with high thermal conductivity such as a conductive ceramic such as one of the disclosure such as at least one of ZrC, ZrB₂, and ZrC—ZrB₂ and ZrC—ZrB₂—SiC composite that is stable to oxidation to 1800° C. to improve the heat transfer from the interior to the exterior of the cell.

In an exemplary embodiment of a SunCell® electrical generator of the disclosure comprising a magnetohydrodynamic (MHD) converter: (i) the EM pump assembly 5kk may comprise stainless steel wherein surfaces exposed to oxidation such as the inside of the EM pump tube 5k6 may be coated with an oxidation resistant coating such as a nickel coating, (ii) the reservoirs 5c may comprise ZrO₂ stabilized in the cubic form by MgO or Y₂O₃, (iii) the union between the reservoir and the EM pump assembly 5kk may comprise a wet seal, (iv) the molten metal may comprise silver, (v) the inlet riser 5qa and injection tube 5k61 may comprise ZrO₂ threaded into a collar in the EM pump assembly base plate 5kk1, (vi) the lower hemisphere 5b41 may comprise ZrO₂ stabilized in the cubic form by MgO or Y₂O₃, (vii) the upper hemisphere 5b42 may comprise ZrO₂ stabilized in the cubic form by MgO or Y₂O₃, (viii) the source of oxygen may comprise a metal oxide such as and alkali or alkaline earth oxide or mixtures thereof, (ix) the source of hydrogen may comprise H₂ gas that may be supplied through a hydrogen permeable membrane in the EM pump tube 5k4 wall using a mass flow controller to control the hydrogen flow from a high-pressure water electrolyzer, (x) the union between the reservoir and the lower hemisphere 5b41 may comprise ceramic glue, (x) the union between the lower hemisphere 5b41 and the upper hemisphere 5b42 may comprise ceramic glue, (xi) the MHD nozzle 307, channel 308, and condensation 309 sections may comprise ZrO₂ stabilized in the cubic form by MgO or Y₂O₃, (xii) the MHD electrodes 304 may comprise Pt coated refractory metal such as Pt-coated Mo or W, carbon that is stable to water reaction to 700° C., ZrC—ZrB₂ and ZrC—ZrB₂—SiC composite that is stable to oxidation to 1800° C., or a silver liquid electrode, and (xiii) the MHD return conduit 310, return EM pump 312, return EM pump tube 313 may comprise stainless steel wherein surfaces exposed to oxidation such as the inside of the tubing and conduits may be coated with an oxidation resistant coating such as a nickel coating. The MHD magnet 306 may comprise a permanent magnet such as a cobalt samarium magnet having 1 T magnetic flux density.

In an exemplary embodiment of a SunCell® electrical generator of the disclosure comprising a magnetohydrodynamic (MHD) converter: (i) the EM pump may comprise a two-stage induction-type wherein the 1^{st} stage serves as the MHD return pump and the 2^{nd} stage serves as the injection pump, (ii) the EM pump tube section of the current loop 405, the EM pump current loop 406, the joint flanges 407, the reservoir baseplate assembly 409, and the MHD return conduit 310 may comprise quartz such as fused quartz, silicon nitride, alumina, zirconia, magnesia, or hafnia, (iii) the transformer windings 401, the transformer yokes 404a and 404b, and the electromagnets 403a and 403b may be water cooled; (iv) the reservoirs 5c, the reaction cell chamber 5b31, the MHD nozzle 307, MHD channel 308, MHD condensation section 309, and gas housing 309b may comprise quartz such as fused quartz, silicon nitride, alumina, zirconia, magnesia, or hafnia wherein the ZrO₂ stabilized in the cubic form by MgO or Y₂O₃, (v) at least one of the gas housing 309b and MHD condensation section 309 may comprise may comprise stainless steel such as 625 SS or iridium coated Mo, (vi) (a) the unions between components may comprise flange seals with gaskets such as carbon gaskets, glued seals, or wet seals wherein wet seal may join dissimilar ceramics or ceramic and metallic parts such as stainless steel parts, (b) flange seals with graphite gaskets may join metallic parts or ceramic to metallic parts that operated below the carbonization temperature of the metal, and (c) flange seals with gaskets may join metallic parts or ceramic to metallic parts wherein graphite gaskets contacts a metallic portion of the seal comprising a metal or coating such as nickel that is not prone to carbonization, or another high-temperature gasket is used at a suitable operating temperature, (vii) the molten metal may comprise silver, (viii) the inlet riser 5qa and injection tube 5k61 may comprise ZrO₂ threaded into a collar in the reservoir baseplate assembly 409, (ix) the source of oxygen and the source of hydrogen may comprise O₂ gas and H₂ gas, respectively, that may be supplied through a gas permeable membrane 309d in the MHD condensation section 309 wall using a mass flow controller to control each gas flow from a high-pressure water electrolyzer, (x) the MHD electrodes 304 may comprise Pt coated refractory metal such as Pt-coated Mo or W, carbon that is stable to water reaction to 700° C., ZrC—ZrB₂ and ZrC—ZrB₂—SiC composite that is stable to oxidation to 1800° C., or a silver liquid electrode, and (xi) the MHD magnets 306 may comprise permanent magnets such as a cobalt samarium magnets having a magnetic flux density in the range of about 0.1 to 1 T.

In an embodiment, the SunCell® power source may comprise an electrode such as the cathode that comprises a refractory metal such as tungsten that may penetrate the wall of the blackbody radiator 5b4 and a molten metal injector counter electrode. The counter electrode such as the EM pump tube injector 5k61 and nozzle 5q may be submerged. Alternatively, the counter electrode may be comprised of an electrically insulating, refractory material such as cubic ZrO₂ or hafnia. The tungsten electrode may be sealed at the penetration of the blackbody radiator 5b4. The electrodes may be electrically isolated by an electrical insulator bushing or spacer between the reservoir 5c and the blackbody radiator 5b4. The electrical insulator bushing or spacer may comprise BN or a metal oxide such as ZrO₂, HfO₂, MgO, or Al₂O₃. In another embodiment, the blackbody radiator 5b4 may comprise an electrical insulator such as a refractory ceramic such as BN or metal oxide such as Zr₂, HfO₂, MgO, or Al₂O₃.

### OTHER EMBODIMENTS

Alternatively, the ice fuel system may comprise an electrical means to create the shock wave in ice such as at least one exploding wire. The exploding wire may comprise a source of high power such as a source of at least one of high voltage and current. The source of high electrical power may comprise at least one capacitor. The capacitor may be capable of high voltage and current. The discharge of the at least one capacitor through the at least one wire may cause it to explode. The wire explosive system may comprise a thin conductive wire and a capacitor. Exemplary wires are ones comprising gold, aluminum, iron, or platinum. In an exemplary embodiment, the wire may be less than 0.5 mm in diameter, and the capacitor may have an energy consumption of about 25 kWh/kg and discharge a pulse of charge density of 10⁴-10⁶ A/mm², leading to temperatures up to 100,000 K wherein the denotation may occur over a time period of about 10⁻⁵-10⁻⁸ seconds. Specifically, a 100 μF oil filled capacitor may be charged to 3 kV using a DC power supply, and the capacitor may be discharged through a 12 inch length of 30 gauge bare iron wire using a knife switch or gas arc switch wherein the wire is embedded in ice that is confined in a steel casing. The ice fuel system may further comprise a source of electricity such as at lest one of a battery, a fuel cell, and a generator such as a SunCell® to charge the capacitor. An exemplary energetic material comprises Ti+Al+H₂O (ice) that is ignited by the exploding wire that may comprise at least one of Ti, Al, and another metal.

In an embodiment, an energetic reaction mixture and system may comprise a hydrino fuel mixture such as one of those of the disclosure and in Prior Applications, which are incorporated by reference. The reaction mixture may comprise water in at least one physical state such as frozen solid state, liquid, and gaseous. The energetic reaction may be initiated by applying a high current such as a current in the range of about 20 A to 50,000 A. The voltage may be low such as in the range of about 1 V to 100 V. The current may be carried through a conductive matrix such as a metal matrix such as Al, Cu, or Ag metal powder. Alternatively, the conductive matrix may comprise a vessel such as a metal vessel wherein the vessel may enclose or encase the reaction mixture. Exemplary metal vessels comprise Al, Cu, or Ag DSC pans. Exemplary energetic reaction mixtures comprising frozen water (ice) or liquid water comprise at least one of Al crucible Ti+H₂O; Al crucible Al+H₂O; Cu crucible Ti+H₂O; Cu crucible Cu+H₂O; Ag crucible Ti+H₂O; Ag crucible Al+H₂O; Ag crucible Ag+H₂O; Ag crucible Cu+H₂O; Ag crucible Ag+H₂O 0+NH₄NO₃ (mole 50:25:25); Al crucible Al+H₂O+NH₄NO₃ (mole 50:25:25). Another exemplary embodiment comprises a silver or Al crucible+silver nanoparticle suspension in H₂O as energetic material for high-current ignition. In an embodiment, the exploding wire may be replaced by a thin-walled vessel such as a metal tube with a hydrino reaction mixture or a source of hydrino reaction mixture such as a hydrino catalyst such as HOH and H inside or a source of hydrino catalyst and H inside. A source of at least one of HOH catalyst and H may be inside such as liquid water, ice, a hydrate or a solid fuel such as one of the disclosure or Mills Prior Applications that reacts to form at least one of H and H₂O. A conductive material such as conductive particles such as silver nanoparticles may be added to increase the reaction rate. The rate may be increased by increasing the ion recombination rate. The conductive material such as silver nanoparticles may comprise a suspension such as a H₂O suspension. The hydrino reaction mixture or a source of hydrino reaction mixture may comprise an energetic material for high-current ignition.

In an embodiment, the hydrogen may comprise at least one of hydrogen (¹H), deuterium (²H), and tritium (³H) in gaseous, liquid, or solid form. The solid form may comprise a compound comprising hydrogen such as an ionic hydride such as an alkali hydride such as LiD. The energetic hydrino reaction mixture may comprise a source of protons and a source of boron such as ¹¹B. The energetic hydrino reaction may force a nuclear reaction such as fusion of at least two nuclei of the reaction mixture.

In an embodiment, an energetic reaction system comprises a source of at least one of HOH catalyst and H such as water in any physical state such as gas, liquid, or solid such as Type I ice and a source of detonation to cause a shock wave. In an embodiment, the energetic reaction system comprises a plurality of source of shock waves. The source of the shock wave may comprise at least one of one or more exploding wires such as one of the disclosure and one or more charges of conventional energetic material such as TNT or another of the disclosure. The energetic reaction system may comprise at least one detonator of the conventional energetic material. The energetic reaction system may further comprise a sequential trigger means such as delay line or at least one timed switch to cause the formation of a plurality of shock waves with a time delay between at least a first and another shock wave. The sequential trigger may cause a delay in detonation to cause a delay between a first and at least one other detonation wherein each detonation forms a shock wave. The trigger may delay power applied to at least one of the exploding wire and the detonator of the conventional energetic material. The delay time may be in at least one range of about 1 femtosecond to 1 second, 1 nanosecond to 1 second, 1 microsecond to 1 second, and 10 microseconds to 10 milliseconds.

Based on the shockwave propagation velocity and the corresponding pressure, the high-current ignition of water in a silver matrix was measured to produce a shock wave that was equivalent to about 10 times more moles of gunpowder. The results of the ignition of energetic material hydrated silver shots as well as other exemplary hydrino based energetic materials shown in TABLE 3 are reported by Mills et al. [R. Mills, Y. Lu, R. Frazer, “Power Determination and Hydrino Product Characterization of Ultra-low Field Ignition of Hydrated Silver Shots”, Chinese Journal of Physics, Vol. 56, (2018), pp. 1667-1717 which is incorporated by reference in its entirety].

TABLE 3
Blast shockwave speed and corresponding pressure at a
distance of 38.1 cm from the blast.

| | Average | |
|---|---|---|
| | Shockwave | Shockwave |
| | Speed | Pressure |
| Sample | (m/s) | (PSI) |
| Hydrated silver shot (70 | 384 | 0.25 |
| mg/6.5 × 10⁻⁴ moles Ag + | | |
| 6.5 × 10⁻⁵ moles H₂O | | |
| Ti powder (15 mg/3.1 × | 400 | 0.45 |
| 10⁻⁴ moles) + H₂O (5 mg/ | | |
| 2.8 × 10⁻⁴ moles) in the | | |
| Al DSC pan | | |
| Ti powder (83 mg/1.7 × | 422 | 1.09 |
| 10⁻³ moles) + H₂O (30 mg/ | | |
| 1.7 × 10⁻³ moles) in the | | |
| Al DSC pan | | |
| Gunpowder (47 mg/0.563 × | 398 | 0.43 |
| 10⁻³ moles) in the Al | | |
| DSC pan | | |
| NH₄NO₃ (58 mg/7.25 × | 390 | 0.44 |
| 10⁻⁴ moles) in the Al | | |
| DSC pan | | |

In an embodiment, the SunCell® may comprise a chemical reactor wherein reactions other than or in addition to hydrino reactants may be supplied to the reactor to form a desired chemical product. The reactant may be supplied through the EM pump tube. The product may be extracted through the EM pump tube. The reactants may be added in batch before the reactor is closed and the reaction initiated. The products may be removed in batch by opening the reactor following its operation. The reaction product may be extracted by permeation through the reactor wall such as the reaction cell chamber wall. The reactor may provide continuous plasma at a blackbody temperature in the range of 1250 K to 10,000K. The reactor pressure may be in the range of 1 atm to 25 atm. The wall temperature may be in the range of 1250 K to 4000 K. The molten metal may comprise one the supports the desired chemical reaction such as at least one of silver, copper, and silver-copper alloy.

In an embodiment, the exploding wire packed in ice may comprise a transition metal such as at least one of Sc, Ti, V, Cr, Mn, Fe, Co, Ni, Cu, and Zn. The wire may further comprise aluminum. The detonation voltage may be a high voltage such as a voltage in at least one range of 1000 V to 100,000 V and 3000 V to 10,000 V. A thin film comprising transition metal and hydrino hydrogen may form such as iron, chromium, or manganese hydrino hydride, molecular hydrino complex, or atomic hydrino complex. FeH wherein H comprises hydrino was formed by detonation of a wire comprising an alloy of Fe, Cr, and Al using 4000 V and kiloamps. The FeH was identified by ToF-SIMs. Other compounds comprising hydrino hydrogen and another element such as another metal may be formed by using an exploding wire comprising the corresponding element such as another metal.

In an embodiment, a means to form macro-aggregates or polymers comprising lower-energy hydrogen species such as molecular hydrino comprises a source of HOH and a source of H such as water in any physical state such as at least one of gas, liquid, and ice, and may further comprise a source of high current such as a detonating wire. The means to form macro-aggregates or polymers comprising lower-energy hydrogen species such as molecular hydrino further comprises a reaction chamber to confine the hydrino reaction products. Exemplary hydrino reactants are water vapor in air or another gas such as a noble gas such as argon. The water vapor pressure may be in the range of 1 mTorr to 1000 Torr. The another gas may be in a pressure range of about 1 mTorr to 100 atm. In an embodiment, the detonation wire may be coated with a hydroscopic salt such as an alkali or alkaline earth halide, hydroxide, sulfate, phosphate, carbonate, chlorate, perchlorate, oxyanion, solid fuel or mixtures such as at least one of KOH, MgCl₂, and Na₂SO₄ wherein the salt or solid fuel may be hydrated. The hydrino reaction may be initiated by the detonation of a wire by electrical power. In an exemplary embodiment, a wire of the disclosure is detonated in a cavity containing ambient water vapor in air by using a detonation means of the disclosure. The ambient water vapor pressure may be in the range of about 1 to 50 Torr. Exemplary products are iron-hydrino polymer such as FeH₂(¼) and molybdenum-hydrino polymer such as MoH(¼)₁₆. The products may be identified by unique physical properties such as novel composition such as ones comprising metal and hydrogen such as iron-hydrogen, zinc-hydrogen, chromium-hydrogen, or molybdenum-hydrogen. The unique composition may be magnetic in the absence of known magnetism of corresponding composition comprising ordinary hydrogen if it exists. In exemplary embodiments, unique compositions polymeric iron-hydrogen, chromium-hydrogen, titanium-hydrogen, zinc-hydrogen, molybdenum-hydrogen, and tungsten-hydrogen are magnetic.

The hydrino compounds comprising lower-energy hydrogen species such as molecular hydrino may be identified by (i) time of flight secondary ion mass spectroscopy (ToF-SIMS) and electrospray time of flight secondary ion mass spectroscopy (ESI-ToF) that may record the unique metal hydrides, hydride ion, and clusters of inorganic ions with bound H₂(¼) such as in the form of an M+2 monomer or multimer units such as K[K₂CO₃H2]₂⁺ wherein n is an integer; (ii) Fourier transform infrared spectroscopy (FTIR) that may record at least one of the H₂(¼) rotational energy at about 1940 cm⁻¹ and libation bands in the finger print region wherein other high energy features of known functional groups may be absent, (iii) proton magic-angle spinning nuclear magnetic resonance spectroscopy (¹H MAS NMR) that may record an upfield matrix peak such as one in the −4 ppm to −6 ppm region, (iv) X-ray diffraction (XRD) that may record novel peaks due to the unique composition that may comprise a polymeric structure, (v) thermal gravimetric analysis (TGA) that may record a decomposition of the hydrogen polymers at very low temperature such as in the region of 200° C. to 900° C. and provide the unique hydrogen stoichiometry or composition such as FeH or K₂CO₃H₂, (vi) e-beam excitation emission spectroscopy that may record the H₂(¼) ro-vibrational band in the 260 nm region comprising peaks spaced at 0.25 eV; (vii) photoluminescence Raman spectroscopy that may record the second order of the H₂(¼) ro-vibrational band in the 260 nm region comprising peaks spaced at 0.25 eV that may reversibly decrease in intensity with temperature when thermal by a cryocooler; (viii) Raman spectroscopy that may record the H₂(¼) rotational peak at about 1940 cm⁻¹, (ix) X-ray photoelectron spectroscopy (XPS) that may record the total energy of H₂(¼) at about 495-500 eV, (x) gas chromatography that may record a negative peak, (xi) electron paramagnetic resonance (EPR) spectroscopy that may record a [H₂(¼)]₂ peak with a maximum shift of about 300 to 600 G, and (xii) quadrupole moment measurements such as magnetic susceptibility and g factor measurements that record a H₂(1/p) quadrupole moment/e of about

$$\frac{1.70127 {a}_{0}^{2}}{{p}^{2}} .$$

Hydrino molecules may form at least one of dimers and solid H₂(1/p). In an embodiment, the end over end rotational energy of integer J to J+1 transition of H₂(¼) dimer ([H₂(¼)]₂) and D₂(¼) dimer ([D₂(¼)]₂) are about (J+1) 44.30 cm⁻¹ and (J+1) 22.15 cm⁻¹, respectively. In an embodiment, at least one parameter of [H₂(¼)]₂) is (i) a separation distance between H₂(¼) molecules of about 1.028 Å, (ii) a vibrational energy between H₂(¼) molecules of about 23 cm⁻¹, and (iii) a van der Waals energy between H₂(¼) molecules of about 0.0011 eV. In an embodiment, at least one parameter of solid H₂(¼) is (i) a separation distance between H₂(¼) molecules of about 1.028 Å, (ii) a vibrational energy between H₂(¼) molecules of about 23 cm⁻¹, and (iii) a van der Waals energy between H₂(¼) molecules of about 0.019 eV. At least one of the rotational and vibrational spectra may be recorded by at least one of FTIR and Raman spectroscopy wherein the bond dissociation energy and separation distance may also be determined from the spectra. The solution of the parameters of hydrino products is given in Mills GUTCP [which is herein incorporate by reference, available at https://brilliantlightpower.com] such as in Chapters 5-6, 11-12, and 16.

In an embodiment, an apparatus to collect molecular hydrino in gaseous, physi-absorbed, liquefied, or in other state comprises a source of macro-aggregates or polymers comprising lower-energy hydrogen species, a chamber to contain the macro-aggregates or polymers comprising lower-energy hydrogen species, a means to thermally decompose the macro-aggregates or polymers comprising lower-energy hydrogen species in the chamber, and a means to collect the gas released from the macro-aggregates or polymers comprising lower-energy hydrogen species. The decomposition means may comprise a heater. The heater may heat the first chamber to a temperature greater that the decomposition temperature of the macro-aggregates or polymers comprising lower-energy hydrogen species such as a temperature in at least one range of about 10° C. to 3000° C., 100° C. to 2000° C., and 100° C. to 1000° C. The means to collect the gas from decomposition of macro-aggregates or polymers comprising lower-energy hydrogen species may comprise a second chamber. The second chamber may comprise at least one of a gas pump, a gas valve, a pressure gauge, and a mass flow controller to at least one of store and transfer the collected molecular hydrino gas. The second chamber may further comprise a getter to absorb molecular hydrino gas or a chiller such as a cryogenic system to liquefy molecular hydrino. The chiller may comprise a cryopump or dewar containing a cryogenic liquid such as liquid helium or liquid nitrogen.

The means to form macro-aggregates or polymers comprising lower-energy hydrogen species may further comprise a source of field such as a source of at least one of an electric field or a magnetic field. The source of the electric field may comprise at least two electrodes and a source of voltage to apply the electric field to the reaction chamber wherein the aggregate or polymers are formed. Alternatively, the source of electric field may comprise an electrostatically charged material. The electrostatically charged material may comprise the reaction cell chamber such as a chamber comprising carbon such as a Plexiglas chamber. The detonation of the disclosure may electrostatically charge the reaction cell chamber. The source of the magnetic field may comprise at least one magnet such as a permanent, electromagnet, or a superconducting magnet to apply the magnetic field to the reaction chamber wherein the aggregate or polymers are formed.

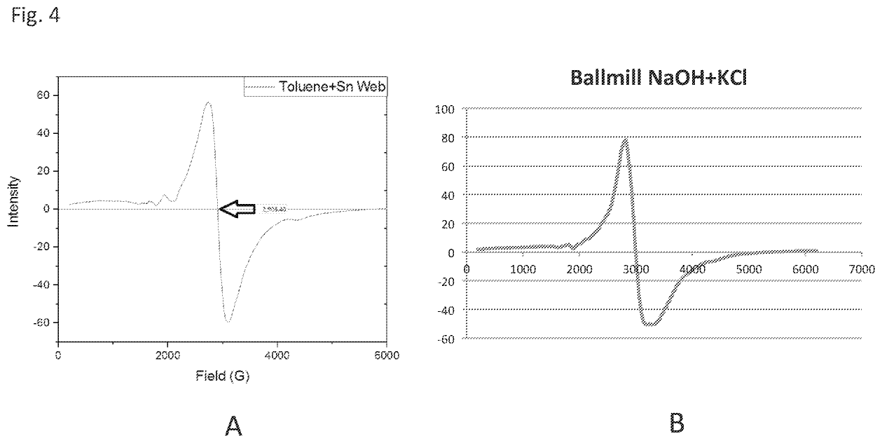

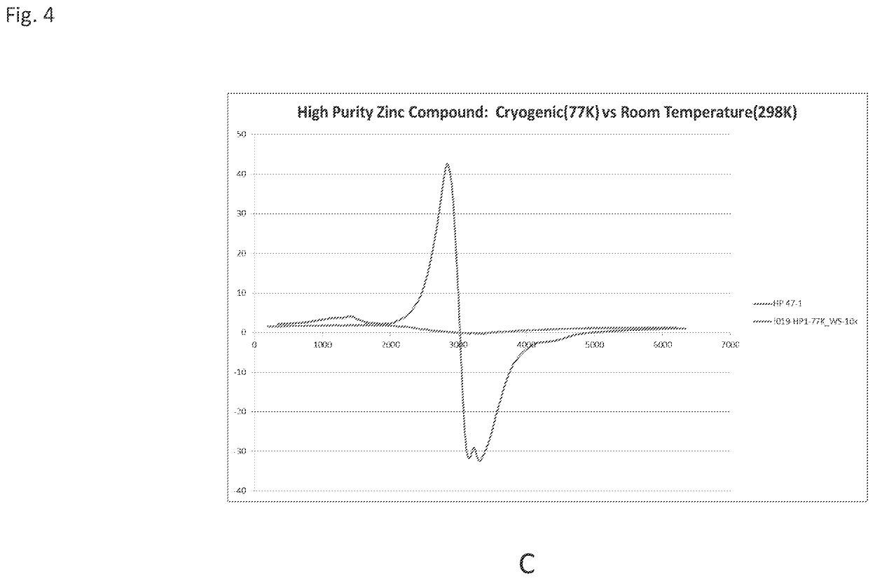

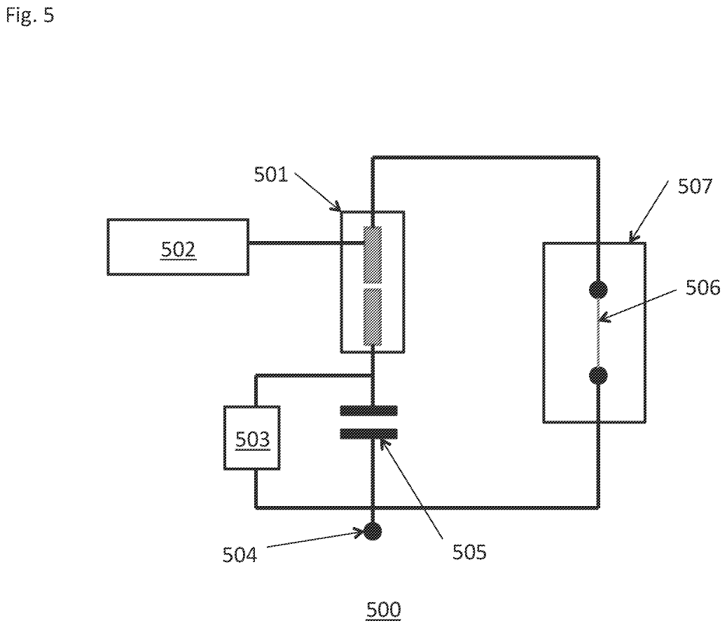

Molecular hydrino such as H₂(¼) may have non-zero f and m, quantum numbers corresponding to orbital angular momentum with a corresponding magnetic moment. H₂(¼) molecules are predicted to form dimers [H₂(¼)]₂ that have a magnetic interaction corresponding to about 474 G. The classical theory derived in analytical equations is given in Mills GUTCP. Due to the interaction orbital magnetic moments, molecular hydrino may be uniquely identified by electron paramagnetic resonance spectroscopy (EPR). Unique EPR nuclear coupling as well as electron nuclear double resonance spectroscopy (ENDOR) signatures due to the reduced electron radius and internuclear distance are further characteristic and uniquely identify molecular hydrino. In an embodiment, the lower-energy hydrogen product may comprise a metal that is not active in electron paramagnetic resonance (EPR) spectroscopy having an EPR spectrum comprising at least one of high g factors, very low g factors, extraordinary line width, and proton splitting. Exemplary EPR spectra of the reaction products comprising lower-energy hydrogen species such as molecular hydrino formed by the detonation of Sn wire in an atmosphere comprising water vapor in air and by the ball milling NaOH—KCl comprising H₂O that serves as a source of H and HOH catalyst to form H₂(¼) dimers are shown in FIGS. 4A-B. The wire detonation system is shown in FIG. 5. The web-like product was suspended in toluene, and EPR was performed on an instrument at Princeton University having a microwave frequency of 9.368 GHz (3343 G). NaOH—KCl was run neat. The EPR peaks match that predicted of a maximum 474 G shift for [H₂(¼)]₂. The peak width of about 375 G is extraordinarily broad due to the nature of peak origin being the interaction of orbital magnetic moments of the molecular hydrino dimer [H₂(¼)]₂. Tin, NaOH, and KCl are not EPR active. The main parameters of EPR spectrum of tin hydroxyl and superoxide radicals: g-factor and line width ΔH, calculated from the corresponding EPR spectra are following: g₁=2.0021 and ΔH₁=1 G, g_{2=2.0009} and ΔH2=0.8 G. The effect of cryogenic temperature was determined on the EPR spectrum of a zinc hydrino compound as shown in FIG. 4C. The molecular hydrino dimer EPR peak was observed at 298K(red trace) and was absent at 77K(blue trace) which is evidence of the predicted hydrino phase change to a compact solid at cryogenic temperatures wherein the magnetism due to dense packing causes the EPR peak to be broadened and out of range.

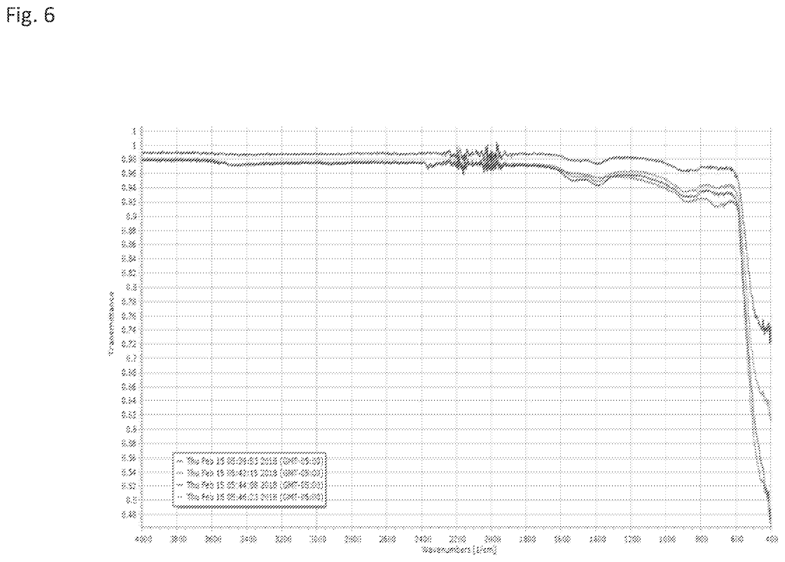

In an embodiment, the hydrino species EPR spectrum shows unique features such as at least one of a high g factor and an extraordinary line width. In addition to a broad EPR signature, molecular hydrino dimer [H₂(¼)]₂ gives rise to a broad IR band in the very low energy finger print region. As shown in Mills GUTCP, [H₂(¼)]₂ has a low vibrational energy which when excited as modes involving an ensemble of [H₂(¼)]₂ dimers as a macroaggregate, the superimposed energies gives rise to a band of IR absorption as observed in FIG. 6.

The electron orbital magnetic moments of a plurality of hydrino molecules such as H₂(¼) may phase couple to give rise to permanent magnetization. Ordinarily, the angular momentum and the corresponding magnetic moment averages to zero and there is no net macroscopic or bulk magnetism due to orbital angular momentum. However, molecular hydrino may give rise to non-zero or finite bulk magnetism when the angular momentum magnetic moments of a plurality of hydrino molecules interact cooperatively wherein multimers such as dimers may occur. Magnetism of dimers, aggregates, or polymers comprising molecular hydrino may arise from the electrodynamic interaction of the cooperatively aligned orbital angular magnetic moments. In an embodiment, the field is equivalent to about 474 G per H₂(¼) unit of the multimer. Moreover, the magnetism may be much greater in the case that the magnetism is due to the interaction of the permananet electron magnetic moment of an additional species having at least one unpaired electrons such as iron atoms.

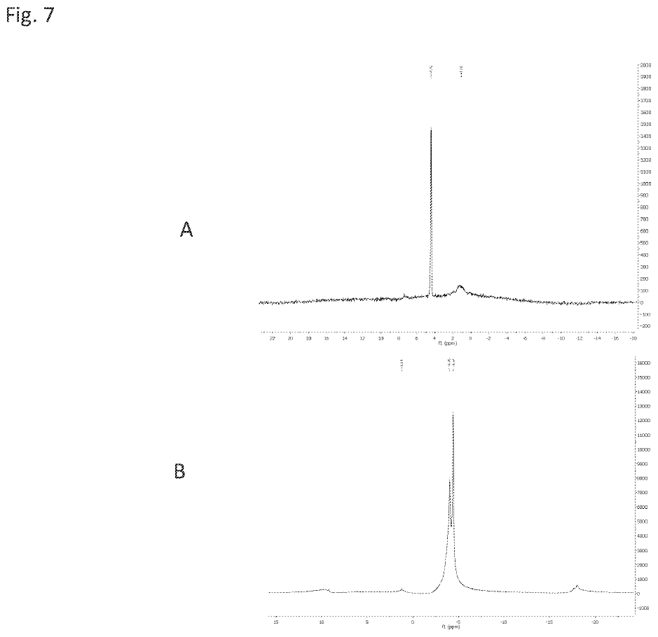

The magnetic characteristic of molecular hydrino is demonstrated by proton magic angle spinning nuclear magnetic resonance spectroscopy (¹H MAS NMR) as shown by Mills et al. in the case of electrochemical cells that produce hydrinos called CIHT cells [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. The presence of molecular hydrino in a solid matrix such as an alkali hydroxide-alkali halide matrix that may further comprise some waters of hydration gives rise to an upfield ¹H MAS NMR peak, typically at −4 to −5 ppm due to the molecular hydrinos' paramagnetic matrix effect; whereas, the initial matrix devoid of hydrino shows the known down-field shifted matrix peak at +4.41 ppm (FIG. 7).

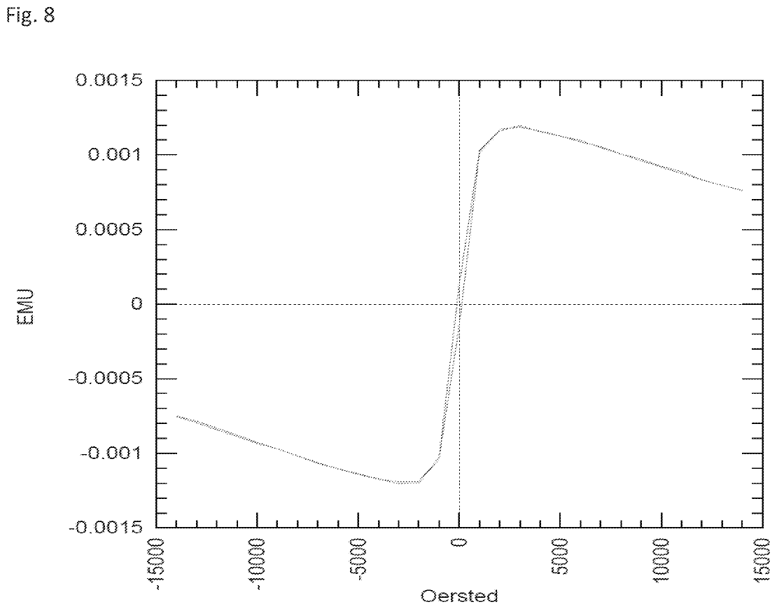

A convenient method to produce molecular hydrino in non-zero angular momentum states is by wire detonation in the presence of H₂O to serve as the hydrino catalyst and source of H. Wire detonations in an atmosphere comprising water vapor produces magnetic linear chains comprising hydrino hydrogen such as molecular hydrino possessing nonzero f and m, quantum states with metal atoms or ions that may aggregate to forms webs. Paramagnetic material responds linearly with the induced magnetism; whereas, an observed “S” shape is characteristic of super paramagnetic, a hybrid of ferromagnetism and para magnetism. In an embodiment the polymeric web compound such as the compound formed by detonating molybdenum wire in air comprising water vapor is superparamagnetic. The vibrating sample magnetosusceptometer recording may show an S-shaped curve as shown in FIG. 8. It is exception that the induced magnetism peaks at 5K Oe and declines with higher applied field. The superparamagnetic hydrino compound may comprise magnetic nanoparticles that may be oriented in a magnetic field.

A self-assembly mechanism may comprise a magnetic ordering in addition to van der Waals forces. It is well known that the application of an external magnetic field causes colloidal magnetic nanoparticles such as magnetite (Fe₂O₃) suspended in a solvent such as toluene to assemble in to linear structures. Due to the small mass and high magnetic moment molecular hydrino magnetically self assembles even in the absence of a magnetic field. In an embodiment to enhance the self-assembly and to control the formation of alternative structures of the hydrino products, an external magnetic field is applied to the hydrino reaction such as the wire detonation. The magnetic field may be applied by placing at least one permanent magnet in the reaction chamber. Alternatively, the detonation wire may comprise a metal that serves as a source of magnetic particles such as magnetite to drive the magnetic self-assembly of molecular hydrino wherein the source may be the wire detonation in water vapor or another source.

In an embodiment, hydrino products such as hydrino compounds or macroaggregates may comprise at least one other element of the periodic chart other than hydrogen. The hydrino products may comprise hydrino molecules and at least one other element such as at least one a metal atom, metal ion, oxygen atom, and oxygen ion. Exemplary hydrino products may comprise H₂(1/p) such as H₂(¼) and at least one of Sn, Zn, Ag, Fe, SnO, ZnO, AgO, FeO, and Fe₂O₃.

The bonding of molecular hydrino molecules H₂(¼) to form a solid at room to elevated temperatures is due to van der Waals forces that are much greater for molecular hydrino than molecular hydrogen due to the decreased dimensions and greater packing as shown in Mills GUTCP. Due to its intrinsic magnetic moment and van der Waals forces, molecular hydrino may self assemble into macroaggregates. In an embodiment, molecular hydrino such as H₂(¼) may assemble into linear chains bound by magnetic dipole forces as well as van der Waals forces. In another embodiment, molecular hydrino can assemble into three-dimensional structures such as a cube having H₂(1/p) such as H₂(¼) at each of the eight vertices. In an embodiment, eight H₂(1/p) molecules such as H₂(¼) molecules are bound into a cube wherein the center of each molecule is at one of the eight vertices of the cube, and each inter-nuclear axis is parallel to an edge of the cube centered on a vertex.

H₁₆ may serve as a unit or moiety for more complex macrostructures formed by self-assembly. In another embodiment, units of Ha comprising H₂(1/p) such as H₂(¼) at each of the four vertices of a square may be added to the cuboid H₁₆ to comprise H₆ wherein n is an integer. Exemplary additional macroaggregates are H₁₆, H₂₄, and H₃₂. The hydrogen macroaggregate neutrals and ions may combine with other species such as O, OH, C, and N as neutrals or ions. In an embodiment, the resulting structure gives rise to an H₁₆ peak in the time-of-flight secondary ion mass spectrum (ToF-SIMS) wherein fragments may be observed masses corresponding to integer H loss from H₁₆ such as H₁₆, H₁₄, H₁₃, and H₁₂. Due to the mass of H of 1.00794 u, the corresponding +1 or −1 ion peaks have masses of 16.125, 15.119, 14.111, 13.103, 12.095 . . . . The hydrogen macroaggregate ions such as H₁₆⁻ or H₁₆⁺ may comprise metastables. The hydrogen macroaggregate ions H₁₆⁻ and H₁₆⁺ having metastable features of broad peaks were observed by ToF-SIMS at 16.125 in the positive and negative spectra. H₁₅⁻ was observed in the negative ToF-SIMS spectrum at 15.119. H₂₄ metastable species H₂₆⁺ and H₂₅⁻ were observed in the positive and negative ToF-SIMS spectra, respectively.

In an embodiment, lower energy hydrogen such as molecular hydrino may assemble into nanotubes. The molecular hydrino that serves as the source of the nanotubes may be formed from the detonation of a metal wire in an atmosphere comprising oxygen and water vapor such as an air atmosphere according to the disclosure. The assembly of molecular hydrino into nanotubes may be promoted on metal or metal oxide particles form by the detonation of the metal wire. The nanotubes may absorb a hydrogen species such as molecular hydrino and ordinary molecular hydrogen.

In an embodiment, the compositions of matter comprising lower-energy hydrogen species such as molecular hydrino (“hydrino compound”) may be separated magnetically. The hydrino compound may be cooled to further enhance the magnetism before being separated magnetically. The magnetic separation method may comprise moving a mixture of compounds containing the desired hydrino compound through a magnetic field such that the hydrino compound is preferentially retarded in mobility relative to the remainder of the mixture or moving a magnet over the mixture to separate the hydrino compound from the mixture. In an exemplary embodiment, hydrino compound is separated from nonhydrino products of the wire detonations by immersing the detonation product material in liquid nitrogen and using magnetic separation wherein the cryo-temperature increases the magnetism of the hydrino compound product. The separation may be enhanced at the boiling surface of the liquid nitrogen.

In an embodiment, a hydrino species such as atomic hydrino, molecular hydrino, or hydrino hydride ion is synthesized by the reaction of H and at least one of OH and H₂O catalyst. In an embodiment, the product of at least one of the SunCell® reaction and the energetic reactions such as ones comprising shot or wire ignitions of the disclosure to form hydrinos is a hydrino compound or species comprising a hydrino species such as H₂(1/p) complexed with at least one of (i) an element other than hydrogen, (ii) an ordinary hydrogen species such as at least one of H⁺, ordinary H₂, ordinary H⁻, and ordinary H₃⁺, an organic molecular species such as an organic ion or organic molecule, and (iv) an inorganic species such as an inorganic ion or inorganic compound. The hydrino compound may comprise an oxyanion compound such as an alkali or alkaline earth carbonate or hydroxide or other such compounds of the present disclosure. In an embodiment, the product comprises at least one of M₂CO₃.H₂(¼) and MOH.H₂(¼) (M=alkali or other cation of the present disclosure) complex. The product may be identified by ToF-SIMS or electrospray time of flight secondary ion mass spectroscopy (ESI-ToF) as a series of ions in the positive spectrum comprising M(M₂CO₃.H₂(¼))ₙ⁺ and M(MOH.H₂(¼))ₙ⁺, respectively, wherein n is an integer and an integer and integer p>1 may be substituted for 4. In an embodiment, a compound comprising silicon and oxygen such as SiO₂ or quartz may serve as a getter for H₂(¼). The getter for H₂(¼) may comprise a transition metal, alkali metal, alkaline earth metal, inner transition metal, rare earth metal, combinations of metals, alloys such as a Mo alloy such as MoCu, and hydrogen storage materials such as those of the present disclosure.

The compounds comprising hydrino species synthesized by the methods of the present disclosure may have the formula MH, MH₂, or M₂H₂, wherein M is an alkali cation and H is a hydrino species. The compound may have the formula MHₙ wherein n is 1 or 2, M is an alkaline earth cation and H is hydrino species. The compound may have the formula MHX wherein M is an alkali cation, X is one of a neutral atom such as halogen atom, a molecule, or a singly negatively charged anion such as halogen anion, and H is a hydrino species. The compound may have the formula MHX wherein M is an alkaline earth cation, X is a singly negatively charged anion, and H is H is a hydrino species. The compound may have the formula MHX wherein M is an alkaline earth cation, X is a double negatively charged anion, and H is a hydrino species. The compound may have the formula M₂HX wherein M is an alkali cation, X is a singly negatively charged anion, and H is a hydrino species. The compound may have the formula MHₙ wherein n is an integer, M is an alkaline cation and the hydrogen content Hₙ of the compound comprises at least one hydrino species. The compound may have the formula M₂Hₙ wherein n is an integer, M is an alkaline earth cation and the hydrogen content Hₙ of the compound comprises at least one hydrino species. The compound may have the formula M₂XHₙ wherein n is an integer, M is an alkaline earth cation, X is a singly negatively charged anion, and the hydrogen content Hₙ of the compound comprises at least one hydrino species. The compound may have the formula M₂X₂Hₙ wherein n is 1 or 2, M is an alkaline earth cation, X is a singly negatively charged anion, and the hydrogen content Hₙ of the compound comprises at least one hydrino species. The compound may have the formula M₂X₃H wherein M is an alkaline earth cation, X is a singly negatively charged anion, and H is a hydrino species. The compound may have the formula M₂XHₙ wherein n is 1 or 2, M is an alkaline earth cation, X is a double negatively charged anion, and the hydrogen content Hₙ of the compound comprises at least one hydrino species. The compound may have the formula M₂XX′H wherein M is an alkaline earth cation, X is a singly negatively charged anion, X′ is a double negatively charged anion, and H is hydrino species. The compound may have the formula MM′Hₙ wherein n is an integer from 1 to 3, M is an alkaline earth cation, M′ is an alkali metal cation and the hydrogen content Hₙ of the compound comprises at least one hydrino species. The compound may have the formula MM′XHₙ wherein n is 1 or 2, M is an alkaline earth cation, M′ is an alkali metal cation, X is a singly negatively charged anion and the hydrogen content Hₙ of the compound comprises at least one hydrino species. The compound may have the formula MM′XH wherein M is an alkaline earth cation, M′ is an alkali metal cation, X is a double negatively charged anion and H is a hydrino species. The compound may have the formula MM′XX′H wherein M is an alkaline earth cation, M′ is an alkali metal cation, X and X′ are singly negatively charged anion and H is a hydrino species. The compound may have the formula MXX′Hₙ wherein n is an integer from 1 to 5, M is an alkali or alkaline earth cation, X is a singly or double negatively charged anion, X′ is a metal or metalloid, a transition element, an inner transition element, or a rare earth element, and the hydrogen content Hₙ of the compound comprises at least one hydrino species. The compound may have the formula MHₙ wherein n is an integer, M is a cation such as a transition element, an inner transition element, or a rare earth element, and the hydrogen content Hₙ of the compound comprises at least one hydrino species. The compound may have the formula MXHₙ wherein n is an integer, M is an cation such as an alkali cation, alkaline earth cation, X is another cation such as a transition element, inner transition element, or a rare earth element cation, and the hydrogen content Hₙ of the compound comprises at least one hydrino species. The compound may have the formula (MHₘMCO₃)ₙ wherein M is an alkali cation or other +1 cation, m and n are each an integer, and the hydrogen content Hₘ of the compound comprises at least one hydrino species. The compound may have the formula (MHₘMNO₃)ₙ⁺nX⁻ wherein M is an alkali cation or other +1 cation, m and n are each an integer, X is a singly negatively charged anion, and the hydrogen content Hₘ of the compound comprises at least one hydrino species. The compound may have the formula (MHMNO₃)ₙ wherein M is an alkali cation or other +1 cation, n is an integer and the hydrogen content H of the compound comprises at least one hydrino species. The compound may have the formula (MHMOH) wherein M is an alkali cation or other +1 cation, n is an integer, and the hydrogen content H of the compound comprises at least one hydrino species. The compound including an anion or cation may have the formula (MHₘM′X)ₙ wherein m and n are each an integer, M and M′ are each an alkali or alkaline earth cation, X is a singly or double negatively charged anion, and the hydrogen content Hₘ of the compound comprises at least one hydrino species. The compound including an anion or cation may have the formula (MHₘM′X′)ₙ⁺nX⁻ wherein m and n are each an integer, M and M′ are each an alkali or alkaline earth cation, X and X′ are a singly or double negatively charged anion, and the hydrogen content Hₘ of the compound comprises at least one hydrino species. The anion may comprise one of those of the disclosure. Suitable exemplary singly negatively charged anions are halide ion, hydroxide ion, hydrogen carbonate ion, or nitrate ion. Suitable exemplary double negatively charged anions are carbonate ion, oxide, or sulfate ion.

In an embodiment, the hydrino compound or mixture comprises at least one hydrino species such as a hydrino atom, hydrino hydride ion, and dihydrino molecule embedded in a lattice such as a crystalline lattice such as in a metallic or ionic lattice. In an embodiment, the lattice is non-reactive with the hydrino species. The matrix may be aprotic such as in the case of embedded hydrino hydride ions. The compound or mixture may comprise at least one of H(1/p), H₂(1/p), and H(1/p) embedded in a salt lattice such as an alkali or alkaline earth salt such as a halide. Exemplary alkali halides are KCl and KI. The salt may be absent any H₂O in the case of embedded H(1/p). Other suitable salt lattices comprise those of the present disclosure.

The hydrino compounds of the present invention are preferably greater than 0.1 atomic percent pure. More preferably, the compounds are greater than 1 atomic percent pure. Even more preferably, the compounds are greater than 10 atomic percent pure. Most preferably, the compounds are greater than 50 atomic percent pure. In another embodiment, the compounds are greater than 90 atomic percent pure. In another embodiment, the compounds are greater than 95 atomic percent pure.

In an embodiment, hydrino compounds may be purified by recrystallization in a suitable solvent. Alternatively, the compounds may be purified by chromatography such as high performance liquid chromatography (HPLC).

Superparamagnetic hydrino compounds may comprise magnetic nanoparticles that may be oriented in a magnetic field. Applications of the magnetic hydrino compounds comprises magnetic storage material such as the memory storage material of computer hard drives, contrast agents in magnetic resonance imaging, a ferrofluid such as one with tunable viscosity, magnetic cell separation such as cell, DNA or protein separation or RNA fishing, and treatments such as targeted drug delivery, magnetic hyperthermia, and magnetofection.

In an embodiment, the compositions of matter comprising lower-energy hydrogen species such as molecular hydrino (“hydrino compound”) may be purified by removing non-hydrino reaction products that do not contain hydrino or hydrino compound. The nonhydrino reaction products may be dissolved and the hydrino compound may be collected by a means to collect un-dissolved material such as one known in the art. In an embodiment wherein the nonhydrino compound products comprise a metal or metal oxide, the non-hydrino products may be dissolved in aqueous acid, and the undissolved hydrino compound may be collected by filtration or centrifugation. In an exemplary embodiment, hydrino compound is a component of a product mixture formed by a metal wire detonation such as a detonation of a Zn, Sn, Fe, or Mo wire, in an atmosphere comprising water vapor. The nonhydrino products comprising unreacted metal and metal oxide may be removed by dissolving the product mixture in aqueous acid solvent such as 1 M HCl. The undissolved hydrino compound may be collected by filtration on filter paper or by centrifugation. The product mixture comprising a hydrino compound and a metal oxide may be purified by dissolving the metal oxide of the product mixture in acid and exchanging the cation of the mixture with another such as K in solution whereby a hydrino compound or mixture comprising K may form. Crystals of the hydrino compound may be permitted to form. Some solvent may be removed by means such as by evaporation such as rotary evaporation to allow crystal to form. The crystals may be removed by a separator means such as filtration. In another embodiment, the hydrino compound may be dissolved in a solvent in which the nonhydrino product is insoluble. The hydrino compound solution may be separated from the solid by means known in the art such as by filtration or centrifugation. The solvent may be removed by evaporation or the hydrino compound may be allowed to precipitate and then collected by means such as filtration or centrifugation.

The hydrino macroaggregate or polymeric material formed by the wire detonation of humidified argon or humidified air may be purified by dissolving in a suitable solvent such as water or DMSO followed by precipitation using a solvent evaporator such as a rotary evaporation. In an embodiment, the purity of the hydrino compound may be increased by wire detonation in a humidified inert gas atmosphere such as a humidified argon atmosphere. The compound can be used for stealth applications due to its strong absorption in the infrared and microwave regions of the electromagnetic spectrum.

In an embodiment, molecular hydrino may be caused to bond to another compound such as an inorganic compound such as an alkali or alkaline earth hydroxide or carbonate by bubbling gas comprising molecular hydrino into or through a solution comprises the another compound. The product may comprise monomer or multimer units such as [K₂CO₃:H₂]ₙ wherein n is an integer.

The SunCell may comprise a transparent window to serve as a light source of wavelengths transparent to the window. The SunCell may comprise a blackbody radiator 5b4 that may serve as a blackbody light source.

### Experimental

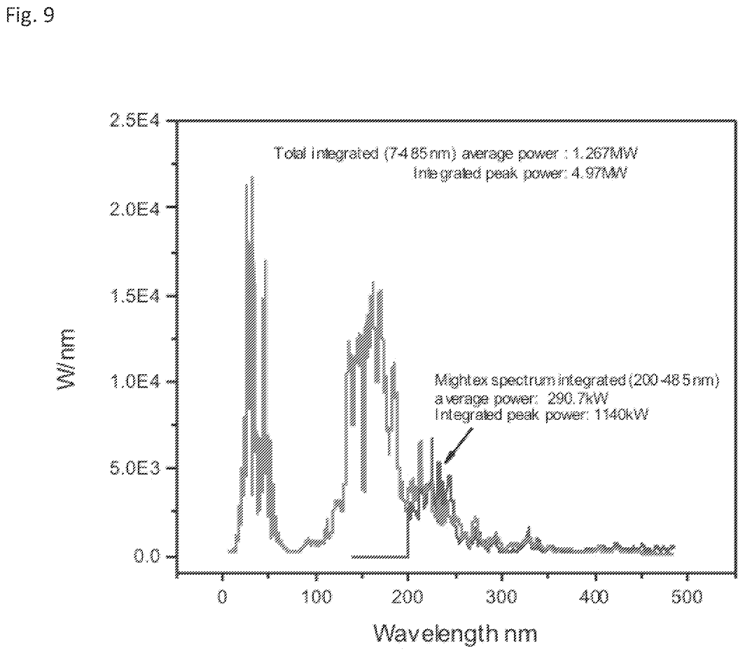

The SunCell® power generation system includes a photovoltaic power converter configured to capture plasma photons generated by the fuel ignition reaction and convert them into useable energy. In some embodiments, high conversion efficiency may be desired. The reactor may expel plasma in multiple directions, e.g., at least two directions, and the radius of the reaction may be on the scale of approximately several millimeters to several meters, for example, from about 1 mm to about 25 cm in radius. Additionally, the spectrum of plasma generated by the ignition of fuel may resemble the spectrum of plasma generated by the sun and/or may include additional short wavelength radiation. FIG. 9 shows an exemplary the absolute spectrum in the 5 nm to 450 nm region of the ignition of a 80 mg shot of silver comprising absorbed H₂O from water addition to melted silver as it cooled into shots showing an average optical power of 1.3 MW, essentially all in the ultraviolet and extreme ultraviolet spectral region. The ignition was achieved with a low voltage, high current using a Taylor-Winfield model ND-24-75 spot welder. The voltage drop across the shot was less than 1 V and the current was about 25 kA. The high intensity UV emission had duration of about 1 ms. The control spectrum was flat in the UV region. The radiation of the solid fuel such as at least one of line and blackbody emission may have an intensity in at least one range of about 2 to 200,000 suns, 10 to 100,000 suns, 100 to 75,000 suns. In an embodiment, the inductance of the welder ignition circuit may be increased to increase the current decay time following ignition. The longer decay time may maintain the hydrino plasma reaction to increase the energy production.

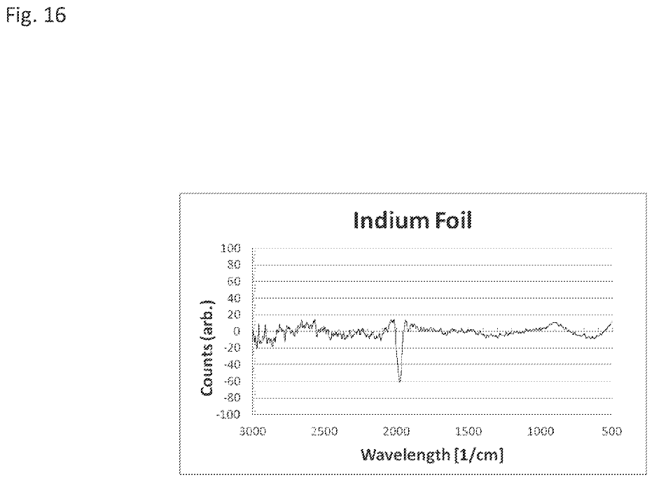

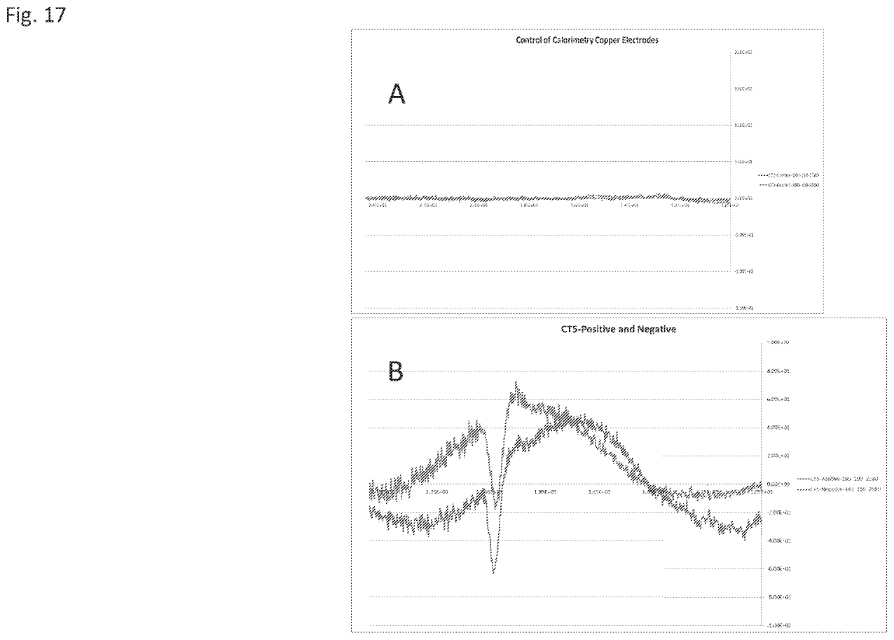

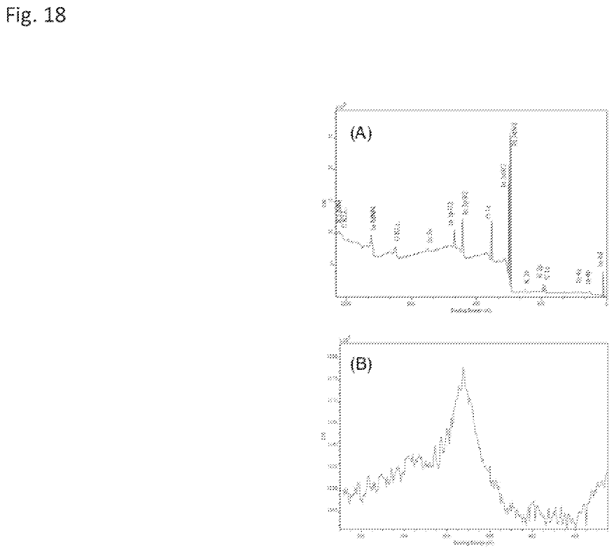

XPS and Raman were performed on the electrodes pre and post detonation. The post-detonation electrodes each showed a very large 1940 cm⁻¹ Raman peak such as that shown in FIGS. 16 and 17B. The post detonation XPS showed a large 496 eV peak such as that shown in FIG. 18 that matched the total energy of H₂(¼). No other primary element peaks of the only alternative assignments, Na, Sn, or Zn, were present confirming that H₂(¼) was the product of the extraordinarily energetic reaction. No Raman or XPS peaks were observed in the 1940 cm⁻¹ or 496 eV regions in the Raman or XPS spectra, respectively, of the per-detonation electrodes.

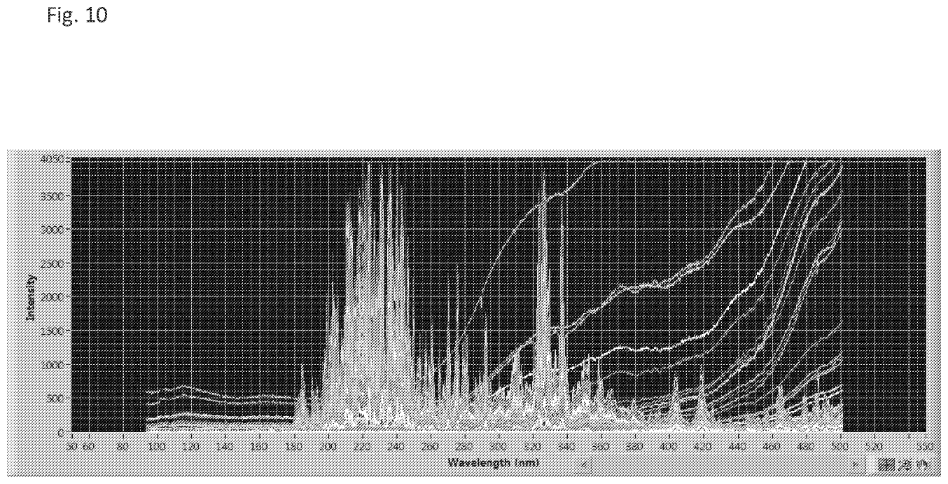

The UV and EUV spectrum may be converted to blackbody radiation. The conversion may be achieved by causing the cell atmosphere to be optically thick for the propagation of at least one of UV and EUV photons. The optical thickness may be increased by causing metal such as the fuel metal to vaporize in the cell. The optically thick plasma may comprise a blackbody. The blackbody temperature may be high due to the extraordinarily high power density capacity of the hydrino reaction and the high energy of the photons emitted by the hydrino reaction. The spectrum (100 nm to 500 nm region with a cutoff at 180 nm due to the sapphire spectrometer window) of the ignition of molten silver pumped into W electrodes in atmospheric argon with an ambient H₂O vapor pressure of about 1 Torr is shown in FIG. 10. The source of electrical power 2 comprised two sets of two capacitors in series (Maxwell Technologies K2 Ultracapacitor 2.85V/3400F) that were connected in parallel to provide about 5 to 6 V and 300 A of constant current with superimposed current pulses to 5 kA at frequency of about 1 kHz to 2 kHz. The average input power to the W electrodes (1 cm×4 cm) was about 75 W. The initial UV line emission transitioned to 5000K blackbody radiation when the atmosphere became optically thick to the UV radiation with the vaporization of the silver by the hydrino reaction power. The power density of a 5000K blackbody radiator with an emissivity of vaporized silver of 0.15 is 5.3 MW/m². The area of the observed plasma was about 1 m². The blackbody radiation may heat a component of the cell 26 such as top cover 5b4 that may serve as a blackbody radiator to the PV converter 26a in a thermophotovoltaic embodiment of the disclosure.

An exemplary test of a melt comprising a source of oxygen comprised the ignition an 80 mg silver/1 wt % borax anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 250 kW of power was observed for duration of about 1 ms. In another exemplary test of a melt comprising a source of oxygen comprised the ignition an 80 mg silver/2 mol % Na₂O anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 370 kW of power was observed for duration of about 1 ms. In another exemplary test of a melt comprising a source of oxygen comprised the ignition an 80 mg silver/2 mol % Li₂O anhydrate shot in an argon/5 mole % H₂ atmosphere with the optical power determined by absolute spectroscopy. Using a welder (Acme 75 KVA spot welder) to apply a high current of about 12 kA at a voltage drop of about 1 V 500 kW of power was observed for duration of about 1 ms.

Based on the size of the plasma recorded with an Edgertronics high-speed video camera, the hydrino reaction and power depends on the reaction volume. The volume may need to be a minimum for optimization of the reaction power and energy such as about 0.5 to 10 liters for the ignition of a shot of about 30 to 100 mg such as a silver shot and a source of H and HOH catalyst such as hydration. From the shot ignition, the hydrino reaction rate is high at very high silver pressure. In an embodiment, the hydrino reaction may have high kinetics with the high plasma pressure. Based on high-speed spectroscopic and Edgertronics data, the hydrino reaction rate is highest at the initiation when the plasma volume is the lowest and the Ag vapor pressure is the highest. The 1 mm diameter Ag shot ignites when molten (T=1235 K). The initial volume for the 80 mg (7.4×10⁻⁴ moles) shot is 5.2×10⁻⁷ liters. The corresponding maximum pressure is about 1.4×10⁵ atm. In an exemplary embodiment, the reaction was observed to expand at about sound speed (343 m/s) for the reaction duration of about 0.5 ms. The final radius was about 17 cm. The final volume without any backpressure was about 20 liters. The final Ag partial pressure was about 3.7E-3 atm. Since the reaction may have higher kinetics at higher pressure, the reaction rate may be increased by electrode confinement by applying electrode pressure and allowing the plasma to expand perpendicular to the inter-electrode axis.

The power released by the hydrino reaction caused by the addition of one mole % or 0.5 mole % bismuth oxide to molten silver injected into ignition electrodes of a SunCell® at 2.5 ml/s in the presence of a 97% argon/3% hydrogen atmosphere was measured. The relative change in slope of the temporal reaction cell water coolant temperature before and after the addition of the hydrino reaction power contribution corresponding to the oxide addition was multiplied by the constant initial input power that served as an internal standard. For duplicate runs, the total cell output powers with the hydrino power contribution following oxygen source addition were determined by the products of the ratios of the slopes of the temporal coolant temperature responses of 97, 119, 15, 538, 181, 54, and 27 corresponding to total input powers of 7540 W, 8300 W, 8400 W, 9700 W, 8660 W, 8020 W, and 10,450 W. The thermal burst powers were 731,000 W, 987,700 W, 126,000 W, 5,220,000 W, 1,567,000 W, 433,100 W, and 282,150 W, respectively.

The power released by the hydrino reaction caused by the addition of one mole % bismuth oxide (Bi₂O₃), one mole % lithium vanadate (LiVO₃), or 0.5 mole % lithium vanadate to molten silver injected into ignition electrodes of a SunCell® at 2.5 ml/s in the presence of a 97% argon/3% hydrogen atmosphere was measured. The relative change in slope of the temporal reaction cell water coolant temperature before and after the addition of the hydrino reaction power contribution corresponding to the oxide addition was multiplied by the constant initial input power that served as an internal standard. For duplicate runs, the total cell output powers with the hydrino power contribution following oxygen source addition were determined by the products of the ratios of the slopes of the temporal coolant temperature responses of 497, 200, and 26 corresponding to total input powers of 6420 W, 9000 W, and 8790 W. The thermal burst powers were 3.2 MW, 1.8 MW, and 230,000 W, respectively.

In an exemplary embodiment, the ignition current was ramped from about 0 A to 2000 A corresponding to a voltage increase from about 0 V to 1 V in about 0.5, at which voltage the plasma ignited. The voltage is then increased as a step to about 16 V and held for about 0.25 s wherein about 1 kA flowed through the melt and 1.5 kA flowed in series through the bulk of the plasma through another ground loop other than the electrode 8. With an input power of about 25 kW to a SunCell® comprising Ag (0.5 mole % LiVO₃) and argon-H₂ (3%) at a flow rate of 9 liters/s, the power output was over 1 MW. The ignition sequence repeated at about 1.3 Hz.

In an exemplary embodiment, the ignition current was about 500 A constant current and the voltage was about 20 V. With an input power of about 15 kW to a SunCell® comprising Ag (0.5 mole % LiVO₃) and argon-H₂ (3%) at a flow rate of 9 liters/s, the power output was over 1 MW.

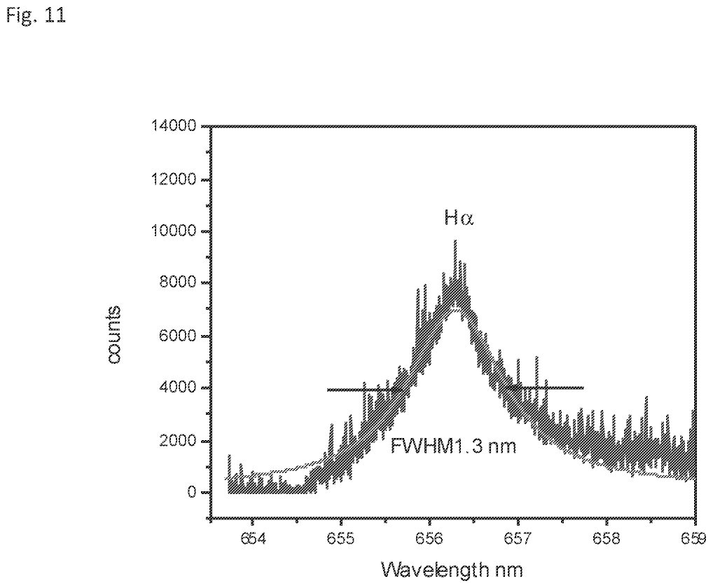

The extraordinary power density produced by the hydrino reaction run in a 2 liter Pyrex SunCell® (FIG. 2I215) is evident from the observed extreme Stark broadening of the H alpha line of 1.3 nm shown in FIG. 11. The broadening corresponds to an electron density of 3.5×10²³/m³. The SunCell® gas density was calculated to be 2.5×10²⁵ atoms/m³ based on an argon-H₂ pressure of 800 Torr and temperature of 3000K. The corresponding ionization fraction was about 10%. Given that argon and H₂ have ionization energies of about 15.5 eV and a recombination lifetime of less than 100 us at high pressure, the power density to sustain the ionization is

$$P = ( \frac{3.5 \times {10}^{23} electrons}{{m}^{3}} ) ( 15.5 eV ) ( \frac{1.6 \times {10}^{- 19} J}{eV} ) ( \frac{1}{{10}^{- 4} s} ) = \frac{8.7 \times {10}^{9} W}{{m}^{3}} .$$

In an embodiment shown in FIG. 5, the system 500 to form macro-aggregates or polymers comprising lower-energy hydrogen species comprises a chamber 507 such as a Plexiglas chamber, a metal wire 506, a high voltage capacitor 505 with ground connection 504 that may be charged by a high voltage DC power supply 503, and a switch such as a 12 V electric switch 502 and a triggered spark gap switch 501 to close the circuit from the capacitor to the metal wire 506 inside of the chamber 507 to cause the wire to detonate. The chamber may comprise water vapor and a gas such as atmospheric air or a noble gas.

An exemplary system to form macro-aggregates or polymers comprising lower-energy hydrogen species comprises a closed rectangular cuboid Plexiglas chamber having a length of 46 cm and a width and height of 12.7 cm, a 10.2 cm long, 0.22˜0.5 mm diameter metal wire mounted between two stainless poles with stainless nuts at a distance of 9 cm from the chamber floor, a 15 kV capacitor (Westinghouse model 5PH349001AAA, 55 uF) charged to about 4.5 kV corresponding to 557 J, a 35 kV DC power supply to charge the capacitor, and a 12 V switch with a triggered spark gap switch (Information Unlimited, model-Trigatron10, 3 kJ) to close the circuit from the capacitor to the metal wire inside of the chamber to cause the wire to detonate. The wire may comprise a Mo (molybdenum gauze, 20 mesh from 0.305 mm diameter wire, 99.95%, Alpha Aesar), Zn (0.25 mm diameter, 99.993%, Alpha Aesar), Fe—Cr—Al alloy (73%-22%-4.8%, 31 gauge, 0.226 mm diameter, KD Cr—Al—Fe alloy wire Part No #1231201848, Hyndman Industrial Products Inc.), or Ti (0.25 mm diameter, 99.99%, Alpha Aesar) wire. In an exemplary run, the chamber contained air comprising about 20 Torr of water vapor. The high voltage DC power supply was turned off before closing the trigger switch. The peak voltage of about 4.5 kV discharged as a damped harmonic oscillator over about 300 us at a peak current of 5 kA. Macro-aggregates or polymers comprising lower-energy hydrogen species formed in about 3-10 minutes after the wire detonation. Analytical samples were collected from the chamber floor and wall, as well as on a Si wafer placed in the chamber. The analytical results matched the hydrino signatures of the disclosure.

In an embodiment shown in FIG. 12, the hydrino ro-vibrational spectrum is observed by electron-beam excitation of a reaction mixture gas comprising inert gas such as argon gas and water vapor that serves as the source of HOH (OH band 309 nm, O 130.4 nm, H 121.7 nm) catalyst and atomic hydrogen. The argon may be in a pressure range of about 100 Torr to 10 atm. The water vapor may be in the range of about 1 micro-Torr to 10 Torr. The electron beam energy may be in the range of about 1 keV to 100 keV. Rotational lines were observed in the 145-300 nm region from atmospheric pressure argon plasmas comprising about 100 mTorr water vapor excited by a 12 keV to 16 keV electron-beam incident the gas in a chamber through a silicon nitride window. The emission was observed through MgF₂ another window of the reaction gas chamber. The energy spacing of 4² times that of hydrogen established the internuclear distance as ¼ that of H₂ and identified H₂(¼) (Eqs. (29-31)). The series matched the P branch of H₂(¼) for the H₂(¼) vibrational transition v=1→v=0 comprising P(1), P(2), P(3), P(4), and P(5) that were observed at 154.8, 160.0, 165.6, 171.6, and 177.8, respectively. In another embodiment, a composition of matter comprising hydrino such as one of the disclosure is thermally decomposed and the decomposition gas comprising hydrino such as H₂(¼) is introduced into the reaction gas chamber wherein the hydrino gas is excited with the electron beam and the ro-vibrational emission spectrum is recorded.

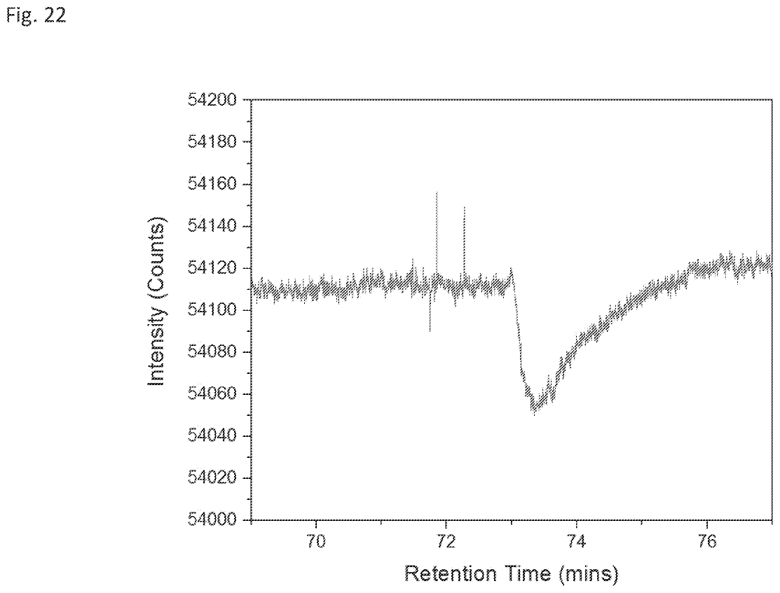

The argon gas was treated with a hot titanium ribbon that removes impurities. The e-beam spectrum was repeated with the purified argon, and the P branch of H₂(¼) was not observed. Raman spectroscopy was performed on the Ti ribbon that was used to remove the H₂(¼) gas, and at peak was observed at 1940 cm⁻¹ that matches the rotational energy of H₂(¼) confirming that it was the source of the series of lines in the 150-180 nm region shown in FIG. 12. The 1940 cm⁻¹ peak matched that shown in FIG. 16. Another confirmation of the presence of molecular hydrino gas in argon was the observation of a negative gas chromatographic peak with hydrogen carrier shown in FIG. 22. The negative peak due to the smaller size, greater mean free path, and higher mobility of molecular hydrino corresponding to a higher thermally conductivity than that of any known gas is characteristic and uniquely confirmatory of molecular hydrino gas.

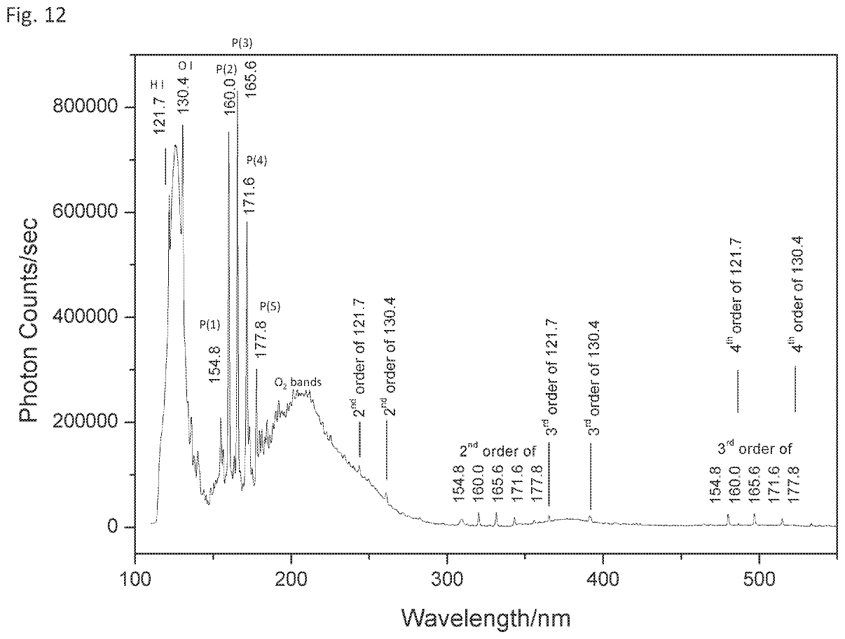

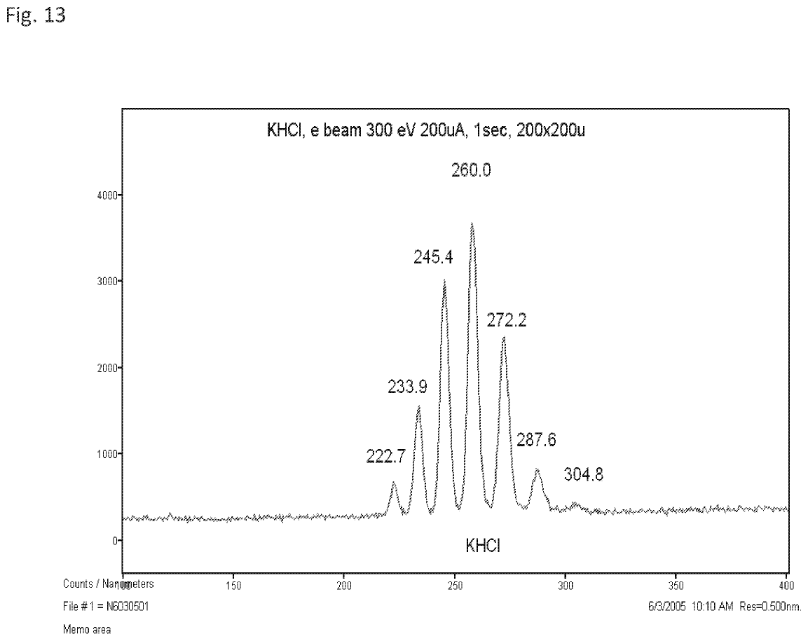

In another embodiment, hydrino gas such as H₂(¼) is absorbed in a getter such as an alkali halide or alkali halide alkali hydroxide matrix. The rotational vibrational spectrum may be observed by electron beam excitation of the getter in vacuum (FIG. 13). The electron beam energy may be in the range of about 1 keV to 100 keV. The rotational energy spacing between peaks may be given by Eq. (30). The vibrational energy given by Eq. (29) may be shifted to lower energy due to a higher effective mass caused by the crystalline matrix. In an exemplary experimental example, ro-vibrational emission of H₂(¼) trapped in the crystalline lattice of getters was excited by an incident 6 KeV electron gun with a beam current of 10-20 μA in at a pressure range of about 5×10⁻⁶ Torr, and recorded by windowless UV spectroscopy. The resolved ro-vibrational spectrum of H₂(¼) (so called 260 nm band) in the UV transparent matrix KCl that served as a getter in a 5 W CIHT cell stack of Mills et al. (R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142 which is incorporated by reference) comprised a peak maximum at 258 nm with representative positions of the peaks at 222.7, 233.9, 245.4, 258.0, 272.2, and 287.6 nm, having an equal spacing of 0.2491 eV. In general, the plot of the energy versus peak number yields a line given by y=−0.249 eV+5.8 eV at R²=0.999 or better in very good agreement with the predicted values for H₂(¼) for the transitions υ=1→υ=0 and Q(0), R(0), R(1), R(2), P(1), P(2), P(3), and P(4) wherein Q(0) is identifiable as the most intense peak of the series.

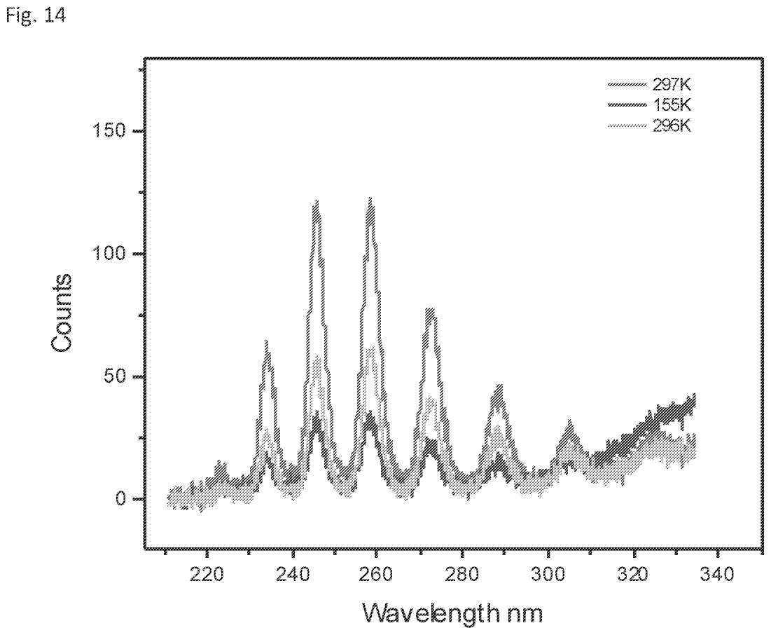

Ro-vibrational excitation bands are de-populated and inhibited from excitation by cooling the sample. Molecular hydrino was formed in a KCl crystal that comprised waters of hydration that served as sources of H and HOH hydrino catalyst. The familiar ro-vibrational emission of H₂ (¼) trapped in the crystalline lattice (260 nm band) was observed by windowless UV spectroscopy (FIG. 14) wherein the pellet sample was excited by an incident 6 KeV electron gun with a beam current of 25 μA. The e-beam pellet sample was thermally cycled from 297 K-155 K-296 K wherein the sample cooling was performed using a cryopump system (Helix Corp., CTI-Cryogenics Model SC compressor; TRI-Research Model T-2000D-IEEE controller; Helix Corp., CTI-Cryogenics model 22 cryodyne). The 0.25 eV-spaced series of peaks reversibly decreased in intensity at the cold temperature with the e-beam current maintained constant. The intensity decrease was due to a change in the 260 nm band emitter since the background in the spectral region above 310 nm actually increased at the cryotemperature. These results confirm that the origin of the emission is due to ro-vibration with a near perfect match to the rotational energy of H₂(¼). It was shown by Mills [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142] that there was no structure to the lines assigned to H₂(¼) using high resolution visible spectroscopy in second order with an accuracy od ±1 Å, further confirming the assign to H₂(¼) ro-vibration.

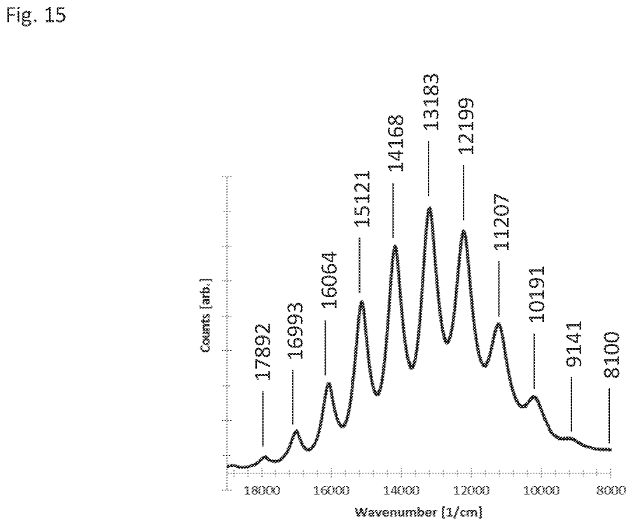

Another successful cross-confirmatory technique in the search for hydrino spectra involved the use of the Raman spectrometer to record the ro-vibration of H₂(¼) as second order fluorescence matching the previously observed first order spectrum in the ultraviolet, the 260 nm e-beam band [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. The Raman spectrum of the KOH:KCl (1:1 wt %) getter of the product gas from 50 sequential argon-atmosphere ignitions of solid fuel pellets, each comprising 100 mg Cu+30 mg deionized water sealed the DSC pan, was recorded using the Horiba Jobin Yvon LabRAM Aramis Raman spectrometer with a HeCd 325 nm laser in microscope mode with a magnification of 40×. No features were observed in the starting material getter. Heating the getter which comprised a hydroxide-halide solid fuel resulted in a low intensity series of 1000 cm⁻¹ (0.1234 eV) equal-energy spaced Raman peaks observed in the 8000 cm⁻¹ to 18,000 cm⁻¹ region. An intense, over an order of magnitude, increase in the series of peaks was observed upon exposure to the ignition product gas. The conversion of the Raman spectrum into the fluorescence or photoluminescence spectrum revealed a match as the second order ro-vibrational spectrum of H₂(¼) corresponding to the 260 nm band first observed by e-beam excitation [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142]. Assigning Q(0) to the most intense peak, the peak assignments given in Table 7 to the Q, R, and P branches for the spectra shown in FIG. 15 are Q(0), R(0), R(1), R(2), R(3), R(4), P(1), P(2), P(3), P(4), and P(5) observed at 13,183, 12,199, 11,207, 10,191, 9141, 8100, 14,168, 15,121, 16,064, 16,993, and 17,892 cm⁻¹, respectively. The theoretical transition energies with peak assignments compared with the observed Raman spectrum are shown in TABLE 4.

TABLE 4
Comparison of the theoretical transition energies and
transition assignments with the observed Raman peaks.

| | Calculated | Experimental | Difference |
|---|---|---|---|
| Assignment | (cm⁻¹ ) | (cm⁻¹) | (%) |
| P(5) | 18,055 | 17,892 | 0.91 |
| P(4) | 17,081 | 16,993 | 0.52 |
| P(3) | 16,107 | 16,064 | 0.27 |
| P(2) | 15,134 | 15,121 | 0.08 |
| P(1) | 14,160 | 14,168 | −0.06 |
| Q(0) | 13,186 | 13,183 | 0.02 |
| R(0) | 12,212 | 12,199 | 0.11 |
| R(1) | 11,239 | 11,207 | 0.28 |
| R(2) | 10,265 | 10,191 | 0.73 |
| R(3) | 9,291 | 9,141 | 1.65 |
| R(4) | 8,318 | 8,100 | 2.69 |

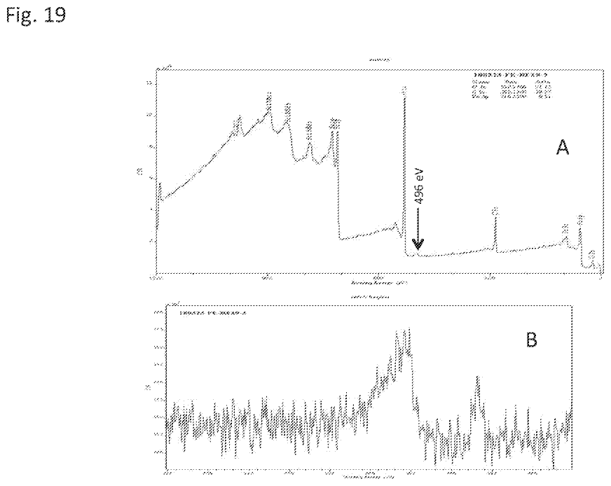

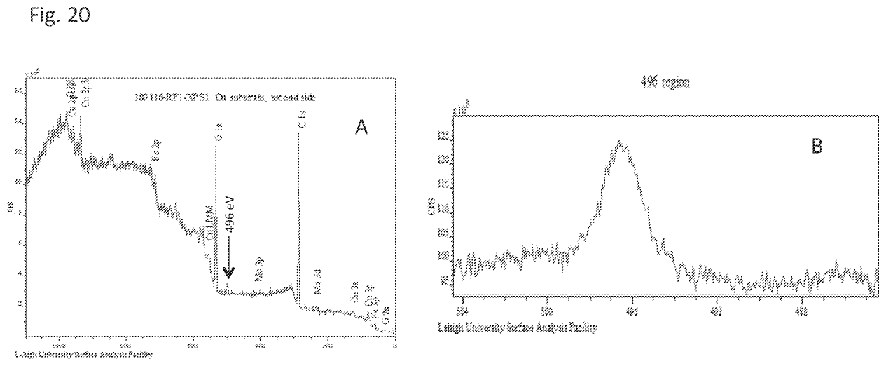

In foil was exposed to the gases from the ignition of the solid fuel comprising 100 mg Cu+30 mg deionized water sealed in the aluminum DSC pan. The predicted hydrino product H₂(¼) was identified by Raman spectroscopy and XPS. Using a Thermo Scientific DXR SmartRaman with a 780 nm diode laser, an absorption peak at 1982 cm⁻¹ having a width of 40 cm⁻¹ was observed (FIG. 16) on the indium metal foil that matched the free space rotational energy of H₂(¼) (0.2414 eV) wherein only O and In were observed present by XPS and no compound of these elements could produce the observed peak. Moreover, the XPS spectrum confirmed the presence of hydrino. Using a Scienta 300 XPS spectrometer, XPS was performed on the In foil sample at Lehigh University. A strong peak was observed at 498.5 eV (FIG. 18) that could not be assigned to any known elements. The peak matched the energy of the theoretically allowed double ionization of molecular hydrino H₂(¼). The 496 eV XPS peak of H₂(¼) was also recorded on polymeric hydrino compounds formed for the wire detonation of Fe and Mo wires in the presence of an argon atmosphere comprising water vapor as shown in FIGS. 19A-B and FIGS. 20A-B, respectively.

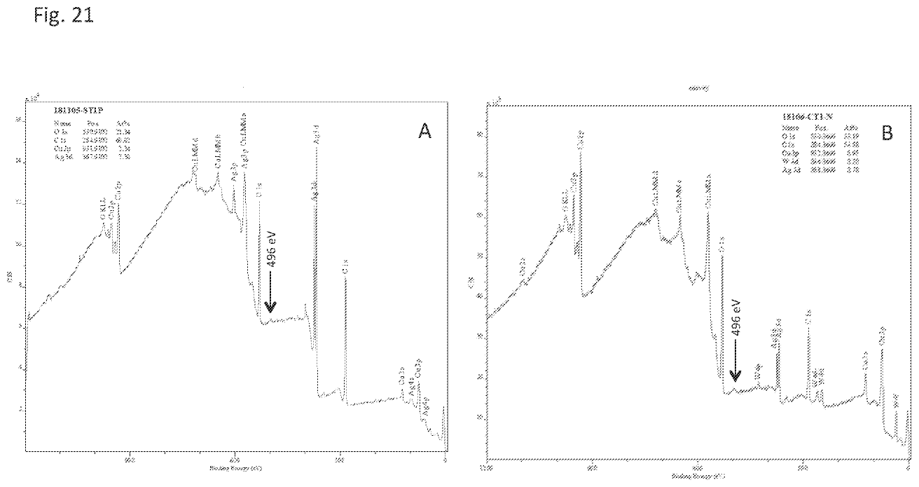

The H₂(¼) rotation energy transition was further confirmed on copper electrodes before and the ignition of 80 mg silver shots comprising 1 mole % H₂O as shown in FIGS. 17A-B. The Raman spectra obtained using the Thermo Scientific DXR SmartRaman spectrometer and the 780 nm laser showed an inverse Raman effect peak at 1940 cm⁻¹ formed by the ignition that matches the free rotor energy of H₂(¼) (0.2414 eV). The peak power of 20 MW was measured on the ignited shots using absolute spectroscopy over the 22.8-647 nm region wherein the optical emission energy was 250 times the applied energy [R. Mills, Y. Lu, R. Frazer, “Power Determination and Hydrino Product Characterization of Ultra-low Field Ignition of Hydrated Silver Shots”, Chinese Journal of Physics, Vol. 56, (2018), pp. 1667-1717, incorporated by reference]. The corresponding XPS spectra on copper electrodes post ignition of a 80 mg silver shot comprising 1 mole % H₂O, wherein the detonation was achieved by applying a 12 V 35,000 A current with a spot welder are shown in FIGS. 21A-B. The peak at 496 eV was assigned to H₂(¼) wherein other possibilities such Na, Sn, and Zn were eliminated since the corresponding peaks of these candidates are absent.

The excitation of the H₂(¼) ro-vibrational spectrum observed in FIG. 15 was deemed to be by the high-energy UV and EUV He and Cd emission of the laser. Overall, the Raman results such as the observation of the 0.241 eV (1940 cm⁻¹) Raman inverse Raman effect peak and the 0.2414 eV-spaced Raman photoluminescence band that matched the 260 nm e-beam spectrum is strong confirmation of molecular hydrino having an internuclear distance that is ¼ that of H₂. The molecular hydrino assignment by Raman spectroscopy, the inverse Raman effect absorption peak centered at 1982 cm⁻¹, as well as the double ionization of molecular hydrino H₂(¼) observed by XPS at 498.5 eV multiply confirm the hydrino product of HOH catalysis of H.

Furthermore, positive ion ToF-SIMS spectra of the getter having absorbed hydrino reaction product gas showed multimer clusters of matrix compounds with di-hydrogen as part of the structure, M:H₂ (M=KOH or K₂CO₃). Specifically, the positive ion spectra of prior hydrino reaction products comprising KOH and K₂CO₃ [R. Mills, X Yu, Y. Lu, G Chu, J. He, J. Lotoski, “Catalyst induced hydrino transition (CIHT) electrochemical cell,” (2012), Int. J. Energy Res., (2013), DOI: 10.1002/er.3142] or having these compounds as getters of hydrino reaction product gas showed K⁺(H₂:KOH)ₙ and K⁺(H₂:K₂CO₃)ₙ consistent with H₂(1/p) as a complex in the structure.

In an embodiment, a composition of matter comprising hydrino such as one of the disclosure is thermally decomposed, and gas chromatography is performed on the decomposition gas comprising hydrino gas such as H₂(¼). Alternatively, hydrino gas may be at least one of formed in situ by maintaining a plasma comprising H₂O such as H₂O in a noble gas such as argon. The plasma may be in a pressure range of about 0.1 mTorr to 1000 Torr. The H₂O plasma may comprise another gas such as a noble gas such as argon. In an exemplary embodiment, atmospheric pressure argon plasma comprising 1 Torr H₂O vapor is maintained with a 6 keV electron beam incident on the gases contained in a sealed vessel wherein the beam traverses a silicon nitride widow. In another embodiment, hydrino gas such as H₂(¼) may be enriched from atmospheric gas by cryro-distillation. In an embodiment, hydrino in argon is obtained by cryro-distillation of argon from atmospheric air. Exemplary results of room temperature gas chromatography (GC) of argon gas on an Agilent column (CP754015, CP-molecular sieve 5 Å, 50 m, 0.32 mm, 30 um, 12.7 cm cage) is shown in FIG. 22. A negative peak was observed at 74 minutes retention time compared to a retention time of 32 minutes for argon wherein the argon peak was positive. Due to the smaller size and greater mean free path H₂(¼) may be more thermally conductive than H₂ carrier gas such that a negative peak is observed. There is no gas known that is more thermally conductive than hydrogen; thus, hydrino H₂(¼) is the only possibility based on the negative peak and the ro-vibrational spectrum shown in FIG. 12. H₂(¼) gas may also be obtained from thermal decomposition of hydrino compounds such as one from the detonation of a Zn or Sn wire in an atmosphere comprise water vapor according to the disclosure. The gas sample may require rapid loading on the GC due to the observed rapid drop in pressure at elevated temperature such as about 800° C. due to the rapid diffusion of the very small H₂(¼) gas from the vacuum tight pressure vessel.

What is claimed is:

1. A power system that generates at least one of electrical energy and thermal energy comprising:
at least one vessel capable of a maintaining a pressure of below, at, or above atmospheric;
reactants, the reactants comprising:
a. at least one source of catalyst or a catalyst comprising nascent H₂O;
b. at least one source of H₂O or H₂O;
c. at least one source of atomic hydrogen or atomic hydrogen; and
d. a molten metal;
a molten metal injector system comprising at least one reservoir that contains some of the molten metal and a molten metal pump with an injector tube that provides a molten metal stream and at least one non-injector reservoir that receives the molten metal stream;
at least one ignition system comprising a source of electrical power to supply electrical power to the at least one steam of molten metal to ignite a plasma;
at least one reactant supply system to replenish reactants that are consumed in a reaction of the reactants to generate at least one of the electrical energy and thermal energy;
at least one power converter or output system of at least one of the light and thermal output to electrical power and/or thermal power.

2. The power system of claim 1 further comprising a heater to melt a metal to comprise the molten metal.

3. The power system of claim 1 further comprising a molten metal recovery system.

4. The power system of claim 1 wherein the molten metal recovery system comprises at least one molten metal overflow channel from the non-injection reservoir to the injector system reservoir that further creates breaks in the molten metal overflow stream to interrupt any current path through the overflowing molten metal.

5. The power system of claim 1 wherein the molten metal recovery system comprises the non-injector reservoir having its inlet to receive molten metal from the injector tube of the injector system at an elevation above the injector tube and further comprising a drip edge to break-up the overflow stream.

6. The power system of claim 5 wherein non-injector reservoir inlet lies in a plane and the plane is aligned perpendicular to the initial direction of the molten metal stream from the injection tube.

7. The power system of claim 6 wherein the non-injector reservoir and the injector tube of the injector system are both aligned along an axis at an angle greater than zero from a horizontal axis that is transverse to the Earth's gravitational axis.

8. The power system of claim 7 wherein the angle is in the range of 25° to 90°.

9. The power system of claim 1 wherein the injector reservoir comprises an electrode in contact with the molten metal therein, and the non-injector reservoir comprises an electrode that makes contact with the molten metal provided by the injector system.

10. The power system of claim 9 wherein the ignition system comprises a source of electrical power to supply opposite voltages to the injector and non-injector reservoir electrodes that supplies current and power flow through the stream of molten metal to cause the reaction of the reactants to form a plasma inside of the vessel.

11. The power system of claim 10 wherein the source of electrical power delivers a high-current electrical energy sufficient to cause the reactants to react to form plasma.

12. The power system of claim 11 wherein the source of electrical power comprises at least one supercapacitor.

13. The power system of claim 1 wherein each electromagnetic pump comprises one of a
a. DC or AC conduction type comprising a DC or AC current source supplied to the molten metal through electrodes and a source of constant or in-phase alternating vector-crossed magnetic field, or
b. induction type comprising a source of alternating magnetic field through a shorted loop of molten metal that induces an alternating current in the metal and a source of in-phase alternating vector-crossed magnetic field.

14. The power system of claim 1 wherein a current from the molten metal ignition system power is in the range of 10 A to 50,000 A.

15. The power system of claim 14 wherein the circuit of the molten metal ignition system is closed by the molten metal stream to cause ignition to further cause an ignition frequency in the range of 0 Hz to 10,000 Hz.

16. The power system of claim 1 wherein the molten metal comprises at least one of silver, silver-copper alloy, and copper.

17. The power system of claim 1 wherein the molten metal has a melting point below 700° C.

18. The power system of claim 17 wherein the molten metal comprises at least one of bismuth, lead, tin, indium, cadmium, gallium, antimony, or alloys such as Rose's metal, Cerrosafe, Wood's metal, Field's metal, Cerrolow 136, Cerrolow 117, Bi—Pb—Sn—Cd—In-T1, and Galinstan.

19. The power system of claim 1 further comprising a vacuum pump and at least one heat exchanger.

20. The power system of claim 1 wherein at least one reservoir comprises boron nitride.

21. The power system of claim 1 wherein the reactants comprise a vessel gas comprising at least one of hydrogen, oxygen, and water.

22. The power system of claim 21 wherein the vessel gas further comprises an inert gas.

23. The power system of claim 22 further comprising a reactants supply and an inert gas supply wherein the supplies maintain the vessel gas at a pressure in the range of 0.01 Torr to 200 atm.

24. The power system of claim 1 wherein the at least one power converter or output system of the reaction power output comprises at least one of the group of a thermophotovoltaic converter, a photovoltaic converter, a photoelectronic converter, a magnetohydrodynamic converter, a plasmadynamic converter, a thermionic converter, a thermoelectric converter, a Sterling engine, a supercritical CO₂ cycle converter, a Brayton cycle converter, an external-combustor type Brayton cycle engine or converter, a Rankine cycle engine or converter, an organic Rankine cycle converter, an internal-combustion type engine, and a heat engine, a heater, and a boiler.

25. The power system of claim 1 wherein the vessel comprises a light transparent photovoltaic (PV) window to transmit light from the inside of the vessel to a photovoltaic converter and at least one of a vessel geometry and at least one baffle to cause a pressure gradient to at least partially prevent the molten metal from coating the PV window.

26. The power system of claim 1 wherein the vessel geometry comprises a decreasing cross sectional area towards the PV window.

27. The power system of claim 24 comprising concentrator photovoltaic cells that comprise at least one compound chosen from crystalline silicon, germanium, gallium arsenide (GaAs), gallium antimonide (GaSb), indium gallium arsenide (InGaAs), indium gallium arsenide antimonide (InGaAsSb), indium phosphide arsenide antimonide (InPAsSb), InGaP/InGaAs/Ge; InAlGaP/AlGaAs/GaInNAsSb/Ge, GaInP/GaAsP/SiGe; GaInP/GaAsP/Si, GaInP/GaAsP/Ge; GaInP/GaAsP/Si/SiGe; GaInP/GaAs/InGaAs; GaInP/GaAs/GaInNAs; GaInP/GaAs/InGaAs/InGaAs; GaInP/Ga(In)As/InGaAs; GaInP-GaAs-wafer-InGaAs; GaInP—Ga(In)As—Ge; GaInP—GaInAs—Ge; a Group III nitride; GaN; AlN; GaAlN, and InGaN.

28. The power system of claim 24 wherein the magnetohydrodynamic power converter comprises a nozzle connected to the reaction vessel, a magnetohydrodynamic channel, electrodes, magnets, a metal collection system, a metal recirculation system, a heat exchanger, and optionally a gas recirculation system.

29. The power system of claim 1 or 28 wherein at least one component of the power system comprises at least one of a ceramic and a metal.

30. The power system of claim 29 wherein the ceramic comprises at least one of a metal oxide, alumina, zirconia, magnesia, hafnia, silicon carbide, zirconium carbide, zirconium diboride, silicon nitride, and a glass ceramic.

31. The power system of claim 29 wherein the metal comprises at least one of a stainless steel and a refractory metal.

32. The power system of claim 28 wherein the molten metal comprises silver and the magnetohydrodynamic converter further comprises a source of oxygen to form silver particles nanoparticles and accelerate the nanoparticles through magnetohydrodynamic nozzle to impart a kinetic energy inventory of the power produced in the vessel.

33. The power system of claim 32 wherein the reactants supply system additionally supplies and controls the source of oxygen to form the silver nanoparticles.

34. The power system of claim 32 wherein at least a portion of the kinetic energy inventory of the silver nanoparticles is converted to electrical energy in the magnetohydrodynamic channel, the nanoparticles coalesce as molten metal in the metal collection system, the molten metal at least partially absorbs the oxygen, the metal comprising absorbed oxygen is returned to the injector reservoir by the metal recirculation system, and the oxygen is released by the plasma in the vessel.

35. The power system of claim 34 wherein plasma is maintained in the magnetohydrodynamic channel and metal collection system to enhance the absorption of the oxygen by the molten metal.

36. The power system of claims 13 and 28 wherein the electromagnetic pump comprises a two-stage pump comprising a first stage that comprises a pump of the metal recirculation system, and a second stage that comprises the pump of the metal injector system.

37. The power system of claim 1 wherein the hydrogen product formed by reaction of the atomic hydrogen and catalyst comprises at least one of the following products:
a. a hydrogen product with a Raman peak at 1900 to 2000 cm⁻¹;
b. a hydrogen product with a plurality of Raman peaks spaced at an integer multiple of 0.23 to 0.25 eV;
c. a hydrogen product with an infrared peak at 1900 to 2000 cm⁻¹;
d. a hydrogen product with a plurality of infrared peaks spaced at an integer multiple of 0.23 to 0.25 eV;
e. a hydrogen product with at a plurality of UV fluorescence emission spectral peaks in the range of 200 to 300 inn having a spacing at an integer multiple of 0.23 to 0.3 eV;
f. a hydrogen product with a plurality of electron-beam emission spectral peaks in the range of 200 to 300 nm having a spacing at an integer multiple of 0.2 to 0.3 eV;
g. a hydrogen product with a plurality of Raman spectral peaks in the range of 5000 to 20,000 cm⁻¹ having a spacing at an integer multiple of 1000±200 cm⁻¹;
h. a hydrogen product with a X-ray photoelectron spectroscopy peak at an energy in the range of 490 to 525 eV;
i. a hydrogen product that causes an upfield MAS NMR matrix shift;
j. a hydrogen product that has an upfield MAS NMR or liquid NMR shift of greater than −5 ppm relative to TMS;
k. a hydrogen product comprising macro-aggregates or polymers Hₙ (n is an integer greater than 3);
l. a hydrogen product comprising macro-aggregates or polymers EL (n is an integer greater than 3) having a time of flight secondary ion mass spectroscopy (ToF-SIMS) peak of 16.12 to 16.13;
m. a hydrogen product comprising a metal hydride wherein the metal comprises at least one of Zn, Fe, Mo, Cr, Cu, and W;
n. a hydrogen product comprising at least one of H₁₆ and H₂₄;
o. a hydrogen product comprising an inorganic compound MₓX_{y} and H₂ wherein M is a cation and X in an anion having at least one of electrospray ionization time of flight secondary ion mass spectroscopy (ESI-ToF) and time of flight secondary ion mass spectroscopy (ToF-SIMS) peaks of M(MₓX_{y}H₂)n wherein n is an integer;
p. a hydrogen product comprising at least one of K₂CO₃H₂ and KOHH₂ having at least one of electrospray ionization time of flight secondary ion mass spectroscopy (ESI-ToF) and time of flight secondary ion mass spectroscopy (ToF-SIMS) peaks of K(K₂H₂CO₃)ₙ⁺ and K(KOHH₂)ₙ⁺, respectively;
q. a magnetic hydrogen product comprising a metal hydride wherein the metal comprises at least one of Zn, Fe, Mo, Cr, Cu, W, and a diamagnetic metal;
r. a hydrogen product comprising a metal hydride wherein the metal comprises at least one of Zn, Fe, Mo, Cr, Cu, W, and a diamagnetic metal that demonstrates magnetism by magnetic susceptometry;
s. a hydrogen product comprising a metal that is not active in electron paramagnetic resonance (EPR) spectroscopy wherein the EPR spectrum comprises at least one of very high g factors, very low g factors, extraordinary line width, and proton splitting;
t. a hydrogen product comprising a hydrogen molecular dimer wherein the EPR spectrum shows at least one peak at 2800-3100 G and ΔH of 10 G to 500 G;
u. a hydrogen product comprising a gas having a negative gas chromatography peak with hydrogen carrier;
v. a hydrogen product having a quadrupole moment/e of
$$\frac{1.70127 {a}_{0}^{2}}{{p}^{2}} \pm 10 \%$$
wherein p is an integer;
w. a protonic hydrogen product comprising a molecular dimer having an end over end rotational energy for the integer J to J+1 transition in the range of (J+1) 44.30 cm⁻¹±20 cm⁻¹ wherein the corresponding rotational energy of the molecular dimer comprising deuterium is ½ that of the dimer comprising protons;
x. a hydrogen product comprising molecular dimers having at leak one parameter from the group of (i) a separation distance of hydrogen molecules of 1.028 Å±10%, (ii) a vibrational energy between hydrogen molecules of 23 cm⁻¹±10%, and (iii) a van der Waals energy between hydrogen molecules of 0.0011 eV±10%;
y. a hydrogen product comprising a solid having at least one parameter from the group of (i) a separation distance of hydrogen molecules of 1.028 Å±10%, (ii) a vibrational energy between hydrogen molecules of 23 cm⁻¹±10% and (iii) a van der Waals energy between hydrogen molecules of 0.019 eV±10%;
z, a hydrogen product having at least one of
1. FTIR and Raman spectral signatures of (i) (J+1) 44.30 cm⁻¹±20 cm⁻¹, (ii) (J+1) 22.15 cm⁻¹±10 cm⁻¹ and (iii) 23 cm⁻¹±10%;
2. an X-ray or neutron diffraction pattern showing a hydrogen molecule separation of 1.028 Å±10%, and
3. a calorimetric determination of the energy of vaporization of 0.0011 eV±10% per molecular hydrogen;
aa. a solid hydrogen product having at least one of
1. FTIR and Raman spectral signatures of (i) (0.1+1) 44.30 cm⁻¹±20 cm⁻¹, (ii) (J+1) 22.15 cm⁻¹±10 cm⁻¹ and (iii) 23 cm⁻¹+10%;
2. an X-ray or neutron diffraction pattern showing a hydrogen molecule separation of 1.028 Å±10%, and
3. a calorimetric determination of the energy of vaporization of 0.019 eV±10% per molecular hydrogen.

38. The power system of claim 1 wherein the hydrogen product formed by reaction of the atomic hydrogen and catalyst comprises at least one of H(¼) and H₂(¼) wherein the hydrogen product has at least one of the following:
a. the hydrogen product has a Fourier transform infrared spectrum (FTIR) comprising at least one of the H₂(¼) rotational energy at 1940 cm⁻¹±10% and libation bands in the finger print region wherein other high energy features are absent;
b. the hydrogen product has a proton magic-angle spinning nuclear magnetic resonance spectrum (¹H MAS NMR) comprising an upfield matrix peak;
c. the hydrogen product has a thermal gravimetric analysis (TGA) result showing the decomposition of at least one of a metal hydride and a hydrogen polymer in the temperature region of 100° C.; to 1000° C.;
d. the hydrogen product has an e-beam excitation emission spectrum comprising the H₂(¼) ro-vibrational band in the 260 nm region comprising a plurality of peaks spaced at 0.23 eV to 0.3 eV from each other;
e. the hydrogen product has an e-beam excitation emission spectrum comprising the H₂(¼) ro-vibrational band in the 260 nm region comprising a plurality of peaks spaced at 0.23 eV to 0.3 eV from each other wherein the peaks decrease in intensity at cryo-temperatures in the range of 0 K to 150 K;
f. the hydrogen product has a photoluminescence Raman spectrum comprising the second order of the H₂(¼) ro-vibrational band in the 260 nm region comprising a plurality of peaks spaced at 0.23 eV to 0.3 eV from each other;
g. the hydrogen product has a photoluminescence Raman spectrum comprising the second order of the H₂(¼) ro-vibrational band comprising a plurality of peaks in the range of 5000 to 20,000 cm⁻¹ having a spacing at an integer multiple of 1000±200 cm⁻¹;
h. the hydrogen product has a Raman spectrum comprising the H₂(¼) rotational peak at 1940 cm⁻¹±10%;
i. the hydrogen product has an X-ray photoelectron spectrum (XPS) comprising the total energy of H₂(¼) at 490-500 eV;
j. the hydrogen product comprises macro-aggregates or polymers H(¼)ₙ (n is an integer greater than 3);
k. the hydrogen product comprises macro-aggregates or polymers H(¼)ₙ (n is an integer greater than 3) having a time of flight secondary ion mass spectroscopy (ToF-SIMS) peak of 16.12 to 16.13;
l. the hydrogen product comprises a metal hydride wherein the metal comprises at least one of Zn, Fe, Mo, Cr, Cu, and W and the hydrogen comprises H(¼);
m. the hydrogen product comprises at least one of H(¼)₁₆ and H(¼)₂₄;
n. the hydrogen product comprises an inorganic compound MₓX_{y} and H(¼)₂ wherein M is a cation and X is an anion and at least one of the electrospray ionization time of flight secondary ion mass spectrum (ESI-ToF and the time of flight secondary ion mass spectrum (ToF-SIMS) comprises peaks of M(MₓX_{y}H(¼)₂)n wherein n is an integer;
o. the hydrogen product comprises at least one of K₂CO₃H(¼)₂ and KOHH(¼)₂ and at least one of the electrospray ionization time of flight secondary ion mass spectrum (ESI-ToF) and the time of flight secondary ion mass spectrum (ToF-SIMS) comprises peaks of K(K₂H₂CO₃)ₙ⁺ and K(KOHH₂)ₙ⁺, respectively;
p. the hydrogen product is magnetic and comprises a metal hydride wherein the metal comprises at least one of Zn; Fe, Mo, Cr, Cu and a diamagnetic metal, and the hydrogen is H(¼);
q. the hydrogen product comprises a metal hydride wherein the metal comprises at least one of Zn, Fe, Mo, Cr, Cu, W, and a diamagnetic metal and H is H(¼) wherein the product demonstrates magnetism by magnetic susceptometry;
r. the hydrogen product comprises a metal that is not active in electron paramagnetic resonance (EPR) spectroscopy wherein the EPR spectrum shows at least one peak at 2800-3100 G and ΔH of 10 to 500 G;
s. the hydrogen product comprises a [H₂(¼)]₂ wherein the EPR spectrum shows at least one peak at 2800-3100 G and ΔH of 10 G to 500 G;
t. the hydrogen product comprises or releases H₂(¼) gas having a negative gas chromatography peak with hydrogen carrier;
u. the hydrogen product comprises H₂(¼) having a quadrupole moment/e of
$$\frac{1.70127 {a}_{0}^{2}}{{4}^{2}} \pm 10 ;$$
v. the hydrogen product comprises [H₂(¼)]₂ or [D₂(¼)]₂ having an end over end rotational energy for the integer J to J+1 transition in the range of (J+1) 44.30 cm⁻¹±20 cm⁻¹ and (J+1) 22.15 cm⁻¹±10 cm⁻¹, respectively;
w. the hydrogen product comprising [H₂(¼)]₂ having at least one parameter from the group of (i) a separation distance of H₂(¼) molecules of 1.028 Å±10%, (ii) a vibrational energy between H₂(¼) molecules of 23 cm⁻¹±10%, and (iii) a van der Waals energy between H₂(¼) molecules of 0.0011 eV±10%, and
x. the hydrogen product comprising a solid of H₂(¼) molecules having at least one parameter from the group of (i) a separation distance of H₂(¼) molecules of 1.028 Å±10%, (ii) a vibrational energy between H₂(¼) molecules of 23 cm⁻¹±10%, and (iii) a van der Waals energy between H₂(¼) molecules of 0.019 eV±10%;
y. the [H₂(¼)]₂ product having at least one of
1. FTIR and Raman spectral signatures of (i) (J+1) 44.30 cm⁻¹±20 cm⁻¹, (ii) (J+1) 22.15 cm⁻¹±10 cm and (iii) 23 cm⁻¹±10%;
2. an X-ray or neutron diffraction pattern showing a H₂(¼) molecule separation of 1.028 Å±10%, and
3. a calorimetric determination of the energy of vaporization of 0.0011 eV±10% per H₂(¼), and
z. the solid H₂(¼) product having at least one of
1. FTIR and Raman spectral signatures of (i) (J+1) 44.30 cm⁻¹±20 cm⁻¹, (ii) (J+1) 22.15 cm⁻¹±10 cm⁻¹ and (iii) 23 cm⁻¹±10%;
2. an X-ray or neutron diffraction pattern showing a hydrogen molecule separation of 1.028 Å±10%, and
3. a calorimetric determination of the energy of vaporization of 0.019 eV±10% per H₂(¼).

39. The power system of claim 37 wherein the hydrogen product formed by reaction of the atomic hydrogen and catalyst comprises at least one of a hydrino species selected from the group of H(1/p), H₂(1/p), and H⁻(1/p) alone or complexed with at least one of (i) an element other than hydrogen, (ii) an ordinary hydrogen species comprising at least one of H⁺, ordinary H₂, ordinary and ordinary H₃⁺; an organic molecular species, and (iv) an inorganic species.

40. The power system of claim 37 wherein the hydrogen product formed by reaction of the atomic hydrogen and catalyst comprises an oxyanion compound.

41. The power system of claim 37 wherein the hydrogen product formed by reaction of the atomic hydrogen and catalyst comprises at least one compound having the formula selected from the group of:
a. MH, MH₂, or M₂H₂, wherein M is an alkali cation and H is a hydrino species;
b. MHₙ wherein n is 1 or 2, M is an alkaline earth cation and H is hydrino species;
c. MHX wherein M is an alkali cation, X is one of a neutral atom such as halogen atom, a molecule, or a singly negatively charged anion such as halogen anion, and H is a hydrino species;
d. MHX wherein M is an alkaline earth cation, X is a singly negatively charged anion, and H is H is a hydrino species;
e. MHX wherein M is an alkaline earth cation, X is a double negatively charged anion, and H is a hydrino species;
f. M₂HX wherein M is an alkali cation, X is a singly negatively charged anion, and H is a hydrino species;
g. MHₙ wherein n is an integer, M is an alkaline cation and the hydrogen content Hₙ of the compound comprises at least one hydrino species;
h. M₂Hₙ wherein n is an integer, M is an alkaline earth cation and the hydrogen content Hₙ of the compound comprises at least one hydrino species;
i. M₂XHₙ wherein n is an integer, M is an alkaline earth cation, X is a singly negatively charged anion, and the hydrogen content Hₙ of the compound comprises at least one hydrino species;
j. M₂X₂Hₙ wherein n is 1 or 2, M is an alkaline earth cation, X is a singly negatively charged anion, and the hydrogen content Hₙ of the compound comprises at least one hydrino species;
k. M₂X₃H wherein M is an alkaline earth cation, X is a singly negatively charged anion, and H is a hydrino species;
l. M₂XHₙ wherein n is 1 or 2, M is an alkaline earth cation, X is a double negatively charged anion, and the hydrogen content Hₙ of the compound comprises at least one hydrino species;
m. M₂XX′H wherein M is an alkaline earth cation, X is a singly negatively charged anion, X′ is a double negatively charged anion, and H is hydrino species;
n. MM′Hₙ wherein n is an integer from 1 to 3, M is an alkaline earth cation, M′ is an alkali metal cation and the hydrogen content Hₙ of the compound comprises at least one hydrino species;
o. MM′XHₙ wherein n is 1 or 2, M is an alkaline earth cation, M′ is an alkali metal cation, X is a singly negatively charged anion and the hydrogen content Hₙ of the compound comprises at least one hydrino species;
p. MM′XH wherein M is an alkaline earth cation, M′ is an alkali metal cation, X is a double negatively charged anion and H is a hydrino species;
q. MM′XX′H wherein M is an alkaline earth cation, M′ is an alkali metal cation, X and X′ are singly negatively charged anion and H is a hydrino species;
r. MXX′Hₙ wherein n is an integer from 1 to 5, M is an alkali or alkaline earth cation, X is a singly or double negatively charged anion; X′ is a metal or metalloid, a transition element, an inner transition element, or a rare earth element, and the hydrogen content Hₙ of the compound comprises at least one hydrino species;
s. MHₙ wherein n is an integer, M is a cation such as a transition element, an inner transition element; or a rare earth element, and the hydrogen content Hₙ of the compound comprises at least one hydrino species;
t. MXHₙ wherein n is an integer, M is an cation such as an alkali cation, alkaline earth cation, X is another cation such as a transition element, inner transition element, or a rare earth element cation, and the hydrogen content Hₙ of the compound comprises at least one hydrino species;
u. (MHₘMCO₃) wherein M is an alkali cation or other +1 cation, in and n are each an integer, and the hydrogen content Hₘ of the compound comprises at least one hydrino species;
v. (MHₘMNO₃)ₙ⁺X⁻ wherein M is an alkali cation or other +1 cation, m and n are each an integer, X is a singly negatively charged anion, and the hydrogen content Hₘ of the compound comprises at least one hydrino species;
w. (MHMNO₃)ₙ wherein M is an alkali cation or other +1 cation, n is an integer and the hydrogen content H of the compound comprises at least one hydrino species;
x. (MHMOH)ₙ wherein M is an alkali cation or other +1 cation, n is an integer, and the hydrogen content H of the compound comprises at least one hydrino species;
y. (MHₘM′X)ₙ wherein m and n are each an integer, M and M′ are each an alkali or alkaline earth cation, X is a singly or double negatively charged anion, and the hydrogen content Hₘ of the compound comprises at least one hydrino species, and
z. (MHₘM′X′)ₙ⁺nX⁻ wherein m and n are each an integer, M and M′ are each an alkali or alkaline earth cation, X and X′ are a singly or double negatively charged anion, and the hydrogen content Hₘ of the compound comprises at least one hydrino species.

42. The power system of claim 41 wherein the anion of hydrogen compound product formed by reaction of the atomic hydrogen and catalyst comprises at least one or more singly negatively charged anions, halide ion, hydroxide ion, hydrogen carbonate ion, nitrate ion, double negatively charged anions, are carbonate ion, oxide, and sulfate ion.

43. The power system of claim 42 wherein the hydrogen product formed by reaction of the atomic hydrogen and catalyst comprises at least one hydrino species embedded in a crystalline lattice.

44. The power system of claim 43 wherein the compound comprises least one of H(1/p), H₂(1/p), and H⁻(1/p) embedded in a salt lattice.

45. The power system of claim 44 wherein the salt lattice comprises at east one of an alkali salt, an alkali halide, an alkali hydroxide, alkaline earth salt, an alkaline earth halide, and an alkaline earth hydroxide.

46. An electrode system comprising:
a. a first electrode and a second electrode;
b. a stream of molten metal (e.g., molten silver, molten gallium, etc.) in electrical contact with said first and second electrodes;
c. a circulation system comprising a pump to draw said molten metal from a reservoir and convey it through a conduit (e.g., a tube) to produce said stream of molten metal exiting said conduit;
d. a source of electrical power configured to provide an electrical potential difference between said first and second electrodes;
wherein said stream of molten metal is in simultaneous contact with said first and second electrodes to create an electrical current between said electrodes.

47. The electrode system according to claim 1, wherein said electrical power is sufficient to create an arc current.

48. An electrical circuit comprising:
a. a heating means for producing molten metal;
b. a pumping means for conveying said molten metal from a reservoir through a conduit to produce a stream of said molten metal exiting said conduit;
c. a first electrode and a second electrode in electrical communication with a power supply means for creating an electrical potential difference across said first and second electrode;
wherein said stream of molten metal is in simultaneous contact with said first and second electrodes to create an electrical circuit between said first and second electrodes.

49. In an electrical circuit comprising a first and second electrode, the improvement comprising passing a stream of molten metal across said electrodes to permit a current to flow there between.
